(19) United States
(12) Patent Application Publication
(10) Pub. No.: US 2015/0069355 A1
(43) Pub. Date: Mar. 12, 2015

(54) CONDENSED COMPOUND AND ORGANIC LIGHT-EMITTING DIODE INCLUDING THE SAME

(71) Applicant: SAMSUNG DISPLAY CO., LTD., Yongin-City (KR)

(72) Inventors: Seok-Hwan HWANG, Yongin-City (KR); Young-Kook KIM, Yongin-City (KR); Jun-Ha PARK, Yongin-City (KR); Hye-Jin JUNG, Yongin-City (KR); Jin-O LIM, Yongin-City (KR); Eun-Young LEE, Yongin-City (KR); Jong-Woo KIM, Yongin-City (KR); Sang-Hyun HAN, Yongin-City (KR); Kwang-Hyun KIM, Yongin-City (KR); Eun-Jae JEONG, Yongin-City (KR); Soo-Yon KIM, Yongin-City (KR)

(21) Appl. No.: 14/447,333

(22) Filed: Jul. 30, 2014

(30) Foreign Application Priority Data
Aug. 30, 2013 (KR) 10-2013-0104401

(51) Int. Cl. H01L 51/00

(52) U.S. Cl. CPC H01L 51/0058; H01L 51/0072; H01L 51/0052; H01L 51/0073; H01L 51/0067; H01L 51/0074; H01L 51/5056
USPC 257/40; 548/444; 549/460; 546/256; 546/276.7; 544/180; 549/43

(57) ABSTRACT

Provided are a condensed compound and an organic light-emitting diode including the same, the condensed compound being represented by Formula 1 or 2:

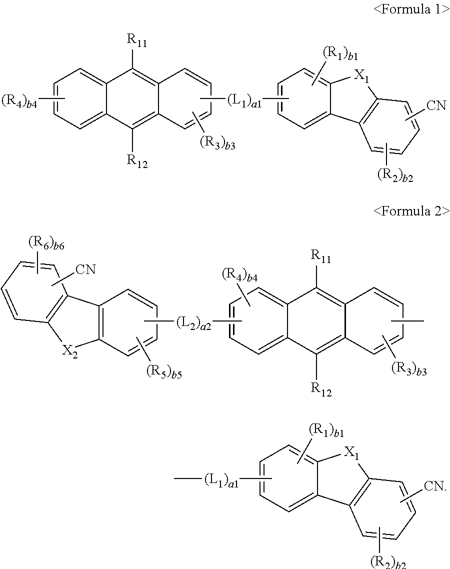

### CROSS-REFERENCE TO RELATED APPLICATION

Korean Patent Application No. 10-2013-0104401, filed on Aug. 30, 2013, in the Korean Intellectual Property Office, and entitled: “Condensed Compound and Organic Light-emitting Diode Including The Same,” is incorporated by reference herein in its entirety.

### BACKGROUND

1. Field

One or more embodiments relate to a condensed compound and an organic light-emitting diode including the same.

2. Description of the Related Art

Organic light emitting diodes are self-emission diodes that may have wide viewing angles, a high contrast ratio, short response times, and excellent brightness, driving voltage, and response speed characteristics, and produce full-color images.

### SUMMARY

Embodiments may be realized by providing a condensed compound for an organic light-emitting diode, the condensed compound being represented by Formula 1 or 2:

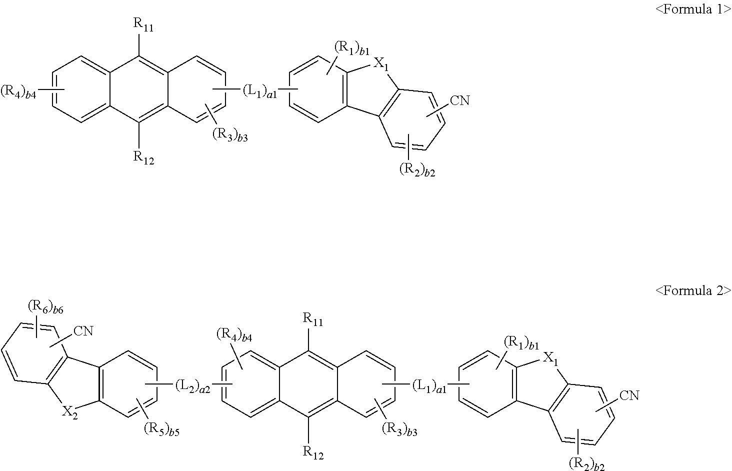

wherein:

X₁ is N(R₂₁), O, or S;

X₂ is N(R₂₂), O, or S;

L₁ and L₂ are each independently selected from a substituted or unsubstituted C₃-C₁₀ cycloalkylene group, a substituted or unsubstituted C₂-C₁₀ heterocycloalkylene group, a substituted or unsubstituted C₃-C₁₀ cycloalkenylene group, a substituted or unsubstituted C₂-C₁₀ heterocycloalkenylene group, a substituted or unsubstituted C₆-C₆₀ arylene group, a substituted or unsubstituted C₂-C₆₀ heteroarylene group, a substituted or unsubstituted divalent non-aromatic condensed polycyclic group, and a substituted or unsubstituted divalent non-aromatic hetero-condensed polycyclic group;

a1 and a2 are each independently selected from 0, 1, 2, and 3;

R₁ to R₆, R₁₁, R₁₂, R₂₁, and R₂₂ are each independently selected from a hydrogen, a deuterium, —F, —Cl, —Br, —I, a hydroxyl group, a cyano group, a nitro group, an amino group, an amidino group, a hydrazine group, a hydrazone group, a carboxylic acid and a salt thereof, a sulfonic acid and a salt thereof, a phosphoric acid and a salt thereof, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₃-C₁₀ cycloalkyl group, a substituted or unsubstituted C₂-C₁₀ heterocycloalkyl group, a substituted or unsubstituted C₃-C₁₀ cycloalkenyl group, a substituted or unsubstituted C₂-C₁₀ heterocycloalkenyl group, a substituted or unsubstituted C₆-C₆₀ aryl group, a substituted or unsubstituted C₆-C₆₀ aryloxy group, a substituted or unsubstituted C₆-C₆₀ arylthio group, a substituted or unsubstituted C₂-C₆₀ heteroaryl group, a substituted or unsubstituted monovalent non-aromatic condensed polycyclic group, a substituted or unsubstituted monovalent non-aromatic hetero-condensed polycyclic group, —N(Q₁)(Q₂), —Si(Q₃)(Q₄)(Q₅), and —B(Q₆)(Q₇);

b1 to b6 are each independently selected from 0, 1, 2, and 3;

at least one substitutent of the substituted C₃-C₁₀ cycloalkylene, the substituted C₂-C₁₀ heterocycloalkylene, the substituted C₃-C₁₀ cycloalkenylene, the substituted C₂-C₁₀ heterocycloalkenylene, the substituted C₆-C₆₀ arylene, the substituted C₂-C₆₀ heteroarylene, the substituted divalent non-aromatic condensed polycyclic group, the substituted divalent non-aromatic hetero-condensed polycyclic group, the substituted C₁-C₆₀ alkyl, the substituted C₂-C₆₀ alkenyl, the substituted C₂-C₆₀ alkynyl, the substituted C₁-C₆₀ alkoxy, the substituted C₃-C₁₀ cycloalkyl, the substituted C₂-C₁₀ heterocycloalkyl, the substituted C₃-C₁₀ cycloalkenyl, the substituted C₂-C₁₀ heterocycloalkenyl, the substituted C₆-C₆₀ aryl, the substituted C₆-C₆₀ aryloxy, the substituted C₆-C₆₀ arylthio, the substituted C₂-C₆₀ heteroaryl, the substituted monovalent non-aromatic condensed polycyclic group, and the substituted monovalent non-aromatic hetero-condensed polycyclic group is selected from

a deuterium, —F, —Cl, —Br, —I, a hydroxyl group, a cyano group, a nitro group, an amino group, an amidino group, a hydrazine group, a hydrazone group, a carboxylic acid and a salt thereof, a sulfonic acid and a salt thereof, a phosphoric acid and a salt thereof, a C₁-C₆₀ alkyl group, a C₂-C₆₀ alkenyl group, a C₂-C₆₀ alkynyl group, and a C₁-C₆₀ alkoxy group;

a C₁-C₆₀ alkyl group, a C₂-C₆₀ alkenyl group, a C₂-C₆₀ alkynyl group, and a C₁-C₆₀ alkoxy group, each substituted with at least one selected from a deuterium, —F, —Cl, —Br, —I, a hydroxyl group, a cyano group, a nitro group, an amino group, an amidino group, a hydrazine group, a hydrazone group, a carboxylic acid and a salt thereof, a sulfonic acid and a salt thereof, a phosphoric acid and a salt thereof, a C₃-C₁₀ cycloalkyl group, a C₂-C₁₀ heterocycloalkyl group, a C₃-C₁₀ cycloalkenyl group, a C₂-C₁₀ heterocycloalkenyl group, a C₆-C₆₀ aryl, a C₆-C₆₀ aryloxy group, a C₆-C₆₀ arylthio group, a C₂-C₆₀ heteroaryl group, a monovalent non-aromatic condensed polycyclic group, a monovalent non-aromatic hetero-condensed polycyclic group, —N(Q₁₁)(Q₁₂), —Si(Q₁₃)(Q₁₄)(Q₁₅), and —B(Q₁₆)(Q₁₇);

a C₃-C₁₀ cycloalkyl group, a C₂-C₁₀ heterocycloalkyl group, a C₃-C₁₀ cycloalkenyl group, a C₂-C₁₀ heterocycloalkenyl group, a C₆-C₆₀ aryl group, a C₆-C₆₀ aryloxy group, a C₆-C₆₀ arylthio group, a C₂-C₆₀ heteroaryl group, a monovalent non-aromatic condensed polycyclic group, and a monovalent non-aromatic hetero-condensed polycyclic group;

a C₃-C₁₀ cycloalkyl group, a C₂-C₁₀ heterocycloalkyl group, a C₃-C₁₀ cycloalkenyl group, a C₂-C₁₀ heterocycloalkenyl group, a C₆-C₆₀ aryl group, a C₆-C₆₀ aryloxy group, a C₆-C₆₀ arylthio group, a C₂-C₆₀ heteroaryl group, a monovalent non-aromatic condensed polycyclic group, and a monovalent non-aromatic hetero-condensed polycyclic group, each substituted with at least one selected from a deuterium, —F, —Cl, —Br, —I, a hydroxyl group, a cyano group, a nitro group, an amino group, an amidino group, a hydrazine group, a hydrazone group, a carboxylic acid and a salt thereof, a sulfonic acid and a salt thereof, a phosphoric acid and a salt thereof, a C₁-C₆₀ alkyl group, a C₂-C₆₀ alkenyl group, a C₂-C₆₀ alkynyl group, a C₁-C₆₀ alkoxy group, a C₃-C₁₀ cycloalkyl group, a C₂-C₁₀ heterocycloalkyl group, a C₃-C₁₀ cycloalkenyl group, a C₂-C₁₀ heterocycloalkenyl group, a C₆-C₆₀ group, aryl group, a C₆-C₆₀ aryloxy group, a C₆-C₆₀ arylthio group, a C₂-C₆₀ heteroaryl group, a monovalent non-aromatic condensed polycyclic group, a monovalent non-aromatic hetero-condensed polycyclic group, —N(Q₂₁)(Q₂₂), —Si(Q₂₃)(Q₂₄)(Q₂₅), and —B(Q₂₆)(Q₂₇); and

—N(Q₃₁)(Q₃₂), —Si(Q₃₃)(Q₃₄)(Q₃₅), and —B(Q₃₆)(Q₃₇); and

Q₁ to Q₇, Q₁₁ to Q₁₇, Q₂₁ to Q₂₇, and Q₃₁ to Q₃₇ are each independently selected from a hydrogen, a deuterium, —F, —Cl, —Br, —I, a hydroxyl group, a cyano group, a nitro group, an amino group, an amidino group, a hydrazine group, a hydrazone group, a carboxylic acid and a salt thereof, a sulfonic acid and a salt thereof, a phosphoric acid and a salt thereof, a C₁-C₆₀ alkyl group, C₂-C₆₀ alkenyl group, a C₂-C₆₀ alkynyl group, a C₁-C₆₀ alkoxy group, a C₃-C₁₀ cycloalkyl group, a C₂-₁₀ heterocycloalkyl group, a C₃-C₁₀ cycloalkenyl group, a C₂-C₁₀ heterocycloalkenyl group, a C₆-C₆₀ aryl group, a C₂-C₆₀ heteroaryl group, a monovalent non-aromatic condensed polycyclic group, and a monovalent non-aromatic hetero-condensed polycyclic group.

Another aspect provides an organic light-emitting diode including: a first electrode; a second elecgtrode facing the first electrode; and an organic layer that is disposed between the first and second electrodes and includes an emission layer, wherein the organic layer includes at least one condensed compound described above.

### BRIEF DESCRIPTION OF THE DRAWINGS

Features will become apparent to those of skill in the art by describing in detail exemplary embdiments with reference to the attached drawings in which:

FIG. 1 illustrates a schematic view of an organic light-emitting diode according to an embodiment.

### DETAILED DESCRIPTION

Example embodiments will now be described more fully hereinafter with reference to the accompanying drawings; however, they may be embodied in different forms and should not be construed as limited to the embodiments set forth herein. Rather, these embodiments are provided so that this disclosure willl be thouough and complete,and will fully convey eemplayr implementations to those skilled in the art.

In the drawing figures, the dimensions of layers and regions may be exaggerated for clarity of illustration. Expressions such as “at least one of,” when preceding a list of elements, modify the entire list of elements and do not modify th eindividual elements of the list.

A condensed compoound according to an embodiment is represented by Formula 1 or 2 below:

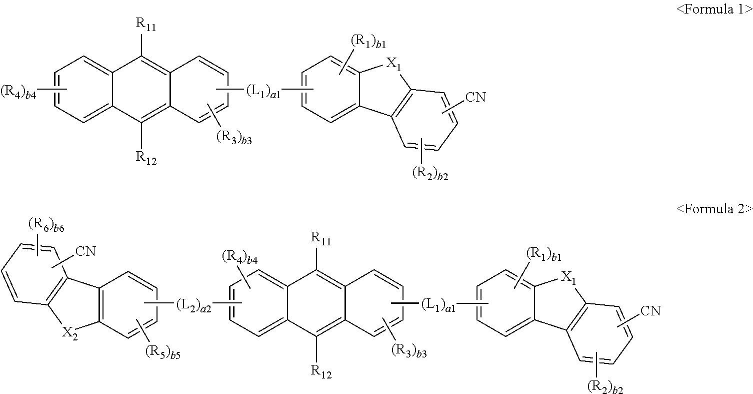

wherein in Formulae 1 and 2, X₁ is N(R₂₁), O, or S, and X₂ is N(R₂₂), O, or S. R₂₁ and R₂₂ may be understood by referring to a detailed description thereof provided below.

L₁ and L₂ in Formulae 1 and 2 may each independently be selected from

a phenylene group, a pentalenylene group, an indenylene group, a naphthylene group, an azulenylene group, a heptalenylene group, an indacenylene group, an acenaphthylene group, a fluorenylene group, a spiro-fluorenylene group, a benzofluorenylene group, a dibenzofluorenylene group, a phenalenylene group, a phenanthrenylene group, an anthracenylene group, a fluoranthenylene group, a triphenylenylene group, a pyrenylene group, a chrysenylene group, a naphthacenylene group, a picenylene group, a perylenylene group, a pentaphenylene group, a hexacenylene group, a pentacenylene group, a rubicenylene group, a coronenylene group, an ovalenylene group, a pyrrolylene group, a thiophenylene group, a furanylene group, an imidazolylene group, a pyrazolylene group, a thiazolylene group, an isothiazolylene group, an oxazolylene group, an isooxazolylene group, a pyridinylene group, a pyrazinylene group, a pyrmidinylene group, a pyridazinylene group, an isoindolylene group, an indolylene group, an indazolylene group, a purinylene group, a quinolinylene group, an isoquinolinylene group, a benzoquinolinylene group, a phthalazinylene group, a naphthyridinylene group, a quinoxalinylene group, a quinazolinylene group, a cinnolinylene group, a carbazolylene group, a phenanthridinylene group, a acridinylene group, a phenanthrolinylene group, a phenazinylene group, a benzoimidazolylene group, a benzofuranylene group, a benzothiophenylene group, an isobenzothiazolylene group, a benzooxazolylene group, an isobenzooxazolylene group, a triazolylene group, a tetrazolylene group, an oxadiazolylene group, a triazinylene group, a dibenzofuranylene group, a dibenzothiophenylene group, a benzocarbazolylene group, a dibenzocarbazolylene group, a thiadiazolylene group, an imidazopyridinylene group and an imidazopyrimidinylene group; and

a phenylene group, a pentalenylene group, an indenylene group, a naphthalene group, an azulenylene group, a heptalenylene group, an indacenylene group, an acenaphthylene group, a fluorenylene group, a spiro-fluorenylene group, a benzofluorenylene group, a dibenzofluorenylene group, a phenalenylene group, a phenanthrenylene group, an anthracenylene group, a fluorantenylene group, a triphenylenylene group, a pyrenylene group, a chrysenylene group, a naphthacenylene group, a picenylene group, a perylenylene group, a pentaphenylene group, a hexacenylene group, a pentacenylene group, a rubicenylene group, a coronenylene group, an ovalenylene group, a pyrrolylene group, a thiophenylene group, a furanylene group, an imidazolylene group, a pyrazolylene group, a thiazolylene group, an isothiazolylene group, an oxazolylene group, an isoxazolylene group, a pyridinylene group, a pyrazinylene group, a pyrimidinylene group, a pyridazinylene group, an isoindolylene group, an indolylene group, an indazolylene group, a purinylene group, a quinolinylene group, an isoquinolinylene group, a benzoquinolinylene group, a phthalazinylene group, a naphthilidinylene group, a quinoxalinylene group, a quinazolinylene group, a cinnolinylene group, a carbazolylene group, a phenanthridinylene group, an acridinylene group, a phenanthrolinylene group, a phenazinylene group, a benzoimidazolylene group, a benzofuranylene group, a benzothiophenylene group, an isobenzothiazolylene group, a benzooxazolylene group, an isobenzooxazolylene group, a triazolylene group, a tetrazolylene group, an oxadiazolylene group, a triazinylene group, a dibenzofuranylene group, a dibenzothiophenylene group, a benzocarbazolylene group, a dibenzocarbazolylene group, a thiadiazolylene group, an imidazopyridinylene group and an imidazopyrimidinylene group, each substituted with at least one selected from a deuterium, —F, —Cl, —Br, —I, a hydroxyl group, a cyano group, a nitro group, an amino group, an amidino group, a hydrazine group, a hydrazone group, a carboxylic acid and a salt thereof, a sulfonic acid and a salt thereof, a phosphoric acid and a salt thereof, a C₁-C₂₀ alkyl group, a C₁-C₂₀ alkoxy group, a cyclopentyl group, a cyclohexyl group, a cycloheptyl group, a cyclopentenyl group, a cyclohexenyl group, a phenyl group, a pentalenyl group, an indenyl group, a naphthyl group, an azulenyl group, a heptalenyl group, a indacenyl group, an acenaphthyl group, a fluorenyl group, a spiro-fluorenyl group, a benzofluorenyl group, a dibenzofluorenyl group, a phenalenyl group, a phenanthrenyl group, an anthracenyl group, a fluorantenyl group, a triphenylenyl group, a pyrenyl group, a chrysenyl group, a naphthacenyl group, a picenyl group, a perylenyl group, a pentaphenyl group, a hexacenyl group, a pentacenyl group, a rubicenyl group, a coronenyl group, an ovalenyl group, a pyrrolyl group, a thiophenyl group, a furanyl group, a imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a phthalazinyl group, a naphthyridinyl group, a quinoxalinyl group, a quinazolinyl group, a cinnolinyl group, a carbazolyl group, a phenanthridinyl group, an acridinyl group, a phenanthrolinyl group, a phenazinyl group, a benzoimidazolyl group, a benzofuranyl group, a benzothiophenyl group, an isobenzothiazolyl group, a benzooxazolyl group, an isobenzooxazolyl group, a triazolyl group, a tetrazolyl group, an oxadiazolyl group, a triazinyl group, a dibenzofuranyl group, a dibenzothiophenyl group, a benzocarbazolyl group, a dibenzocarbazolyl group, a thiadiazolyl group, an imidazolpyridinyl group and an imidazopyrimidinyl group.

According to another embodiment, L₁ and L₂ in Formulae 1 and 2 may each independently be represented by one of Formulae 3-1 to 3-32 below:

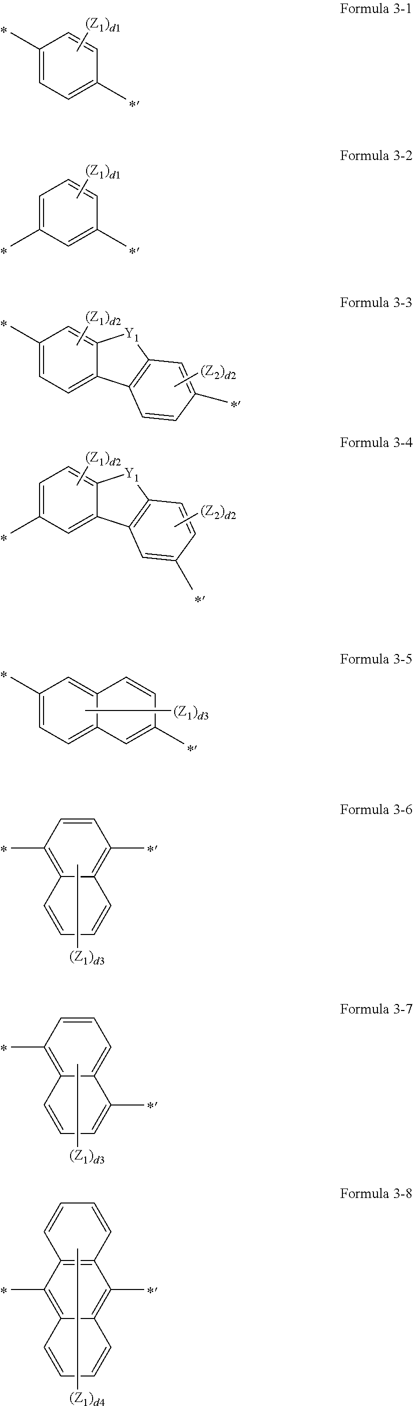

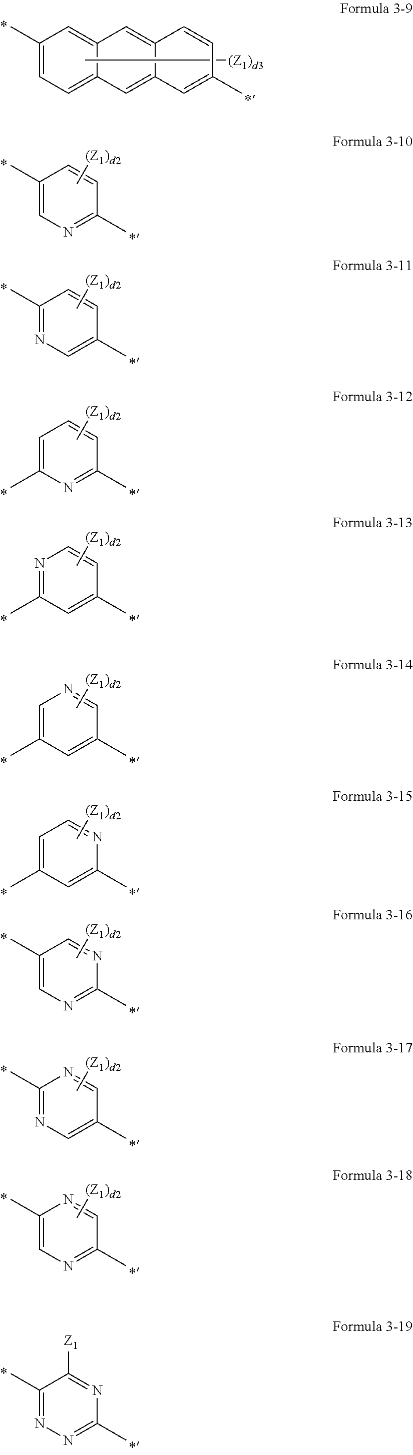

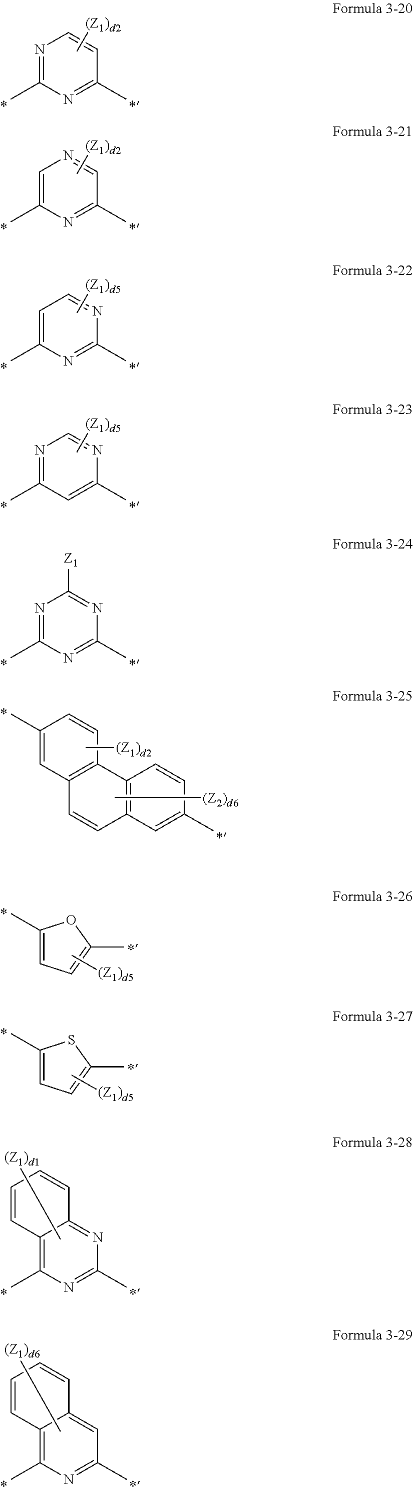

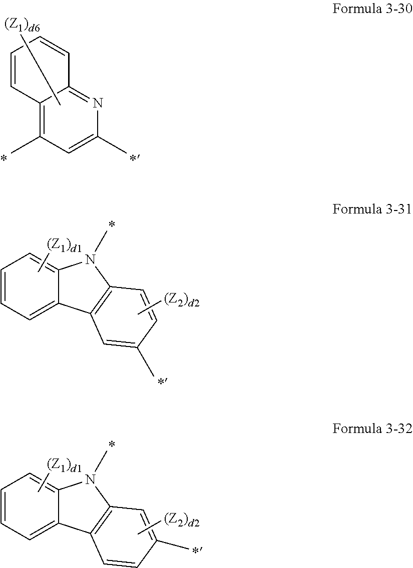

wherein in Formulae 3-1 to 3-32,

Y₁ is O, S, C(Z₃)(Z₄), N(Z₅), or Si(Z₆)(Z₇);

Z₁ to Z₇ are each independently selected from a hydrogen, a deuterium, —F, —Cl, —Br, —I, a hydroxyl group, a cyano group, a nitro group, an amino group, an amidino group, a hydrazine group, a hydrazone group, a carboxylic acid and a salt thereof, a sulfonic acid and a salt thereof, a phosphoric acid and a salt thereof, a C₁-C₂₀ alkyl group, a C₁-C₂₀ alkoxy group, a phenyl group, a naphthyl group, a fluorenyl group, a spiro-fluorenyl group, a benzofluorenyl group, a dibenzofluorenyl group, a phenanthrenyl group, an anthracenyl group, a pyrenyl group, a chrysenyl group, a pyridinyl group, a pyrazinyl group, a pyrimidinyl group, a pyridazinyl group, a quinolinyl group, an isoquinolinyl group, a quinoxalinyl group, a quinazolinyl group, a carbazolyl group and a triazinyl group;

d1 is selected from an integer of 1 to 4;

d2 is selected from an integer of 1 to 3;

d3 is selected from an integer of 1 to 6;

d4 is selected from an integer of 1 to 8;

d5 is 1 or 2;

d6 is selected from an integer of 1 to 5; and

* and *′ represent bonding sites in the condensed compound,

According to another embodiment, L₁ and L₂ in Formulae 1 and 2 may each independently be represented by one of Formulae 4-1 to 4-23 below:

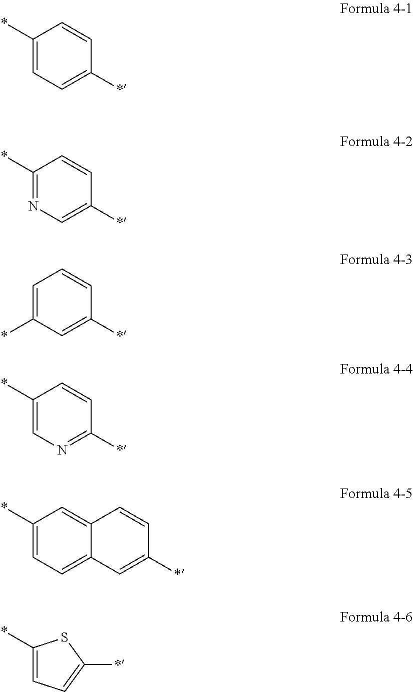

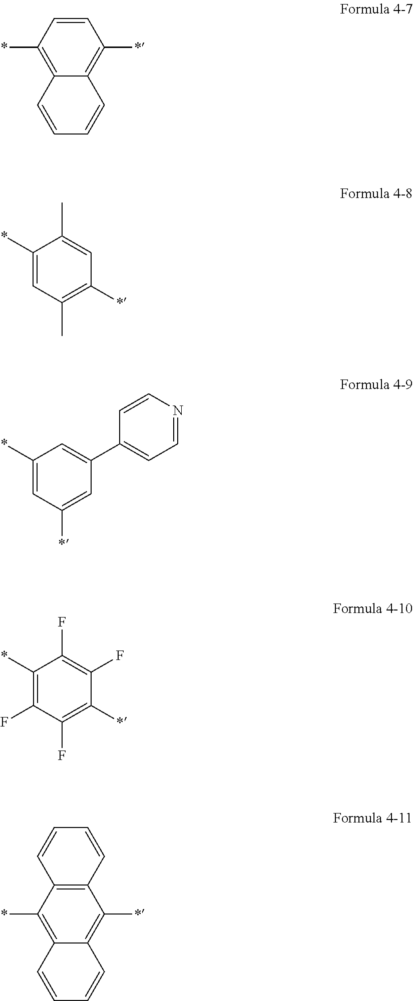

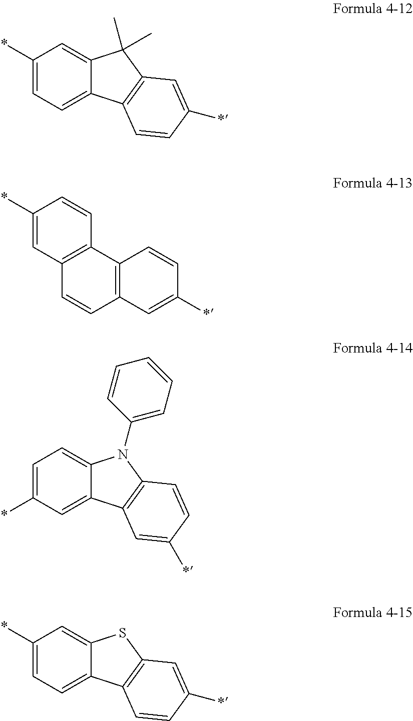

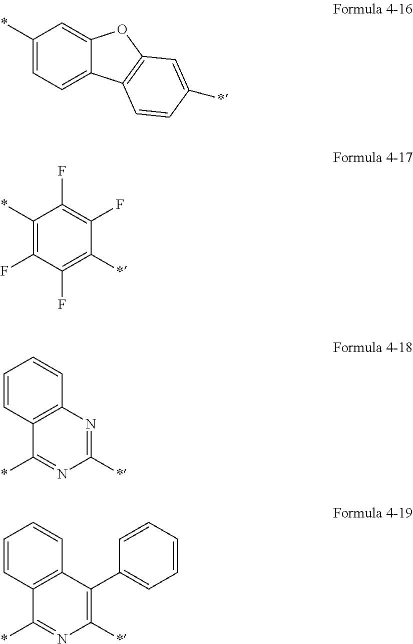

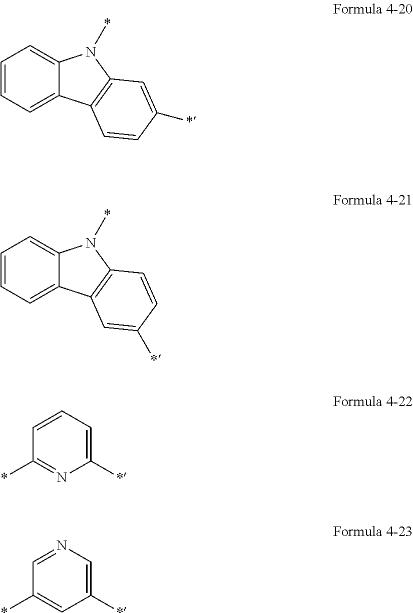

wherein * and *′ represent bonding sites in the condensed compound.

a1 in Formulae 1 and 2 may be selected from 0, 1, 2, and 3. For example, a1 in Formulae 1 and 2 may be 0 or 1. When a1 in Formula 1 is 0, —(L₁)ₐ₁— is a single bond. When a1 is 2 or more, a plurality of L₁s may be identical or different.

a2 in Formula 2 may be selected from 0, 1, 2, and 3. For example, a2 in formula 2 may be 0 or 1. When a2 in Formula 2 is 0, —(L₂)ₐ₂— is a single bond. When a2 is 2 or more, a plurality of L₂s may be identical or different.

Regarding Formulae 1 and 2, when X₁ is N(R₂₁) or X₂ N(R₂₂), R₂₁ and R₂₂ may each independently be selected from

a cyclopentyl group, a cyclohexyl group, a cycloheptyl group, a cyclopentenyl group, a cyclohexenyl group, a phenyl group, a pentalenyl group, an indenyl group, a naphthyl group, an azulenyl group, a heptalenyl group, an indacenyl group, an acenaphthyl group, a fluorenyl group, a spiro-fluorenyl group, a benzofluorenyl group, a dibenzofluorenyl group, a phenalenyl group, a phenanthrenyl group, an anthracenyl group, a fluoranthenyl group, a triphenylenyl group, a pyrenyl group, a chrysenyl group, a naphthacenyl group, a picenyl group, a perylenyl group, a pentaphenyl group, a hexacenyl group, a pentacenyl group, a rubicenyl group, a coronenyl group, an ovalenyl group, a pyrrolyl group, a thiophenyl group, a furanyl group, an imidazolyl group, a pyrazolyl group, a thiazolyl group, an isothiazolyl group, an oxazolyl group, an isooxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a phthalazinyl group, a naphthyridinyl group, a quinoxalinyl group, a quinazolinyl group, a cinnolinyl group, a carbazolyl group, a phenanthridinyl group, an acridinyl group, a phenanthrolinyl group, a phenazinyl group, a benzoimidazolyl group, a benzofuranyl group, a benzothiophenyl group, an isobenzothiazolyl group, a benzooxazolyl group, an isobenzooxazolyl group, a triazolyl group, a tetrazolyl group, an oxadiazolyl group, a triazinyl group, a dibenzofuranyl group, a dibenzothiophenyl group, a benzocarbazolyl group, a dibenzocarbazolyl group, a thiadiazolyl group, an imidazolpyridinyl and an imidazopyrimidinyl group; and

a cyclopentyl group, a cyclohexyl group, a cycloheptyl group, a cyclopentenyl group, a cyclohexenyl group, a phenyl group, a pentalenyl group, an indenyl group, a naphthyl group, an azulenyl group, a heptalenyl group, an indacenyl group, an acenaphthyl group, a fluorenyl group, a spiro-fluorenyl group, a benzofluorenyl group, a dibenzofluorenyl group, a phenalenyl group, a phenanthrenyl group, an anthracenyl group, a fluoranthenyl group, a triphenylenyl group, a pyrenyl group, a chrysenyl group, a naphthacenyl group, a picenyl group, a perylenyl group, a pentaphenyl group, a hexacenyl group, a pentacenyl group, a rubicenyl group, a coronenyl group, an ovalenyl group, a pyrrolyl group, a thiophenyl group, a furanyl group, an imidazolyl group, a pyrazolyl group, a thiazolyl group, an isothiazolyl group, an oxazolyl group, an isooxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a phthalazinyl group, a naphthyridinyl group, a quinoxalinyl group, a quinazolinyl group, a cinnolinyl group, a carbazolyl group, a phenanthridinyl group, an acridinyl group, a phenanthrolinyl group, a phenazinyl group, a benzoimidazolyl group, a benzofuranyl group, a benzothiophenyl group, an isobenzothiazolyl group, a benzooxazolyl group, an isobenzooxazolyl group, a triazolyl group, a tetrazolyl group, an oxadiazolyl group, a triazinyl group, a dibenzofuranyl group, a dibenzothiophenyl group, a benzocarbazolyl group, a dibenzocarbazolyl group, a thiadiazolyl group, an imidazolpyridinyl and an imidazopyrimidinyl group, each substituted with at least one selected from a deuterium, —F, —Cl, —Br, —I, a hydroxyl group, a cyano group, a nitro group, an amino group, an amidino group, a hydrazine group, a hydrazone group, a carboxylic acid and a salt thereof, a sulfonic acid and a salt thereof, a phosphoric acid and a salt thereof, a C₁-C₂₀ alkyl group, a C₁-C₂₀ alkoxy group, a cyclopentyl group, a cyclohexyl group, a cycloheptyl group, a cyclopentenyl group, a cyclohexenyl group, a phenyl group, a pentalenyl group, an indenyl group, a naphthyl group, an azulenyl group, a heptalenyl group, an indacenyl group, an acenaphthyl group, a fluorenyl group, a spiro-fluorenyl group, a benzofluorenyl group, a dibenzofluorenyl group, a phenalenyl group, a phenanthrenyl group, an anthracenyl group, a fluoranthenyl group, a triphenylenyl group, a pyrenyl group, a chrysenyl group, a naphthacenyl group, a picenyl group, a perylenyl group, a pentaphenyl group, a hexacenyl group, a pentacenyl group, a rubicenyl group, a coronenyl group, an ovalenyl group, a pyrrolyl group, a thiophenyl group, a furanyl group, an imidazolyl group, a pyrazolyl group, a thiazolyl group, an isothiazolyl group, an oxazolyl group, an isooxazolyl group, a pyridinyl group, a pyrazinyl group, a pyrimidinyl group, a pyridazinyl group, an isoquinolinyl group, an indolyl group, an indazolyl group, a purinyl group, a quinolinyl group, an isoquinolinyl group, a benzoquinolinyl group, a phthalazinyl group, a naphthyridinyl group, a quinoxalinyl group, a quinazolinyl group, a cinnolinyl group, a carbazolyl group, a phenanthridinyl group, an acridinyl group, a phenanthrolinyl group, a phenazinyl group, a benzoimidazolyl group, a benzofuranyl group, a benzothiophenyl group, an isobenzothiazolyl group, a benzooxazolyl group, an isobenzooxazolyl group, a triazolyl group, a tetrazolyl group, an oxadiazolyl group, a triazinyl group, a dibenzofuranyl group, a dibenzothiophenyl group, a benzocarbazolyl group, a dibenzocarbazolyl group, a thiadiazolyl group, an imidazolpyridinyl and an imidazopyrimidinyl group.

According to an embodiment, regarding Formulae 1 and 2, when X₁ is N(R₂₁) or X₂ is N(R₂₂), R₂₁ and R₂₂ are each independently selected from

a phenyl group, a naphthylene group, a fluorenylene group, a spiro-fluorenylene group, a benzofluorenyl group, a dibenzofluorenyl group, a phenanthrenyl group, an anthracenyl group, a pyrenyl group, a chrysenyl group, a pyridinyl group, a pyrazinyl group, a pyrimidinyl group, a pyridazinyl group, a quinolinyl group, an isoquinolinyl group, a quinoxalinyl group, a quinazolinyl group, a carbazolyl group and a triazinyl group; and

a phenyl group, a naphthyl group, a fluorenyl group, a spiro-fluorenyl group, a benzofluorenyl group, a dibenzofluorenyl group, a phenanthrenyl group, an anthracenyl group, a pyrenyl group, a chrysenyl group, a pyridinyl group, a pyrazinyl group, a pyrimidinyl group, a pyridazinyl group, a quinolinyl group, an isoquinolinyl group, a quinoxalinyl group, a quinazolinyl group, a carbazolyl group and a triazinyl group, each substituted with at least one selected from a deuterium, —F, —Cl, —Br, —I, a hydroxyl group, a cyano group, a nitro group, an amino group, an amidino group, a hydrazine group, a hydrazone group, a carboxylic acid and a salt thereof, a sulfonic acid and a salt thereof, a phosphoric acid and a salt thereof, a C₁-C₂₀ alkyl group, a C₁-C₂₀ alkoxy group, a phenyl group, a naphthyl group, a fluorenyl group, a spiro-fluorenyl group, a benzofluorenyl group, a dibenzofluorenyl group, a phenanthrenyl group, an anthracenyl group, a pyrenyl group, a chrysenyl group, a pyridinyl group, a pyrazinyl group, a pyrimidinyl group, a pyridazinyl group, a quinolinyl group, an isoindolyl group, a quinoxalinyl group, a quinazolinyl group, a carbazolyl group and a triazinyl group.

According to another embodiment, R₁ to R₆ in Formulae 1 and 2 may each independently be selected from a hydrogen, a deuterium, —F, —Cl, —Br, —I, a hydroxyl group, a cyano group, a nitro group, an amino group, an amidino group, a hydrazine group, a hydrazone group, a carboxylic acid and a salt thereof, a sulfonic acid and a salt thereof, a phosphoric acid and a salt thereof, a C₁-C₂₀ alkyl group, a C₁-C₂₀ alkoxy group, a phenyl group, a naphthyl group, a fluorenyl group, a spiro-fluorenyl group, a benzofluorenyl group, a dibenzofluorenyl group, a phenanthrenyl group, an anthracenyl group, a pyrenyl group, a chrysenyl group, a pyridinyl group, a pyrazinyl group, a pyrimidinyl group, a pyridazinyl group, a quinolinyl group, an isoindolyl group, a quinoxalinyl group, a quinazolinyl group, a carbazolyl group, a triazinyl group, and Si(Q₃)(Q₄)(Q₅) (wherein Q₃ to Q₅ may each independently be selected from a C₁-C₂₀ alkyl group, a C₁-C₂₀ alkoxy group, a phenyl group and a naphthyl group).

For example, R₁ to R₆ in Formulae 1 and 2 may each be hydrogen.

According to another embodiment, R₁₁ and R₁₂ in Formulae 1 and 2 may each independently be selected from

a C₁-C₂₀ alkyl group and a C₁-C₂₀ alkoxy group;

a phenyl group, a naphthyl group, a fluorenyl group, a spiro-fluorenyl group, a benzofluorenyl group, a dibenzofluorenyl group, a phenanthrenyl group, an anthracenyl group, a pyrenyl group, a chrysenyl group, a pyridinyl group, a pyrazinyl group, a pyrimidinyl group, a pyridazinyl group, a quinolinyl group, an isoindolyl group, a quinoxalinyl group, a quinazolinyl group, a carbazolyl group and a triazinyl group;

a phenyl group, a naphthyl group, a fluorenyl group, a spiro-fluorenyl group, a benzofluorenyl group, a dibenzofluorenyl group, a phenanthrenyl group, an anthracenyl group, a pyrenyl group, a chrysenyl group, a pyridinyl group, a pyrazinyl group, a pyrimidinyl group, a pyridazinyl group, a quinolinyl group, an isoindolyl group, a quinoxalinyl group, a quinazolinyl group, a carbazolyl group and a triazinyl group, each substituted with at least one selected from a deuterium, —F, —Cl, —Br, —I, a hydroxyl group, a cyano group, a nitro group, an amino group, an amidino group, a hydrazine group, a hydrazone group, a carboxylic acid and a salt thereof, a sulfonic acid and a salt thereof, a phosphoric acid and a salt thereof, a C₁-C₂₀ alkyl group, a C₁-C₂₀ alkoxy group, a phenyl group, a naphthyl group, a fluorenyl group, a spiro-fluorenyl group, a benzofluorenyl group, a dibenzofluorenyl group, a phenanthrenyl group, an anthracenyl group, a pyrenyl group, a chrysenyl group, a pyridinyl group, a pyrazinyl group, a pyrimidinyl group, a pyridazinyl group, a quinolinyl group, an isoindolyl group, a quinoxalinyl group, a quinazolinyl group, a carbazolyl group and a triazinyl group; and

Si(Q₃)(Q₄)(Q₅) (wherein Q₃ to Q₅ may each independently be selected from a C₁-C₂₀ alkyl group, a C₁-C₂₀ alkoxy group, a phenyl group and a naphthyl group).

According to another embodiment, regarding formulae 1 and 2,

R₂₁ and R₂₂ may each independently be selected from Formulae 5-1 to 5-34 below;

R₁ to R₆ are each independently selected from a hydrogen, a deuterium, —F, —Cl, —Br, —I, a hydroxyl group, a cyano group, a nitro group, an amino group, an amidino group, a hydrazine group, a hydrazone group, a carboxylic acid and a salt thereof, a sulfonic acid and a salt thereof, a phosphoric acid and a salt thereof, a C₁-C₂₀ alkyl group, a C₁-C₂₀ alkoxy group, and Formulae 5-1 to 5-34 below;

R₁₁ and R₁₂ may each independently be selected from a C₁-C₂₀ alkyl group, (for example, a methyl group, an ethyl group, a propyl group, a butyl group, a pentyl group or a hexyl group), and Formulae 5-1 to 5-34 below:

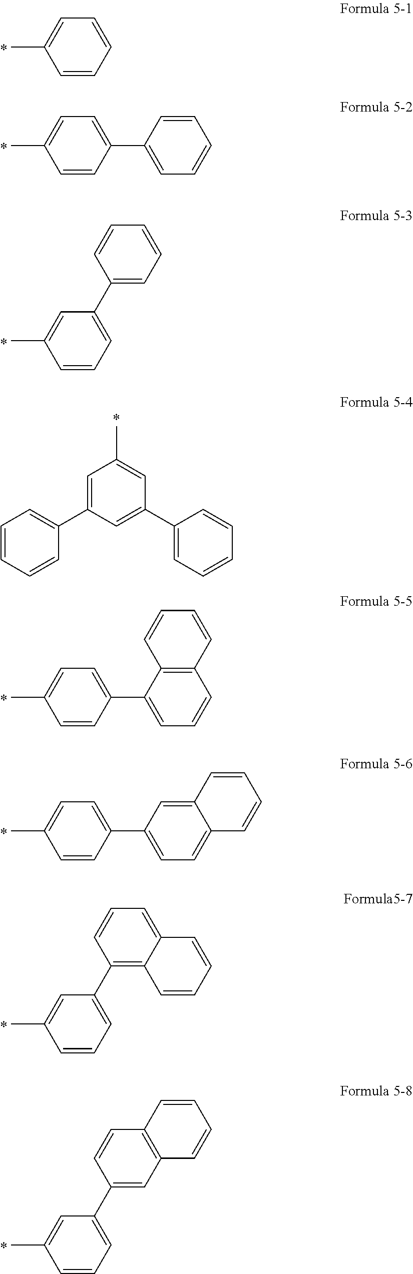

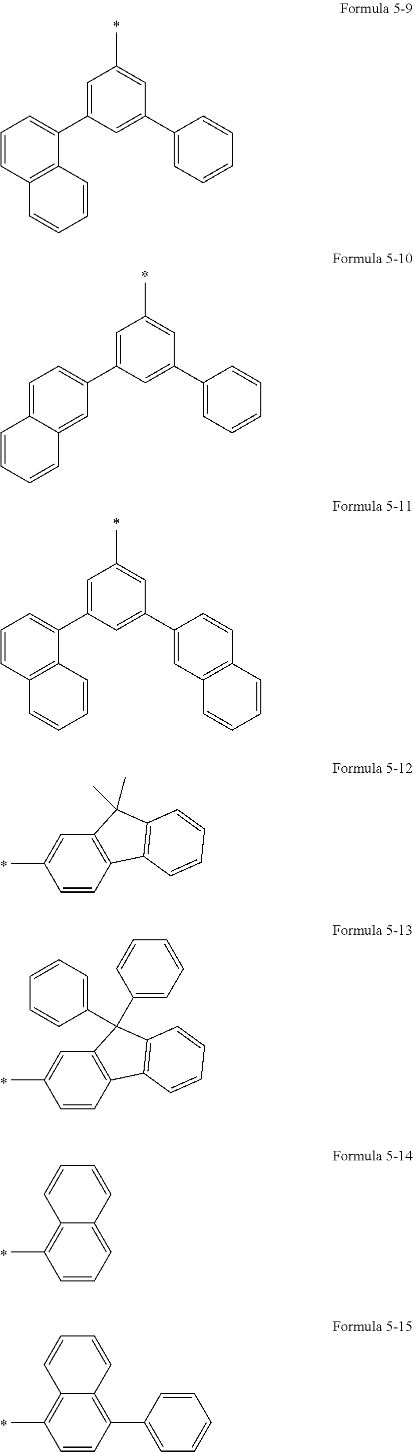

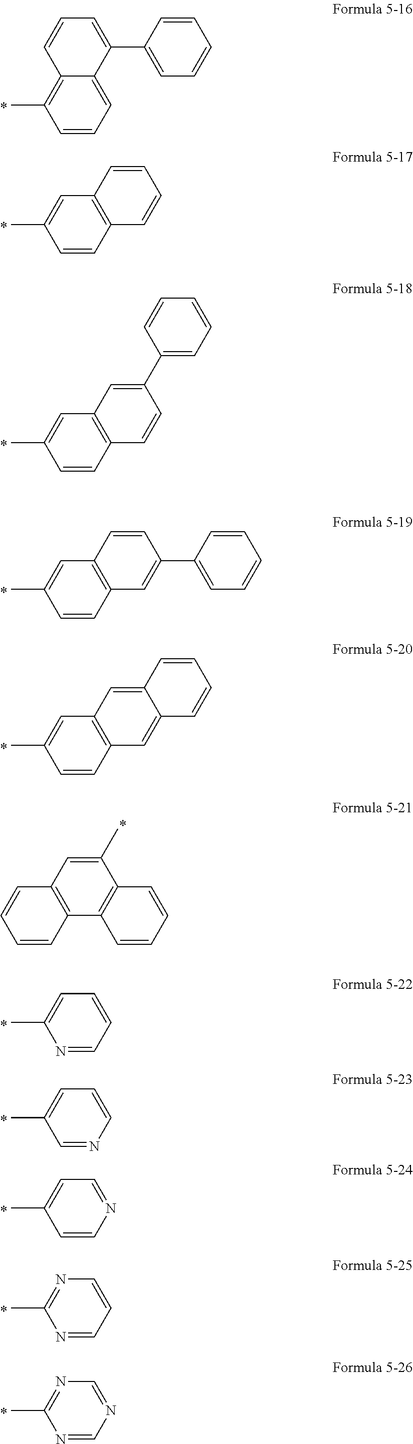

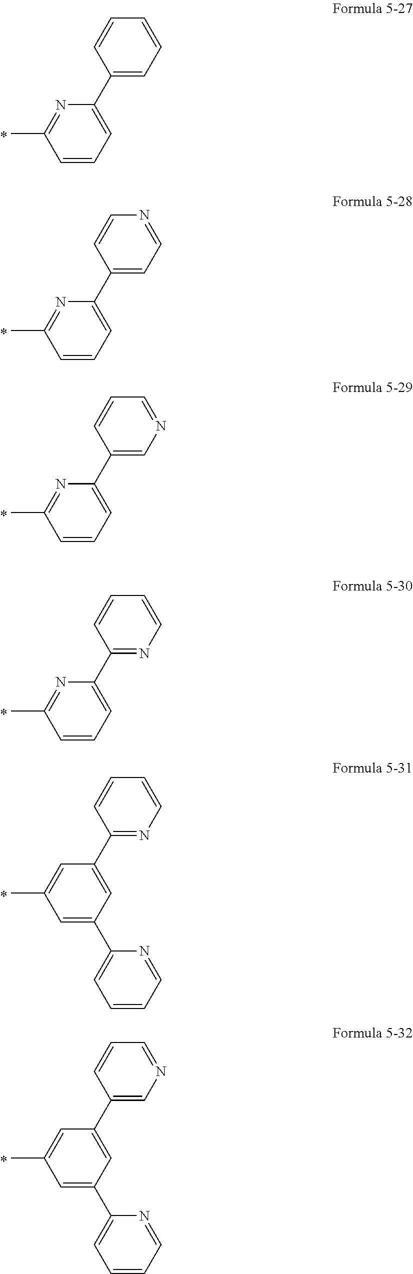

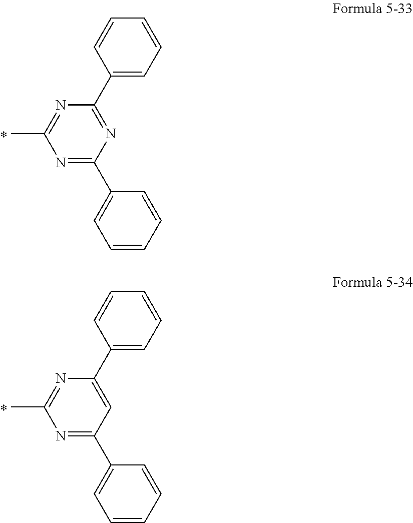

wherein * represents a bonding sites in the condensed compound.

b1 in Formulae 1 and 2 may be selected from 0, 1, 2, and 3. For example, b1 may be 0, 1, or 2. When b1 is 2 or more, a plurality of Rᵢs may be identical or different. b2 to b6 may be understood by referring to the description provided in connection with b1.

For example, the condensed compound represented by Formula 1 may be represented by one of Formulae 1-1 to 1-12 and 2-1 to 2-12:

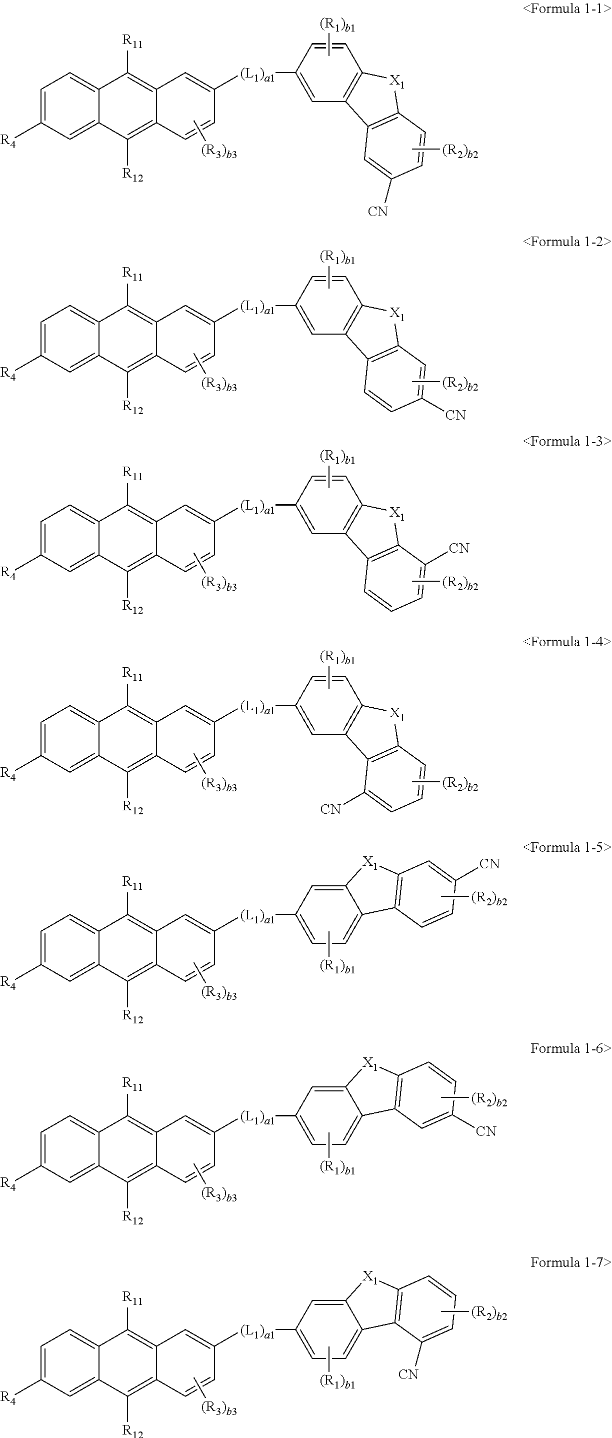

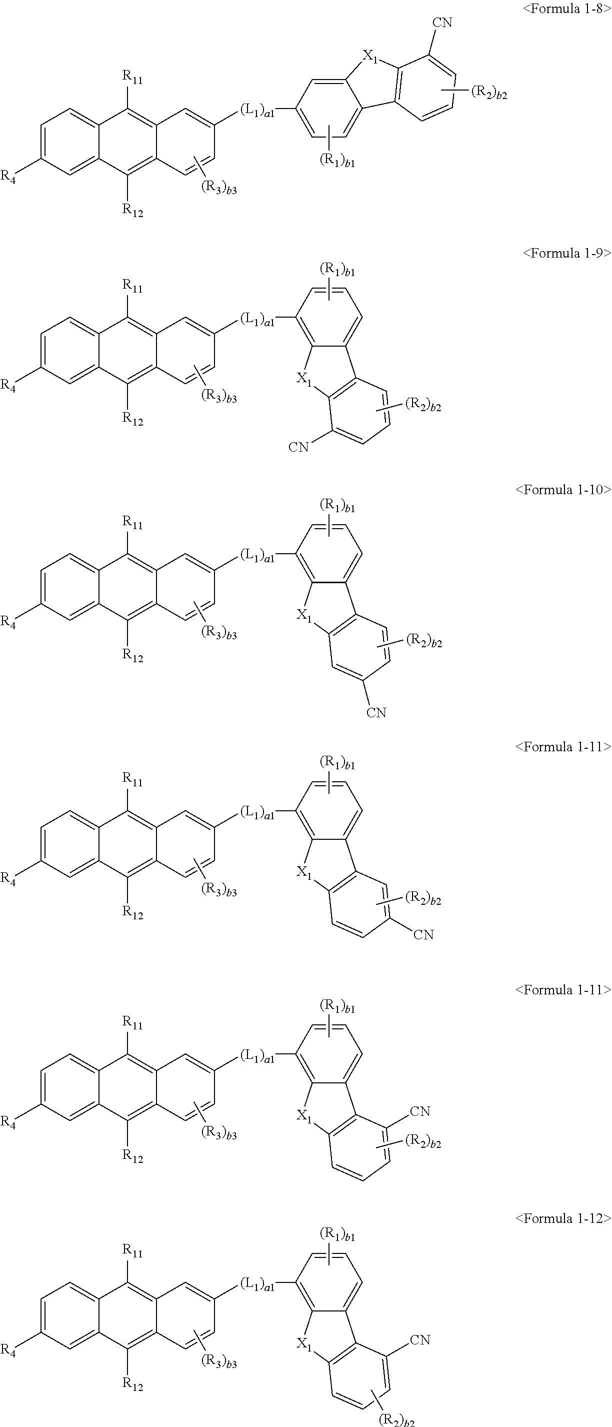

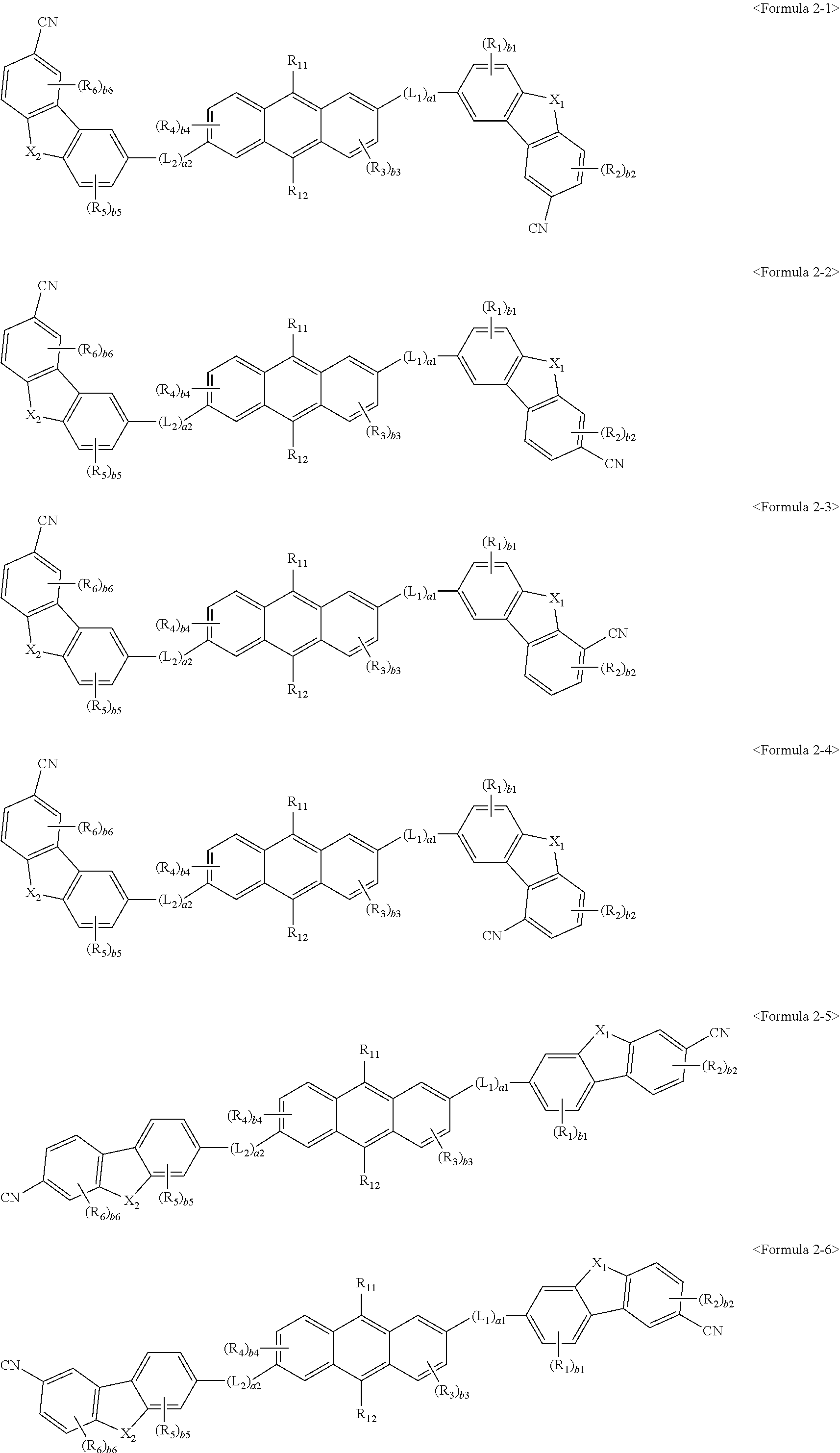

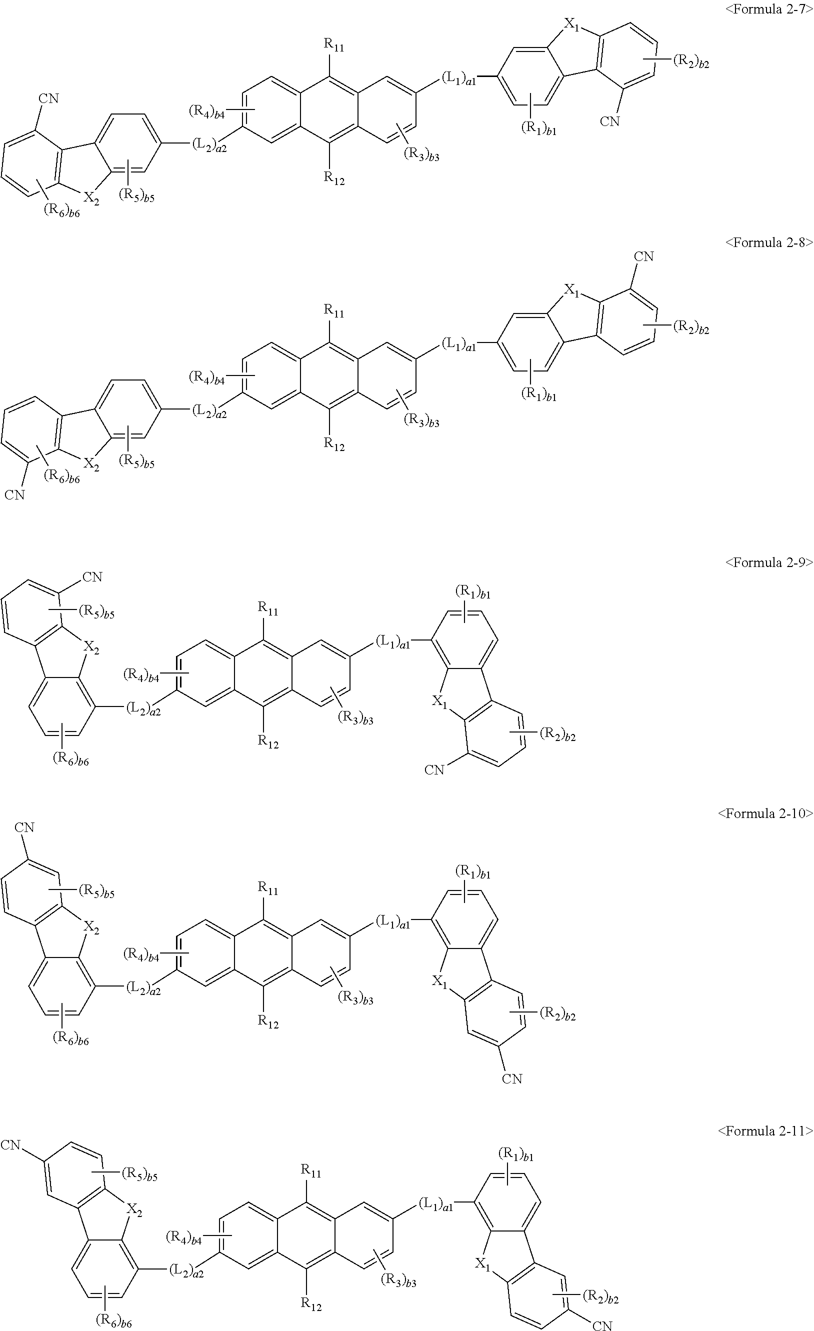

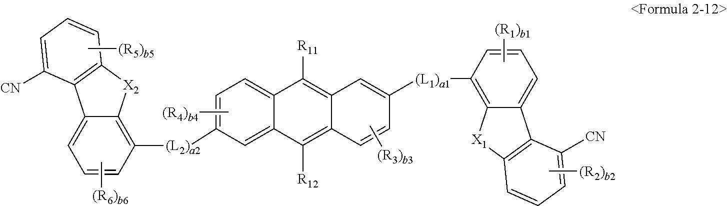

X₁, X₂, L₁, L₂, a1, a2, R₁ to R₆, R₁₁, R₁₂, and b1 to b6 in Formulae 1-1 to 1-12 and 2-1 to 2-12 may be understood by referring to the corresponding description provided herein.

According to an embodiment, the condensed compound may be represented by one of Formulae 1-1 to 1-12 and 2-1 to 2-12, L₁ and L₂ in Formulae 1-1 to 1-12 and 2-1 to 2-12 may each independently be one of Formulae 4-1 to 4-23; a1 and a2 may each independently be 0 or 1; R₂₁ and R₂₂ may each independently be selected from Formulae 5-1 to 5-34; R₁ to R₆ may each independently be selected from a hydrogen, a deuterium, —F, —Cl, —Br, —I, a hydroxyl group, a cyano group, a nitro group, an amino group, an amidino group, a hydrazine group, a hydrazone group, a carboxylic acid and a salt thereof, a sulfonic acid and a salt thereof, a phosphoric acid and a salt thereof, a C₁-C₂₀ alkyl group, a C₁-C₂₀ alkoxy group and Formulae 5-1 to 5-34; R₁₁ and R₁₂ may each independently be selected from a C₁-C₂₀ alkyl group and Formulae 5-1 to 5-34; and b1 to b6 may each independently be 0, 1, or 2.

According to another embodiment, the condensed compound represented by Formula 1 or Formula 2 may be represented by one of Formulae 1-1, 1-5, 1-9, 2-1, 2-5, and 2-9.

The condensed compound represented by Formula 1 or Formula 2 may be one of Compounds 1 to 119 below.

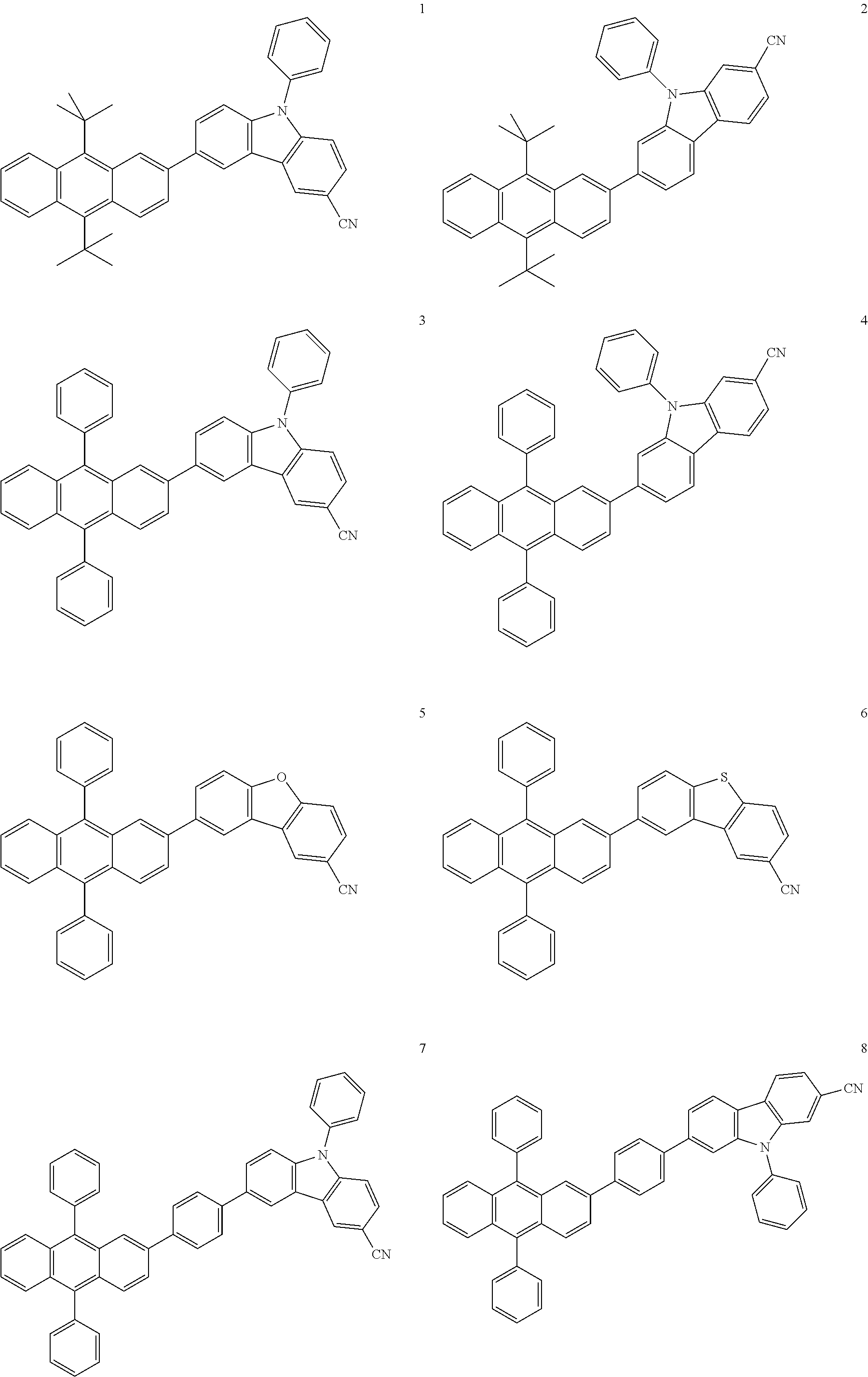

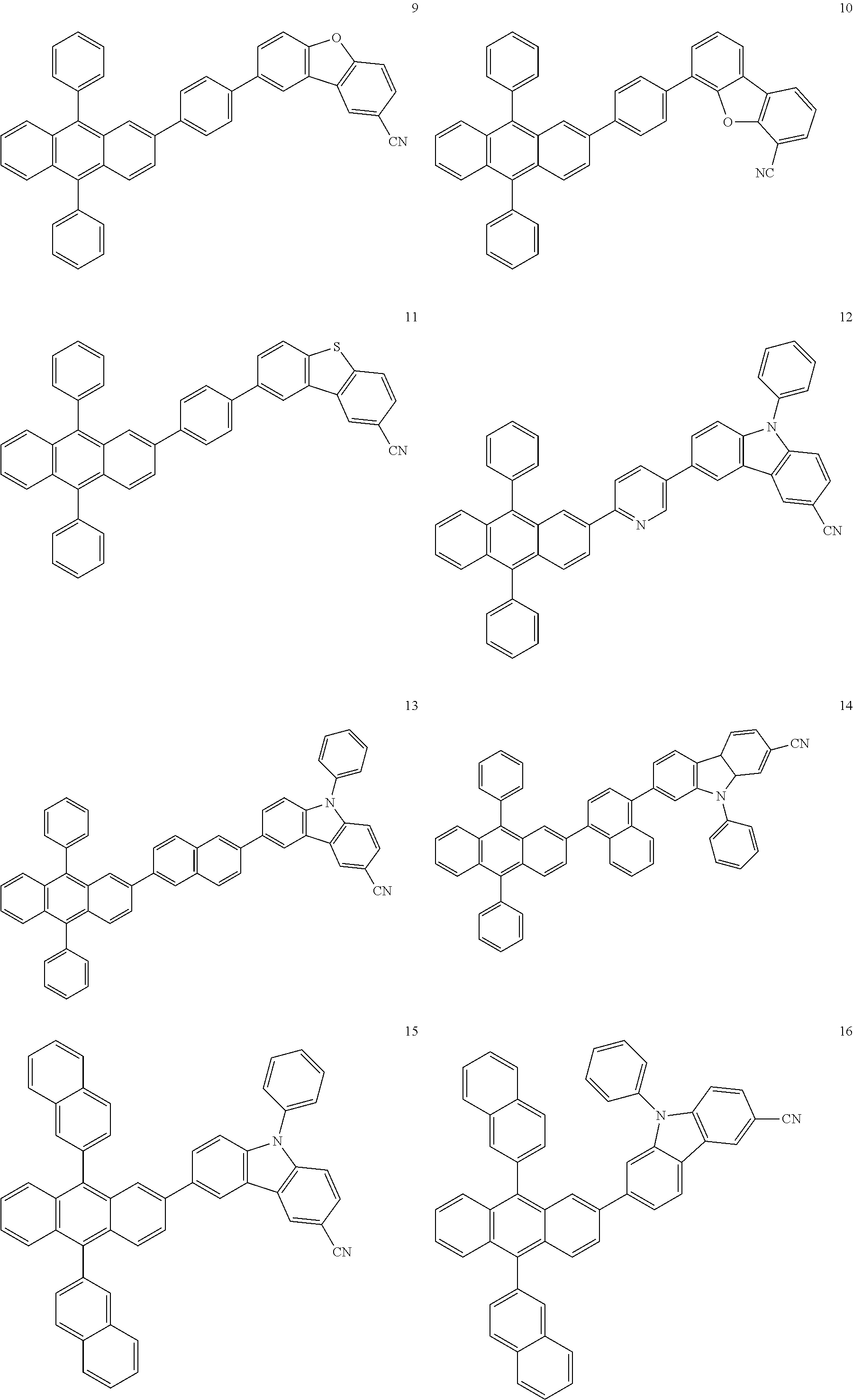

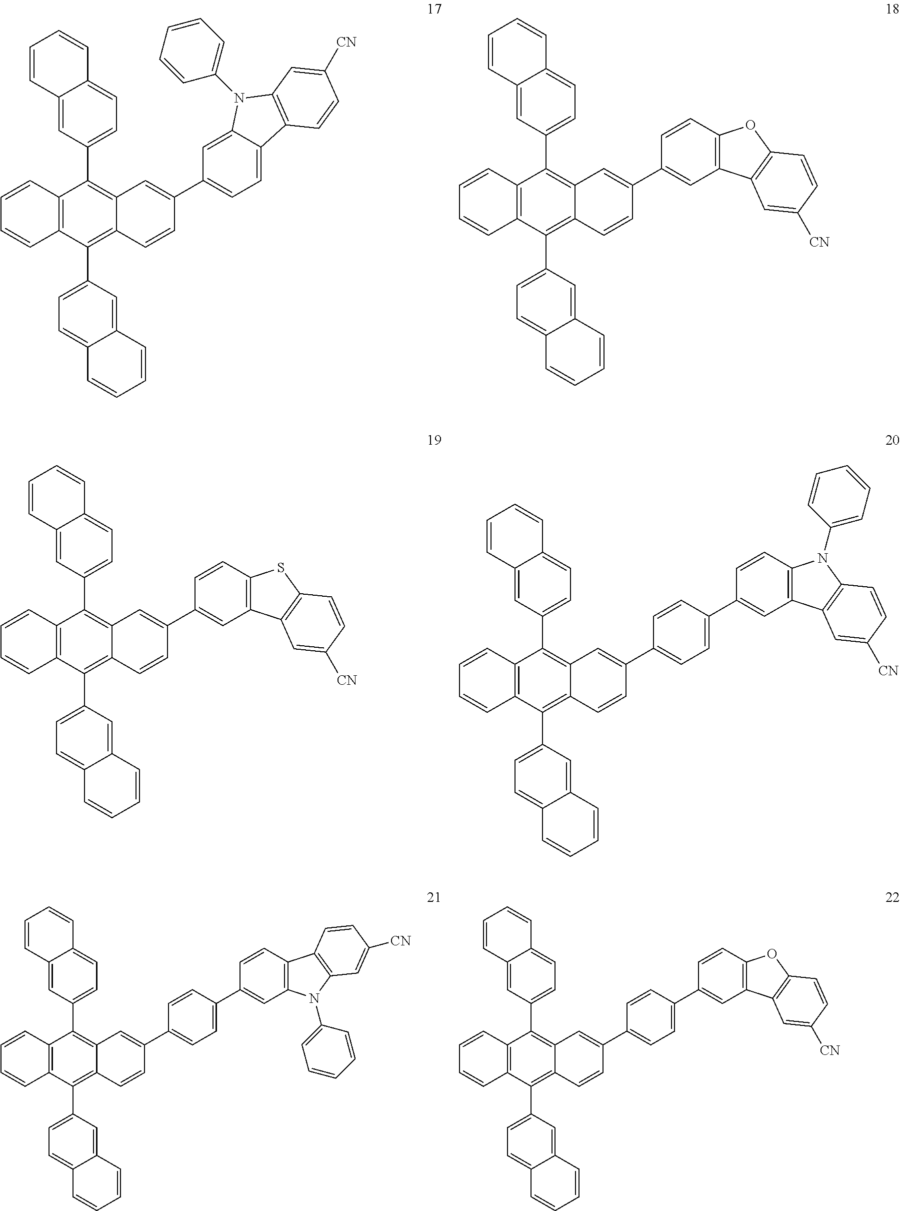

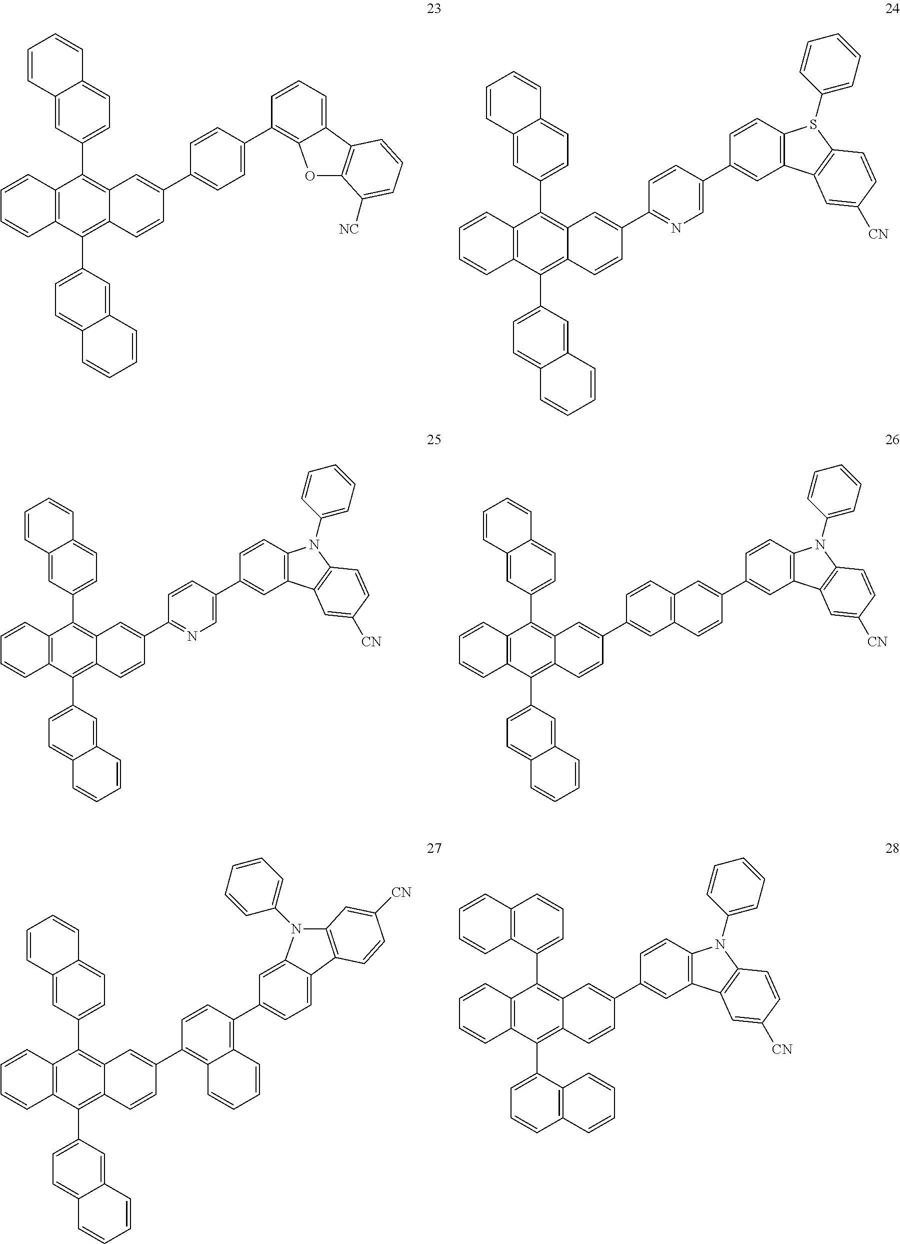

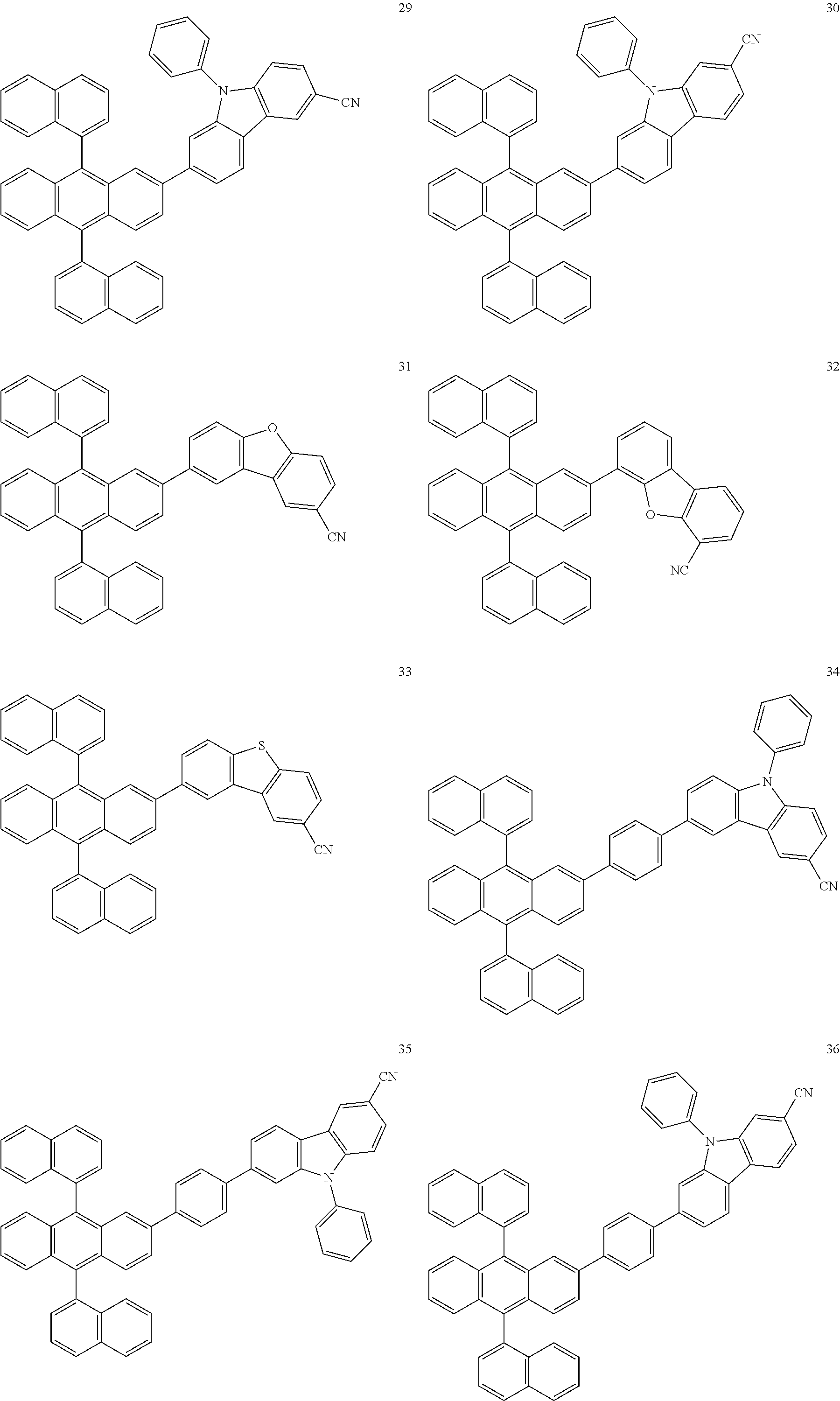

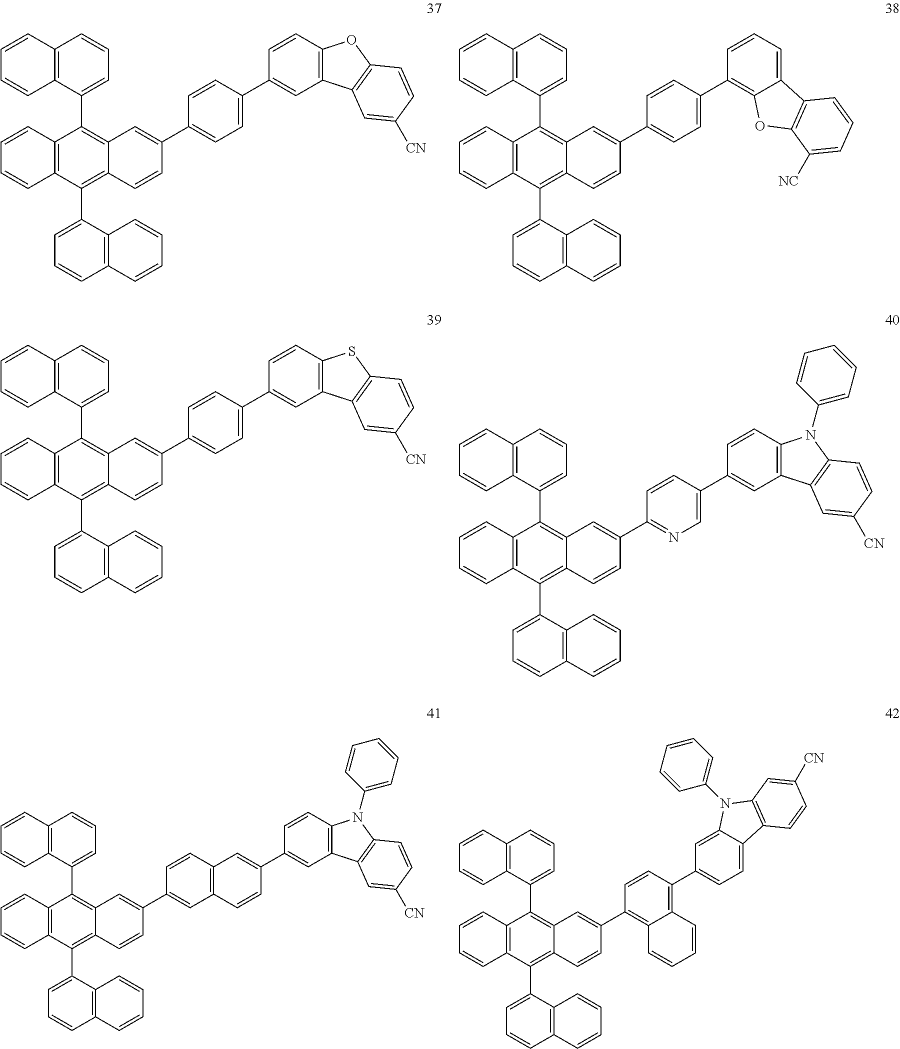

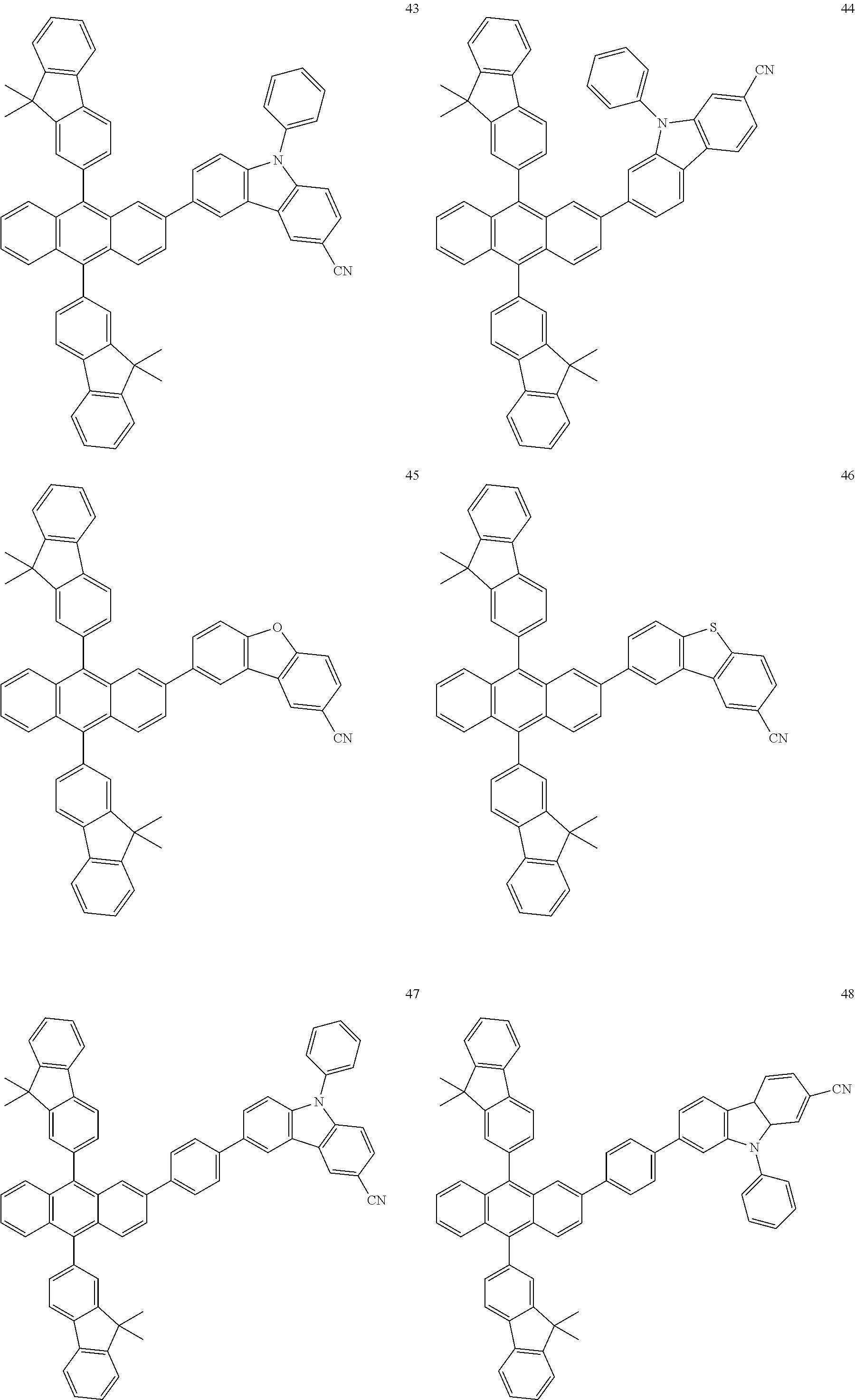

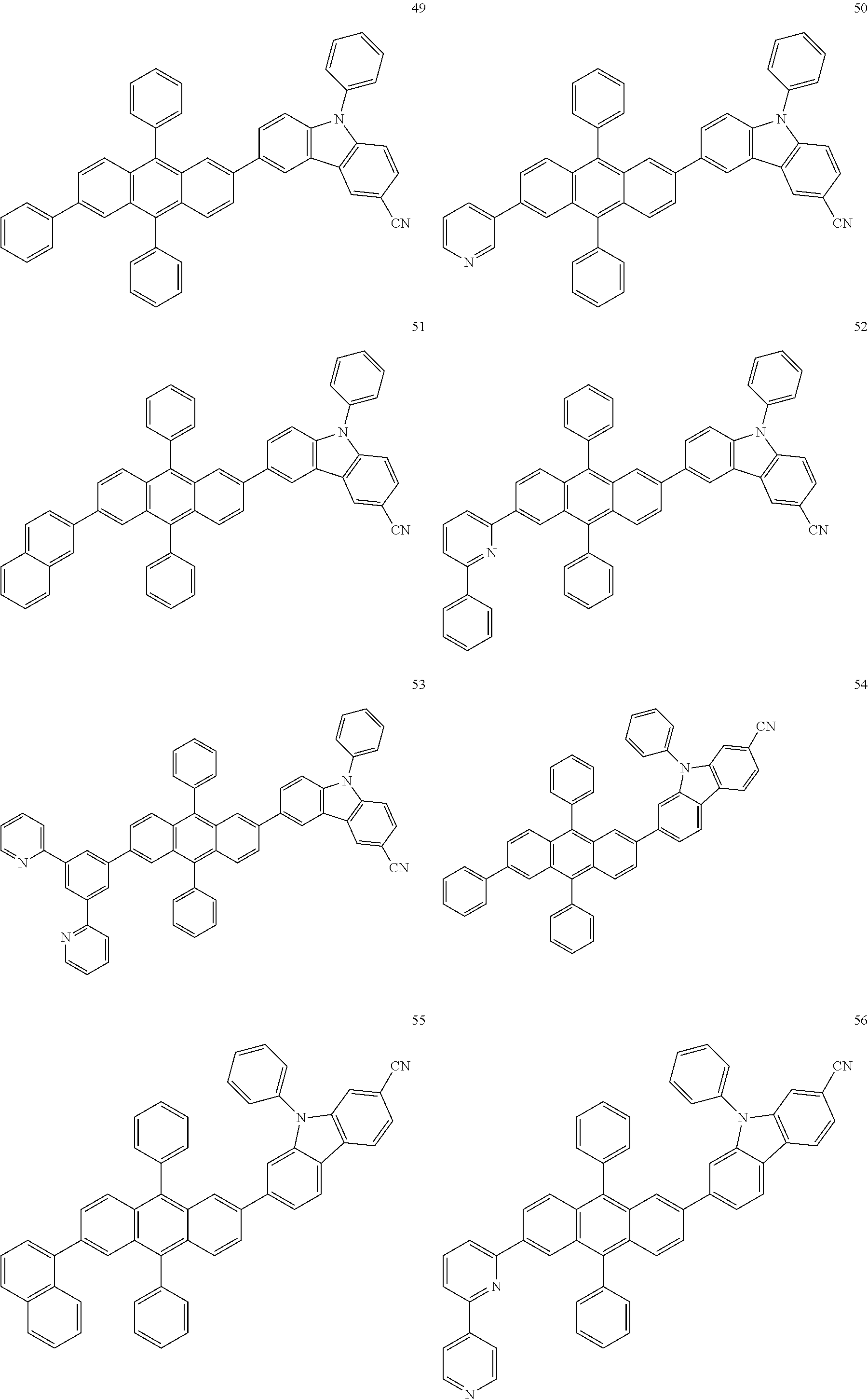

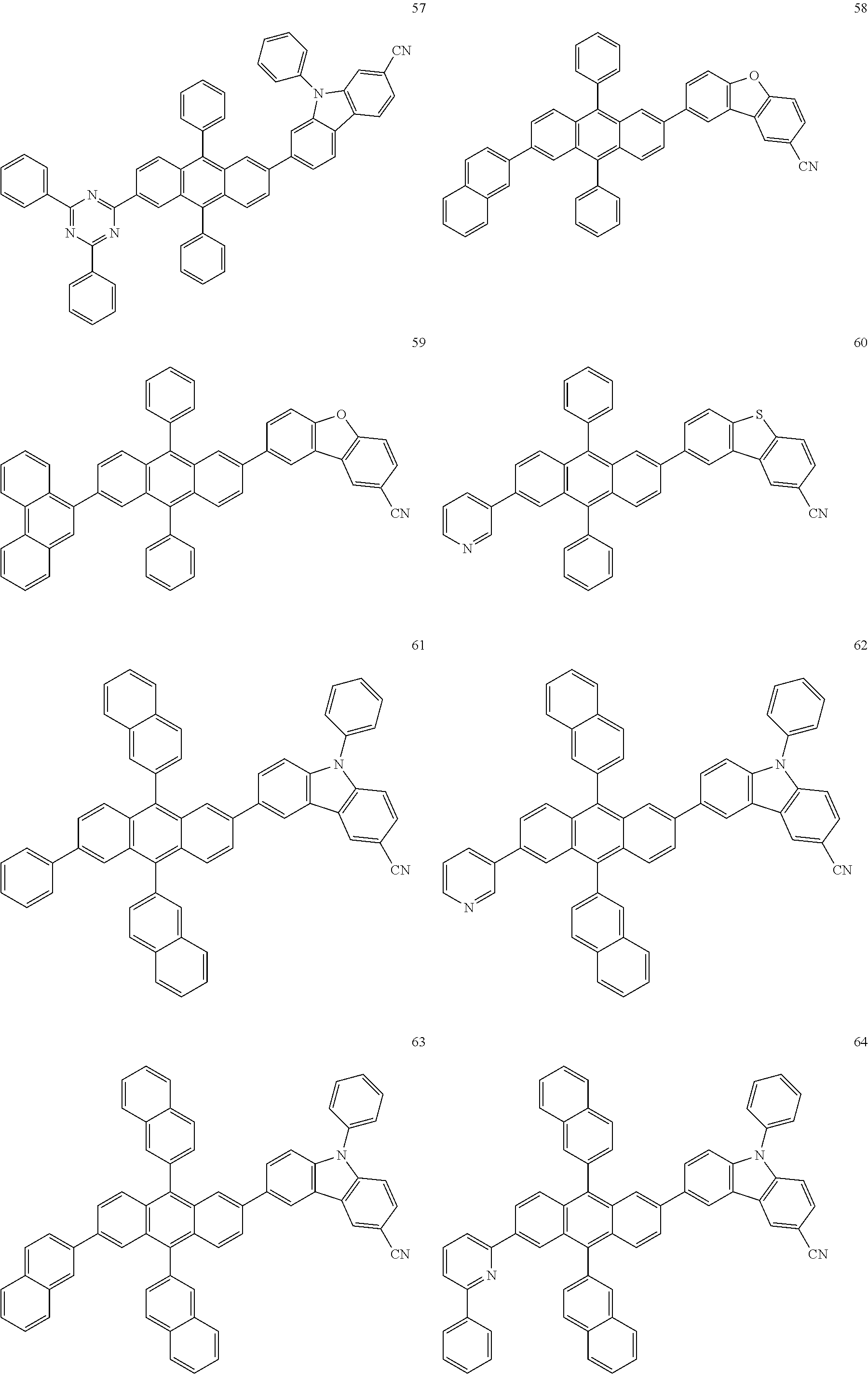

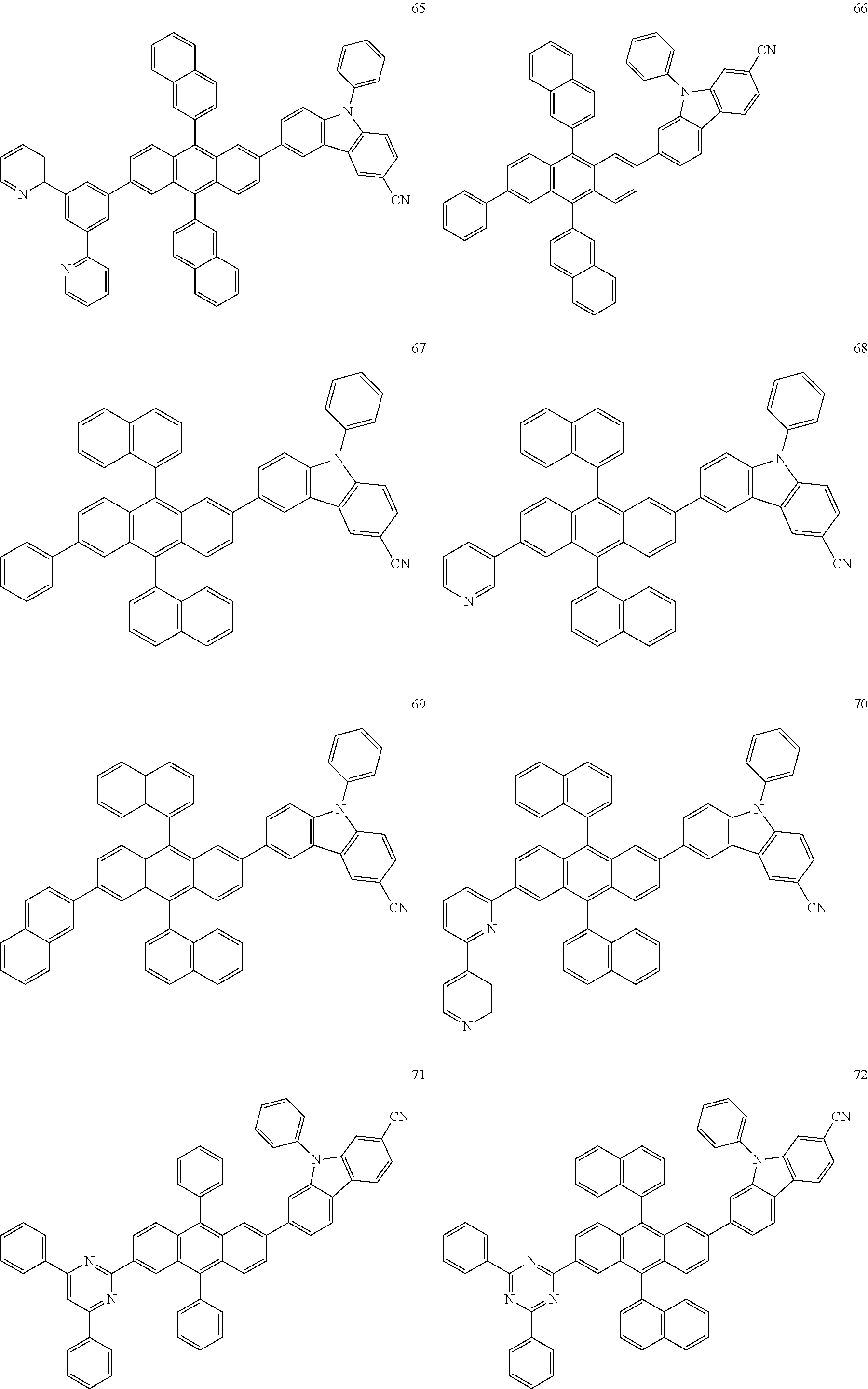

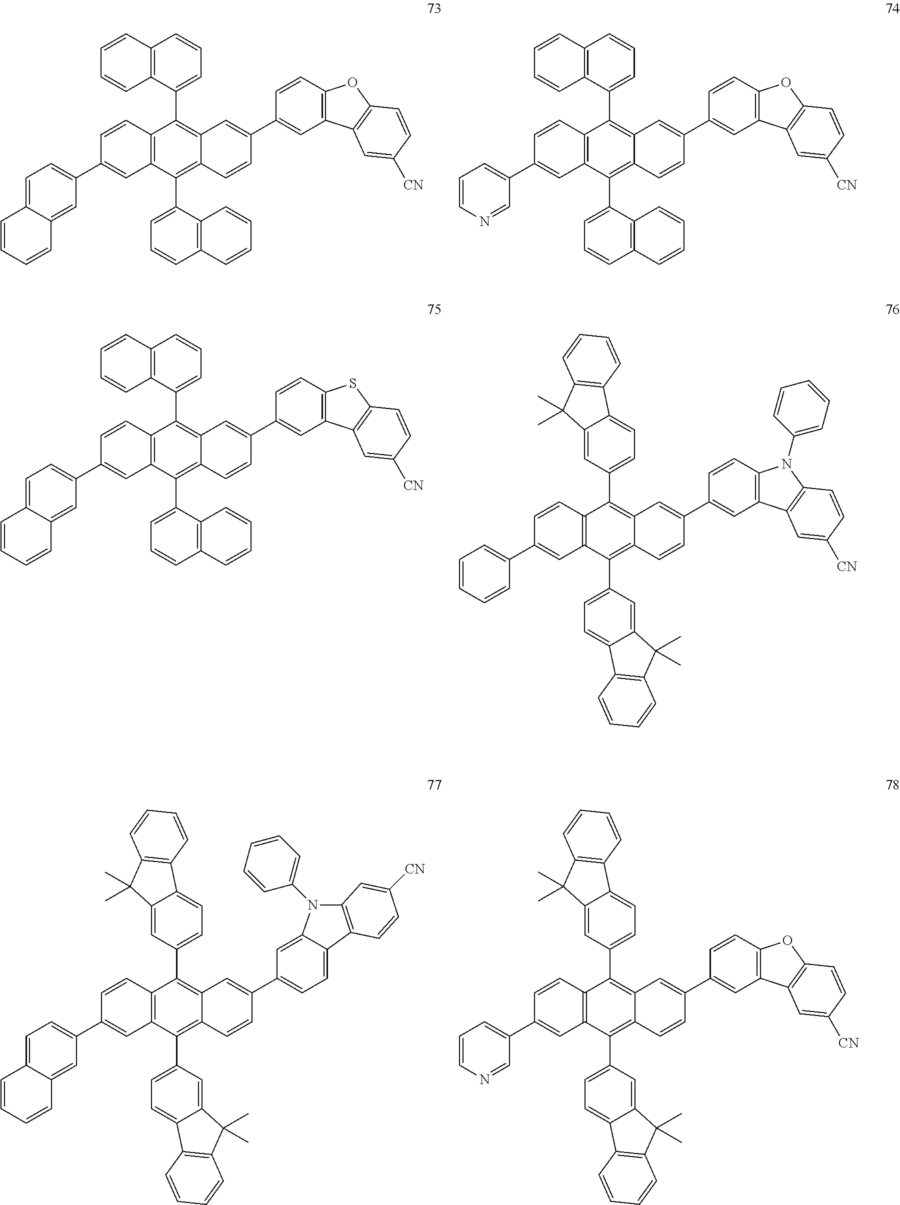

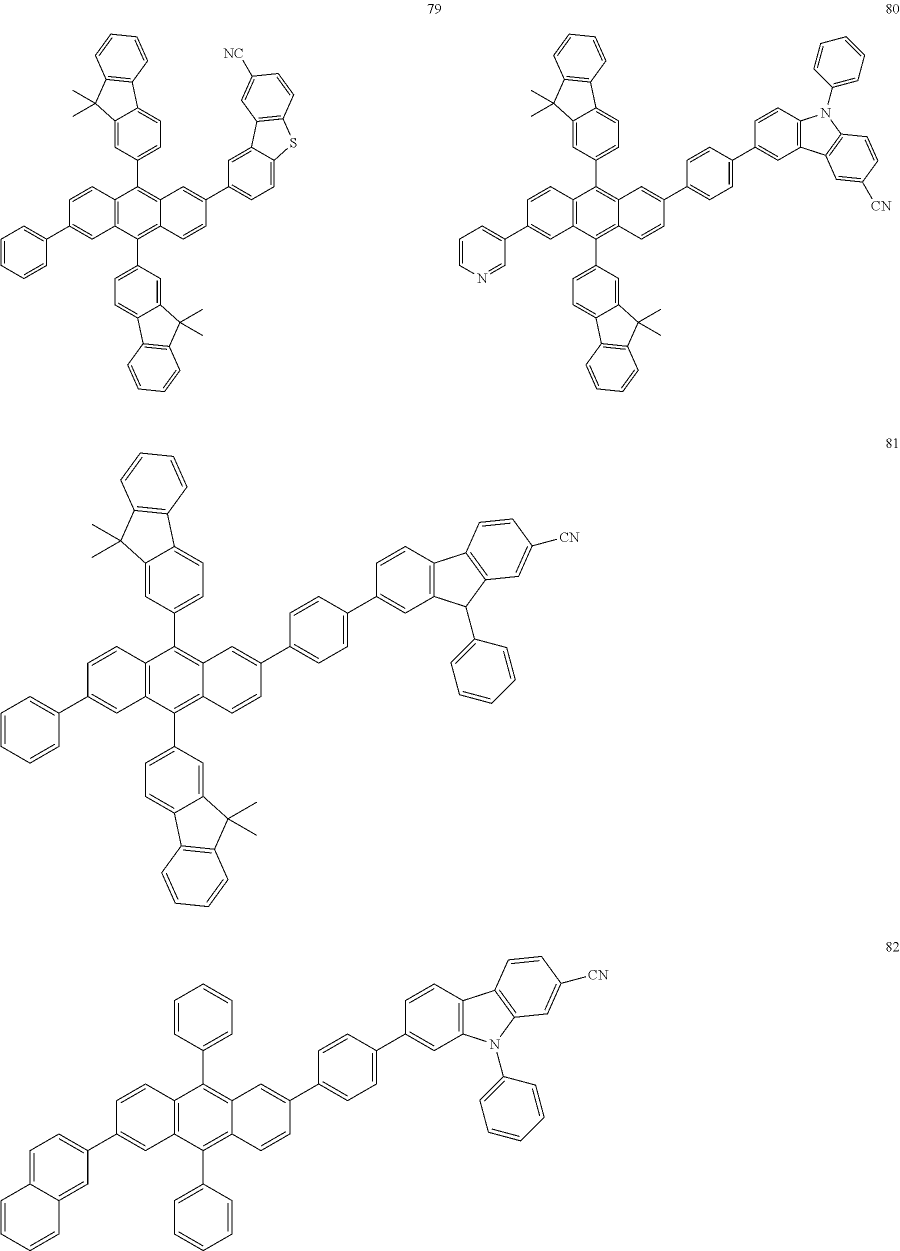

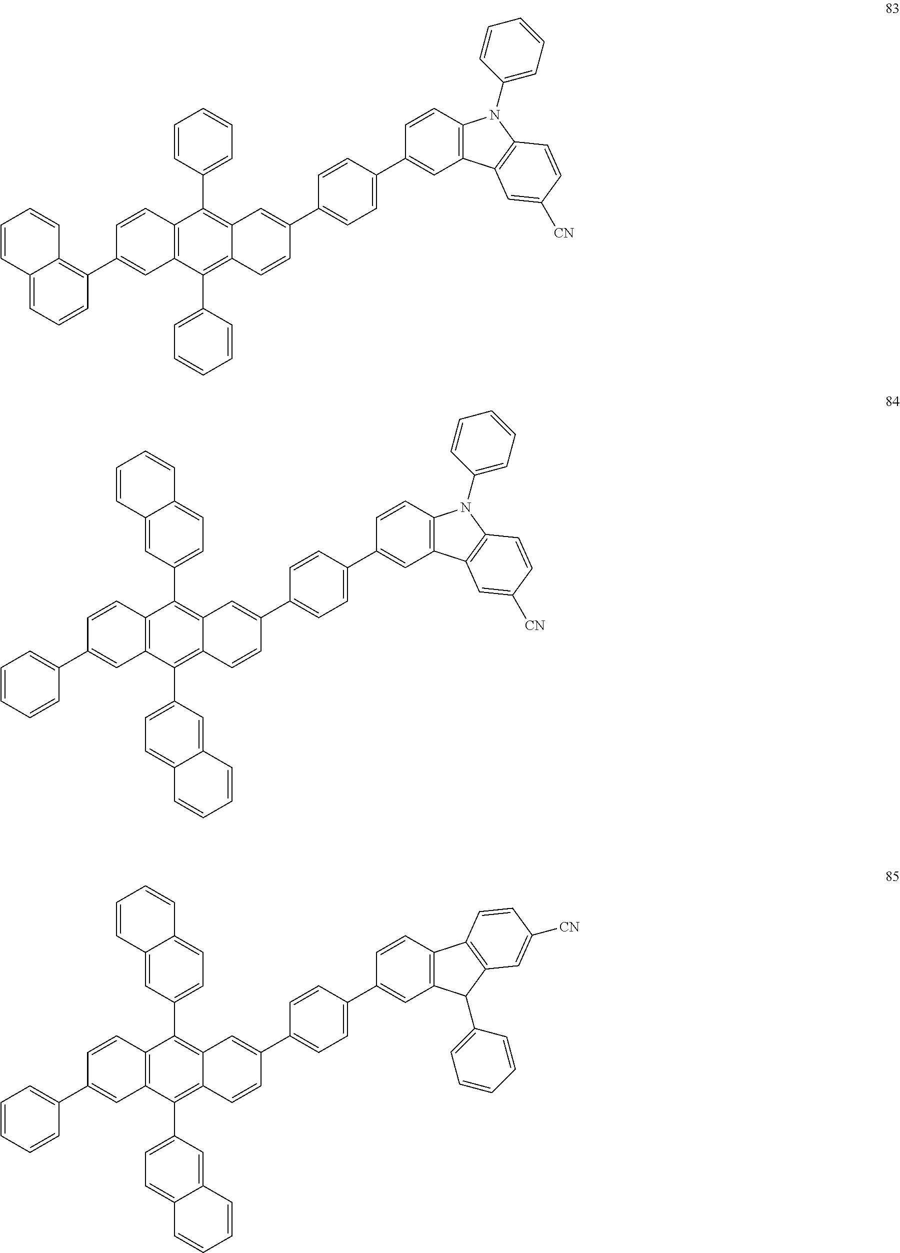 [SMILES: N#Cc1ccc2c(c1)c1cc(-c3ccc(-c4ccc5c(-c6ccccc6)c6cc(-c7cccc8ccccc78)ccc6c(-c6ccccc6)c5c4)cc3)ccc1n2-c1ccccc1 ; N#Cc1ccc2c(c1)c1cc(-c3ccc(-c4ccc5c(-c6ccc7ccccc7c6)c6cc(-c7ccccc7)ccc6c(-c6ccc7ccccc7c6)c5c4)cc3)ccc1n2-c1ccccc1 ; N#Cc1ccc2c(c1)C(c1ccccc1)c1cc(-c3ccc(-c4ccc5c(-c6ccc7ccccc7c6)c6cc(-c7ccccc7)ccc6c(-c6ccc7ccccc7c6)c5c4)cc3)ccc1-2]

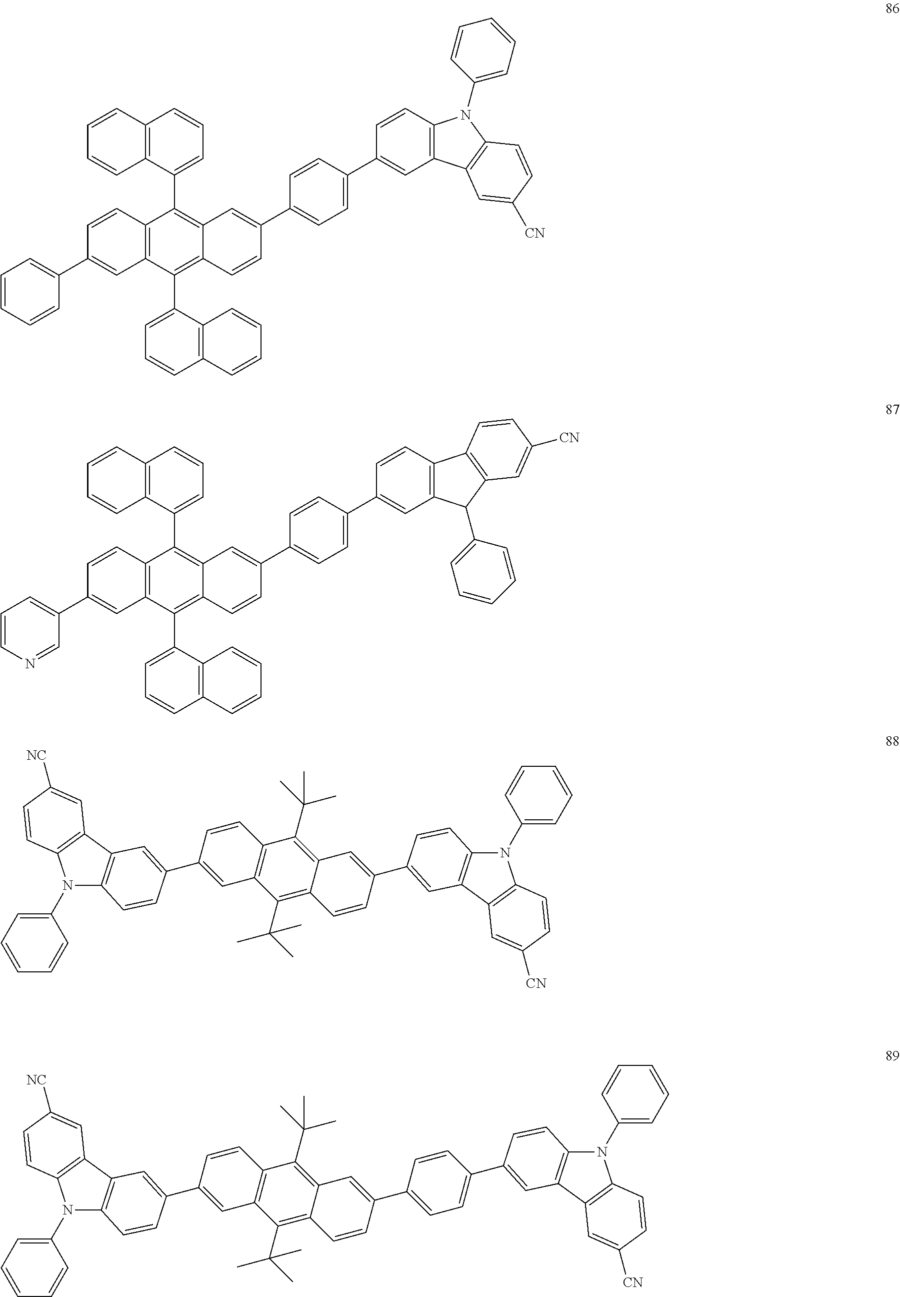 [SMILES: N#Cc1ccc2c(c1)c1cc(-c3ccc(-c4ccc5c(-c6cccc7ccccc67)c6cc(-c7ccccc7)ccc6c(-c6cccc7ccccc67)c5c4)cc3)ccc1n2-c1ccccc1 ; N#Cc1ccc2c(c1)C(c1ccccc1)c1cc(-c3ccc(-c4ccc5c(-c6cccc7ccccc67)c6cc(-c7cccnc7)ccc6c(-c6cccc7ccccc67)c5c4)cc3)ccc1-2 ; CC(C)(C)c1c2ccc(-c3ccc4c(c3)c3cc(C#N)ccc3n4-c3ccccc3)cc2c(C(C)(C)C)c2ccc(-c3ccc4c(c3)c3cc(C#N)ccc3n4-c3ccccc3)cc12 ; CC(C)(C)c1c2ccc(-c3ccc4c(c3)c3cc(C#N)ccc3n4-c3ccccc3)cc2c(C(C)(C)C)c2ccc(-c3ccc(-c4ccc5c(c4)c4cc(C#N)ccc4n5-c4ccccc4)cc3)cc12]

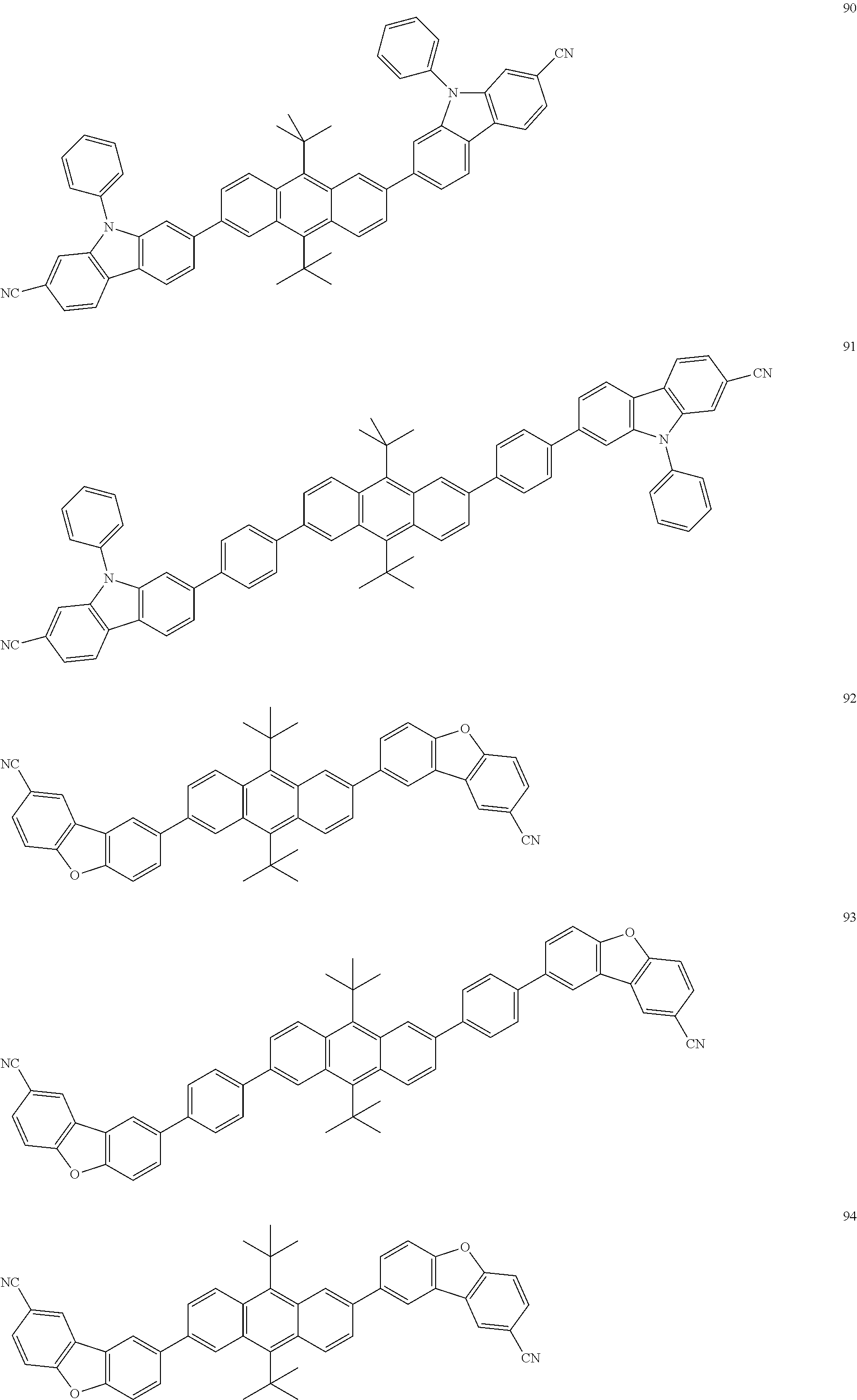

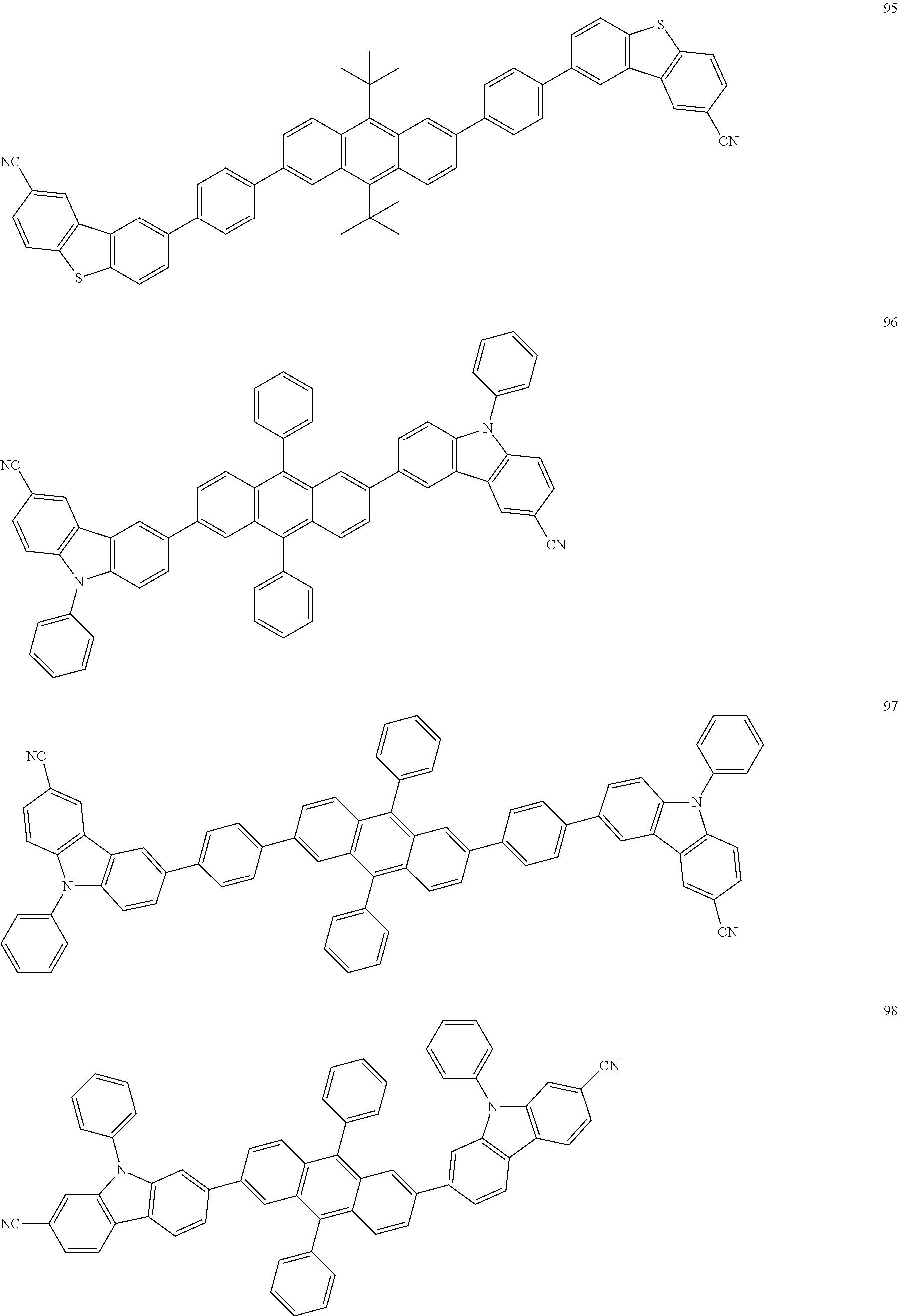 [SMILES: CC(C)(C)c1c2ccc(-c3ccc(-c4ccc5sc6ccc(C#N)cc6c5c4)cc3)cc2c(C(C)(C)C)c2ccc(-c3ccc(-c4ccc5sc6ccc(C#N)cc6c5c4)cc3)cc12 ; N#Cc1ccc2c(c1)c1cc(-c3ccc4c(-c5ccccc5)c5cc(-c6ccc7c(c6)c6cc(C#N)ccc6n7-c6ccccc6)ccc5c(-c5ccccc5)c4c3)ccc1n2-c1ccccc1 ; N#Cc1ccc2c(c1)c1cc(-c3ccc(-c4ccc5c(-c6ccccc6)c6cc(-c7ccc(-c8ccc9c(c8)c8cc(C#N)ccc8n9-c8ccccc8)cc7)ccc6c(-c6ccccc6)c5c4)cc3)ccc1n2-c1ccccc1 ; N#Cc1ccc2c3ccc(-c4ccc5c(-c6ccccc6)c6cc(-c7ccc8c9ccc(C#N)cc9n(-c9ccccc9)c8c7)ccc6c(-c6ccccc6)c5c4)cc3n(-c3ccccc3)c2c1]

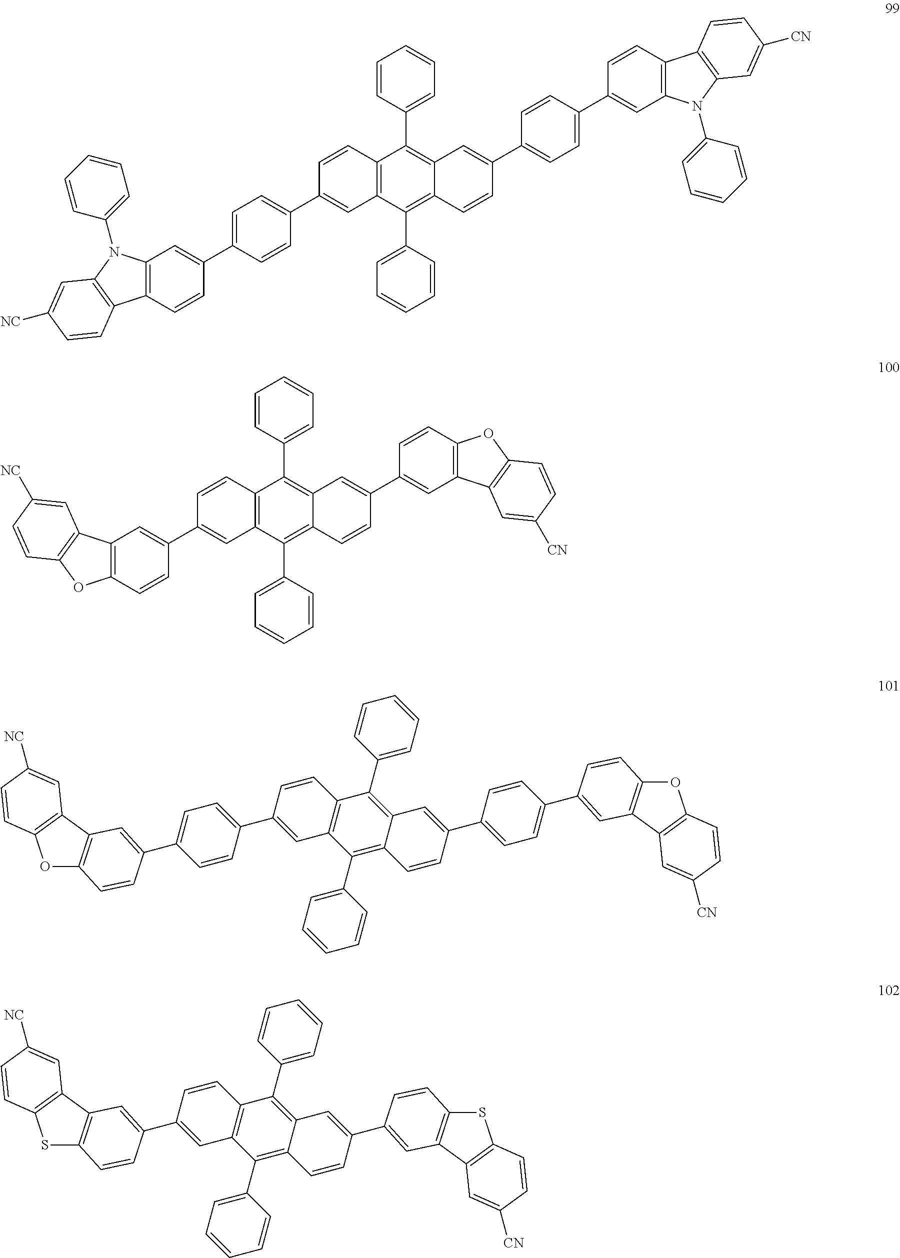 [SMILES: N#Cc1ccc2c3ccc(-c4ccc(-c5ccc6c(-c7ccccc7)c7cc(-c8ccc(-c9ccc%10c%11ccc(C#N)cc%11n(-c%11ccccc%11)c%10c9)cc8)ccc7c(-c7ccccc7)c6c5)cc4)cc3n(-c3ccccc3)c2c1 ; N#Cc1ccc2oc3ccc(-c4ccc5c(-c6ccccc6)c6cc(-c7ccc8oc9ccc(C#N)cc9c8c7)ccc6c(-c6ccccc6)c5c4)cc3c2c1 ; N#Cc1ccc2oc3ccc(-c4ccc(-c5ccc6c(-c7ccccc7)c7cc(-c8ccc(-c9ccc%10oc%11ccc(C#N)cc%11c%10c9)cc8)ccc7c(-c7ccccc7)c6c5)cc4)cc3c2c1 ; N#Cc1ccc2sc3ccc(-c4ccc5c(-c6ccccc6)c6cc(-c7ccc8sc9ccc(C#N)cc9c8c7)ccc6c(-c6ccccc6)c5c4)cc3c2c1]

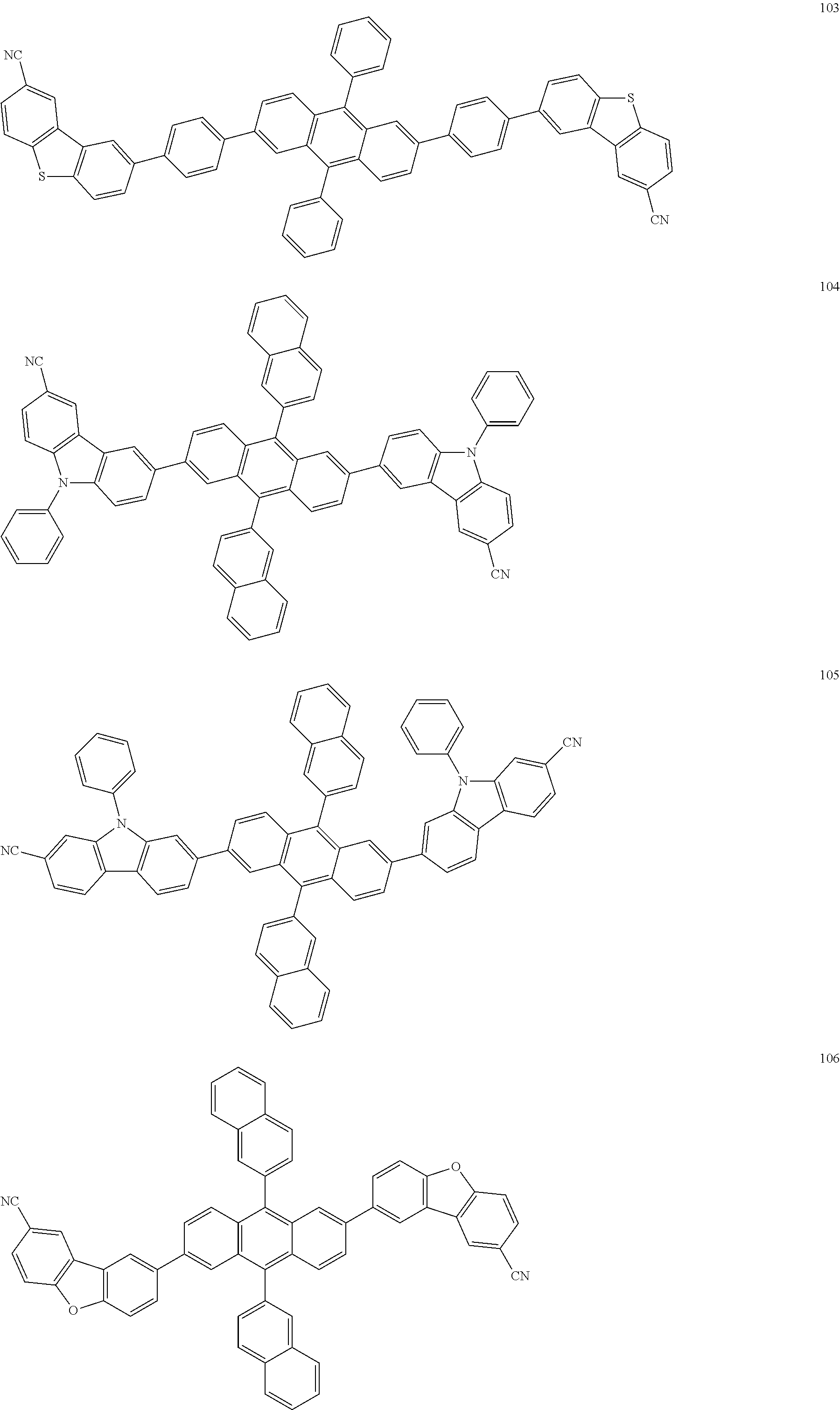

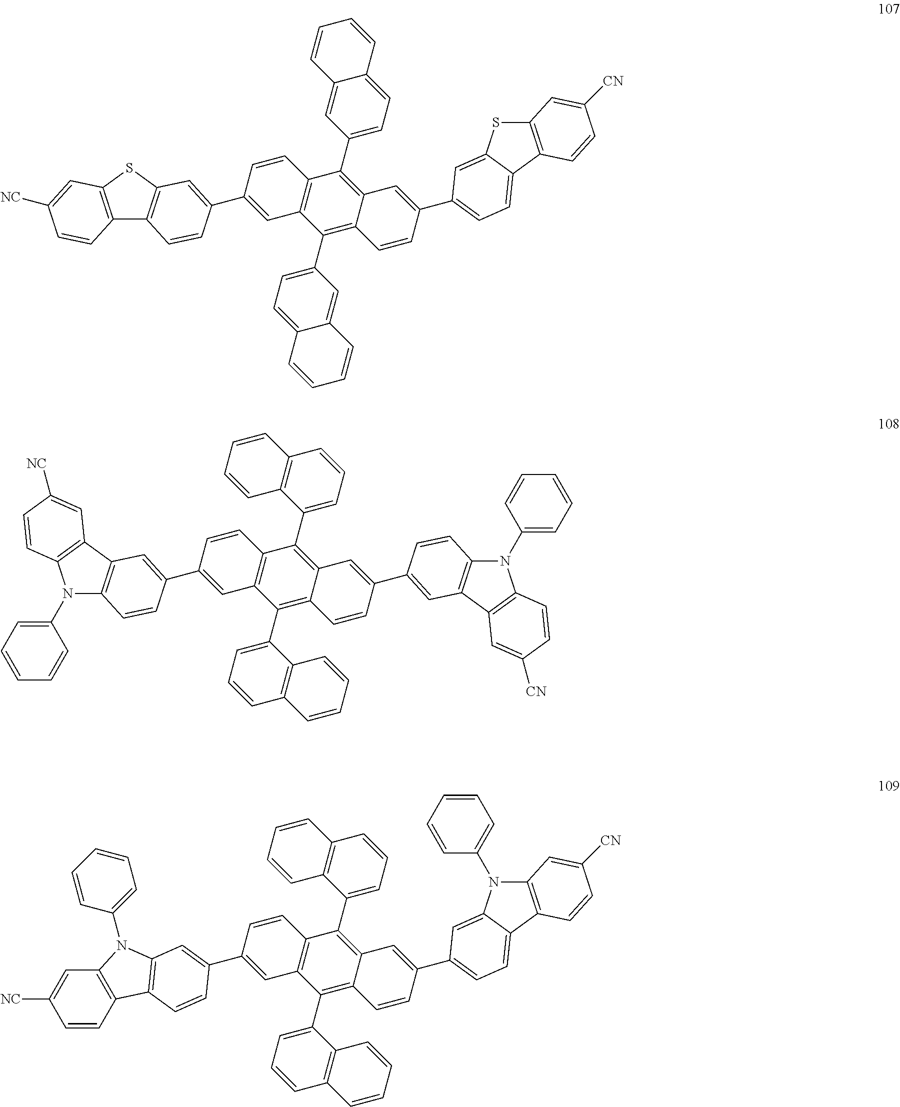 [SMILES: N#Cc1ccc2c(c1)sc1cc(-c3ccc4c(-c5ccc6ccccc6c5)c5cc(-c6ccc7c(c6)sc6cc(C#N)ccc67)ccc5c(-c5ccc6ccccc6c5)c4c3)ccc12 ; N#Cc1ccc2c(c1)c1cc(-c3ccc4c(-c5cccc6ccccc56)c5cc(-c6ccc7c(c6)c6cc(C#N)ccc6n7-c6ccccc6)ccc5c(-c5cccc6ccccc56)c4c3)ccc1n2-c1ccccc1 ; N#Cc1ccc2c3ccc(-c4ccc5c(-c6cccc7ccccc67)c6cc(-c7ccc8c9ccc(C#N)cc9n(-c9ccccc9)c8c7)ccc6c(-c6cccc7ccccc67)c5c4)cc3n(-c3ccccc3)c2c1]

The condensed compound represented by Formula 1 or Formula 2 may be synthesized using an organic synthesis method. A synthesis method of the condensed compound may be determined by one of skill in the art in view of the following embodiments.

The condensed compound of Formula 1 or Formula 2 may be used between a pair of electrodes of an organic light-emitting diode. For example, the condensed compound may be included in an electron transport region, for example, an electron transport layer. Accordingly, an organic light-emitting diode according to an embodiment includes: a first electrode; a second electrode facing the first electrode; and an organic layer that is disposed between the first and second electrodes and includes an emission layer, wherein the organic layer includes at least one of the condensed compounds described above.

The expression “(an organic layer) includes at least one condensed compound” used herein includes a case in which “(an organic layer) includes one condensed compound of Formula 1 or Formula 2 and a case in which (an organic layer) includes two or more different condensed compounds of Formula 1 or Formula 2”.

For example, the organic layer may include, as the condensed compound, only Compound 1. In this regard, Compound 1 may exist in an electron transport layer of the organic light-emitting diode. In another embodiment, the organic layer may include, as the condensed compound, Compound 1 and Compound 2. In this regard, Compound 1 and Compound 2 may exist in an identical layer (for example, Compound 1 and Compound 2 may both exist in an electron transport layer), or different layers (for example, Compound 1 may exist in an emission layer and Compound 2 may exist in an electron transport layer).

The organic layer includes i) a hole transport region that is disposed between the first electrode and the emission layer and includes at least one of a hole injection layer, a hole transport layer, a buffer layer, and an electron blocking layer, and ii) an electron transport region that is disposed between the emission layer and the second electrode and includes at least one selected from a hole blocking layer, an electron transport layer, and an electron injection layer. The electron transport region may include a condensed compound represented by Formula 1 or Formula 2. For example, the electron transport region may include an electron transport layer including the condensed compound represented in Formula 1 or Formula 2.

The expression “organic layer” used herein refers to a single layer and/or a plurality of layers disposed between the first and second electrodes of an organic light-emitting diode. Each material of the “organic layer” is not limited to being an organic material.

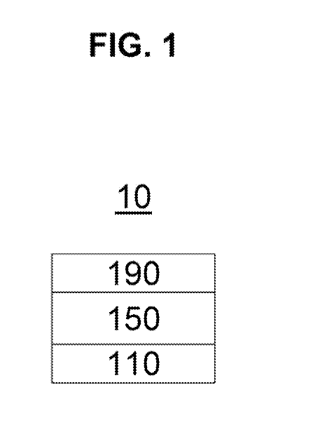

FIG. 1 illustrates a schematic view of an organic light-emitting diode 10 according to an embodiment. The organic light-emitting diode 10 includes a first electrode 110, an organic layer 150, and a second electrode 190.

Hereinafter, the structure of an organic light-emitting diode according to an embodiment and a method of manufacturing an organic light-emitting diode, according to an embodiment, will be described in connection with FIG. 1.

In FIG. 1, a substrate may be additionally disposed under the first electrode 110 or above the second electrode 190. The substrate may be a glass substrate or a transparent plastic substrate, each with excellent mechanical strength, thermal stability, transparency, surface smoothness, ease of handling, and water repellency.

The first electrode 110 may be formed by depositing or sputtering a material for forming the first electrode 110 on the substrate. When the first electrode 110 is an anode, the material for the first electrode 110 may be selected from materials with a high work function to make holes be easily injected. The first electrode 110 may be a reflective electrode or a transmissive electrode. The material for the first electrode 110 may be a transparent and highly conductive material, and examples of such a material are indium tin oxide (ITO), indium zinc oxide (IZO), tin oxide (SnO₂), and zinc oxide (ZnO). When the first electrode 110 is a semi-transmissive electrode or a reflective electrode, a material for forming the first electrode 110 may include at least one of magnesium (Mg), aluminum (Al), aluminum-lithium (Al—Li), calcium (ca), magnesium-indium (Mg—In), and magnesium-silver (Mg—Ag).

The first electrode 110 may have a single-layer structure, or a multi-layer structure including, two or more layers. For example, the first electrode 110 may have a three-layered structure of ITO/Ag/ITO.

The organic layer 150 is disposed on the first electrode 110. The organic layer 150 may include an emission layer.

The organic layer 150 may further include a hole transport region disposed between the first electrode 110 and the emission layer, and an electron transport region disposed between the emission layer and the second electrode 190.

The hole transport region may include at least one selected from a hole injection layer, a hole transport layer, a buffer layer, and an electron blocking layer, and the electron transport region may include at least one selected from a hole blocking layer, an electron transport layer, and an electron injection layer.

The hole transport region may have a single-layered structure formed using a single material, a single-layered structure formed using different materials, or a multi-layered structure having a plurality of layers formed using different materials.

For example, the hole transport region may have a single-layered structure formed using different materials, or a structure of hole injection layer/hole transport layer, a structure of hole injection layer/hole transport layer/buffer layer, a structure of hole injection layer/buffer layer, a structure of hole transport layer/buffer layer, or a structure of hole injection layer/hole transport layer/electron blocking layer, wherein layers of each structure are sequentially stacked from the first electrode 110 in this stated order.

When the hole transport region includes a hole injection layer, the hole injection layer may be formed on the first electrode 110 by various methods, such as vacuum deposition, spin coating, casting, a Langmuir-Blodgett (LB) method, ink-jet printing, laser-printing, or laser-induced thermal imaging.

When a hole injection layer is formed by vacuum deposition, for example, the vacuum deposition may be performed at a deposition temperature of about 100 to about 500° C., at a vacuum degree of about 10⁻⁸ to about 10⁻³ torr, and at a deposition rate of about 0.01 to about 100 Å/sec in consideration of a compound for a hole injection layer to be deposited, and the structure of a hole injection layer to be formed.

When a hole injection layer is formed by spin coating, the spin coating may be performed at a coating rate of about 2000 rpm to about 5000 rpm, and at a temperature of about 80° C. to 200° C. in consideration of a compound for a hole injection layer to be deposited, and the structure of a hole injection layer to be formed.

When the hole transport region includes a hole transport layer, the hole transport layer may be formed on the first electrode 110 or the hole injection layer by various methods, such as vacuum deposition, spin coating, casting, an LB method, ink-jet printing, laser-printing, or laser-induced thermal imaging. When the hole transport layer is formed by vacuum deposition or spin coating, deposition and coating conditions for the hole transport layer may be determined by referring to the deposition and coating conditions for the hole injection layer.

The hole transport region may include at least one selected from m-MTDATA, TDATA, 2-TNATA, NPB, β-NPB, TPD, Spiro-TPD, Spiro-NPB, α-NPB, TAPC, HMTPD, 4,4′,4″-tris(N-carbazolyl)triphenylamine (TCTA), polyaniline/dodecyclbenzenesulfonic acid (Pani/DBSA), poly(3,4-ethylenedioxythiophene)/poly(4-styrenesulfonate) (PEDOT/PSS), polyaniline/camphor sulfonic acid (Pani/CSA), (polyaniline)/poly(4-styrenesulfonate) (PANI/PSS), a compound represented by Formula 201 below, and a compound represented by Formula 202 below:

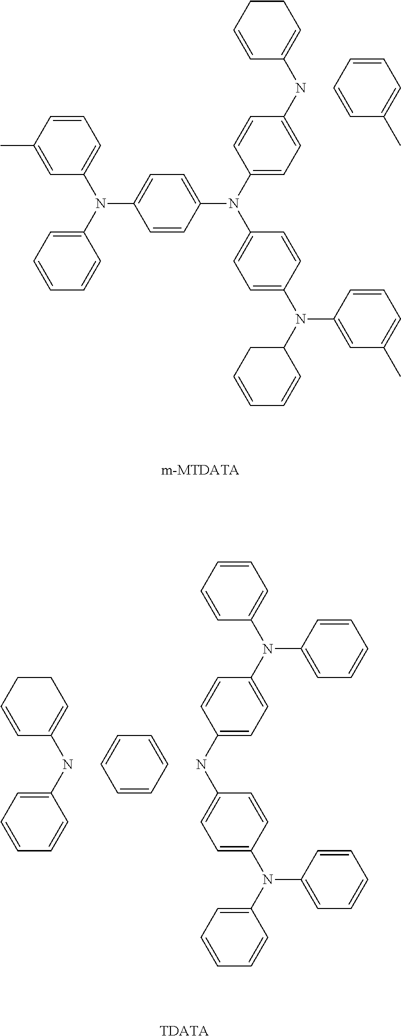

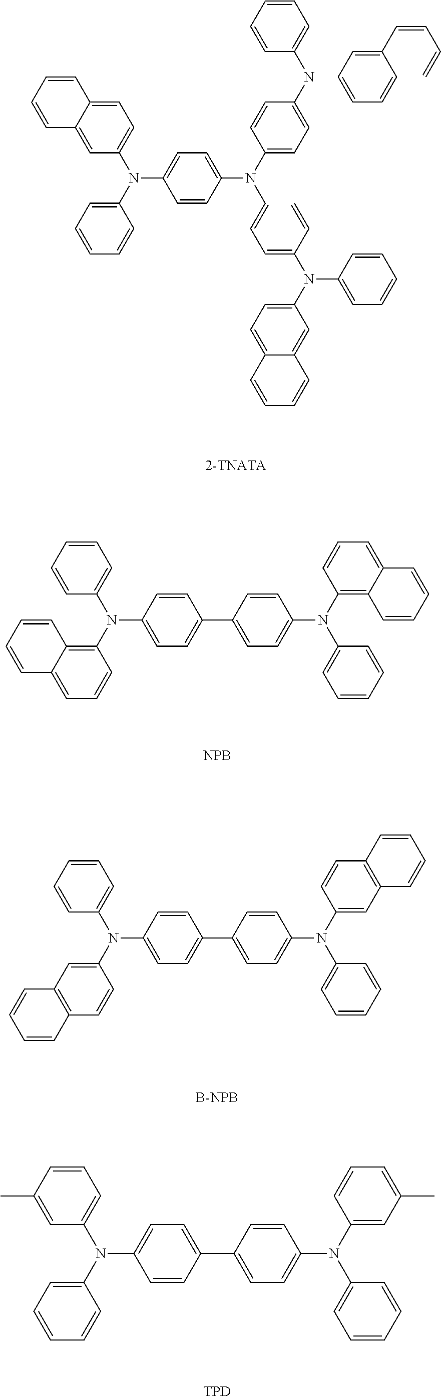

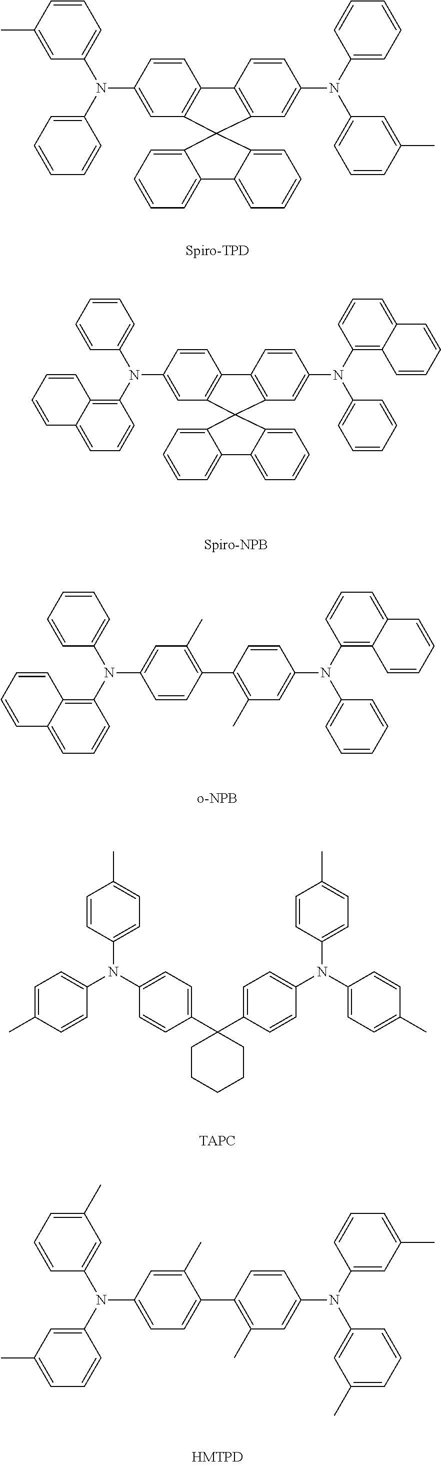

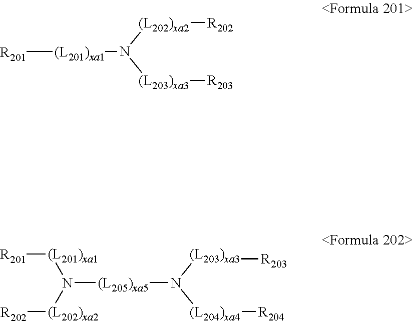

wherein in Formulae 201 and 202,

L₂₀₁ to L₂₀₅ may be understood by referring to the description provided herein in connection with L₁;

xa1 to xa4 may each independently be selected from 0, 1, 2, and 3;

xa5 may be selected from 1, 2, 3, 4, and 5; and

R₂₀₁ to R₂₀₅ may be understood by referring to the description provided herein in connection with R₂₁.

In Formulae 201 and 202,

L₂₀₁ to L₂₀₅ may each independently be selected from

a phenylene group, a naphthylene group, a fluorenylene group, a spiro-fluorenylene group, a benzofluoenylene group, a dibenzofluoenylene group, a phenanthrenylene group, an anthracenylene group, a pyrenylene group, a chrysenylene group, a pyridinylene group, a pyrazinylene group, a pyrimidinylene group, a pyridazinylene group, a quinolinylene group, an isoquinolinylene group, a quinoxalinylene group, a quinazolinylene group, a carbazolylene group and a triazinylene group; and

a phenylene group, naphthylene group, a fluorenylene group, a spiro-fluorenylene group, a benzofluoenylene group, a dibenzofluoenylene group, a phenanthrenylene group, an anthracenylene group, a pyrenylene group, a chrysenylene group, a pyridinylene group, a pyrazinylene group, a pyrimidinylene group, a pyridazinylene group, a quinolinylene group, an isoquinolinylene group, a quinoxalinylene group, a quinazolinylene group, a carbazolylene group and a triazinylene group, each substituted with at least one selected from a deuterium, —F, —Cl, —Br, —I, a hydroxyl group, a cyano group, a nitro group, an amino group, an amidino group, a hydrazine group, a hydrazone group, a carboxylic acid and a salt thereof, a sulfonic acid and a salt thereof, a phosphoric acid and a salt thereof, a C₁-C₂₀ alkyl group, a C₁-C₂₀ alkoxy group, a phenyl group, a naphthyl group, a fluorenyl group, a spiro-fluorenyl group, a benzofluorenyl group, a dibenzofluorenyl group, a phenanthrenyl group, an anthracenyl group, a pyrenyl group, a chrysenyl group, a pyridinyl group, a pyrazinyl group, a pyrimidinyl group, a pyridazinyl group, an isoindolyl group, a quinolinyl group, an isoquinolinyl group, a quinoxalinyl group, a quinazolinyl group, a carbazolyl group and a triazinyl group;

xa1 to xa4 may each independently be 0, 1, or 2;

xa5 may be 1, 2, or 3; and

R₂₀₁ to R₂₀₅ are each independently selected from

a phenyl group, a naphthyl group, a fluorenyl group, a spiro-fluorenyl group, a benzofluorenyl group, a dibenzofluorenyl group, a phenanthrenyl group, an anthracenyl group, a pyrenyl group, a chrysenyl group, a pyridinyl group, a pyrazinyl group, a pyrimidinyl group, a pyridazinyl group, a quinolinyl group, an isoquinolinyl group, a quinoxalinyl group, a quinazolinyl group, a carbazolyl group and a triazinyl group; and

a phenyl group, a naphthyl group, a fluorenyl group, a spiro-fluorenyl group, a benzofluorenyl group, a dibenzofluorenyl group, a phenanthrenyl group, an anthracenyl group, a pyrenyl group, a chrysenyl group, a pyridinyl group, a pyrazinyl group, a pyrimidinyl group, a pyridazinyl group, a quinolinyl group, an isoquinolinyl group, a quinoxalinyl group, a quinazolinyl group, a carbazolyl group and a triazinyl group, each substituted with at least one selected from a deuterium, —F, —Cl, —Br, —I, a hydroxyl group, a cyano group, a nitro group, an amino group, an amidino group, a hydrazine group, a hydrazone group, a carboxylic acid and a salt thereof, a sulfonic acid and a salt thereof, a phosphoric acid and a salt thereof, a C₁-C₂₀ alkyl group, a C₁-C₂₀ alkoxy group, a phenyl group, a naphthyl group, a fluorenyl group, a spiro-fluorenyl group, a benzofluorenyl group, a dibenzofluorenyl group, a phenanthrenyl group, an anthracenyl group, a pyrenyl group, a chrysenyl group, a pyridinyl group, a pyrazinyl group, a pyrimidinyl group, a pyridazinyl group, a quinolinyl group, an isoindolyl group, a quinoxalinyl group, a quinazolinyl group, a carbazolyl group and a triazinyl group.

The compound represented by Formula 201 may be represented by Formula 201A:

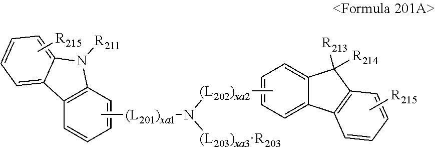

For example, the compound represented by Formula 201 may be represented by Formula 201A-1 below:

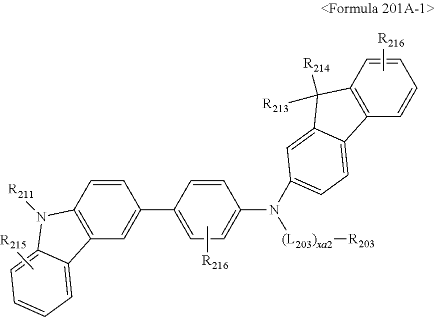

For example, the compound represented by Formula 202 may be represented by Formula 202A below:

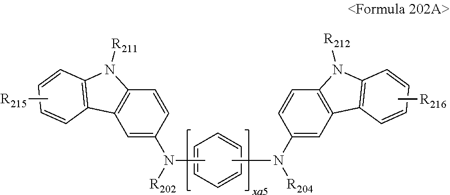

L₂₀₁ to L₂₀₃, xa1 to xa3, xa5, and R₂₀₂ to R₂₀₄ in Formulae 201A, 201A-1, and 202A are described above, R₂₁₁ may be understood by referring to the description provided in connection with R₂₀₃, and R₂₁₃ to R₂₁₆ may each independently be selected from a hydrogen, a deuterium, —F, —Cl, —Br, —I, a hydroxyl group, a cyano group, a nitro group, an amino group, an amidino group, a hydrazine group, a hydrazone group, a carboxylic acid and a salt thereof, a sulfonic acid and a salt thereof, a phosphoric acid and a salt thereof, a C₁-C₆₀ alkyl group, a C₂-C₆₀ alkenyl group, a C₁-C₆₀ alkoxy group, a C₃-C₁₀ cycloalkyl group, a C₂-C₁₀ heterocycloalkyl group, a C₃-C₁₀ cycloalkenyl group, a C₂-C₁₀ heterocycloalkenyl group, a C₆-C₆₀ aryl group, a C₆-C₆₀ aryloxy group, a C₆-C₆₀ arylthio group, a C₂-C₆₀ heteroaryl group, a monovalent non-aromatic condensed polycyclic group and a monovalent non-aromatic hetero-condensed polycyclic group.

For example,

L₂₀₁ to L₂₀₃ in Formulae 201A, 201A-1, and 202A may each independently be selected from

a phenylene group, a naphthylene group, a fluorenylene group, a spiro-fluorenylene group, a benzofluorenylene group, a dibenzofluorenylene group, a phenanthrenylene group, an anthracenylene group, a pyrenylene group, a chrysenylene group, a pyridinylene group, a pyrazinylene group, a pyrimidinylene group, a pyridazinylene group, a quinolinylene group, an isoquinolinylene group, a quinoxalinylene group, a quinazolinylene group, a carbazolylene group, and a triazinylene group; and

a phenylene group, a naphthylene group, a fluorenylene group, a spiro-fluorenylene group, a benzofluorenylene group, a dibenzofluorenylene group, a phenanthrenylene group, an anthracenylene group, a pyrenylene group, a chrysenylene group, a pyridinylene group, a pyrazinylene group, a pyrimidinylene group, a pyridazinylene group, a quinolinylene group, an isoquinolinylene group, a quinoxalinylene group, a quinazolinylene group, a carbazolylene group, and a triazinylene group, each substituted with at least one selected from a deuterium, —F, —Cl, —Br, —I, a hydroxyl group, a cyano group, a nitro group, an amino group, an amidino group, a hydrazine group, a hydrazone group, a carboxylic acid and a salt thereof, a sulfonic acid and a salt thereof, a phosphoric acid and a salt thereof, a C₁-C₂₀ alkyl group, a C₁-C₂₀ alkoxy group, a phenyl group, a naphthyl group, a fluorenyl group, a spiro-fluorenyl group, a benzofluorenyl group, a dibenzofluorenyl group, a phenanthrenyl group, an anthracenyl group, a pyrenyl group, a chrysenyl group, a pyridinyl group, a pyrazinyl group, a pyrimidinyl group, a pyridazinyl group, a quinolinyl group, an isoquinolinyl group, a quinoxalinyl group, a quinazolinyl group, a carbazolyl group and a triazinyl group;

xa1 to xa3 may each independently be 0 or 1;

R₂₀₃, R₂₁₁, and R₂₁₂ may each independently be selected from

a phenyl group, a naphthyl group, a fluorenyl group, a spiro-fluorenyl group, a benzofluorenyl group, a dibenzofluorenyl group, a phenanthrenyl group, an anthracenyl group, a pyrenyl group, a chrysenyl group, a pyridinyl group, a pyrazinyl group, a pyrimidinyl group, a pyridazinyl group, a quinolinyl group, an isoquinolinyl group, a quinoxalinyl group, a quinazolinyl group, a carbazolyl group and a triazinyl group; and

a phenyl group, a naphthyl group, a fluorenyl group, a spiro-fluorenyl group, a benzofluorenyl group, a dibenzofluorenyl group, a phenanthrenyl group, an anthracenyl group, a pyrenyl group, a chrysenyl group, a pyridinyl group, a pyrazinyl group, a pyrimidinyl group, a pyridazinyl group, a quinolinyl group, an isoquinolinyl group, a quinoxalinyl group, a quinazolinyl group, a carbazolyl group and a triazinyl group, each substituted with at least one selected from a deuterium, —F, —Cl, —Br, —I, a hydroxyl group, a cyano group, a nitro group, an amino group, an amidino group, a hydrazine group, a hydrazone group, a carboxylic acid and a salt thereof, a sulfonic acid and a salt thereof, a phosphoric acid and a salt thereof, a C₁-C₂₀ alkyl group, a C₁-C₂₀ alkoxy group, a phenyl group, a naphthyl group, a fluorenyl group, a spiro-fluorenyl group, a benzofluorenyl group, a dibenzofluorenyl group, a phenanthrenyl group, an anthracenyl group, a pyrenyl group, a chrysenyl group, a pyridinyl group, a pyrazinyl group, a pyrimidinyl group, a pyridazinyl group, a quinolinyl group, an isoquinolinyl group, a quinoxalinyl group, a quinazolinyl group, a carbazolyl group and a triazinyl group;

R₂₁₃ and R₂₁₄ are each independently selected from

a C₁-C₂₀ alkyl group and a C₁-C₂₀ alkoxy group;

a C₁-C₂₀ alkyl group and a C₁-C₂₀ alkoxy group, each substituted with at least one selected from a deuterium, —F, —Cl, —Br, —I, a hydroxyl group, a cyano group, a nitro group, an amino group, an amidino group, a hydrazine group, a hydrazone group, a carboxylic acid and a salt thereof, a sulfonic acid and a salt thereof, a phosphoric acid and a salt thereof, a phenyl group, a naphthyl group, a fluorenyl group, a spiro-fluorenyl group, a benzofluorenyl group, a dibenzofluorenyl group, a phenanthrenyl group, an anthracenyl group, a pyrenyl group, a chrysenyl group, a pyridinyl group, a pyrazinyl group, a pyrimidinyl group, a pyridazinyl group, a quinolinyl group, an isoquinolinyl group, a quinoxalinyl group, a quinazolinyl group, a carbazolyl group and a triazinyl group;

a phenyl group, a naphthyl group, a fluorenyl group, a spiro-fluorenyl group, a benzofluorenyl group, a dibenzofluorenyl group, a phenanthrenyl group, an anthracenyl group, a pyrenyl group, a chrysenyl group, a pyridinyl group, a pyrazinyl group, a pyrimidinyl group, a pyridazinyl group, a quinolinyl group, an isoquinolinyl group, a quinoxalinyl group, a quinazolinyl group, a carbazolyl group and a triazinyl group; and

a phenyl group, a naphthyl group, a fluorenyl group, a spiro-fluorenyl group, a benzofluorenyl group, a dibenzofluorenyl group, a phenanthrenyl group, an anthracenyl group, a pyrenyl group, a chrysenyl group, a pyridinyl group, a pyrazinyl group, a pyrimidinyl group, a pyridazinyl group, a quinolinyl group, an isoquinolinyl group, a quinoxalinyl group, a quinazolinyl group, a carbazolyl group and a triazinyl group, each substituted with at least one selected from a deuterium, —F, —Cl, —Br, —I, a hydroxyl group, a cyano group, a nitro group, an amino group, an amidino group, a hydrazine group, a hydrazone group, a carboxylic acid and a salt thereof, a sulfonic acid and a salt thereof, a phosphoric acid and a salt thereof, a C₁-C₂₀ alkyl group, a C₁-C₂₀ alkoxy group, a phenyl group, a naphthyl group, a fluorenyl group, a spiro-fluorenyl group, a benzofluorenyl group, a dibenzofluorenyl group, a phenanthrenyl group, an anthracenyl group, a pyrenyl group, a chrysenyl group, a pyridinyl group, a pyrazinyl group, a pyrimidinyl group, a pyridazinyl group, a quinolinyl group, an isoquinolinyl group, a quinoxalinyl group, a quinazolinyl group, a carbazolyl group and a triazinyl group;

R₂₁₅ and R₂₁₆ are each independently selected from

a hydrogen, a deuterium, —F, —Cl, —Br, —I, a hydroxyl group, a cyano group, a nitro group, an amino group, an amidino group, a hydrazine group, a hydrazone group, a carboxylic acid and a salt thereof, a sulfonic acid and a salt thereof, a phosphoric acid and a salt thereof, a C₁-C₂₀ alkyl group, a C₁-C₂₀ alkoxy group;

a C₁-C₂₀ alkyl group and a C₁-C₂₀ alkoxy group, each substituted with at least one selected from a deuterium, —F, —Cl, —Br, —I, a hydroxyl group, a cyano group, a nitro group, an amino group, an amidino group, a hydrazine group, a hydrazone group, a carboxylic acid and a salt thereof, a sulfonic acid and a salt thereof, a phosphoric acid and a salt thereof, a phenyl group, a naphthyl group, a fluorenyl group, a spiro-fluorenyl group, a benzofluorenyl group, a dibenzofluorenyl group, a phenanthrenyl group, an anthracenyl group, a pyrenyl group, a chrysenyl group, a pyridinyl group, a pyrazinyl group, a pyrimidinyl group, a pyridazinyl group, a quinolinyl group, an isoquinolinyl group, a quinoxalinyl group, a quinazolinyl group, a carbazolyl group and a triazinyl group;

a phenyl group, a naphthyl group, a fluorenyl group, a spiro-fluorenyl group, a benzofluorenyl group, a dibenzofluorenyl group, a phenanthrenyl group, an anthracenyl group, a pyrenyl group, a chrysenyl group, a pyridinyl group, a pyrazinyl group, a pyrimidinyl group, a pyridazinyl group, a quinolinyl group, an isoquinolinyl group, a quinoxalinyl group, a quinazolinyl group, a carbazolyl group and a triazinyl group;

a phenyl group, a naphthyl group, a fluorenyl group, a spiro-fluorenyl group, a benzofluorenyl group, a dibenzofluorenyl group, a phenanthrenyl group, an anthracenyl group, a pyrenyl group, a chrysenyl group, a pyridinyl group, a pyrazinyl group, a pyrimidinyl group, a pyridazinyl group, a quinolinyl group, an isoquinolinyl group, a quinoxalinyl group, a quinazolinyl group, a carbazolyl group and a triazinyl group, each substituted with at least one selected from a deuterium, —F, —Cl, —Br, —I, a hydroxyl group, a cyano group, a nitro group, an amino group, an amidino group, a hydrazine group, a hydrazone group, a carboxylic acid and a salt thereof, a sulfonic acid and a salt thereof, a phosphoric acid and a salt thereof, a C₁-C₂₀ alkyl group, a C₁-C₂₀ alkoxy group, a phenyl group, a naphthyl group, a fluorenyl group, a spiro-fluorenyl group, a benzofluorenyl group, a dibenzofluorenyl group, a phenanthrenyl group, an anthracenyl group, a pyrenyl group, a chrysenyl group, a pyridinyl group, a pyrazinyl group, a pyrimidinyl group, a pyridazinyl group, a quinolinyl group, an isoquinolinyl group, a quinoxalinyl group, a quinazolinyl group, a carbazolyl group and a triazinyl group; and

xa5 may be 1 or 2.

R₂₁₃ and R₂₁₄ in Formulae 201A and 201A-1 may bind to each other to form a saturated or unsaturated ring.

the compound represented by Formula 201 and the compound represented by Formula 202 may include compounds HT1 to HT20 illustrated below:

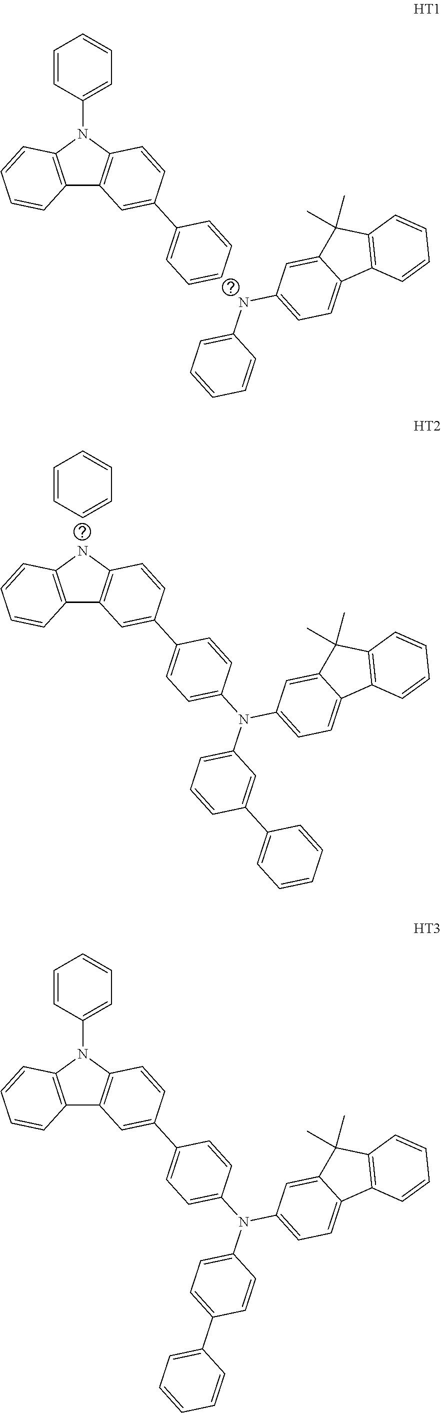

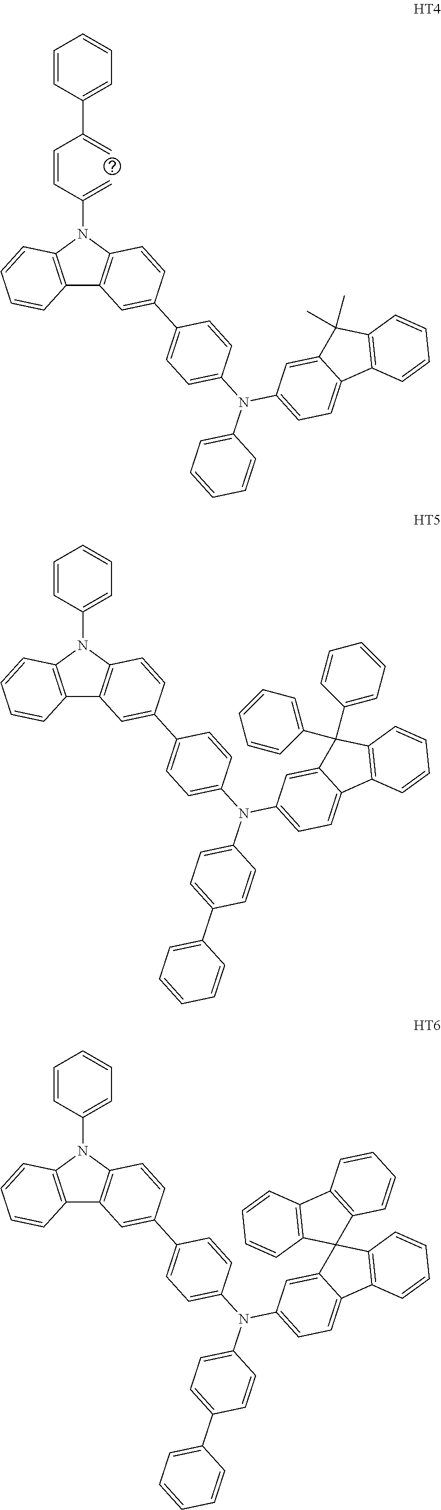 [SMILES: C=C(/C=C\C(=C)n1c2ccccc2c2cc(-c3ccc(N(c4ccccc4)c4ccc5c(c4)C(C)(C)c4ccccc4-5)cc3)ccc21)c1ccccc1 ; c1ccc(-c2ccc(N(c3ccc(-c4ccc5c(c4)c4ccccc4n5-c4ccccc4)cc3)c3ccc4c(c3)C(c3ccccc3)(c3ccccc3)c3ccccc3-4)cc2)cc1 ; c1ccc(-c2ccc(N(c3ccc(-c4ccc5c(c4)c4ccccc4n5-c4ccccc4)cc3)c3ccc4c(c3)C3(c5ccccc5-c5ccccc53)c3ccccc3-4)cc2)cc1]

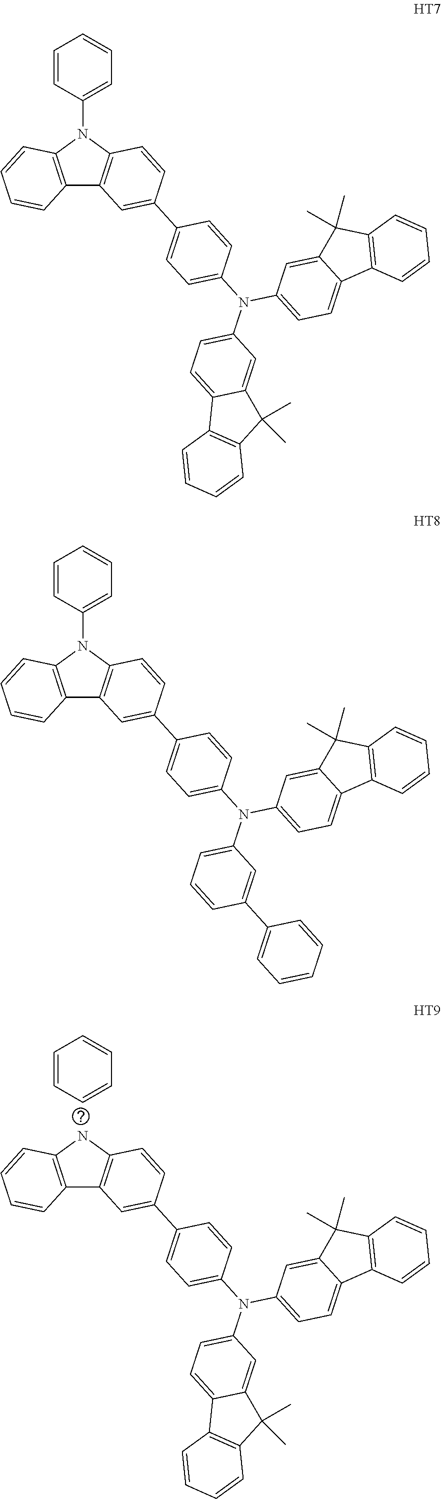

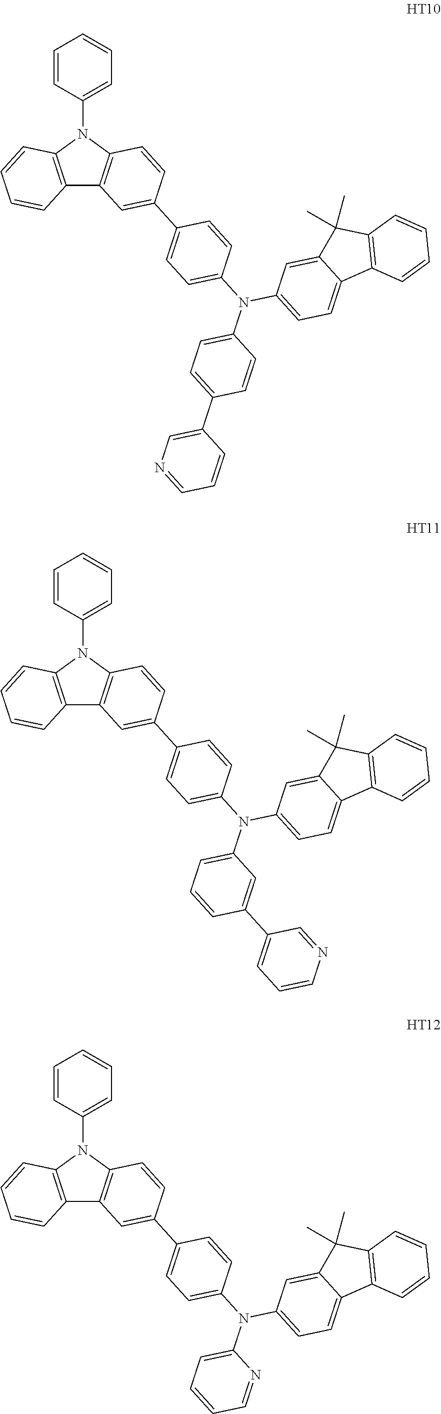 [SMILES: CC1(C)c2ccccc2-c2ccc(N(c3ccc(-c4cccnc4)cc3)c3ccc(-c4ccc5c(c4)c4ccccc4n5-c4ccccc4)cc3)cc21 ; CC1(C)c2ccccc2-c2ccc(N(c3ccc(-c4ccc5c(c4)c4ccccc4n5-c4ccccc4)cc3)c3cccc(-c4cccnc4)c3)cc21 ; CC1(C)c2ccccc2-c2ccc(N(c3ccc(-c4ccc5c(c4)c4ccccc4n5-c4ccccc4)cc3)c3ccccn3)cc21]

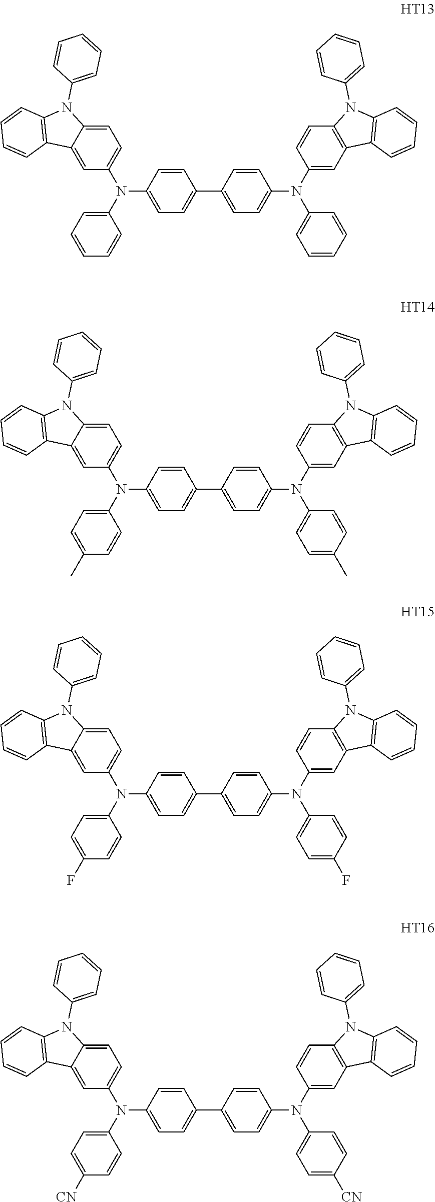

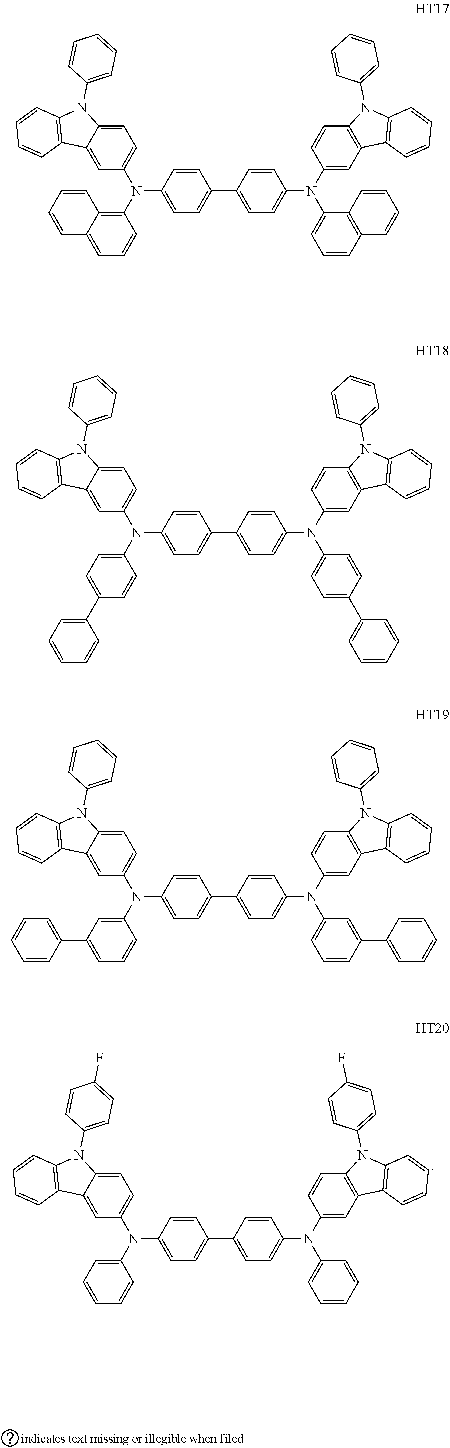 [SMILES: c1ccc(-n2c3ccccc3c3cc(N(c4ccc(-c5ccc(N(c6ccc7c(c6)c6ccccc6n7-c6ccccc6)c6cccc7ccccc67)cc5)cc4)c4cccc5ccccc45)ccc32)cc1 ; c1ccc(-c2ccc(N(c3ccc(-c4ccc(N(c5ccc(-c6ccccc6)cc5)c5ccc6c(c5)c5ccccc5n6-c5ccccc5)cc4)cc3)c3ccc4c(c3)c3ccccc3n4-c3ccccc3)cc2)cc1 ; c1ccc(-c2cccc(N(c3ccc(-c4ccc(N(c5cccc(-c6ccccc6)c5)c5ccc6c(c5)c5ccccc5n6-c5ccccc5)cc4)cc3)c3ccc4c(c3)c3ccccc3n4-c3ccccc3)c2)cc1 ; Fc1ccc(-n2c3ccccc3c3cc(N(c4ccccc4)c4ccc(-c5ccc(N(c6ccccc6)c6ccc7c(c6)c6ccccc6n7-c6ccc(F)cc6)cc5)cc4)ccc32)cc1]

A thickness of the hole transport region may be in a range of about 100 Å to about 10000 Å, for example, about 100 Å to about 1000 Å. When the hole transport region includes a hole injection layer an a hole transport layer, a thickness of the hole injection layer may be in a range of about 100 Å to about 10000 Å, for example, about 100 Å to about 10000 ÅA, and a thickness of the hole transport layer may be in a range of about 50 Åto about 2000 Å, for example, about 100 Å to about 1500 Å. Maintaining the thicknesses of the hole transport region, the hole injection layer, and the hole transport layer within these ranges may help provide satisfactory hole transporting characteristics without a substantial increase in driving voltage.

The hole transport region may further include, in addition to these materials, a charge-generation material for the improvement of conductive properties. The charge-generation material may be homogeneously or non-homogeneously dispersed in the hole transport region.

The charge-generation material may be, for example, a p-dopant. Exemplary p-dopants include a quinone derivative, such as tetracyanoquinonedimethane (TCNQ) or 2,3,5,6-tetrafluoro-tetracyano-1,4-benzoquinonedimethane (F4-TCNQ); a metal oxide, such as a tungsten oxide or a molybdenum oxide; and a cyano group-containing compound, such as Compound HT-D1 illustrated below:

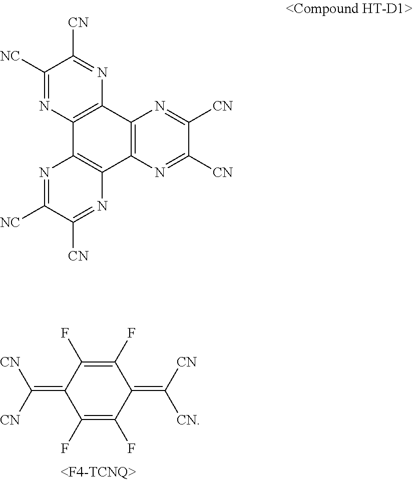

The hole transport region may further include, in addition to the hole injection layer and the hole transport layer, at least one of a buffer layer and an electron blocking layer. The buffer layer may compensate for an optical resonance distance according to a wavelength of light emitted from the emission layer, and a light-emission efficiency of a formed organic light-emitting diode may be improved. For use as a material of the buffer layer, materials of the hole transport region may be used. The electron blocking layer prevents injection of electrons from the electron transport region.

An emission layer is formed on the first electrode 110 or the hole transport region by various methods, such as vacuum deposition, spin coating, casting, an LB method, ink-jet printing, laser-printing, or laser-induced thermal imaging. When the emission layer is formed by vacuum deposition or spin coating, deposition and coating conditions for the emission layer may be determined by referring to the deposition and coating conditions for the hole injection layer.

When the organic light-emitting diode 10 is a full color organic light-emitting diode, the emission layer may be patterned into, for example, a red emission layer, a green emission layer, and a blue emission layer, according to a sub-pixel. In some embodiments, the emission layer may have a stacked structure of a red emission layer, a green emission layer, and a blue emission layer, or may include a red-light emission material, a green-light emission material, and a blue-light emission material, which are mixed with each other in a single layer, to emit white light.

The emission layer may include a host and a dopant.

The host may include at least one selected from TPBi, TBADN, AND (also referred to as “DNA”), CBP, CDBP, and TCP.

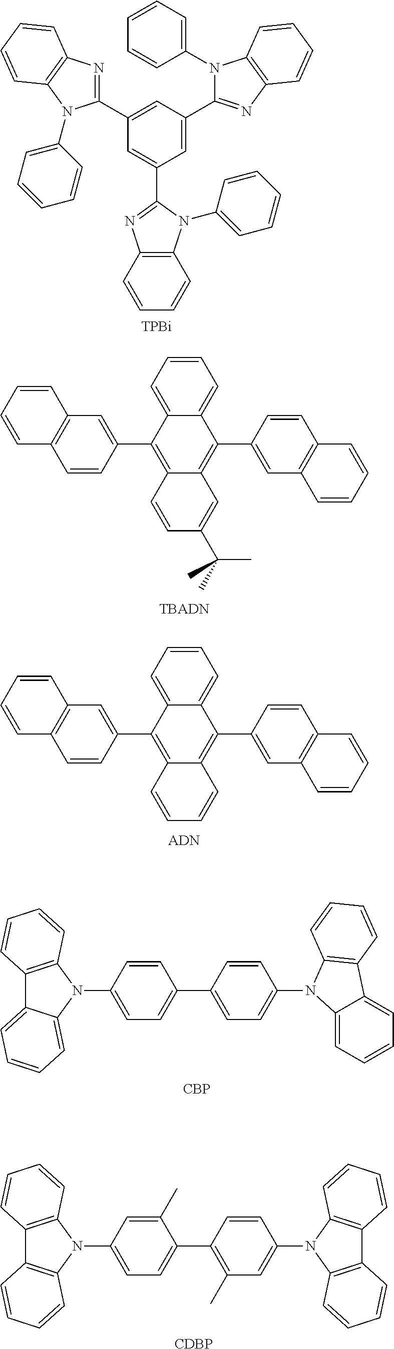

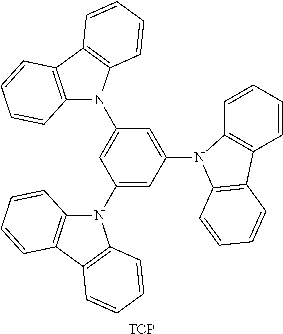

According to another embodiment, the host may include a compound represented by Formula 301 below.

Ar₃₀₁-[(L₃₀₁)_{xb1}-R₃₀₁]_{xb2} <Formula 301>

wherein in Formula 301,

Ar₃₀₁ may be selected from

a naphthalene, a heptalene, a fluorenene, a spiro-fluorenene, a benzofluorenene, a dibenzofluorenene, a phenalene, a phenanthrene, an anthracene, a fluoranthene, a triphenylene, a pyrene, a chrysene, a naphthacene, a picene, a perylene, a pentaphene, and an indenoanthracene;

a naphthalene, a heptalene, a fluorenene, a spiro-fluorenene, a benzofluorenene, a dibenzofluorenene, a phenalene, a phenanthrene, an anthracene, a fluoranthene, a triphenylene, a pyrene, a chrysene, a naphthacene, a picene, a perylene, a pentaphene, and an indenoanthracene, each substituted with at least one selected from a deuterium, —F, —Cl, —Br, —I, a hydroxyl group, a cyano group, a nitro group, an amino group, an amidino group, a hydrazine group, a hydrazone group, a carboxylic acid and a salt thereof, a sulfonic acid and a salt thereof, a phosphoric acid and a salt thereof, a C₁-C₆₀ alkyl group, a C₂-C₆₀ alkenyl group, a C₂-C₆₀ alkynyl group, a C₁-C₆₀ alkoxy group, a C₃-C₁₀ cycloalkyl group, a C₂-C₁₀ heterocycloalkyl group, a C₃-C₁₀ cycloalkenyl group, a C₂-C₁₀ heterocycloalkenyl group, a C₆-C₆₀ aryl group, a C₆-C₆₀ aryloxy group, a C₆-C₆₀ arylthio group, a C₂-C₆₀ heteroaryl group, a monolavent non-aromatic condensed polycyclic group, a monolavent non-aromatic hetero-condensed polycyclic group and —Si(Q₃₀₁)(Q₃₀₂)(Q₃₀₃) (wherein Q₃₀₁ to Q₃₀₃ are each independently selected from hydrogen, a C₁-C₆₀ alkyl group, a C₂-C₆₀ alkenyl group, a C₆-C₆₀ aryl group, and a C₂-C₆₀ heteroaryl group);

L₃₀₁ may be understood by referring to the description provided in connection with L₂₀₁;

R₃₀₁ may be selected from

a C₁-C₂₀ alkyl group and a C₁-C₂₀ alkoxy group;

a C₁-C₂₀ alkyl group and a C₁-C₂₀ alkoxy group, each substituted with at least one selected from a deuterium, —F, —Cl, —Br, —I, a hydroxyl group, a cyano group, a nitro group, an amino group, an amidino group, a hydrazine group, a hydrazone group, a carboxylic acid and a salt thereof, a sulfonic acid and a salt thereof, a phosphoric acid and a salt thereof, a phenyl group, a naphthyl group, a fluorenyl group, a spiro-fluorenyl group, a benzofluorenyl group, a dibenzofluorenyl group, a phenanthrenyl group, an anthracenyl group, a pyrenyl group, a chrysenyl group, a pyridinyl group, a pyrazinyl group, a pyrimidinyl group, a pyridazinyl group, a quinolinyl group, an isoquinolinyl group, a quinoxalinyl group, a quinazolinyl group, a carbazolyl group and a triazinyl group;

a phenyl group, a naphthyl group, a fluorenyl group, a spiro-fluorenyl group, a benzofluorenyl group, a dibenzofluorenyl group, a phenanthrenyl group, an anthracenyl group, a pyrenyl group, a chrysenyl group, a pyridinyl group, a pyrazinyl group, a pyrimidinyl group, a pyridazinyl group, a quinolinyl group, an isoquinolinyl group, a quinoxalinyl group, a quinazolinyl group, a carbazolyl group and a triazinyl group; and

a phenyl group, a naphthyl group, a fluorenyl group, a spiro-fluorenyl group, a benzofluorenyl group, a dibenzofluorenyl group, a phenanthrenyl group, an anthracenyl group, a pyrenyl group, a chrysenyl group, a pyridinyl group, a pyrazinyl group, a pyrimidinyl group, a pyridazinyl group, a quinolinyl group, an isoquinolinyl group, a quinoxalinyl group, a quinazolinyl group, a carbazolyl group and a triazinyl group, each substituted with at least one selected from a deuterium, —F, —Cl, —Br, —I, a hydroxyl group, a cyano group, a nitro group, an amino group, an amidino group, a hydrazine group, a hydrazone group, a carboxylic acid and a salt thereof, a sulfonic acid and a salt thereof, a phosphoric acid and a salt thereof, a C₁-C₂₀ alkyl group, a C₁-C₂₀ alkoxy group, a phenyl group, a naphthyl group, a, fluorenyl group, a spiro-fluorenyl group, a benzofluorenyl group, a dibenzofluorenyl group, a phenanthrenyl group, an anthracenyl group, a pyrenyl group, a chrysenyl group, a pyridinyl group, a pyrazinyl group, a pyrimidinyl group, a pyridazinyl group, a quinolinyl group, an isoquinolinyl group, a quinoxalinyl group, a quinazolinyl group, a carbazolyl group and a triazinyl group; and

xb1 may be selected from 0, 1, 2, and 3; and

xb2 may be selected from 1, 2, 3, and 4.

In this regard, in Formula 301,

L₃₀₁ may be selected from

a phenylene group, a naphthylene group, a fluorenyl group, a spiro-fluorenylene group, a benzofluorenylene group, a dibenzofluorenylene group, a phenanthrenylene group, an anthracenylene group, a pyrenylene group and a chrysenylene group; and

a phenylene group, a naphthylene group, a fluorenyl group, a spiro-fluorenylene group, a benzofluorenylene group, a dibenzofluorenylene group, a phenanthrenylene group, an anthracenylene group, a pyrenylene group and a chrysenylene group, each substituted with at least one selected from a deuterium, —F, —Cl, —Br, —I, a hydroxyl group, a cyano group, a nitro group, an amino group, an amidino group, a hydrazine group, a hydrazone group, a carboxylic acid and a salt thereof, a sulfonic acid and a salt thereof, a phosphoric acid and a salt thereof, a C₁-C₂₀ alkyl group, a C₁-C₂₀ alkoxy group, a phenyl group, a naphthyl group, a, fluorenyl group, a spiro-fluorenyl group, a benzofluorenyl group, a dibenzofluorenyl group, a phenanthrenyl group, an anthracenyl group, a pyrenyl group, a chrysenyl group; and

R₃₀₁ may be selected from

a C₁-C₂₀ alkyl group and a C₁-C₂₀ alkoxy group;

a C₁-C₂₀ alkyl group and a C₁-C₂₀ alkoxy group, each substituted with at least one selected from a deuterium, —F, —Cl, —Br, —I, a hydroxyl group, a cyano group, a nitro group, an amino group, an amidino group, a hydrazine group, a hydrazone group, a carboxylic acid and a salt thereof, a sulfonic acid and a salt thereof, a phosphoric acid and a salt thereof, a phenyl group, a naphthyl group, a fluorenyl group, a spiro-fluorenyl group, a benzofluorenyl group, a dibenzofluorenyl group, a phenanthrenyl group, an anthracenyl group, a pyrenyl group and a chrysenyl group;

a phenyl group, a naphthyl group, a fluorenyl group, a spiro-fluorenyl group, a benzofluorenyl group, a dibenzofluorenyl group, a phenanthrenyl group, an anthracenyl group, a pyrenyl group, a chrysenyl group; and

a phenyl group, a naphthyl group, a fluorenyl group, a spiro-fluorenyl group, a benzofluorenyl group, a dibenzofluorenyl group, a phenanthrenyl group, an anthracenyl group, a pyrenyl group, a chrysenyl group, each substituted with at least one selected from a deuterium, —F, —Cl, —Br, —I, a hydroxyl group, a cyano group, a nitro group, an amino group, an amidino group, a hydrazine group, a hydrazone group, a carboxylic acid and a salt thereof, a sulfonic acid and a salt thereof, a phosphoric acid and a salt thereof, a C₁-C₂₀ alkyl group, a C₁-C₂₀ alkoxy group, a phenyl group, a naphthyl group, a fluorenyl group, a spiro-fluorenyl group, a benzofluorenyl group, a dibenzofluorenyl group, a phenanthrenyl group, an anthracenyl group, a pyrenyl group and a chrysenyl group.

For example, the host may include a compound represented by Formula 301A below:

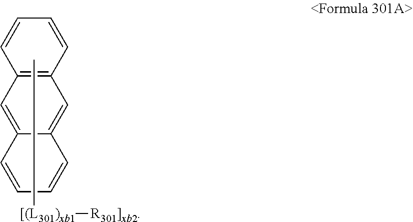

Substituents of Formula 301A are described above.

The compound represented by Formula 301 may include at least one of Compounds H1 to H42:

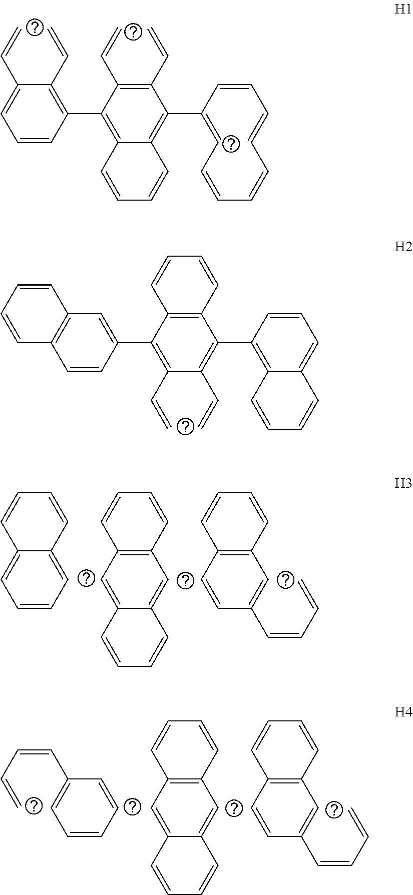

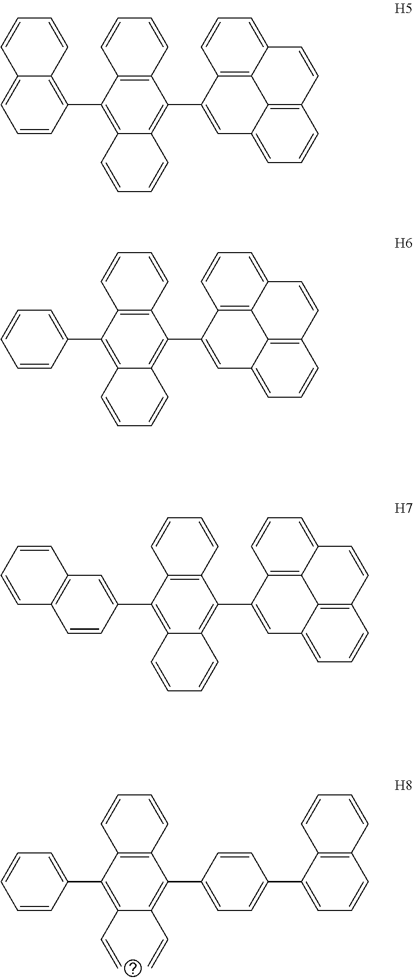

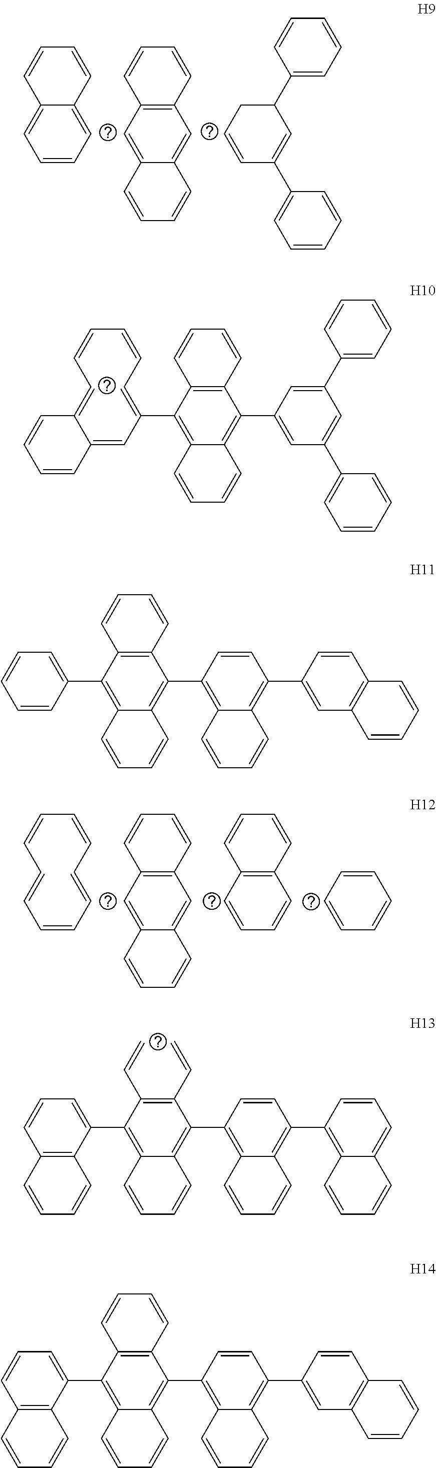

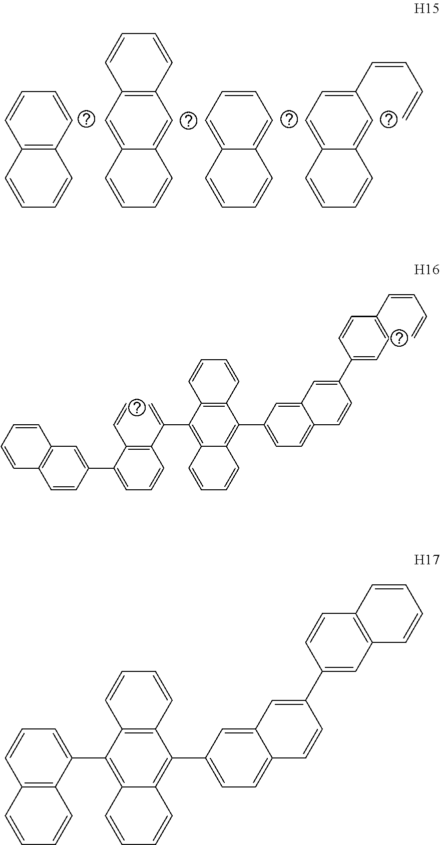

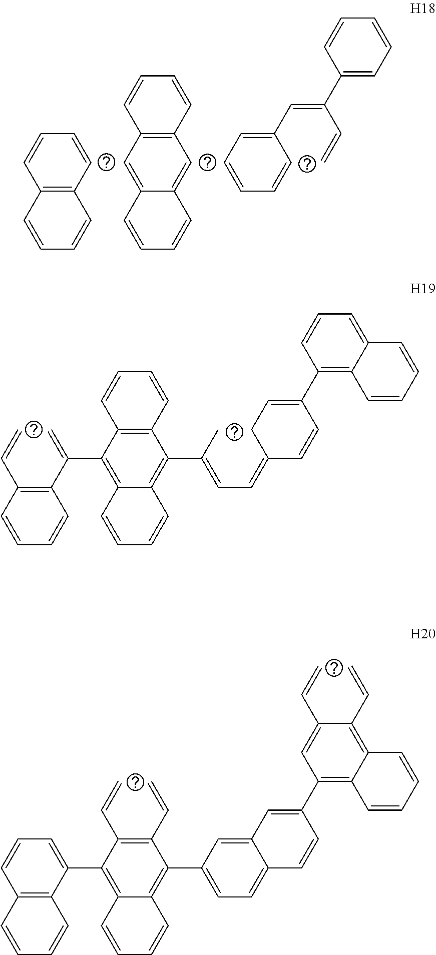

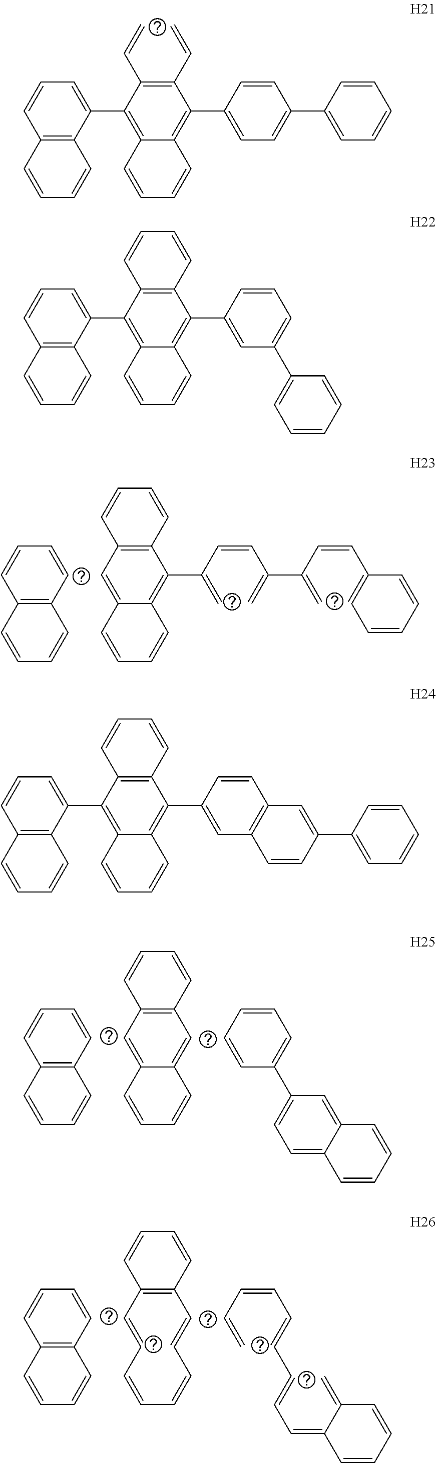

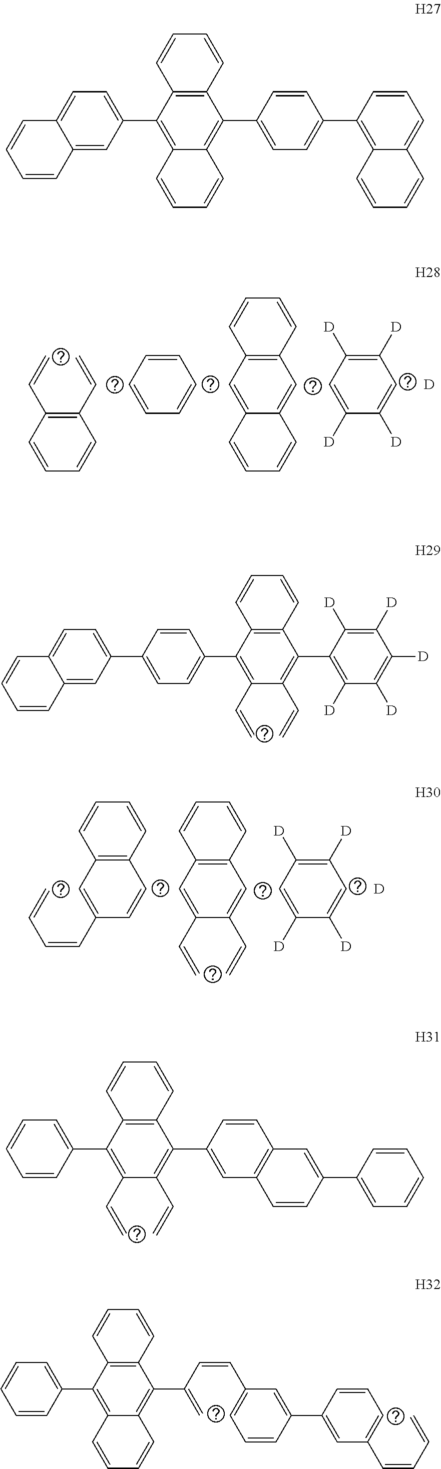

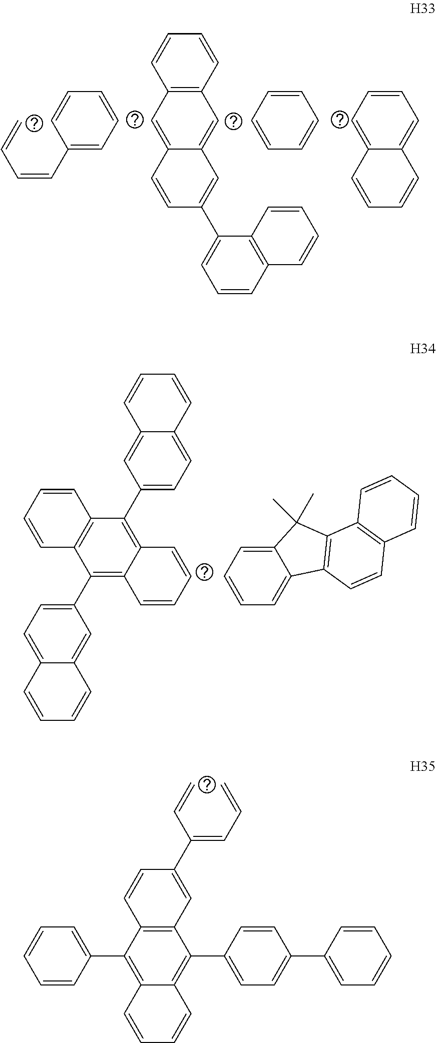

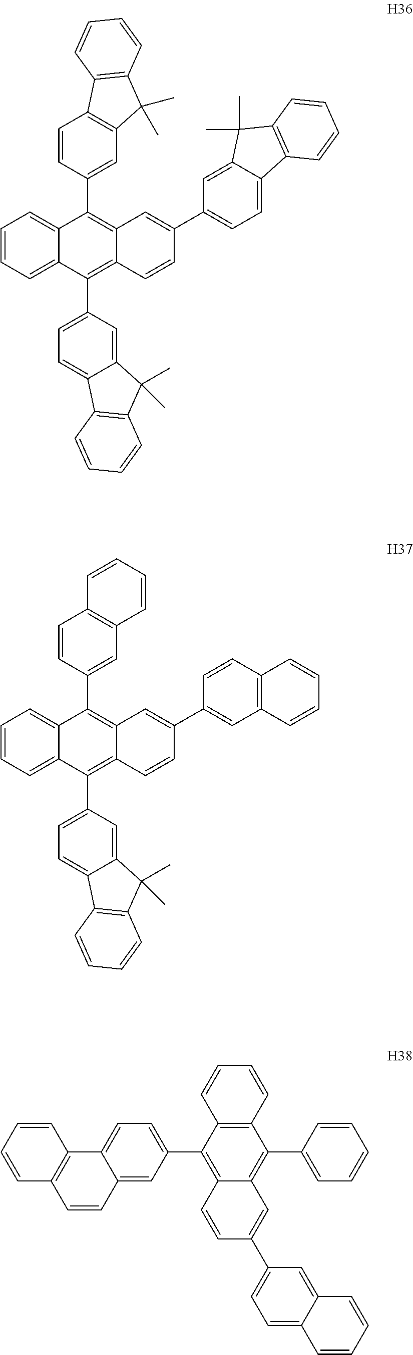

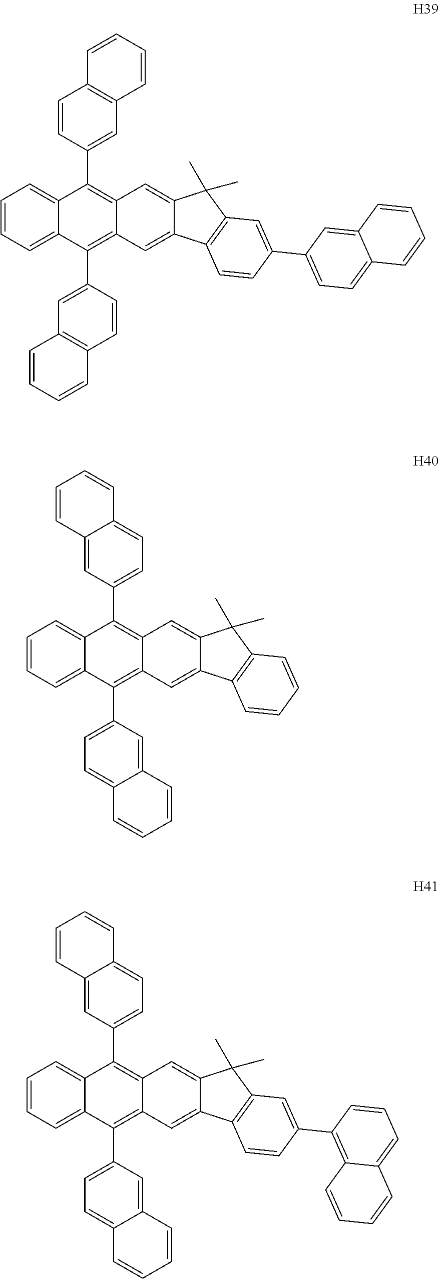

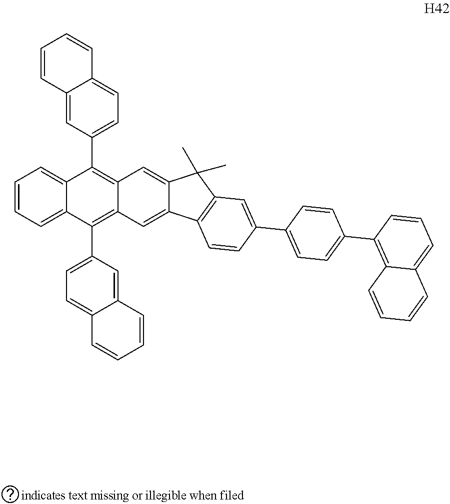 [SMILES: CC1(C)c2cc(-c3ccc(-c4cccc5ccccc45)cc3)ccc2-c2cc3c(-c4ccc5ccccc5c4)c4ccccc4c(-c4ccc5ccccc5c4)c3cc21]

According to another embodiment, the host may include at least one of Compounds H43 to H49 below:

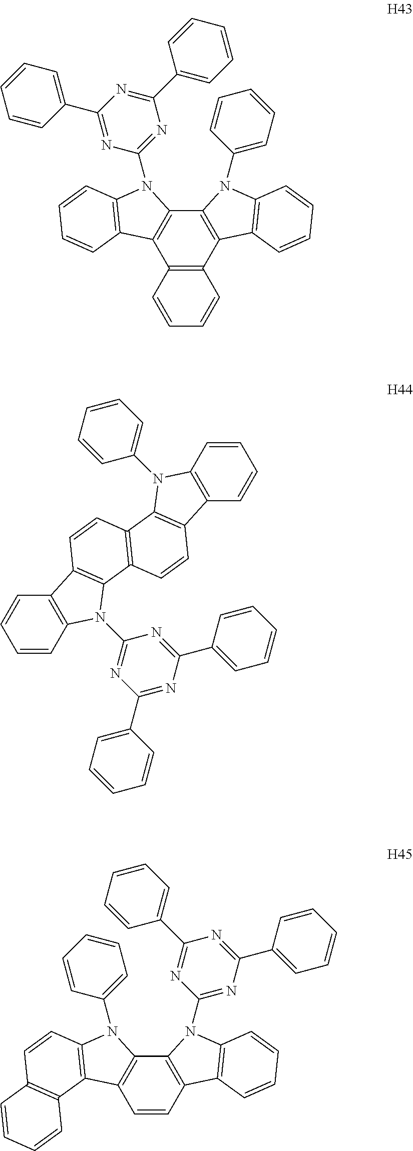 [SMILES: c1ccc(-c2nc(-c3ccccc3)nc(-n3c4ccccc4c4c5ccccc5c5c6ccccc6n(-c6ccccc6)c5c43)n2)cc1 ; c1ccc(-c2nc(-c3ccccc3)nc(-n3c4ccccc4c4ccc5c(ccc6c7ccccc7n(-c7ccccc7)c65)c43)n2)cc1 ; c1ccc(-c2nc(-c3ccccc3)nc(-n3c4ccccc4c4ccc5c6c7ccccc7ccc6n(-c6ccccc6)c5c43)n2)cc1]

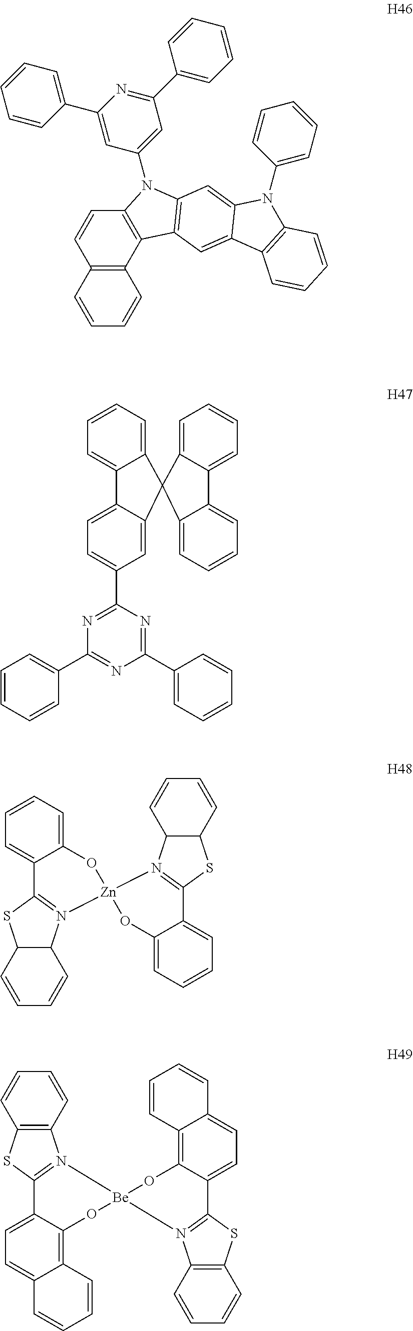

The dopant may be at least one selected from a fluorescent dopant and a phosphorescent dopant.

The phosphorescent dopant may include an organometallic complex represented by Formula 401 below:

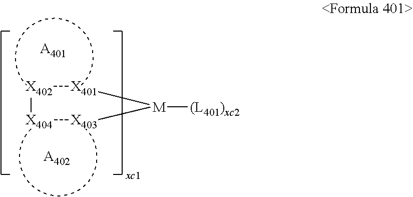

wherein in Formula 401,

M may be selected from iridium (Ir), platinum (Pt), osmium (Os), titanium (Ti), zirconium (Zr), hafnium (Hf), euroform (Eu), terbium (Tb), and thulium (TM);

X₄₀₁ to X₄₀₄ may each independently be nitrogen or carbon;

A₄₀₁ and A₄₀₂ rings may each independently be selected from a substituted or unsubstituted benzene, a substituted or unsubstituted naphthalene, a substituted or unsubstituted fluorenene, a substituted or unsubstituted spiro-fluorenene, a substituted or unsubstituted indene, a substituted or unsubstituted pyrrol, a substituted or unsubstituted thiophene, a substituted or unsubstituted furan, a substituted or unsubstituted imidazole, a substituted or unsubstituted pyrazole, a substituted or unsubstituted thiazole, a substituted or unsubstituted isothiazole, a substituted or unsubstituted oxazole, a substituted or unsubstituted isoxazole, a substituted or unsubstituted pyridine, a substituted or unsubstituted pyrazine, a substituted or unsubstituted pyrimidine, a substituted or unsubstituted pyridazine, a substituted or unsubstituted quinoline, a substituted or unsubstituted isoquinoline, a substituted or unsubstituted benzoquinoline, a substituted or unsubstituted quinoxaline, a substituted or unsubstituted quinazoline, a substituted or unsubstituted carbazol, a substituted or unsubstituted benzoimidazole, a substituted or unsubstituted benzofuran, a substituted or unsubstituted benzothiophene, a substituted or unsubstituted isobenzothiophene, a substituted or unsubstituted benzooxazole, a substituted or unsubstituted isobenzooxazole, a substituted or unsubstituted triazole, a substituted or unsubstituted oxadiazole, a substituted or unsubstituted triazine, a substituted or unsubstituted dibenzofuran, and a substituted or unsubstituted dibenzothiophene; and

a substituent of at least one selected from the substituted benzene, substituted naphthalene, substituted fluorenene, substituted spiro-fluorenene, substituted indene, substituted pyrrol, substituted thiophene, substituted furan, substituted imidazole, substituted pyrazole, substituted thiazole, substituted isothiazole, substituted oxazole, substituted isoxazole, substituted pyridine, substituted pyrazine, substituted pyrimidine, substituted pyridazine, substituted quinoline, substituted isoquinoline, substituted benzoquinoline, substituted quinoxaline, substituted quinazoline, substituted carbazol, substituted benzoimidazole, substituted benzofuran, substituted benzothiophene, substituted isobenzothiophene, substituted benzooxazole, substituted isobenzooxazole, substituted triazole, substituted oxadiazole, substituted triazine, substituted dibenzofuran, and substituted dibenzothiophene may be selected from

a deuterium, —F, —Cl, —Br, —I, a hydroxyl group, a cyano group, a nitro group, an amino group, an amidino group, a hydrazine group, a hydrazone group, a carboxylic acid and a salt thereof, a sulfonic acid and a salt thereof, a phosphoric acid and a salt thereof, a phosphoric acid and a salt thereof, a C₁-C₆₀ alkyl group, a C₂-C₆₀ alkenyl group, a C₂-C₆₀ alkynyl group, and a C₁-C₆₀ alkoxy group;

a C₁-C₆₀ alkyl group, a C₂-C₆₀ alkenyl group, a C₂-C₆₀ alkynyl group, and a C₁-C₆₀ alkoxy group, each substituted with at least one selected from a deuterium, —F, —Cl, —Br, —I, a hydroxyl group, a cyano group, a nitro group, an amino group, an amidino group, a hydrazine group, a hydrazone group, a carboxylic acid and a salt thereof, a sulfonic acid and a salt thereof, a phosphoric acid and a salt thereof, a a C₃-C₁₀ cycloalkyl group, a C₂-C₁₀ heterocycloalkyl group, a C₃-C₁₀ cycloalkenyl group, a C₂-C₁₀ heterocycloalkenyl group, a C₆-C₆₀ aryl group, a C₆-C₆₀ aryloxy group, a C₆-C₆₀ arylthio group, a C₂-C₆₀ heteroaryl group, a monovalent non-aromatic condensed polycyclic group, a monovalent non-aromatic hetero-condensed polycyclic group, —N(Q₄₀₁)(Q₄₀₂), —Si(Q₄₀₃)(Q₄₀₄)(Q₄₀₅), and —B(Q₄₀₆)(Q₄₀₇);

a C₃-C₁₀ cycloalkyl group, a C₂-C₁₀ heterocycloalkyl group, a C₃-C₁₀ cycloalkenyl group, a C₂-C₁₀ heterocycloalkenyl group, a C₆-C₆₀ aryl group, a C₆-C₆₀ aryloxy group, a C₆-C₆₀ arylthio group, a C₂-C₆₀ heteroaryl group, a monovalent non-aromatic condensed polycyclic group and a monovalent non-aromatic hetero-condensed polycyclic group;

a C₃-C₁₀ cycloalkyl group, a C₂-C₁₀ heterocycloalkyl group, a C₃-C₁₀ cycloalkenyl group, a C₂-C₁₀ heterocycloalkenyl group, a C₆-C₆₀ aryl group, a C₆-C₆₀ aryloxy group, a C₆-C₆₀ arylthio group, a C₂-C₆₀ heteroaryl group, a monovalent non-aromatic condensed polycyclic group, and a monovalent non-aromatic hetero-condensed polycyclic group, each substituted with at least one selected from a deuterium, —F, —Cl, —Br, —I, a hydroxyl group, a cyano group, a nitro group, an amino group, an amidino group, a hydrazine group, a hydrazone group, a carboxylic acid and a salt thereof, a sulfonic acid and a salt thereof, a phosphoric acid and a salt thereof, a C₁-C₆₀ alkyl group, a C₂-C₆₀ alkenyl group, a C₂-C₆₀ alkynyl group, a C₁-C₆₀ alkoxy group, a C₃-C₁₀ cycloalkyl group, a C₂-C₁₀ heterocycloalkyl group, a C₃-C₁₀ cycloalkenyl group, a C₂-C₁₀ heterocycloalkenyl group, a C₆-C₆₀ group, aryl group, a C₆-C₆₀ aryloxy group, a C₆-C₆₀ arylthio group, a C₂-C₆₀ heteroaryl group, a monovalent non-aromatic condensed polycyclic group, a monovalent non-aromatic hetero-condensed polycyclic group, —N(Q₄₁₁)(Q₄₁₂), —Si(Q₄₁₃)(Q₄₁₄)(Q₄₁₅), and —B(Q₄₁₆)(Q₄₁₇); and

—N(Q₄₂₁)(Q₄₂₂), —Si(Q₄₂₃)(Q₄₂₄)(Q₄₂₅), and —B(Q₄₂₆)(Q₄₂₇); and

L₄₀₁ is an organic ligand;

xc1 is 1, 2, or 3; and

xc2 is 0, 1, 2, or 3.

L₄₀₁ may be a monovalent, divalent, or trivalent organic ligand, For example, L₄₀₁ may be selected from a halogen ligand (for example, Cl or F), a diketone ligand (for example, acetylacetonate, 1,3-diphenyl-1,3-propandionate, 2,2,6,6-tetramethyl-3,5-heptandionate, or hexafluoracetonate), a carboxylic acid ligand (for example, picolinate, dimethyl-3-pyrazolecarboxylate, or benzoate), a carbon mono-oxide ligand, an isonitrile ligand, a cyano ligand, and a phosphorous ligand (for example, phosphine and phosphaite).

When A₄₀₁ in Formula 401 has two or more substituents, the substituents of A₄₀₁ may bind to each other to form a saturated or unsaturated ring.

When A₄₀₁ in Formula 402 has two or more substituents, the substituents of A₄₀₂ may bind to each other to form a saturated or unsaturated ring.

When xc1 in Formula 401 is two or more, a plurality of ligands

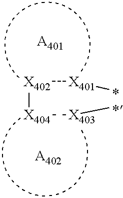

in Formula 401 may be identical or different. When xc1 in Formula 401 is two or more, A₄₀₁ and A₄₀₂ may be respectively directly connected to A₄₀₁ and A₄₀₂ of other neighboring ligands with or without a linker (for example, a C₁-C₅ alkylene group, or —N(R′)— (wherein R′ may be a C₁-C₁₀ alkyl group or a C₆-C₂₀ aryl group) or —C(═O)—) therebetween.

The phosphorescent dopant may include at least one of Compounds PD1 to PD74 below:

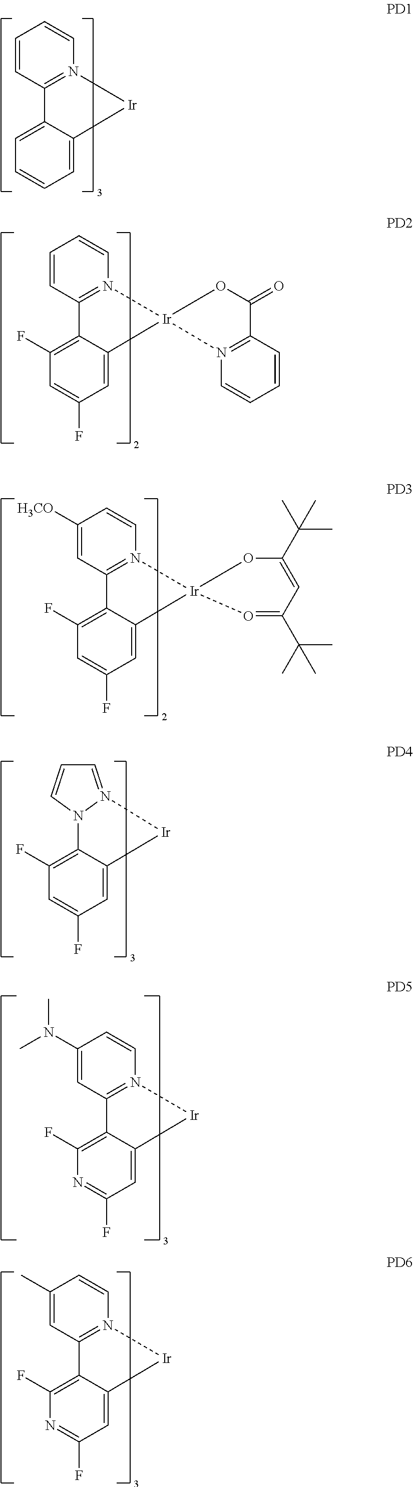

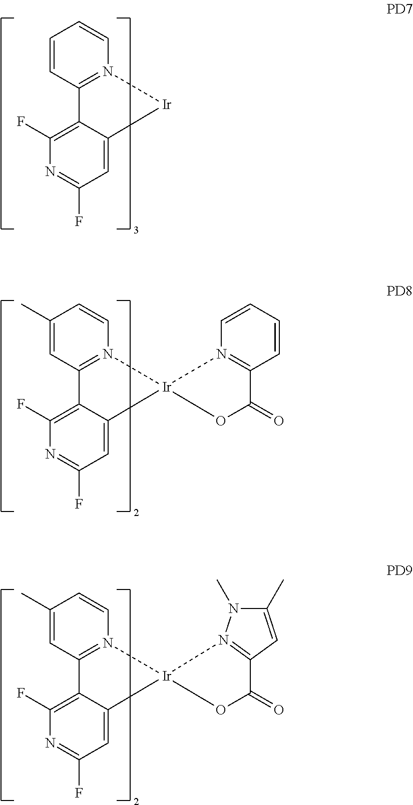

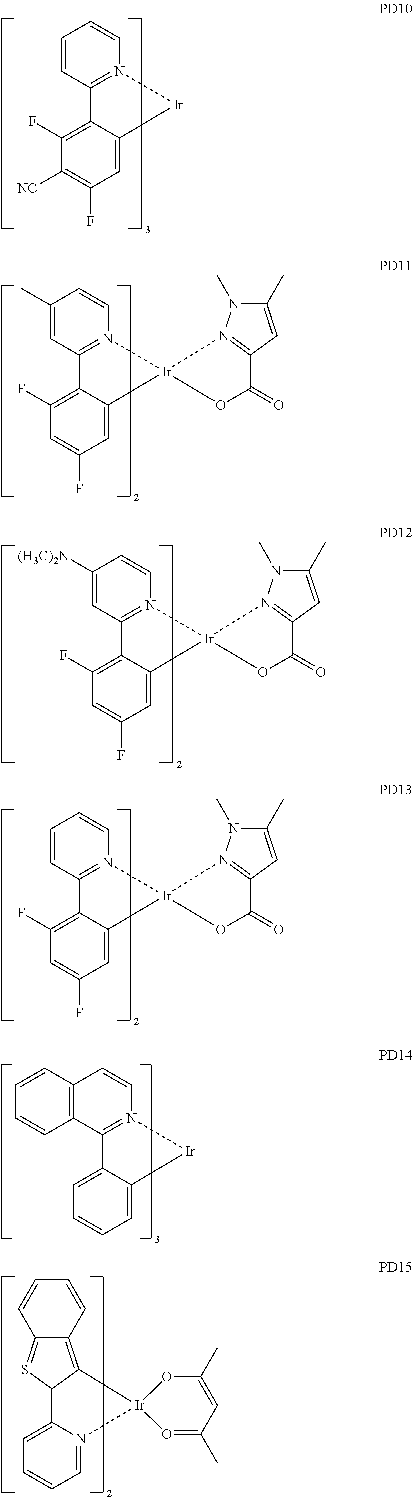

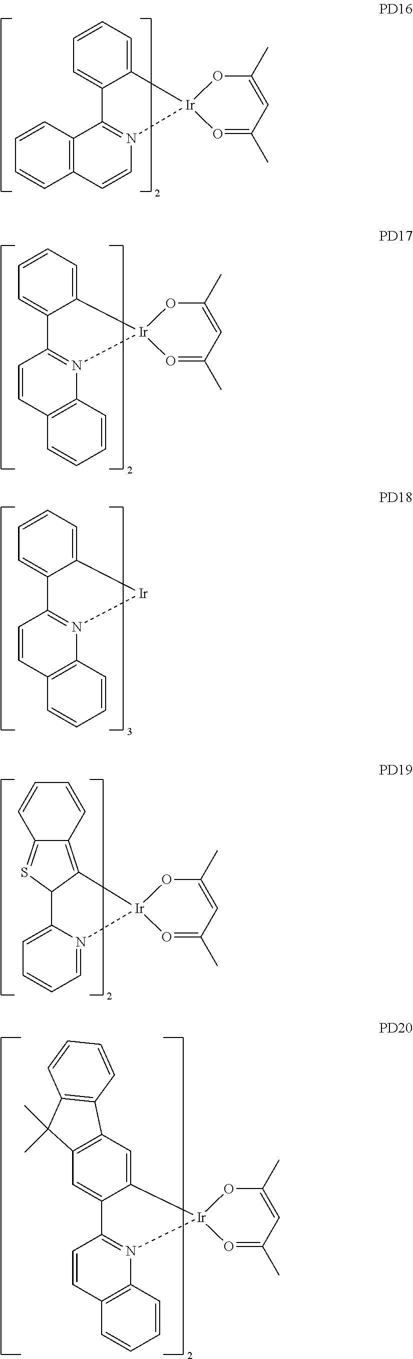

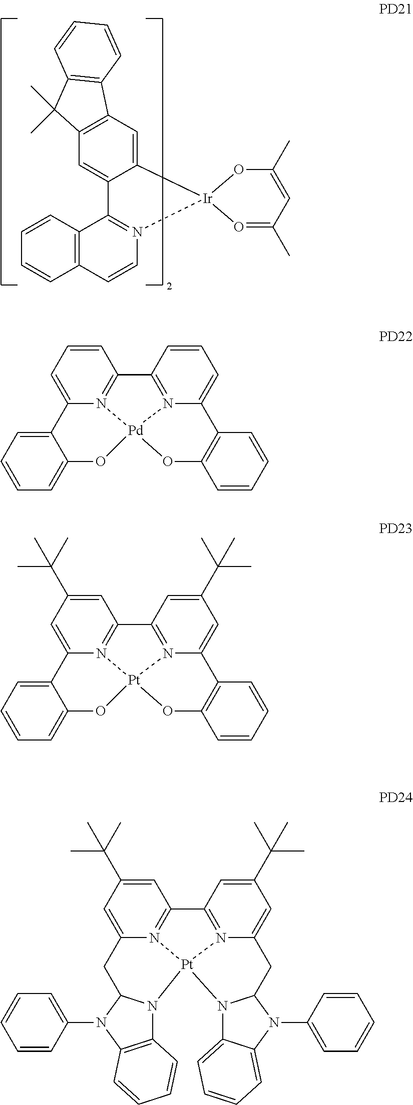

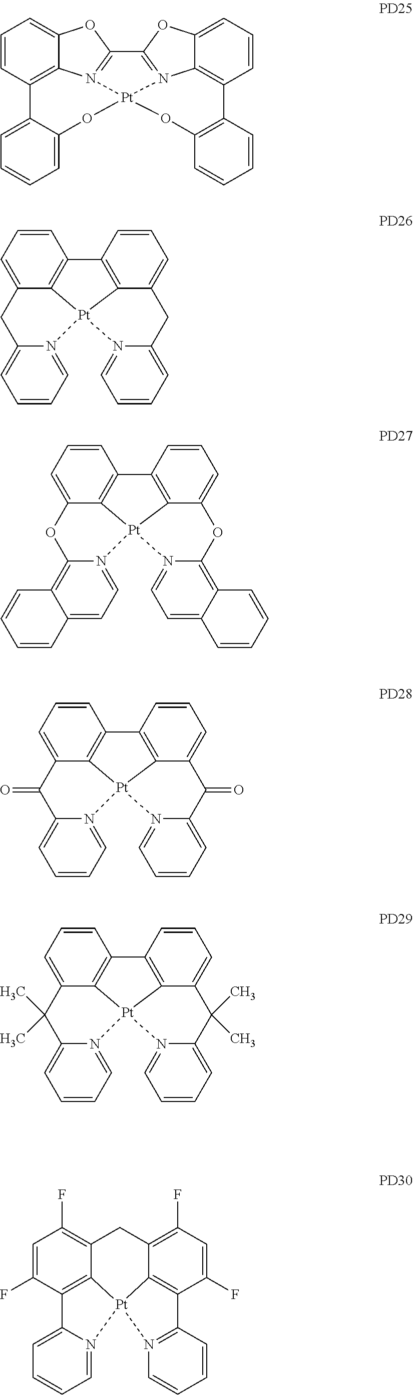

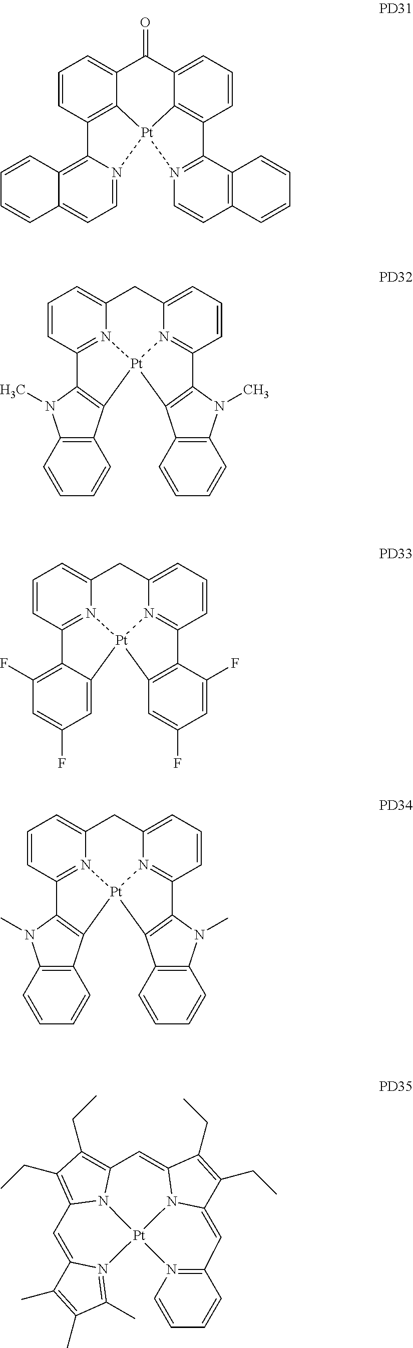

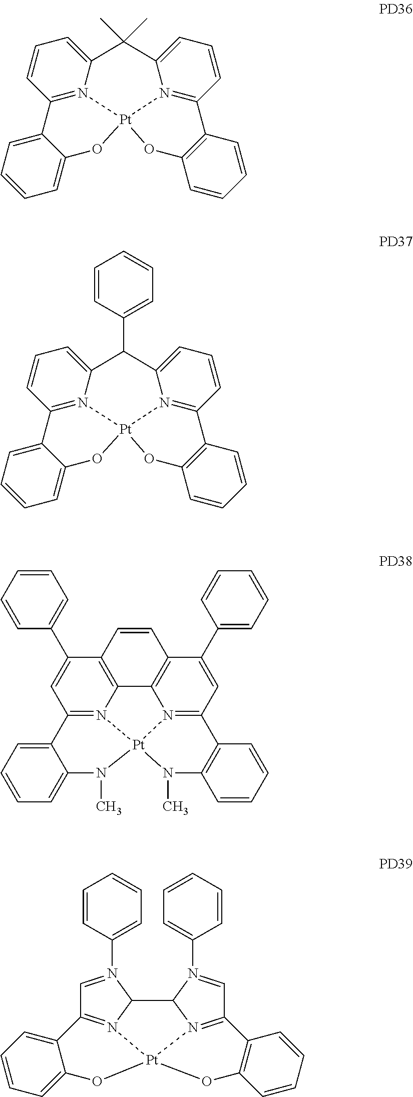

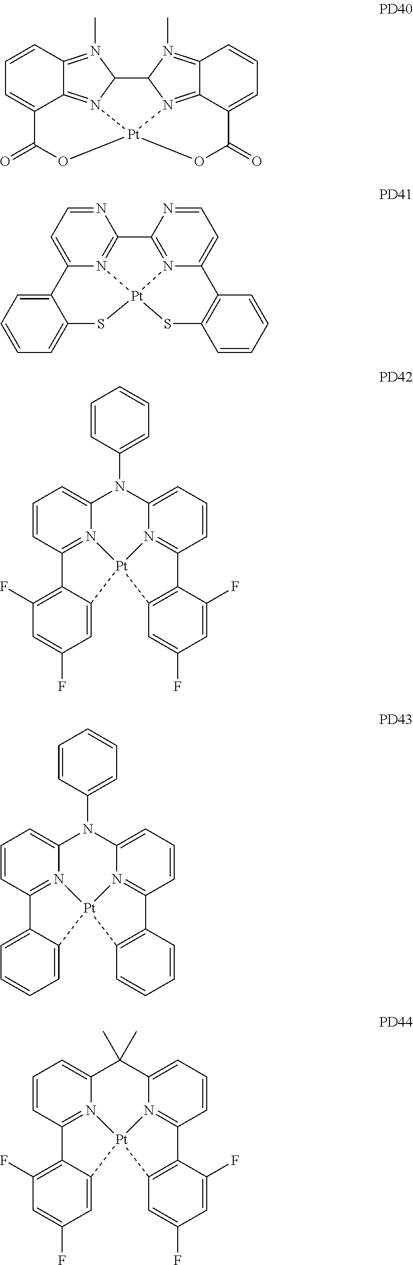

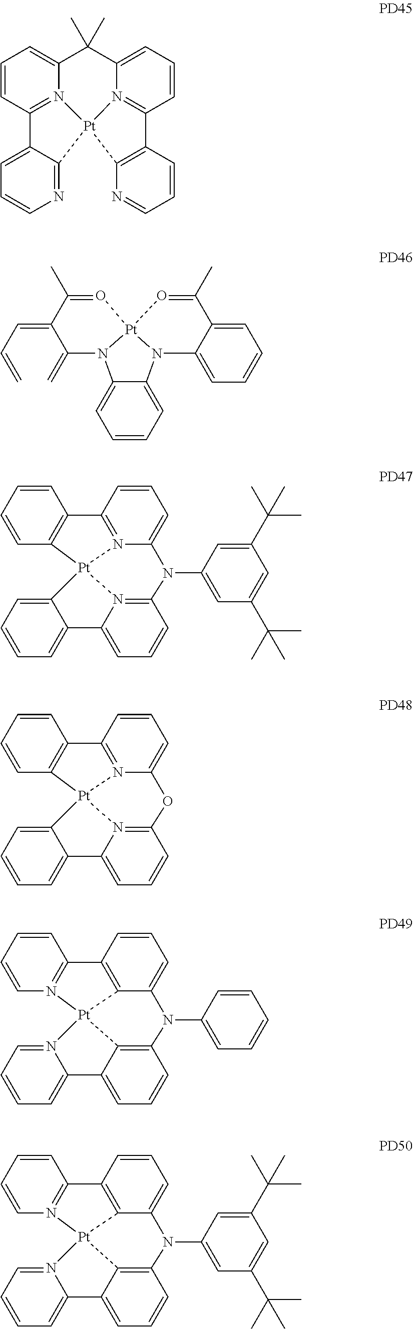

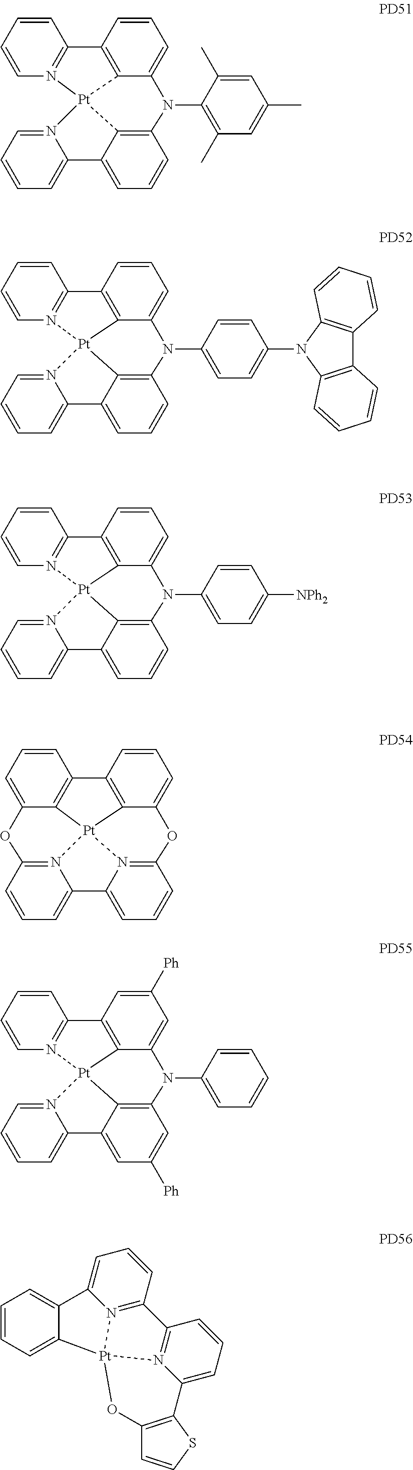

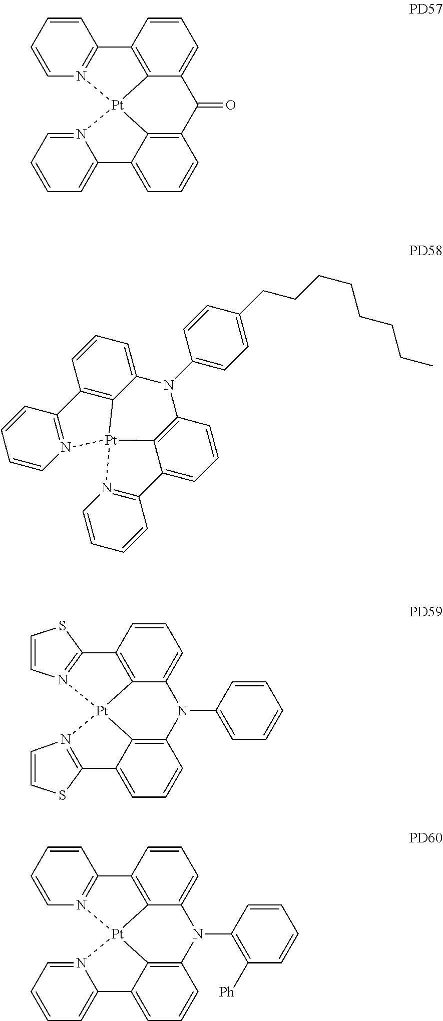

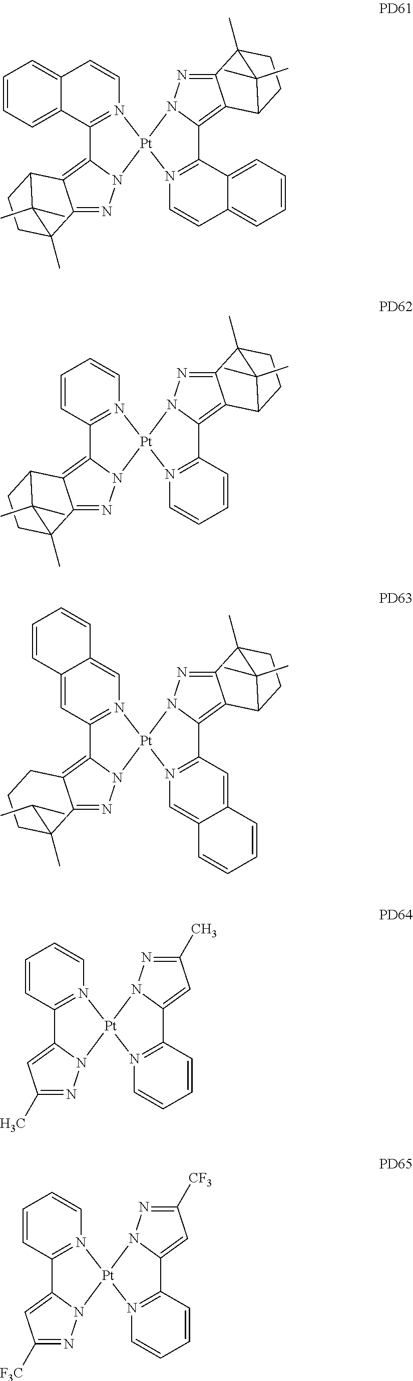

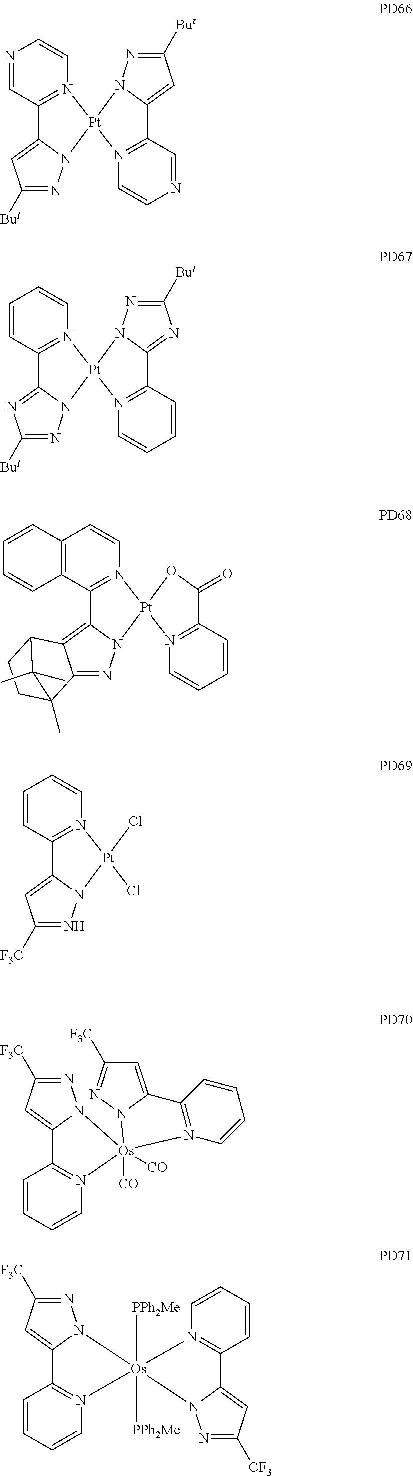

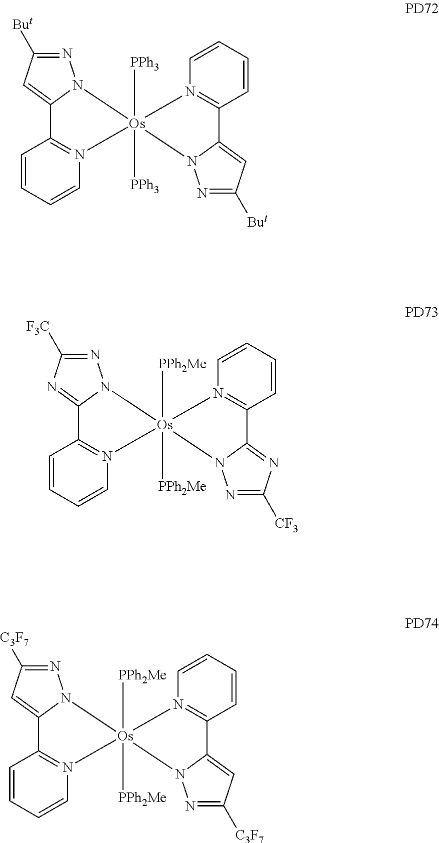

According to another embodiment, the phosphorescent dopant may include PtOEP:

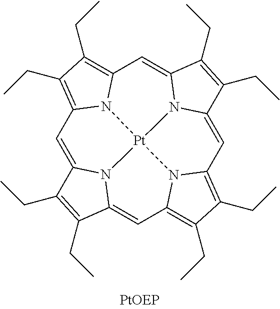

The fluorescent dopant may include at least one selected from DPAVBi, BDAVBi, TBPe, DCM, DCJTB, Coumarin 6, and C545T:

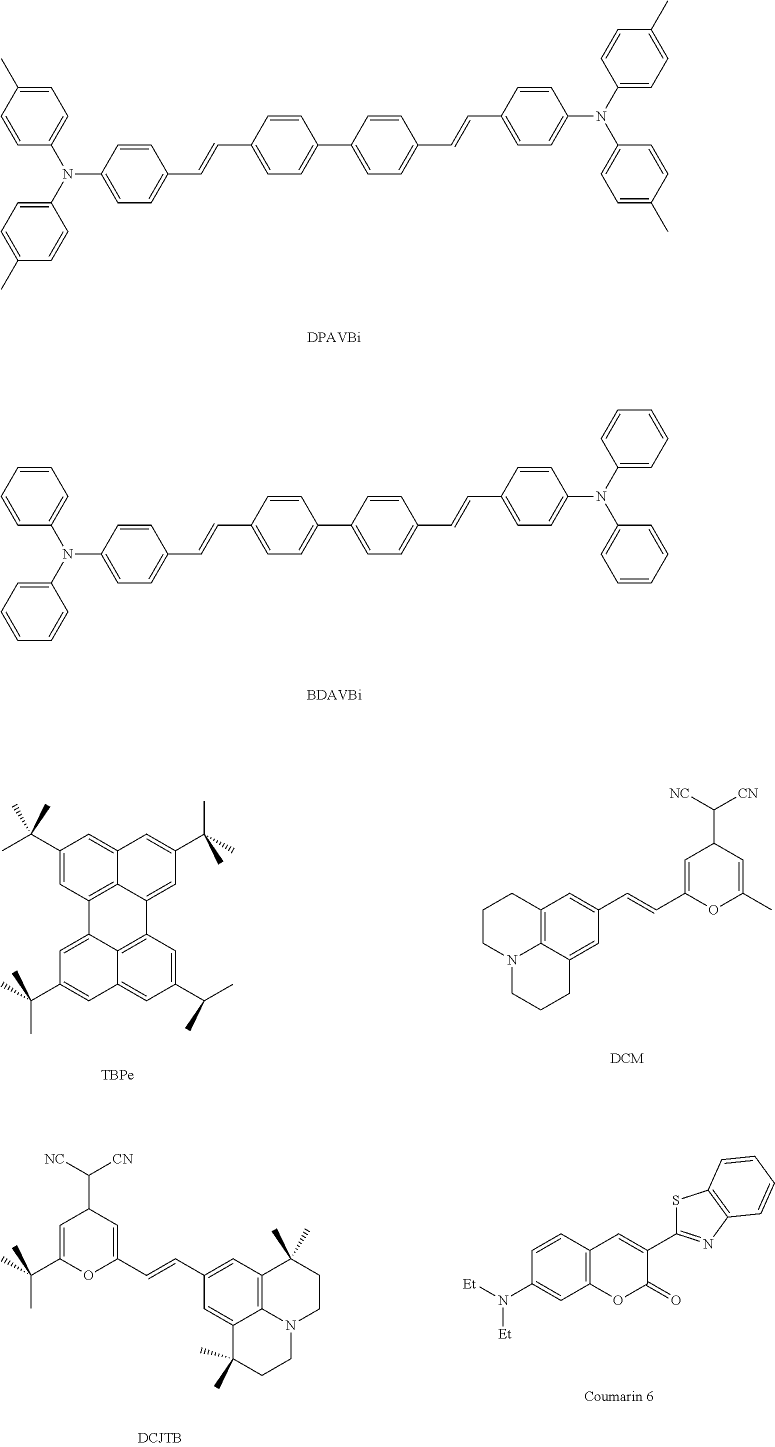

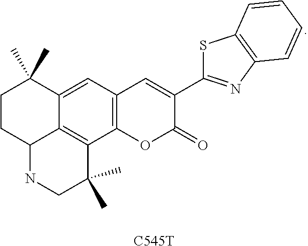

According to another embodiment, the fluorescent dopant may include a compound represented by Formula 501 below.

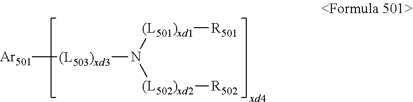

wherein in Formula 501,

Ar₅₀₁ may be selected from

a naphthalene, a heptalene, a fluorenene, a spiro-fluorenene, a benzofluorenene, a dibenzofluorenene, a phenalene, a phenanthrene, an anthracene, a fluoranthene, a triphenylene, a pyrene, a chrysene, a naphthacene, a picene, a perylene, a pentaphene, and an indenoanthracene;

a naphthalene, a heptalene, a fluorenene, a spiro-fluorenene, a benzofluorenene, a dibenzofluorenene, a phenalene, a phenanthrene, an anthracene, a fluoranthene, a triphenylene, a pyrene, a chrysene, a naphthacene, a picene, a perylene, a pentaphene, and an indenoanthracene, each substituted with at least one selected from a deuterium, —F, —Cl, —Br, —I, a hydroxyl group, a cyano group, a nitro group, an amino group, an amidino group, a hydrazine group, a hydrazone group, a carboxylic acid and a salt thereof, a sulfonic acid and a salt thereof, a phosphoric acid and a salt thereof, a C₁-C₆₀ alkyl group, a C₂-C₆₀ alkenyl group, a C₂-C₆₀ alkynyl group, a C₁-C₆₀ alkoxy group, a C₃-C₁₀ cycloalkyl group, a C₂-C₁₀ heterocycloalkyl group, a C₃-C₁₀ cycloalkenyl group, a C₂-C₁₀ heterocycloalkenyl group, a C₆-C₆₀ aryl group, a C₆-C₆₀ aryloxy group, a C₆-C₆₀ arylthio group, a C₂-C₆₀ heteroaryl group, a monovalent non-aromatic condensed polycyclic group, a monovalent non-aromatic hetero-condensed polycyclic group, —Si(Q₅₀₁)(Q₅₀₂)(Q₅₀₃) (wherein Q₅₀₁ to Q₅₀₃ are each independently selected from a hydrogen, C₁-C₆₀ alkyl group, a C₂-C₆₀ alkenyl group, a C₂-C₆₀ aryl group, and a C₂-C₆₀ heteroaryl group);

L₅₀₁ to L₅₀₃ may be understood by referring to the description provided herein in connection with L₂₀₁;

R₅₀₁ and R₅₀₂ may each independently be selected from

a phenyl group, a naphthyl group, a fluorenyl group, a spiro-fluorenyl group, a benzofluorenyl group, a dibenzofluorenyl group, a phenanthrenyl group, an anthracenyl group, a pyrenyl group, a chrysenyl group, a pyridinyl group, a pyrazinyl group, a pyrimidinyl group, a pyridazinyl group, a quinolinyl group, an isoquinolinyl group, a quinoxalinyl group, a quinazolinyl group, a carbazolyl group and a triazinyl group, a dibenzofuranyl group and a dibenzothiophenyl group; and

a phenyl group, a naphthyl group, a fluorenyl group, a spiro-fluorenyl group, a benzofluorenyl group, a dibenzofluorenyl group, a phenanthrenyl group, an anthracenyl group, a pyrenyl group, a chrysenyl group, a pyridinyl group, a pyrazinyl group, a pyrimidinyl group, a pyridazinyl group, a quinolinyl group, an isoquinolinyl group, a quinoxalinyl group, a quinazolinyl group, a carbazolyl group, a triazinyl group a dibenzofuranyl group and a dibenzothiophenyl group, each substituted with at least one selected from a deuterium, —F, —Cl, —Br, —I, a hydroxyl group, a cyano group, a nitro group, an amino group, an amidino group, a hydrazine group, a hydrazone group, a carboxylic acid and a salt thereof, a sulfonic acid and a salt thereof, a phosphoric acid and a salt thereof, a C₁-C₂₀ alkyl group, a C₁-C₂₀ alkoxy group, a phenyl group, a naphthyl group, a fluorenyl group, a spiro-fluorenyl group, a benzofluorenyl group, a dibenzofluorenyl group, a phenanthrenyl group, an anthracenyl group, a pyrenyl group, a chrysenyl group, a pyridinyl group, a pyrazinyl group, a pyrimidinyl group, a pyridazinyl group, a quinolinyl group, an isoindolyl group, a quinoxalinyl group, a quinazolinyl group, a carbazolyl group and a triazinyl group, a dibenzofuranyl group and a dibenzothiophenyl group; and

xd1 to xd3 may each independently be selected from 0, 1, 2, and 3; and

xb4 may be selected from 1, 2, 3, and 4.

The fluorescent host may include at least one of Compounds FD1 to FD8 below;

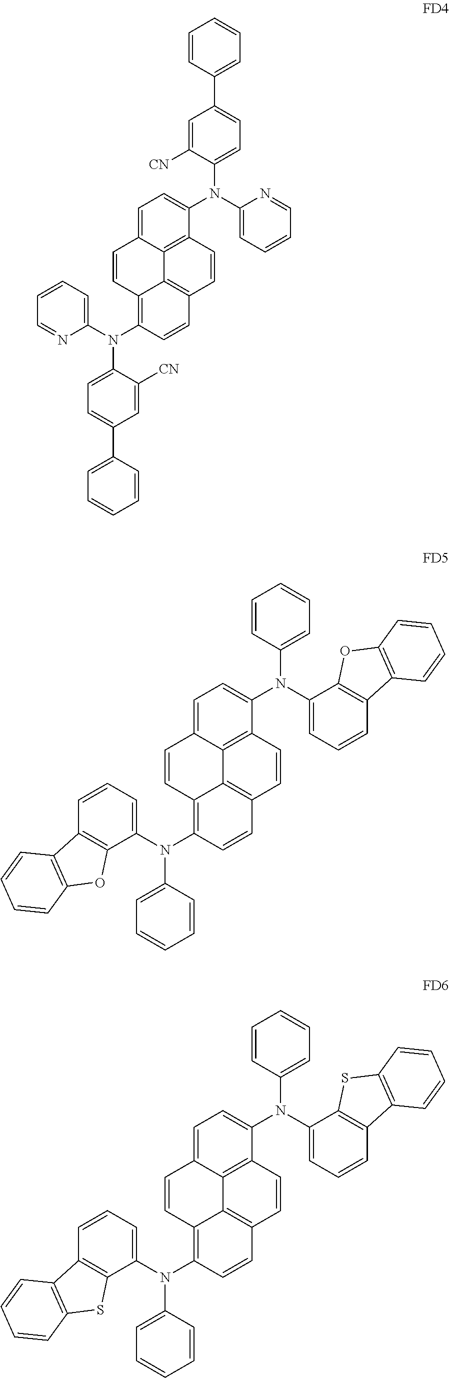

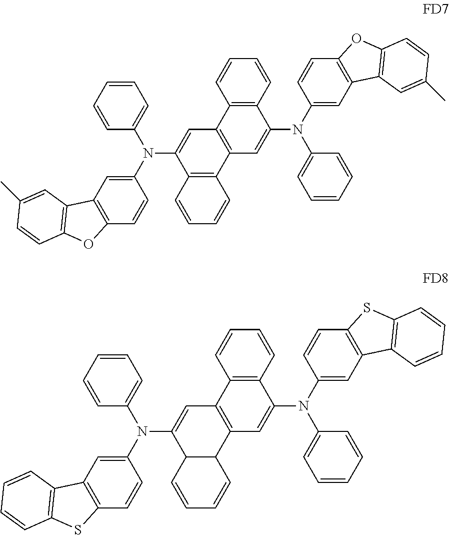

An amount of the dopant in the emission layer may be, for example, in a range of about 0.01 to about 15 parts by weight based on 100 parts by weight of the host.

A thickness of the emission layer may be in a range of about 100 Å to about 1000 Å, for example, about 200 Å to about 600 Å. Maintaining the thickness of the emission layer within this range may help provide excellent light-emission characteristics without a substantial increase in driving voltage.

Then, an electron transport region may be disposed on the emission layer.

The electron transport region may include at least one selected from a hole blocking layer, an electron transport layer, and an electron injection layer.

For example, the electron transport region may have a structure of electron transport layer/electron injection layer or a structure of hole blocking layer/electron transport layer/electron injection layer, wherein layers of each structure are sequentially stacked from the emission layer in the stated order.

According to an embodiment, the organic layer 150 of the organic light-emitting diode includes an electron transport region disposed between the emission layer and the second electrode 190, wherein the electron transport region includes the condensed compound represented by Formula 1 or Formula 2.

The electron transport region may include a hole blocking layer. The hole blocking layer may be formed, when the emission layer includes a phosphorescent dopant, to prevent diffusion of excitons or holes into an electron transport layer.

When the electron transport region includes a hole blocking layer, the hole blocking layer may be formed on the emission layer by various methods, such as vacuum deposition, spin coating casting, an LB method, ink-jet printing, laser-printing, or laser-induced thermal imaging. When the hole blocking layer is formed by vacuum deposition or spin coating, deposition and coating conditions for the hole blocking layer may be determined by referring to the deposition and coating conditions for the hole injection layer.

The hole blocking layer may include, for example, at least one of BCP and Bphen:

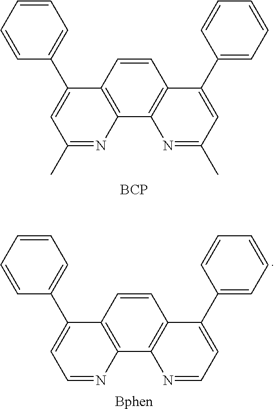

A thickness of the hole blocking layer may be in a range of about 20 Å to about 1000 Å, for example, about 30 Å to about 300 Å. Maintaining the thickness of the hole blocking layer within these ranges may help provide the hole blocking layer with excellent hole blocking characteristics without a substantial increase in driving voltage.

The election transport region may include an electron transport layer. The electron transport layer may be formed on the emission layer or the hole blocking layer by various methods, such as vacuum deposition, spin coating casting, an LB method, ink-jet printing, laser-printing, or laser-induced thermal imaging. When an electron transport layer is formed by vacuum deposition or spin coating, deposition and coating conditions for the electron transport layer may be determined by referring to the deposition and coating conditions for the hole injection layer.

According to an embodiment, the organic layer 150 of the organic light-emitting diode includes an electron transport region disposed between the emission layer and the second electrode 190, wherein the electron transport region includes an electron transport layer, and the electron transport layer includes the condensed compound represented by Formula 1 or Formula 2.

The electron transport layer may further include, in addition to the condensed compound represented by Formula 1 or Formula 2, at least one selected from BCP, Bphen, and Alq₃, Balq, TAZ, and NTAZ, which are illustrated below:

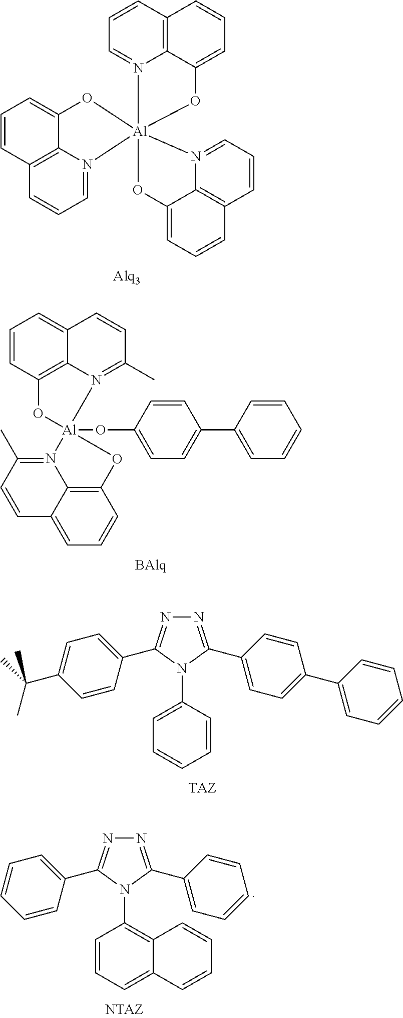

A thickness of the electron transport layer may be in a range of about 100 Å to about 1000 Å, for example, about 150 Å to about 500 Å. Maintaining the thickness of the electron transport layer within the range described above may help provide the electron transport layer with satisfactory electron transportation characteristics without a substantial increase in driving voltage.

Also, the electron transport layer may further include, in addition to the materials described above, a metal-containing material.

The metal-containing material may include a Li complex. The Li complex may include, for example, Compound ET-D1 (lithium quinolate, LiQ) or ET-D2.

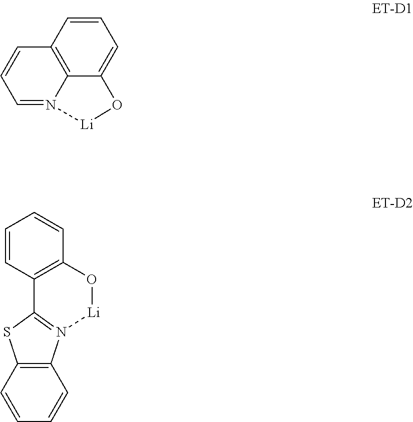

The electron transport region may include an electron injection layer that allows electrons to be easily provided from the second electrode 190.

The electron injection layer may be formed on the electron transport layer by various methods, such as vacuum deposition, spin coating casting, an LB method, ink-jet printing, laser-printing, or laser-induced thermal imaging. When an electron injection layer is formed by vacuum deposition or spin coating, deposition and coating conditions for the electron injection layer may be determined by referring to the deposition and coating conditions for the hole injection layer.

The electron injection layer may include at least one selected from, LiF, NaCl, CsF, Li₂O, BaO, and LiQ.

A thickness of the electron injection layer may be in a range of about 1 Å to about 100 Å, for example, about 3 Å to about 90 Å. Maintaining the thickness of the electron injection layer within the range described above may help provide the electron injection layer with satisfactory electron transportation characteristics without a substantial increase in driving voltage.

The second electrode 190 is disposed on the organic layer 150 having such a structure. The second electrode 190 may be a cathode that is an electron injection electrode, and in this regard, a material for forming the second electrode 190 may be a material having a low work function, and such a material may be metal, alloy, an electrically conductive compound, or a mixture thereof. Detailed examples of the second electrode 190 are lithium (Li), magnesium (Mg), aluminum (Al), aluminum-lithium (Al—Li), calcium (Ca), magnesium-indium (Mg—In), or magnesium-silver (Mg—Ag). According to another embodiment, the material for forming the second electrode 190 may be ITO or IZO. The second electrode 190 maybe a reflective electrode, a semi-transmissive electrode, or a transmissive electrode.

Hereinbefore, thee organic light-emitting diode has been described with reference to FIG. 1; other implementations may have other structures.

A C₁-C₆₀ alkyl group used herein refers to a linear or branched aliphatic hydrocarbon monovalent group having 1 to 60 carbon atoms, and detailed examples thereof are a methyl group, an ethyl group, a propyl group, an isobutyl group, a sec-butyl group, a ter-butyl group, a pentyl group, an iso-amyl group, and a hexyl group. A C₁-C₆₀ alkylene group used herein refers to a divalent group having the same structure as the C₁-C₆₀ alkyl group.

A C₁-C₆₀ alkoxy group used herein refers to a monovalent group represented by —OA₁₀₁ (wherein A₁₀₁ is the C₁-C₆₀ alkyl group), and detailed examples thereof are a methoxy group, an ethoxy group, and am isopropyloxy group.

A C₂-C₆₀ alkenyl group used herein refers to a hydrocarbon group formed by substituting at least one carbon double bond in the middle or terminal of the C₂-C₆₀ alkyl group, and detailed examples thereof are an ethenyl group, a prophenyl group and a butenyl group. A C₂-C₆₀ alkenylene group used herein refers to a divalent group having the same structure as the C₂-C₆₀ alkenyl group.

A C₂-C₆₀ alkynyl group used herein refers to a hydrocarbon group formed by substituting at least one carbon triple bond in the middle or terminal of the C₂-C₆₀ alkyl group, and detailed examples thereof are an ethynyl group and a propynyl group. A C₂-C₆₀ alkynylene group used herein refers to a divalent group having the same structure as the C₂-C₆₀ alkynyl group.

A C₃-C₁₀ cycloalkyl group used herein refers to a monovalent hydrocarbon monocyclic group having 3 to 10 carbon atoms, and detailed examples thereof are a cyclopropyl group, a cyclobutyl group, a cyclopentyl group, a cyclohexyl group, and a cycloheptyl group. A C₃-C₁₀ cycloalkylene group used herein refers to a divalent group having the same structure as the C₃-C₁₀ cycloalkyl group.

A C₂-C₁₀ heterocycloalkyl group used herein refers to a monovalent monocyclic group having at least one heteroatom selected from N, O, P, and S as a ring-forming atom and 2 to 10 carbon atoms, and detailed examples thereof are a tetrahydrofuranyl group and a tetrahydrothiophenyl group. A C₂-C₁₀ heterocycloalkylene group used herein refers to a divalent group having the same structure as the C₂-C₁₀ heterocycloalkyl group.

A C₃-C₁₀ cycloalkenyl group used herein refers to a monovalent monocyclic group that has 3 to 10 carbon atoms and at least one double bond in the ring thereof and does not have aromacity, and detailed examples thereof are a cyclopentenyl group, a cyclohexenyl group, and a cycloheptenyl group. A C₃-C₁₀ cycloalkenylene group used herein refers to a divalent group having the same structure as the C₃-C₁₀ cycloalkenyl group.

A C₂-C₁₀ heterocycloalkenyl group used herein refers to a monovalent monocyclic group that has at least one heteroatom selected from N, O, P, and S as a ring-forming atom 2 to 10 carbon atoms, and at least one double bond in its ring. Detailed examples of the C₃-C₁₀ heterocycloalkenyl are a 2,3-hydrofuranyl group and a 2,3-hydrothiophenyl group. A C₂-C₁₀ heterocycloalkenylene group used herein refers to a divalent group having the same structure as the C₂-C₁₀ heterocycloalkenyl group.

A C₆-C₆₀ aryl group used herein refers to a monovalent group having a carbocyclic aromatic system having 6 to 60 carbon atoms, and a C₆-C₆₀ arylene group used herein refers to a divalent group having a carbocyclic aromatic system having 6 to 60 carbon atoms. Detailed examples of the C₆-C₆₀ aryl group are a phenyl group, a naphthyl group, an anthracenyl group, a phenanthrenyl group, a pyrenyl group, and a chrysenyl group. When the C₆-C₆₀ aryl group and the C₆-C₆₀ arylene group each include two or more rings, the rings may be fused to each other.

A C₂-C₆₀ heteroaryl group used herein refers to a monovalent group having a carbocyclic aromatic system that has at least one heteroatom selected from N, O, P, and S as a ring-forming atom, and 2 to 60 carbon atoms. A C₂-C₆₀ heteroarylene group used herein refers to a divalent group having a carbocyclic aromatic system that has at least one heteroatom selected from N, O, P, and S as a ring-forming atom, and 2 to 60 carbon atoms. Detailed examples of the C₂-C₆₀ heteroaryl group are a pyridinyl group, a pyrimidinyl group, a pyrazinyl group, a pyridazinyl group, a triazinyl group, a quinolinyl group, and an isoquinolinyl group. When the C₂-C₆₀ heteroaryl group and the C₂-C₆₀ heteroarylene group each include two or more rings, the rings may be fused to each other.

A C₆-C₆₀ aryloxy group used herein indicates —OA₁₀₂ (wherein A₁₀₂ is the C₆-C₆₀ aryl group), and a C₆-C₆₀ arylthio group used herein indicates —SA₁₀₃ (wherein A₁₀₃ is the C₆-C₆₀ aryl group).

A monovalent non-aromatic condensed polycyclic group (for example, having 6 80 carbon atoms) used herein refers to a monovalent group that has two or more rings condensed to each other, only carbon atoms as a ring-forming atom, and non-aromacity in the entire molecular structure. A detailed example of the monovalent non-aromatic condensed polycyclic group is a fluorenyl group. A divalent non-aromatic condensed polycyclic group used herein refers to a divalent group having the same structure as the monovalent non-aromatic condensed polycyclic group.

A monovalent non-aromatic condensed heteropolycyclic group (for example, having 2 to 80 carbon atoms) used herein refers to a monovalent group that has two or more rings condensed to each other, has a heteroatom selected from N, O P, and S, other than carbon atoms, as a ring forming atom, and has non-aromacity in the entire molecular structure. Detailed examples of the monovalent non-aromatic condensed heteropolycyclic group are a carbazolyl group. A divalent non-aromatic condensed heteropolycyclic group used herein refers to a divalent group having the same structure as the monovalent non-aromatic condensed heteropolycyclic group.

The term “Ph” used herein refers to a phenyl group, the term “Me” used herein refers to a methyl group, the term “Et” used herein refers to an ethyl group, and the term “ter-Bu” or “But” used herein refers to tert-butyl.

Hereinafter, an organic light-emitting diode according to an embodiment will be described in detail with reference to Synthesis Examples and Examples. The wording “B was used instead of A” used in describing Synthesis Examples means that a molar equivalent of A was identical to a molar equivalent of B.

The following Examples and Comparative Examples are provided in order to highlight characteristics of one or more embodiments, but it will be understood that the Examples and Comparative Examples are not to be construed as limiting the scope of the embodiments, nor are the Comparative Examples to be construed as being outside the scope of the embodiments. Further, it will be understood that the embodiments are not limited to the particular details described in the Examples and Comparative Examples.

### EXAMPLES

### Synthesis Example 1

### Synthesis of Compound 7

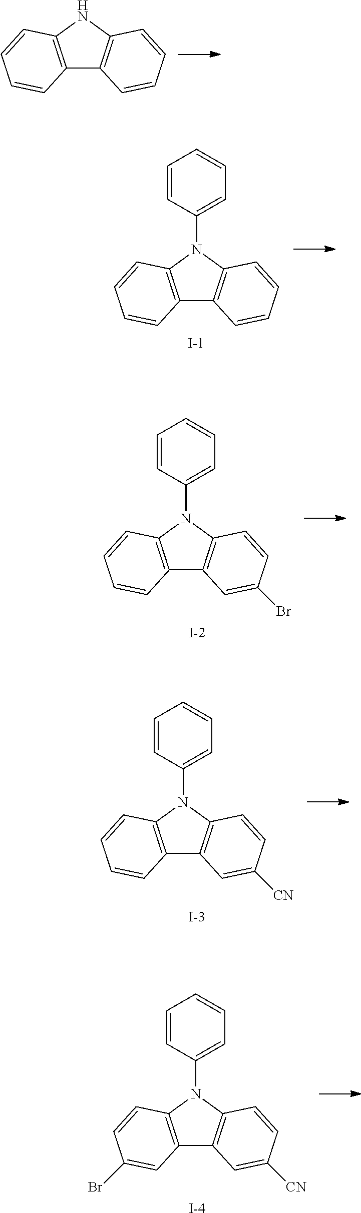

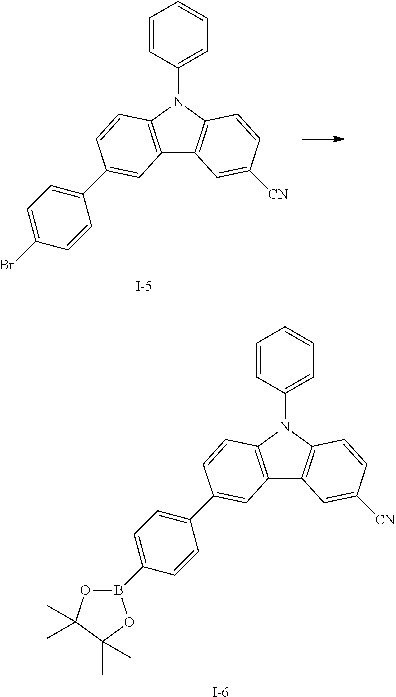

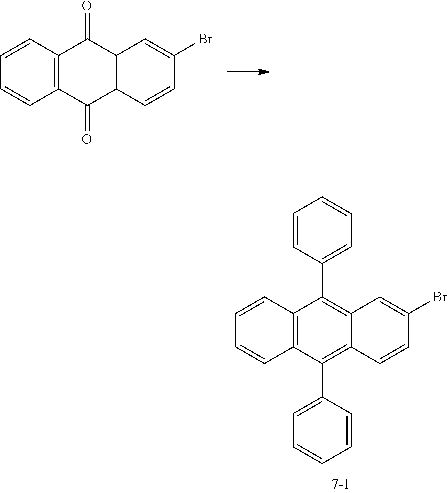 [SMILES: O=C1c2ccccc2C(=O)C2C=C(Br)C=CC12 ; Brc1ccc2c(-c3ccccc3)c3ccccc3c(-c3ccccc3)c2c1]

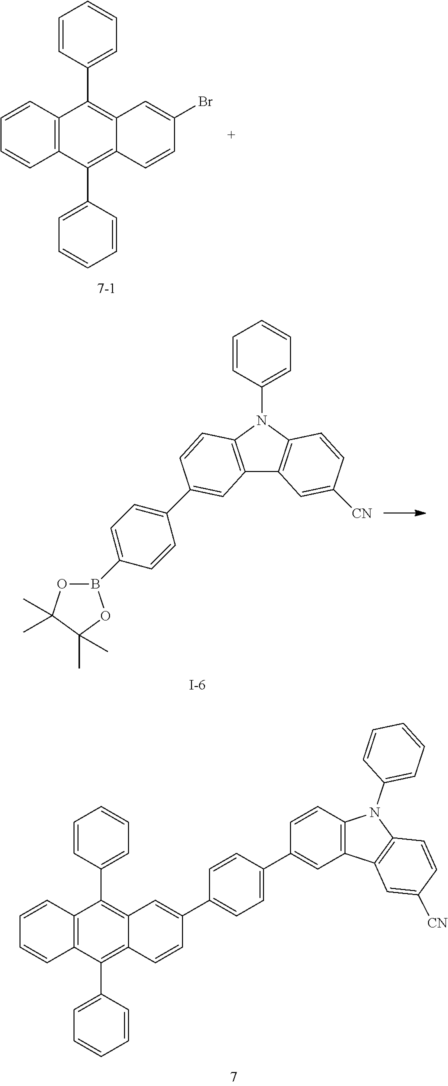

### Synthesis of Intermediate I-1

5.02 g (30 mmol) of 9H-carbazol, 4.71 g (30 mmol) of bromobenzene, 1.14 g (18 mmol) of copper powder, and 6.22 g (45 mmol) of K₂CO₃ were dissolved in 80 mL of o-dichlorobenzene, and then, the mixture was stirred at a temperature of 180° C. for 24 hours. The reaction solution was cooled to room temperature, 60 mL of water was added thereto, and then an extraction was perforated thereon three times using 50 mL of ethyl acetate. An organic layer obtained therefrom was dried using magnesium sulfate and then was dried to remove a solvent therefrom, and the obtained residual was separation-purified by using silica gel column chromatography to obtain 5.47 g of Intermediate I-1 (yield: 75%). The obtained compound was identified by LC-MS. C₁₈H₁₃N:M⁺ 245.10

### Synthesis of Intermediate I-2

5.47 g (22.5 mmol) of Intermediate I-1 was completely dissolved in 80 mL of CH₂Cl₂, 4.00 g (22.5 mmol) of N-bromosuccinimide was added thereto, and the resultant solution was stirred at room temperature for 12 hours. 60 mL of water was added to the reaction solution, and then an extraction was performed thereon three times using 50 mL of CH₂Cl₂. An organic layer was dried using magnesium sulfate, a solvent was evaporated therefrom, and then, the resultant solution was re-crystallized using methanol to obtain 6.16 g (yield 85%) of Intermediate I-2. The obtained compound was identified by LC-MS. C₁₈H₁₂BrN:M⁺ 321.0

### Synthesis of Intermediate I-3

6.16 g (19.1 mmol) of Intermediate I-2 and 2.57 g (28.7 mmol) of CuCN were dissolved in 70 mL of DMF, and then, the mixture was stirred at a temperature of 150° C. for 24 hours. The reaction solution was cooled at room temperature, and then, 60 mL of ammonia water and 60 mL of water were added thereto and then extracted three times using 50 mL of CH₂Cl₂. An organic layer obtained therefrom was dried using magnesium sulfate and then was dried to remove a solvent therefrom, and the obtained residual was separation-purified by using silica gel column chromatography to obtain 4.71 g (yield: 92%) of Intermediate I-3. The obtained compound was identified by LC-MS. C₁₉H₁₂N₂:M⁺ 268.1.

### Synthesis of Intermediate I-4

4.71 g (17.6 mmol) of Intermediate I-3 was completely dissolved in 80 mL of CH₂Cl₂, 3.13 g (17.6 mmol) of N-bromosuccinimide was added thereto, and the resultant solution was stirred at room temperature for 8 hours. 60 mL of water was added to the reaction solution, and then an extraction was performed thereon three times using 50 mL of CH₂Cl₂. An organic layer was dried using magnesium sulfate, and then, a solvent was evaporated therefrom, and then, the resultant solution was re-crystallized using methanol to obtain 5.81 g (yield 95%) of Intermediate I-4. The obtained compound was identified by LC-MS. C₁₉H₁₁BrN₂:M⁺ 346.0

### Synthesis of Intermediate I-5

5.81 g (16.7 mmol) of Intermediate I-4, 3.53 g (17.6 mmol) of 4-bromophenylboronic acid, 0.68 g (0.59 mmol) of Pd(PPh₃)₄, and 4.85 g (35.1 mmol) of K₂CO₃ were dissolved in 60 mL of THF and 30 mL of H₂O, and then, the resultant solution was stirred at a temperature of 80° C. for 12 hours. The reaction solution was cooled to room temperature, and then, extracted three times using 30 mL of water and 30 mL of ethyl acetate. An organic layer obtained therefrom was dried using magnesium sulfate, and then, the residual obtained by evaporating a solvent therefrom was separation-purified by using silica gel column chromatography to obtain 5.30 g (yield: 75%) of Compound I-6. The obtained compound was identified by LC-MS. C₂₅H₁₅BrN₂:M⁺ 422.0

### Synthesis of Intermediate I-6

5.81 g (12.6 mmol) of Intermediate I-5, 0.46 g (0.63 mmol) of Pd(dppf)₂Cl₂, and 3.71 g (37.8 mmol) of KOAc were dissolved in 80 mL of DMSO, and then, the resultant solution was stirred at a temperature of 150° C. for 24 hours. The reaction solution was cooled to room temperature, 100 mL of water was added thereto, and then, the resultant reaction solution was extracted three times using 50 mL of CH₂Cl₂. An organic layer obtained therefrom was dried using magnesium sulfate and then was dried to remove a solvent therefrom, and the obtained residual was separation-purified by using silica gel column chromatography to obtain 4.15 g (yield: 70%) of Intermediate I-6. The obtained compound was identified by LC-MS. C₃₁H₂₇BN₂O:M⁺ 470.2

### Synthesis of Intermediate 7-1

5.42 g (34.5 mmol) of bromobenzene was dissolved in 60 mL of THF, and then, 13.8 mL (34.5 mmol, 2.5 M in hexane) of nBuLi was slowly added thereto at a temperature of −78° C., and then, the resultant mixture was stirred for 1 hour, 4.33 g (15.0 mmol) of 2-bromo-4a, 9a-dihydro-anthraquinone was slowly dropped to the reaction solution and then, the resultant reaction solution was stirred at room temperature for 12 hours. 60 mL of water was added to the reaction solution, the resultant solution was extracted three times using 50 mL of ethyl acetate, and then, the obtained organic layer was dried using magnesium sulfate.

After a solvent was evaporated, 22.4 g (135 mmol) of KI and 21.3 g (165 mmol) of Na₂H₂PO₂.H₂O dissolved in 50 mL of acetic acid were added to the obtained residual, and then, heated at a temperature of 120° C. for 1 hour. The reaction solution was cooled at room temperature, and then, 60 mL of water was added thereto, and filtered. The obtained residual was separation-purified by using silica gel column chromatography to obtain 5.05 g (yield: 82%) of Intermediate I-11. The obtained compound was identified by LC-MS. C₂₆H₁₇Br:M^{+ b 408.0}

### Synthesis of Compound 7

6.97 g (yield: 62%) of Compound 7 was obtained in the same manner as used to synthesize Intermediate I-5, except that Intermediate 7-1 was used, instead of Intermediate I-4 and Intermediate I-6 was used instead of 4-bromophenylboronic acid. The obtained compound was identified by MS/FAB and 1H NMR. C₅₁H₃₂N₂ cal. 672.26, found 672.27

### Synthesis Example 2

### Synthesis of Compound 15

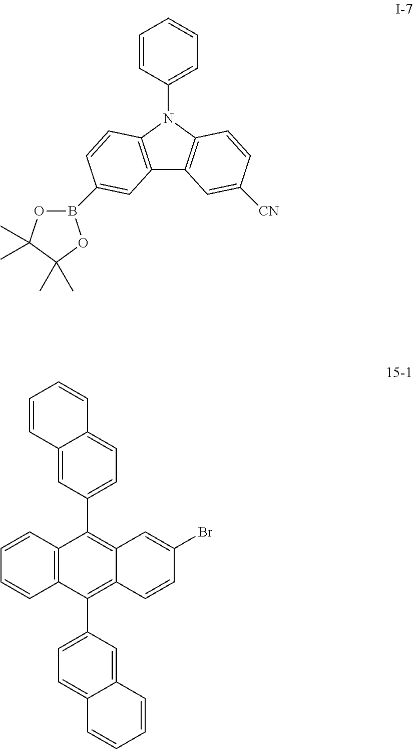 [SMILES: CC1(C)OB(c2ccc3c(c2)c2cc(C#N)ccc2n3-c2ccccc2)OC1(C)C ; Brc1ccc2c(-c3ccc4ccccc4c3)c3ccccc3c(-c3ccc4ccccc4c3)c2c1]

### Synthesis of Intermediate I-7

3.42 g (yield: 69%) of Intermediate I-7 was obtained in the same manner as used to synthesize Intermediate I-6 in Synthesis Example 1, except that Intermediate I-4 was used instead of Intermediate I-5. The obtained compound was identified by LC-MS. C₂₅H₂₃BN₂O₂:M⁺ 394.2

### Synthesis of Intermediate 15-1

5.73 g (yield: 75%) of Intermediate 15-1 was obtained in the same manner as used to synthesize Intermediate 7-1 in Synthesis Example 1, except that 2-bromonaphthalene was used instead of bromobenzene. The obtained compounds was identified by LC-MS. C₃₄H₂₁Br:M⁺ 508.0

### Synthesis of Compound 15

5.38 g (yield: 72%) of Compound 15 was obtained in the same manner as used to synthesize Compound 7 in Synthesis Example 1, except that Intermediate 15-1 and Intermediate I-7 were respectively used instead of Intermediate 7-I and Intermediate I-6. The obtained compound was identified by MS/FAB and ¹H NMR, and results thereof are shown in Table 1. C₅₃H₃₂N₂ cal. 696.26, found 696.28

### Synthesis Example 3

### Synthesis of Compound 20

4.38 g (yield: 70%) of Compound 15 was obtained to the same manner as used to synthesize Compound 7 in Synthesis Example 1, except that Intermediate 15-1 was used instead of Intermediate 7-1. The obtained compound was identified by MS/FAB and ¹H NMR. C₆₉H₃₆N₂ cal. 772.29, found 772.29

### Synthesis Example 4

### Synthesis of Compound 29

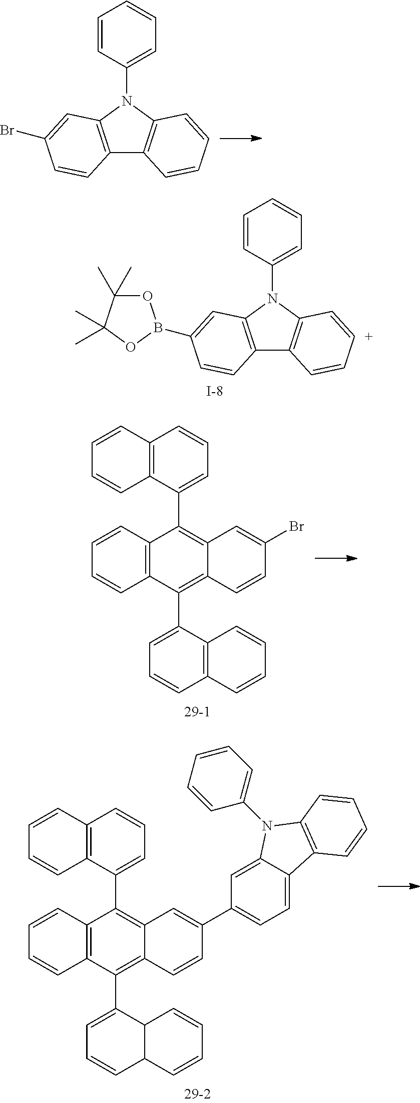

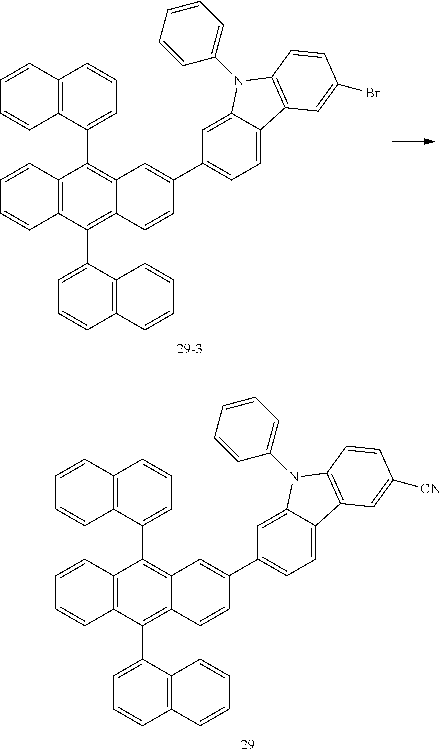 [SMILES: Brc1ccc2c(c1)c1ccc(-c3ccc4c(-c5cccc6ccccc56)c5ccccc5c(-c5cccc6ccccc56)c4c3)cc1n2-c1ccccc1 ; N#Cc1ccc2c(c1)c1ccc(-c3ccc4c(-c5cccc6ccccc56)c5ccccc5c(-c5cccc6ccccc56)c4c3)cc1n2-c1ccccc1]

### Synthesis of Intermediate I-8

3.65 g (yield: 72%) of Intermediate I-8 was obtained in the same manner as used to synthesize Intermediate I-6 in Synthesis Example 1, except that 2-bromo-9-phenyl-9H-carbazol was used instead of Intermediate I-5. The obtained compound was identified by LC-MS. C₂₄H₂₄BNO₂:M⁺ 369.2

### Synthesis of Intermediate 29-1

4.02 g (yield: 78%) of Intermediate 29-1 was obtained in the same manner as used to synthesize Intermediate 7-1 in Synthesis Example 1, except that 1-bromonaphthalene was used instead of bromobenzene. The obtained compound was identified by LC-MS. C₃₄H₂₁Br:M⁺ 508.0

### Synthesis of Intermediate 29-2

3.72 g (yield: 70%) of Intermediate 29-2 was obtained in the same manner as used to synthesize Intermediate I-5 in Synthesis Example 1, except that Intermediate 29-1 was used instead of Intermediate I-4 and Intermediate I-8 was used instead of 4-bromophenylboronic acid. the obtained compound was identified by MS/FAB and ¹H NMR. C₅₂H₃₃N cal. 671.26, found 671.26

### Synthesis of Intermediate 29-3

2.41 g (yield: 58%) of Intermediate 29-3 was obtained in the same manner as used to synthesize Intermediate I-2 in Synthesis Example 1, except that Intermediate 29-2 was used instead of Intermediate I-1. The obtained compound was identified by MS/FAB and ¹H NMR. C₅₂H₃₂BrN cal. 749.17, found 749.18

### Synthesis of Compound 29

1.82 g (yield: 81%) of Compound 29 was obtained in the same manner as used to synthesize Intermediate I-3 in Synthesis Example 1, except that Intermediate 29-3 was used instead of Intermediate I-2. The obtained compound was identified by MS/FAB and ¹H NMR. C₅₃H₃₂N₂ cal. 696.26, found 696.27

### Synthesis Example 5

### Synthesis of Compound 36

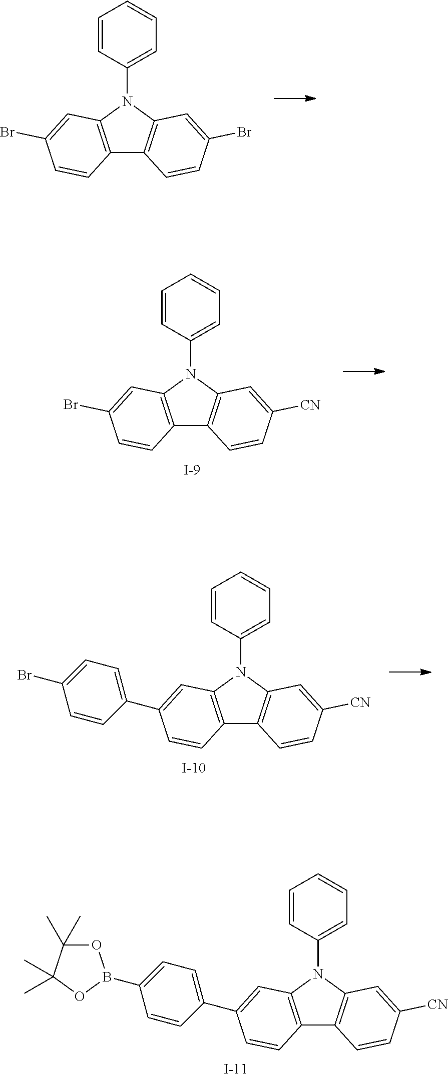

### Synthesis of Intermediate I-9

6.08 g (yield: 35%) of Intermediate I-9 was obtained in the same manner as used to synthesize Intermediate I-3 in Synthesis Example 1, except that 2,7-dibromo-9-phenyl-9H-carbazol was used instead of Intermediate I-2. The obtained compound was identified by LC-MS. C₁₉H₁₁BrN₂:M⁺ 346.0

### Synthesis of Intermediate I-10

4.58 g (yield: 62%) of Intermediate I-10 was obtained in the same manner as used to synthesize Intermediate I-5 in Synthesis Example 1, except that Intermediate I-7 was used instead of Intermediate I-4. The obtained compound was identified by LC-MS. C₂₅H₁₅BrN₂:M⁺ 422.0

### Synthesis of Intermediate I-11

3.83 g (yield: 75%) of Intermediate I-11 was obtained in the same manner as used to synthesize Intermediate I-6 in Synthesis Example 1, except that Intermediate I-10 was used instead of Intermediate I-5. The obtained compound was identified by LC-MS. C₃₁H₂₇BN₂O₂:M⁺ 470.2

### Synthesis of Compound 36

3.55 g (yield: 72%) of Compound 36 was obtained in the same manner as used to synthesize Compound 7 in Synthesis Example 1, except that intermediate 29-1 and Intermediate I-11 were respectively used instead of Intermediate 7-1 and intermediate I-6. The obtained compound was identified by MS/FAB and ¹H NMR. C₅₉H₃₆N₂ cal. 772.29, found 772.29

### Synthesis Example 6

### Synthesis of Compound 45

### Synthesis of Intermediate I-12

4.52 g (yield: 52%) of Intermediate I-12 was obtained in the same manner as used to synthesize Intermediate I-3 in Synthesis Example 1, except that 2,8-dibromodibenzofuran was used instead of Intermediate I-2. The obtained compound was identified by LC-MS. C₁₃H₆BrNO:M⁺ 270.9

### Synthesis of Intermediate I-13

3.44 g (yield: 65%) of Intermediate I-13 was obtained in the same manner as used to synthesize Intermediate I-6 in Synthesis Example 1, except that Intermediate I-12 was used instead of Intermediate I-5. The obtained compound was identified by LC-MS. C₁₉H₁₈BNO₃:M⁺ 319.1

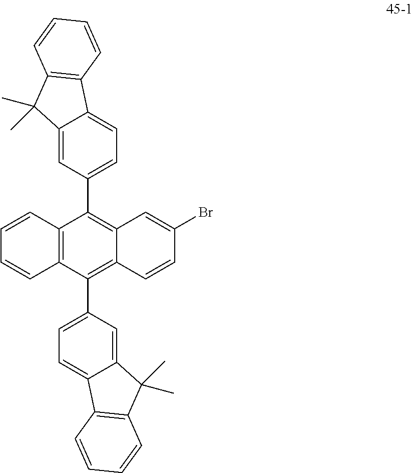 [SMILES: CC1(C)c2ccccc2-c2ccc(-c3c4ccccc4c(-c4ccc5c(c4)C(C)(C)c4ccccc4-5)c4cc(Br)ccc34)cc21]

### Synthesis of Intermediate 45-1

43.88 g (yield: 76%) of Intermediate 45-1 was obtained in the same manner as used to synthesize Intermediate 7-1 in Synthesis Example 2, except dial 2-bromo-9,9-dimethyl-9H-fluorenene was used instead of bromobenzene. The obtained compound was identified by LC-MS. C₄H₂₃Br:M⁺ 640.2

### Synthesis of Compound 45

3.56 g (yield: 78%) of Compound 45 was obtained in the same manner as used to synthesize Compound 7 in Synthesis Example 1, except that Intermediate 45-1 and Intermediate I-13 were respectively used instead of Intermediate 7-1 and Intermediate I-6. The obtained compound was identified by MS/FAB and ¹H NMR. C₅₉H₃₆N₂ cal. 753.30, found 753.30

### Synthesis Example 7

### Synthesis of Compound 65

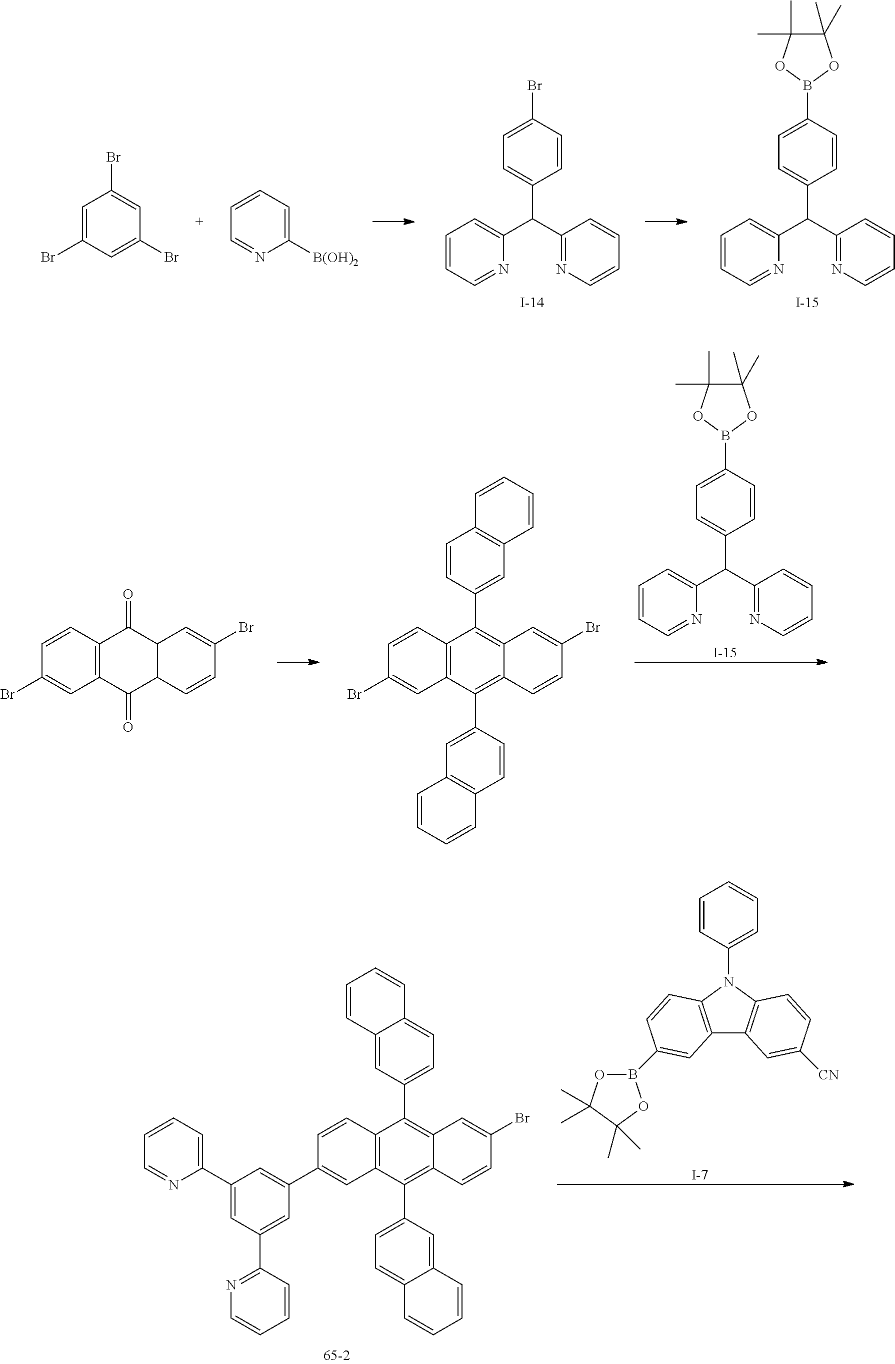

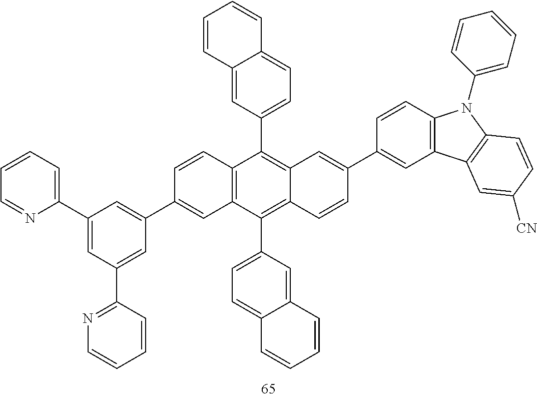 [SMILES: N#Cc1ccc2c(c1)c1cc(-c3ccc4c(-c5ccc6ccccc6c5)c5cc(-c6cc(-c7ccccn7)cc(-c7ccccn7)c6)ccc5c(-c5ccc6ccccc6c5)c4c3)ccc1n2-c1ccccc1]

### Synthesis of Intermediate I-14

3.50 g (yield: 66%) of Intermediate I-14 was obtained in the same manner as used to synthesize Intermediate I-5 in Synthesis Example 1, except that 1,3,5-tribromobenzene was used instead of Intermediate I-4 and 2-pyridineboronic acid was used instead of 4-bromophenylboronic acid. The obtained compound was identified by LC-MS. C₁₆H₁₁BrN₂:M⁺ 310.0

### Synthesis of Intermediate I-15

3.15 (yield: 78%) of Intermediate I-15 was obtained in the same manner as used to synthesize Intermediate I-6 in Synthesis Example 1, except that Intermediate I-14 was used instead of Intermediate I-5. The obtained compound was identified by LC-MS. C₂₂H₂₃BN₂O₂:M⁺ 358.1

### Synthesis of Intermediate 65-1

3.42 g (yield: 61%) of Intermediate 65-1 was obtained in the same manner as used to synthesize Intermediate 7-1 in Synthesis Example 2, except that 2,6-dibromo-4a,9a-dihydro-anthraquinone was used instead of 2-bromo-4a,9a-dihydro-anthraquinone and 2-bromonaphthalene was used instead of bromobenzene. The obtained compound was identified by LC-MS. C₄₄H₂₀ Br₂:M⁺ 585.9

### Synthesis of Intermediate 65-2

3.05 g (yield: 71%) of Intermediate 52-2 was obtained in the same manner as used to synthesis Intermediate I-5 in Synthesis Example 1, except that Intermediate 52-1 was used instead of Intermediate I-4 and Intermediate I-15 was used instead of 4-bromophenylboronic acid. The obtained compound was identified by LC-MS. C₅₆ H₃₁BrN₂:M⁺ 738.1

### Synthesis of Compound 65

3.10 g (yield: 81%) of Compound 65 was obtained in the same manner as used to synthesize Compound 7 in Synthesis Example 1, except that Intermediate 65-2 and Intermediate I-7 were respectively used instead of Intermediate 7-1 and Intermediate I-6. The obtained compound was identified by MS/FAB and ¹H NMR. C₆₉H₄₂N₄ cal. 926.34, found 926.35

### Synthesis Example 8

### Synthesis of Compound 62

3.20 g (yield: 65%) of Compound 62 was obtained in the same manner as in Synthesis Example 7, except that in synthesizing Intermediate 65-2, 3-pyridineboronic acid was used instead of Intermediate I-15. The obtained compound was identified by MS/FAB and ¹H NMR. C₅₈H₃₅N₈ cal. 773.28, found 773.28

### Synthesis Example 9

### Synthesis of Compound 69

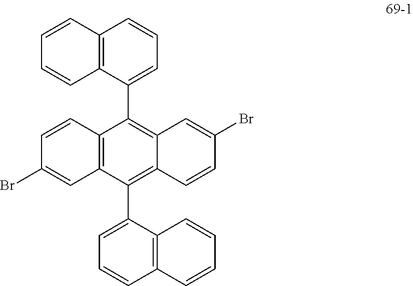 [SMILES: Brc1ccc2c(-c3cccc4ccccc34)c3cc(Br)ccc3c(-c3cccc4ccccc34)c2c1]

3.18 g (yield: 71%) of Compound 69 was obtained in the same manner as in Synthesis Example 7, except that in synthesizing Intermediate 65-2, 1-naphthylboronic acid was used instead of Intermediate I-15. The obtained compound was identified by MS/FAB and ¹H NMR. C₆₃H₃₈N₂ cal. 822.30, found 822.31

### Synthesis Example 10

### Synthesis of Compound 72

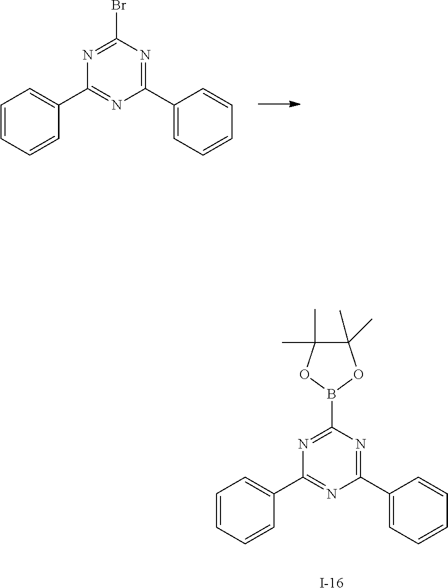

### Synthesis of Intermediate I-16

3.68 (yield: 79%) of Intermediate I-16 was obtained in the same manner as used to synthesize Intermediate I-6 in Synthesis Example 1, except that 2-bromo-4,6-diphenyl-1,3,5-triazine was used instead of Intermediate I-5. The obtained compound was identified by LC-MS. C₂₁H₂₂BN₃O₂:M⁺ 359.1

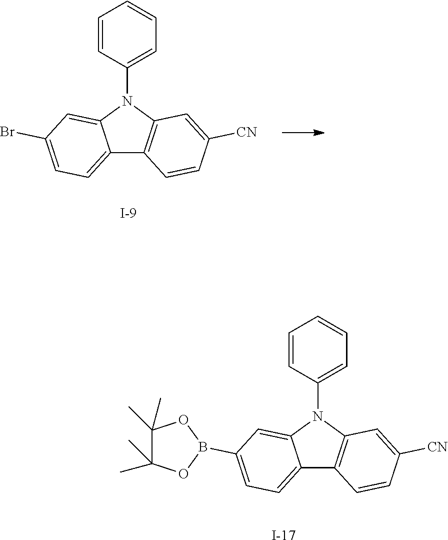

### Synthesis of Intermediate I-17

3.10 g (yield: 82%) of Intermediate I-17 was obtained in the same manner as used to synthesize Intermediate I-6 in Synthesis Example 1, except that Intermediate I-9 was used instead of Intermediate I-5. The obtained compound was identified by LC-MS, C₂₅H₂₃BN₂O₂:M⁺ 394.1

### Synthesis of Compound 72

4.03 g (yield: 73%) of Compound 72 was obtained in the same manner as in Synthesis Example 7, except that in synthesizing Intermediate 65-1, 1-bromonaphthalene was used instead of 2-bromonaphthalene and Intermediate I-16 was used instead of Intermediate I-15, and in synthesizing Compound 65, Intermediate I-17 was used instead of Intermediate I-7. The obtained compound was identified by MS/FAB and ¹H NMR. C₆₈H₄₁N₅ cal. 927.34, found 927.34

### Synthesis Example 11

### Synthesis of Compound 89

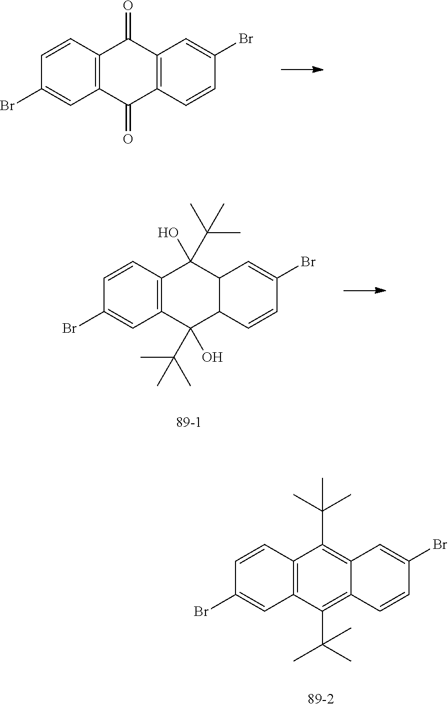 [SMILES: O=C1c2ccc(Br)cc2C(=O)c2ccc(Br)cc21 ; CC(C)(C)C1(O)c2ccc(Br)cc2C(O)(C(C)(C)C)C2C=CC(Br)=CC21 ; CC(C)(C)c1c2ccc(Br)cc2c(C(C)(C)C)c2ccc(Br)cc12]

### Synthesis of Intermediate 89-1

In a nitrogen atmosphere, 2.9 g (10 mmol) of 2,6-dibromo-4a,9a-dihydro-anthraquinone was dissolved in 50 mL of purified tetrahydrofuran, and cooled to a temperature of −78° C., and then, 5 mL (2.0 M in diethyl ether) of t-butylmagnesium chloride was slowly added thereto. At the same temperature, the resultant solution was stirred for 30 minutes, and then a cooling diode was removed to raise a temperature thereof to room temperature. After stirring for one hour, when the reaction was terminated, the temperature was decreased to 0° C., and then, 10 mL of ammonium chloride aqueous solution teas slowly added thereto. Then, the resultant solution was extracted two times using 40 mL of diethyl ether, an organic layer obtained therefrom was dried using magnesium sulfate and filtered, and a solvent was evaporated therefrom. The obtained compound was identified by LC-MS. C₂₂H₂₈Br₂O₂:M⁺ 482.0

### Synthesis of Intermediate 89-2

A mixture of 2.6 g (5.39 mmol) of Intermediate 89-1, 10.7 g (53.9 mmol) of potassium iodide, 11.4 g (129 mmol) of sodium hypophosphate hydrate was refluxed in a mixed solution including 600 mL of ortho-dichloro benzene and 80 mL of an acetic acid for 24 hours. The reaction solution was cooled to room temperature, extracted using chloroform, and then, dehydrated using anhydrous magnesium sulfate, followed by compression to remove a solvent therefrom. The residual obtained therefrom was separation-purified by silica gel column chromatography to obtain 2.70 g (yield: 73%) of Intermediate 89-2. The obtained compound was identified by LC-MS. C₂₂H₂₆Br₂:M⁺ 448.0

### Synthesis of Compound 89

4.40 g (yield: 75%) of Compound 89 was obtained in the same manner as used to synthesize Compound 7 in Synthesis Example 1, except that Intermediate 89-2 was used instead of Intermediate 7-1. The obtained compound was identified by MS/FAB and ¹H NMR. C₇₂ H₅₄N₄ cal. 974.43, found 974.43

### Synthesis Example 12

### Synthesis of Compound 96

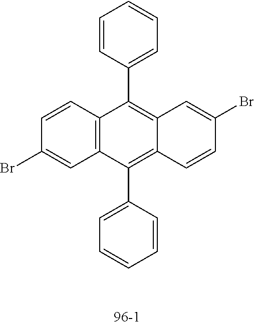 [SMILES: Brc1ccc2c(-c3ccccc3)c3cc(Br)ccc3c(-c3ccccc3)c2c1]

3.05 g (yield: 65%) of Compound 96 was obtained in the same manner as in Synthesis Example 7, except that in synthesizing Intermediate 65-2, Intermediate 96-1 and Intermediate I-7 were respectively used instead of Intermediate 65-1 and Intermediate I-15. The obtained compound was identified by MS/FAB and ¹H NMR. C₆₄H₃₈N₄ cal. 862.31, found 862.32

### Synthesis Example 13

### Synthesis of Compound 103

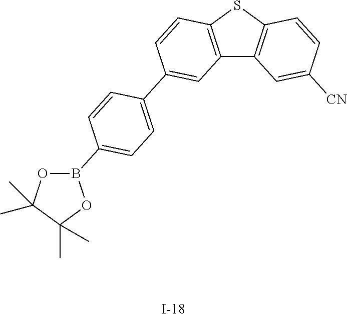

### Synthesis of Intermediate I-18

Intermediate I-18 was obtained in the same manner as used to synthesize Intermediates I-2, I-3, I-4, I-5, and I-6 in Synthesis Example 1, except that 2,8-dibromodibenzothiophene was used instead of Intermediate I-1.

### Synthesis of Compound 103

3.76 g (yield: 75%) of Compound 103 was obtained in the same manner as in Synthesis Example 7, except that in synthesizing Intermediate 65-2, Intermediate 96-1 and Intermediate I-18 were respectively used instead of Intermediate 65-1 and Intermediate I-15. The obtained compound was identified by MS/FAB and ¹H NMR. C₆₄H₃₆N₂S₂ cal. 896.23, found 896.24

### Synthesis Example 14

### Synthesis of Compound 104

3.89 g (yield: 70%) of Compound 104 was obtained in the same manner as in Synthesis Example 7, except that in synthesizing Intermediate 65-2, Intermediate I-7 was used instead of Intermediate I-15. The obtained compound was identified by MS/FAB and ¹H NMR. C₇₂H₄₂N₄ cal. 962.34, found 962.34

### Synthesis Example 15

### Synthesis of Compound 109

3.31 g (yield: 72%) of Compound 109 was obtained in the same manner as in Synthesis Example 7, except that in synthesizing Intermediate 65-2, Intermediate 69-1 and Intermediate I-17 were respectively used instead of Intermediate 65-1 and Intermediate I-15. The obtained compound was identified by MS/FAB and ¹H NMR. C₇₂H₄₂N₄ cal. 962.34, found 962.34

### Synthesis Example 16

### Synthesis of Compound 112

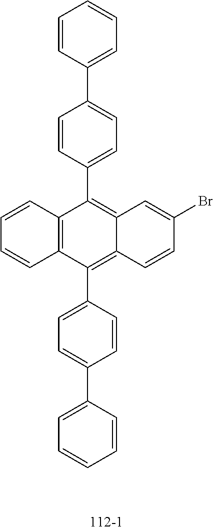 [SMILES: Brc1ccc2c(-c3ccc(-c4ccccc4)cc3)c3ccccc3c(-c3ccc(-c4ccccc4)cc3)c2c1]

2.85 g (yield: 74%) of Compound 112 was obtained in the same manner as used to synthesize Compound 7 in Synthesis Example 1, except that Intermediate 112-1 and Intermediate I-7 were respectively used instead of Intermediate 7-1 and Intermediate I-6. The obtained compound was identified by MS/FAB and ¹H NMR. C₅₇H₃₆N₂ cal. 748.29, found 748.30

### Synthesis Example 17

### Synthesis of Compound 116

3.08 g (yield: 69%) of Compound 116 was obtained in the same manner as used to synthesize Compound 7 in Synthesis Example 1, except that Intermediate 112-1 and Intermediate I-11 were respectively used instead of Intermediate 7-1 and Intermediate I-6. The obtained compound was identified by MS/FAB and ¹H NMR. C₆₃H₄₀N₂ cal. 824.32, found 824.32

### Synthesis Example 18

### Synthesis of Compound 1

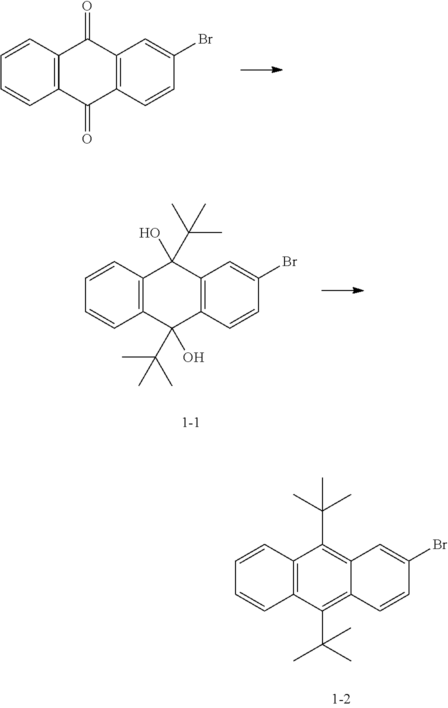 [SMILES: O=C1c2ccccc2C(=O)c2cc(Br)ccc21 ; CC(C)(C)C1(O)c2ccccc2C(O)(C(C)(C)C)c2cc(Br)ccc21 ; CC(C)(C)c1c2ccccc2c(C(C)(C)C)c2cc(Br)ccc12]

### Synthesis of Intermediate I-2

Intermediate 1-2 was prepared in the same manner as used to synthesize Intermediate 89-1 and 89-2 in Synthesis Example 11, except that 2-bromo-4a,9a-dihydro-anthraquinone was used instead of 2,6-dibromo-4a,9a-dihydro-anthraquinone.

### Synthesis of Compound 1

4.02 g (yield: 75%) of Compound 1 was obtained in the same manner as used to synthesize Compound 7 in Synthesis Example 1, except that Intermediate I-2 and Intermediate I-7 were respectively used instead of Intermediate 7-2 and Intermediate I-6. The obtained compound was identified by MS/FAB and ¹H NMR.

### Synthesis Example 19

### Synthesis of Compound 5

3.77 g (yield: 64%) of Compound 5 was obtained in the same manner as used to synthesize Compound 7 in Synthesis Example 1, except that Intermediate I-13 was used instead of Intermediate I-6. The obtained compound was identified by MS/FAB and ¹H NMR.

### Synthesis Example 20

### Synthesis of Compound 8

2.87 g (yield: 62%) of Compound 8 was obtained in the same manner as used to synthesis Compound 7 in Synthesis Example 1, except that Intermediate I-11 was used instead of Intermediate I-6. The obtained compound was identified by MS/FAB and ¹H NMR.

### Synthesis Example 21

### Synthesis of Compound 12

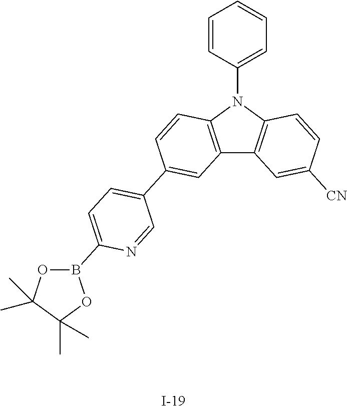

### Synthesis of Intermediate I-19

Intermediate I-19 was synthesized in the same manner as used to synthesize Intermediates I-5 and I-6 in Synthesis Example 1, except that in synthesizing Intermediate I-5, 5-bromo-2-(4,4,5,5-tetramethyl-1,3,2-dioxaborolan-2-yl)pyridine was used instead of 4-bromophenylboronic acid.

### Synthesis of Compound 12

3.02 g (yield: 71%) of Compound 12 was obtained in the same manner as used to synthesize Compound 7 in Synthesis Example 1, except that Intermediate I-9 was used instead of Intermediate I-6. The obtained compound was identified by MS/FAB and ¹H NMR.

### Synthesis Example 22

### Synthesis of Compound 24

3.88 g (yield: 75%) of Compound 24 was obtained in the same manner as used to synthesize Compound 7 in Synthesis Example 24, except that Intermediate 15-2 and Intermediate I-18 were respectively used instead of Intermediate 7-1 and Intermediate I-6. The obtained compound was identified by MS/FAB and ¹H NMR.

### Synthesis Example 23

### Synthesis of Compound 26

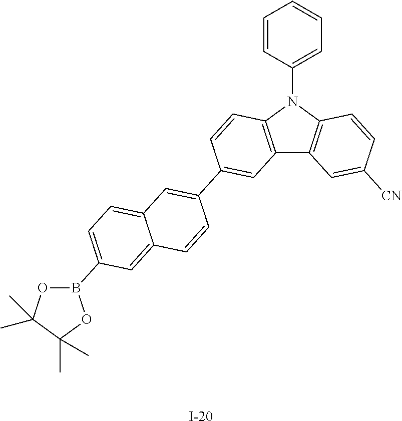

### Synthesis of Intermediate I-20

Intermediate I-19 was synthesized in the same manner as used to synthesize Intermediates I-5 and I-6 in Synthesis Example 1, except that in synthesizing Intermediate I-5, 1-(2-bromonaphthalen-6-yl)-4,4,5,5-tetramethyl-1,3,2-dioxaborolane was used instead of 4-bromophenylboronic acid.

### Synthesis of Compound 26

3.44 g (yield: 63%) of Compound 26 was obtained in the same manner as used to synthesize Compound 7 in Synthesis Example 24, except that Intermediate 15-2 and Intermediate I-20 were respectively used instead of Intermediate 7-1 and Intermediate I-6. The obtained compound was identified by MS/FAB and ¹H NMR.

### Synthesis Example 24

### Synthesis of Compound 43

4.00 g (yield: 78%) of Compound 43 was obtained in the same manner as used to synthesize Compound 7 in Synthesis Example 43, except that Intermediate 45-1 and Intermediate I-7 were respectively used instead of Intermediate 7-1 and Intermediate I-6. The obtained compound was identified by MS/FAB and ¹H NMR.

### Synthesis Example 25

### Synthesis of Compound 49

3.89 g (yield: 69%) of Compound 49 was obtained in the same manner as in Synthesis Example 7, except that in synthesizing Intermediate 65-1, bromobenzene was used instead of 2-bromonaphthalene, and in synthesizing Intermediate 65-2, phenylboronic acid was used instead of Intermediate I-15. The obtained compound was identified by MS/FAB and ¹H NMR.

### Synthesis Example 26

### Synthesis of Compound 52

4.00 g (yield: 74%) of Compound 52 was obtained in the same manner as in Synthesis Example 7, except that in synthesizing Intermediate 65-1, bromobenzene was used instead of 2-bromonaphthalene, and in synthesizing Intermediate 65-2, 2-(4,4,5,5-tetramethyl-1,3,2-dioxaborolan-2-yl)-6-phenylpyridine was used instead of Intermediate I-15. The obtained compound was identified by MS/FAB and ¹H NMR.

### Synthesis Example 27

### Synthesis of Compound 58

3.46 g (yield: 62%) of Compound 58 was obtained is the same manner as in Synthesis Example 7, except that in synthesizing Intermediate 65-1, bromobenzene was used instead of 2-bromonaphthalene, in synthesizing Intermediate 65-2, 2-naphthylboronic acid was used instead of Intermediate I-15, and in synthesizing Compound 65, Intermediate I-13 was used instead of Intermediate I-7. The obtained compound was identified by MS/FAB and ¹H NMR.

### Synthesis Example 28

### Synthesis of Compound 64

4.03 g (yield: 79%) of Compound 64 was obtained in the same manner as in Synthesis Example 7, except that in synthesizing Intermediate 65-2, 2-(4,4,5,5-tetramethyl-1,3,2-dioxaborolan-2-yl)-6-phenylpyridine was used instead of Intermediate I-15. The obtained compound was identified by MS/FAB and ¹H NMR.

### Synthesis Example 29

### Synthesis of Compound 79

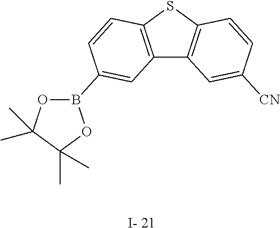 [SMILES: CC1(C)OB(c2ccc3sc4ccc(C#N)cc4c3c2)OC1(C)C ; "I- 21"]

### Synthesis of Intermediate I-21

Intermediate I-12 was synthesized in the same manner as used to synthesize Intermediates I-12 and I-13 in Synthesis Example 6, except that 2,8-dibromodibenzothiophene was used instead of 2,8-dibromodibenzofuran.

### Synthesis of Compound 79

3.22 g (yield: 70%) of Compound 79 was obtained in the same manner as in Synthesis Example 7, except that in synthesizing Intermediate 65-1, 2-bromo-9,9-dimethyl-9H-fluorenene was used instead of 2-bromonaphthalene, in synthesizing Intermediate 65-2, phenylboronic acid was used instead of Intermediate I-15, and in synthesizing Compound 65, Intermediate I-21 was used instead of Intermediate I-7, the Synthesis Example 7. The obtained compound was identified by MS/FAB and ¹H NMR.

### Synthesis Example 30

### Synthesis of Compound 83

3.79 g (yield: 72%) of Compound 83 was obtained is the same manner as in Synthesis Example 7, except that in synthesizing Intermediate 65-1, bromobenzene was used instead of 2-bromonaphthalene, in synthesizing Intermediate 65-2, 1-naphthylboronic acid was used instead of Intermediate I-15, and in synthesizing Compound 65, Intermediate I-6 was used instead of Intermediate I-7. The obtained compound was identified by MS/FAB and ¹H NMR.

### Synthesis Example 31

### Synthesis of Compound 92

3.89 g (yield: 70%) of Compound 104 was obtained in the same manner as in Synthesis Example 7, except that in synthesizing Intermediate 6589, Intermediate I-7 was used instead of Intermediate I-15. The obtained compound was identified by MS/FAB and ¹H NMR.

### Synthesis Example 32

### Synthesis of Compound 94

3.25 f (yield: 74%) of Compound 94 was obtained in the same manner as in Example 11, except that in synthesizing Compound 89, Intermediate I-21 was used instead of Intermediate I-6. The obtained compound was identified by MS/FAB and ¹H NMR.

### Synthesis Example 33

### Synthesis of Compound 110

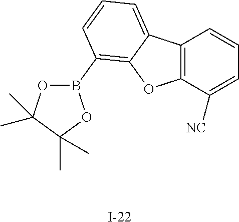

### Synthesis of Intermediate I-22

Intermediate I-22 was synthesized in the same manner as used to synthesize Intermediates I-12 and I-13 in Synthesis Example 6, except that 4,6-dibromodibenzofuran was used instead of 2,8-dibromodibenzofuran.

### Synthesis of Compound 110

3.75 g (yield: 75%) of Compound 110 was obtained in the same manner as in Synthesis Example 11, except that in synthesizing Compound 89, Intermediate 69-1 and Intermediate I-22 were respectively used instead of Intermediate 89-2 and Intermediate I-6. The obtained compound was identified by MS/FAB and ¹H NMR.

¹H NMR and MS/FAB results of the synthesized compounds are shown in Table 1 below.

Synthesis methods for compounds other than those listed in Table 1 may be determined by one of skill in the art by referring to the synthetic paths and source materials of Synthesis Examples 1 to 33.

TABLE 1

| | | MS/FAB | |
|---|---|---|---|
| Compound | ¹H NMR (CDCl₃, 400 MHz) | Found | calc. |
| 1 | 8.32-8.30 (m, 1H), 8.27-8.25 (m, 1H), 8.13-8.09 | 556.30 | 556.29 |
| | (m, 3H), 7.84 (d, 1H), 7.68-7.62 (m, 2H), 7.57-7.54 | | |
| | (m, 2H), 7.52-7.40 (m, 6H), 7.34-7.25 (m, 2H), | | |
| | 1.54 (s, 9H), 1.51 (s, 9H) | | |
| 5 | 8.45-8.43 (m, 1H), 8.40-8.38 (m, 1H), 7.93-7.83 | 521.18 | 521.18 |
| | (m, 3H), 7.81-7.75 (m, 6H), 7.71-7.69 (m, 1H), | | |
| | 7.65-7.62 (m, 2H), 7.57-7.46 (m, 5H), 7.41-7.25 | | |
| | (m, 4H) | | |
| 7 | 8.35-8.32 (m, 1H), 8.22-8.20 (m, 1H), 7.97-7.93 | 672.27 | 672.26 |
| | (m, 5H), 7.85-7.77 (m, 6H), 7.71-7.69 (m, 2H), | | |
| | 7.63-7.61 (m, 2H), 7.57-7.46 (m, 9H), 7.41-7.25 | | |
| | (m, 6H) | | |
| 8 | 8.03-7.93 (m, 5H), 7.91-7.89 (m, 1H), 7.88-7.84 | 672.26 | 672.26 |
| | (m, 2H), 7.82-7.76 (m, 6H), 7.74-7.67 (m, 2H), | | |
| | 7.60-7.45 (m, 10H), 7.41-7.27 (m, 6H) | | |
| 12 | 8.68-8.66 (m, 1H), 8.62-8.60 (m, 1H), 8.38-8.36 | 673.26 | 673.25 |
| | (m, 1H), 8.31-8.26 (m, 2H), 8.14 (d, 1H), 8.09 (dd, | | |
| | 1H), 7.92 (d, 1H), 7.81-7.77 (m, 4H), 7.71-7.62 (m, | | |
| | 3H), 7.57-7.46 (m, 9H), 7.41-7.26 (m, 7H) | | |
| 15 | 8.31-8.29 (m, 1H), 8.27-8.24 (m, 1H), 8.17-8.15 | 696.28 | 696.26 |
| | (m, 1H), 8.07-8.05 (m, 1H), 7.98-7.96 (m, 1H), | | |
| | 7.96-7.83 (m, 10H), 7.76-7.68(m, 3H), 7.65-7.46 | | |
| | (m, 10H), 7.40-7.25 (m, 4H) | | |
| 20 | 8.31-8.29 (m, 1H), 8.21-8.19 (m, 1H), 8.08-8.06 | 772.29 | 772.29 |
| | (m, 2H), 8.00-7.98 (m, 1H), 7.96-7.88 (m, 12H) | | |
| | 7.85-7.79 (m, 2H), 7.75-7.73(m, 1H), 7.70-7.46 | | |
| | (m, 12H), 7.40-7.25 (m, 4H) | | |
| 24 | 8.40-8.35 (m, 2H), 8.12-7.89 (m, 5H), 7.95-7.88 | 713.22 | 713.22 |
| | (m, 10H), 7.85-7.74 (m, 5H), 7.71-7.65 (m, 3H), | | |
| | 7.62-7.54 (m, 4H), 7.40-7.32 (m, 2H) | | |
| 26 | 8.33-8.30 (m, 3H), 8.27-8.25 (m, 1H), 8.07-8.05 | 822.31 | 822.30 |
| | (m, 1H), 8.01-7.88 (m, 14H), 7.83-7.79 (m, 2H), | | |
| | 7.76-7.68 (m, 2H), 7.65-7.45 (m, 11H), 7.40-7.25 | | |
| | (m, 5H) | | |
| 29 | 8.50-8.48 (m, 1H), 8.39-8.37 (m, 1H), 8.31-8.29 | 696.27 | 696.26 |
| | (m, 1H), 8.21-8.19 (m, 1H), 7.97-7.95 (m, 1H), | | |
| | 7.90-7.79 (m, 6H), 7.72-7.68 (m, 4H), 7.63 (dd, | | |
| | 1H), 7.59-7.44 (m, 7H), 7.37-7.25 (m, 7H), 6.96- | | |
| | 6.93 (m, 2H) | | |
| 36 | 8.39-8.37 (m, 1H), 8.16 (d, 1H), 8.03-7.89 (m, | 772.29 | 772.29 |
| | 13H), 7.76-7.69 (m, 5H), 7.60-7.50 (m, 7H), 7.46- | | |
| | 7.44 (m, 1H), 7.37-7.27 (m, 6H), 6.98-7.94 (m, | | |
| | 2H) | | |
| 43 | 8.21-8.19 (m, 1H), 8.15-8.13 (m, 1H), 7.98-7.96 | 828.36 | 828.35 |
| | (m, 1H), 7.93-7.88 (m, 5H), 7.86-7.79 (m, 5H), | | |
| | 7.75-7.69 (m, 3H), 7.63 (dd, 1H), 7.52-7.47 (m, | | |
| | 4H), 7.45-7.25 (m, 7H), 7.15-7.09 (m, 4H), 1.61 (s, | | |
| | 12H) | | |
| 45 | 8.45-8.43 (m, 1H), 8.40-8.38 (m, 1H), 7.94-7.68 | 753.31 | 753.30 |
| | (m, 15H), 7.63 (d, 1H), 7.43-7.30 (m, 5H), 7.15- | | |
| | 7.09 (m, 4H), 1.60 (s, 12H) | | |
| 49 | 8.32-8.30 (m, 1H), 8.26-8.24 (m, 1H), 8.07-8.04 | 672.27 | 672.26 |
| | (m, 1H), 7.94-7.90 (m, 2H), 7.86-7.71 (m, 9H), | | |
| | 7.65-7.60 (m, 3H), 7.53-7.46 (m, 10H), 7.42-7.37 | | |
| | (m, 3H), 7.32-7.25 (m, 2H) | | |
| 52 | 8.70-8.68 (m, 2H), 8.45-8.43 (m, 1H), 8.34-8.27 | 926.35 | 926.34 |
| | (m, 4H), 8.24-8.22 (m, 1H), 8.13-8.01 (m, 5H), | | |
| | 7.97-7.83 (m, 10H), 7.75-7.69 (m, 5H), 7.65-7.46 | | |
| | (m, 10H), 7.34-7.26 (m, 4H) | | |
| 58 | 8.45-8.43 (m, 1H), 8.41-8.39 (m, 1H), 8.25-8.23 | 647.23 | 647.22 |
| | (m, 1H), 8.07 (d, 1H), 7.98 (d, 1H), 7.96-7.75 (m, | | |
| | 14H), 7.64-7.56 (m, 3H), 7.53-7.48 (m, 5H), 7.41- | | |
| | 7.37 (m, 2H) | | |
| 62 | 8.89-8.87 (m, 1H), 8.55-8.53 (m, 1H), 8.31-8.25 | 773.29 | 773.28 |
| | (m, 3H), 8.09-7.96 (m, 4H), 7.97-7.83 (m, 11H), | | |
| | 7.74 (dd, 1H), 7.65-7.46 (m, 12H), 7.34-7.26 (m, | | |
| | 2H) | | |
| 64 | 8.83-8.81 (m, 1H), 8.39-8.06 (m, 9H), 7.97-7.90 | 849.32 | 849.31 |
| | (m, 10H), 7.86-7.47 (m, 16H), 7.41-7.38 (m, 1H), | | |
| | 7.32-7.25 (m, 2H) | | |
| 65 | 8.70-8.66 (m, 2H), 8.44 (t, 1H), 8.35-8.33 (m, 2H), | 926.34 | 926.34 |
| | 8.30-8.27 (m, 2H), 8.24-8.22 (m, 1H), 8.13-8.01 | | |
| | (m, 5H), 7.97-7.63 (m, 10H), 7.75-7.69 (m, 5H), | | |
| | 7.65-7.45 (m, 10H), 7.34-7.25 (m, 4H) | | |
| 69 | 8.41-8.38 (m, 2H), 8.31-8.25 (m, 3H), 8.19-8.17 | 822.31 | 822.30 |
| | (m, 2H), 8.07-8.05 (m, 1H), 8.01-7.90 (m, 5H) | | |
| | 7.86-7.82 (m, 5H), 7.73-7.68 (m, 6H), 7.65-7.57 | | |
| | (m, 4H), 7.52-7.46 (m, 4H), 7.36-7.25 (m, 4H), | | |
| | 6.96-6.94 (m, 2H) | | |
| 72 | 8.90-8.88 (m, 1H), 8.73-8.68 (m, 5H), 8.43-8.39 | 927.34 | 927.34 |
| | (m, 3H), 8.23 (d, 1H), 8.04-7.93 (m, 4H), 7.89-7.80 | | |
| | (m, 4H), 7.72-7.68 (m, 4H), 7.63-7.51 (m, 11H), | | |
| | 7.42-7.27 (m, 6H), 6.96-6.94 (m, 2H) | | |
| 79 | 8.60-8.58 (m, 1H), 8.35-8.33 (m, 1H), 8.12 (d, 1H), | 845.32 | 845.31 |
| | 8.02 (d, 1H), 7.95-7.74 (m, 15H), 7.69-7.67 (m, | | |
| | 1H), 7.51-7.47 (m, 2H), 7.43-7.36 (m, 3H), 7.33- | | |
| | 7.28 (m, 2H), 7.15-7.09 (m, 4H), 1.61 (s, 12H) | | |
| 83 | 8.32-8.30 (m, 1H), 8.21-8.17 (m, 2H), 7.97-7.96 | 798.31 | 798.30 |
| | (m, 1H), 7.93-7.79 (m, 14H), 7.96-7.61 (m, 4H), | | |
| | 7.53-7.46 (m, 10H), 7.41-7.37 (m, 2H), 7.34-7.28 | | |
| | (m, 3H), 7.02-7.00 (m, 1H) | | |
| 89 | 8.31-8.29 (m, 1H), 8.23-8.21 (m, 2H), 8.15-8.13 | 974.43 | 974.43 |
| | (m, 2H), 7.94-7.91 (m, 4H), 7.85-7.82 (m, 2H), | | |
| | 7.74-7.70 (m, 4H), 7.65-7.58 (m, 8H), 7.52-7.46 | | |
| | (m, 8H), 7.34-7.25 (m, 5H), 1.59 (s, 18H) | | |
| 92 | 8.41-8.39 (m, 2H), 8.30-8.27 (m, 2H), 8.24-8.20 | 672.29 | 672.28 |
| | (m, 2H), 7.86 (dd, 2H), 7.76-7.72 (m, 4H), 7.64- | | |
| | 7.56 (m, 6H), 1.58 (s, 18H) | | |
| 94 | 8.55-8.53 (m, 2H), 8.38-8.35 (m, 2H), 8.18-8.11 | 704.24 | 704.23 |
| | (m, 4H), 8.03-8.01 (m, 2H), 7.81 (dd, 2H), 7.68 | | |
| | (dd, 2H), 7.60-7.56 (m, 4H), 1.59 (s, 18H) | | |
| 96 | 8.31-8.28 (m, 2H), 8.25-8.22 (m, 2H), 8.05-8.02 | 862.32 | 862.31 |
| | (m, 2H), 7.91 (dd, 2H), 7.86-7.80 (m, 6H), 7.72 | | |
| | (dd, 2H), 7.65-7.59 (n, 4H), 7.53-7.46 (m, 12H), | | |
| | 7.41-7.37 (m, 2H), 7.34-7.25 (m, 4H). | | |
| 103 | 8.35-8.30- (m, 4H), 8.11 (dd, 2H), 8.03-7.91 (m, | 896.24 | 896.23 |
| | 8H), 7.85-7.76 (m, 12H), 7.69-7.63 (m, 4H), 7.53- | | |
| | 7.48 (m, 4H), 7.41-7.37 (m, 2H) | | |
| 104 | 8.31-8.29 (m, 2H), 8.27-8.25 (m, 2H), 8.22-8.19 | 962.35 | 962.34 |
| | (m, 2H), 8.07-8.05 (m, 2H), 7.97-7.91 (m, 10H), | | |
| | 7.65-7.63 (m, 2H), 7.74-7.71 (m, 2H), 7.65-7.46 | | |
| | (m, 16H), 7.34-7.25 (m, 4H) | | |
| 109 | 8.41-8.39 (m, 1H), 8.24-8.22 (m, 2H), 8.04-7.93 | 962.34 | 962.34 |
| | (m, 7H), 7.89-7.80 (m, 6H), 7.72-7.68 (m, 6H), | | |
| | 7.60-7.51 (m, 12H), 7.38-7.27 (m, 6H), 6.98-6.94 | | |
| | (m, 2H) | | |
| 110 | 8.41-8.35 (m, 6H), 8.14-8.08 (m, 4H), 7.94-7.90 | 812.25 | 812.25 |
| | (m, 6H), 7.64-7.62 (m, 2H), 7.72-7.68 (m, 4H), | | |
| | 7.59-7.55 (m, 4H), 7.48-7.44 (n, 2H), 7.36-7.32 (m, | | |
| | 2H), 6.98-6.94 (m, 2H) | | |
| 112 | 8.31-8.29 (m, 1H), 8.27-8.25 (m, 1H), 8.05-8.03 | 748.30 | 748.29 |
| | (m, 1H), 7.90-7.71 (m, 12H), 7.67-7.59 (m, 7H), | | |
| | 7.53-7.46 (m, 8H), 7.42-7.25 (m, 6H) | | |
| 116 | 8.03-7.95 (m, 5H), 7.91-7.89 (m, 1H), 7.85-7.71 | 824.32 | 824.32 |
| | (m, 14H), 7.67-7.65 (m, 1H), 7.62-7.56 (m, 5H), | | |
| | 7.54-7.49 (m, 8H), 7.42-7.27 (m, 6H) | | |

### Example 1

An ITO glass substrate (a product of Corning Co., Ltd) including an ITO layer having a thickness of 15 Ω/cm² (1200 Å) was cut to a size of 50 mm×50 mm×0.7 mm, sonicated using isopropyl alcohol and pure water each for 5 minutes, and cleaned by the exposure to ultraviolet rays for 30 minutes and then to ozone. Then, the ITO glass substrate was mounted on a vacuum deposition apparatus.

2-TNATA was deposited on the ITO layer acting as an anode to form a hole injection layer having a thickness of 600 Å, NPB was deposited on the hole injection layer to form a hole transport layer having a thickness of 300 Å, and then, ADN(host) and DPAVBi(dopant) were co-deposited at a weight ratio of 98:2 on the emission layer to form an emission layer having a thickness of 300 Å.

Thereafter, Compound 7 was deposited on the emission layer to form an electron transport layer having a thickness of 300 Å, LiF was deposited on the electron transport layer to form an electron injection layer having a thickness of 10 Å, and Al was deposited on the electron injection layer to form a cathode having a thickness of 3000 Å, thereby completing the manufacture of an organic light-emitting diode.

### Example 2

An organic light-emitting diode was manufactured in the same manner as in Example 1, except that in forming an electron transport layer, Compound 15 was used instead of Compound 7.

### Example 3

An organic light-emitting diode was manufactured in the same manner as in Example 1, except that in forming an electron transport layer, Compound 20 was used instead of Compound 7.

### Example 4

An organic light-emitting diode was manufactured in the same manner as in Example 1, except that in forming an electron transport layer, Compound 24 was used instead of Compound 7.

### Example 5

An organic light-emitting diode was manufactured in the same manner as in Example 1, except that in forming an electron transport layer, Compound 29 was used instead of Compound 7.

### Example 6

An organic light-emitting diode was manufactured in the same manner as in Example 1, except that in forming an electron transport layer, Compound 36 was used instead of Compound 7.

### Example 7

An organic light-emitting diode was manufactured in the same manner as in Example 1, except that in forming an electron transport layer, Compound 45 was used instead of Compound 7.

### Example 8

An organic light-emitting diode was manufactured in the same manner as in Example 1, except that in forming an electron transport layer, Compound 52 was used instead of Compound 7.

### Example 9

An organic light-emitting diode was manufactured in the same manner as in Example 1, except that in forming an electron transport layer, Compound 62 was used instead of Compound 7.

### Example 10

An organic light-emitting diode was manufactured in the same manner as in Example 1, except that in forming an electron transport layer, Compound 69 was used instead of Compound 7.

### Example 11

An organic light-emitting diode was manufactured in the same manner as in Example 1, except that in forming an electron transport layer, Compound 72 was used instead of Compound 7.

### Example 12

An organic light-emitting diode was manufactured in the same manner as in Example 1, except that in forming an electron transport layer, Compound 78 was used instead of Compound 7.

### Example 13

An organic light-emitting diode was manufactured in the same manner as in Example 1, except that in forming an electron transport layer, Compound 89 was used instead of Compound 7.

### Example 14

An organic light-emitting diode was manufactured in the same manner as in Example 1, except that in forming an electron transport layer, Compound 96 was used instead of Compound 7.

### Example 15

An organic light-emitting diode was manufactured in the same manner as in Example 1, except that in forming an electron transport layer, Compound 103 was used instead of Compound 7.

### Example 16

An organic light-emitting diode was manufactured in the same manner as in Example 1, except that in forming an electron transport layer, Compound 104 was used instead of Compound 7.

### Example 17

An organic light-emitting diode was manufactured in the same manner as in Example 1, except that in forming an electron transport layer, Compound 109 was used instead of Compound 7.

### Example 18

An organic light-emitting diode was manufactured in the same manner as in Example 1, except that in forming an electron transport layer, Compound 110 was used instead of Compound 7.

### Example 19

An organic light-emitting diode was manufactured in the same manner as in Example 1, except that in forming an electron transport layer, Compound 112 was used instead of Compound 7.

### Example 20

An organic light-emitting diode was manufactured in the same manner as in Example 1, except that in forming an electron transport layer, Compound 117 was used instead of Compound 7.

### Comparative Example 1

An organic light-emitting diode was manufactured in the same manner as in Example 1, except that in forming an electron transport layer, Alq₃ was used instead of Compound 7.

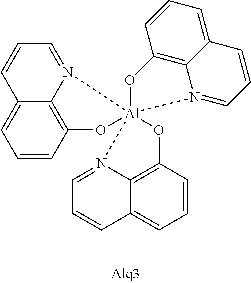

### Comparative Example 2

An organic light-emitting diode was manufactured in the same manner as in Example 1, except that in forming an electron transport layer, Compound A was used instead of Compound 7.

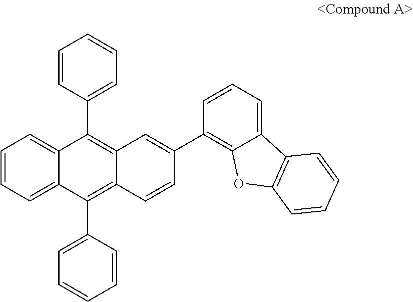 [SMILES: c1ccc(-c2c3ccccc3c(-c3ccccc3)c3cc(-c4cccc5c4oc4ccccc45)ccc23)cc1]

### Evaluation Example 1

The driving voltage, current density, brightness, efficiency, and half-lifespan of the organic light-emitting diodes manufactured according to Examples 1 to 20, and Comparative Examples 1 and 2 were measured using a Kethley SMU 236 and a brightness photometer PR650, and results thereof are shown in Table 2. The half-lifespan is a period of time that is taken until the brightness of the organic light-emitting diode reduces down to 50% of the initial brightness.

TABLE 2

| | | Driving | Current | | | | Half lifespan |
|---|---|---|---|---|---|---|---|
| | Electron | voltage | Density | Brightness | Efficiency | Emission | (hr @100 mA/ |
| | transport layer | (V) | (mA/cm²) | (cd/m²) | (cd/A) | color | cm²) |
| Example 1 | Compound 7 | 5.41 | 50 | 3130 | 6.26 | Blue | 463 |
| Example 2 | Compound 15 | 5.32 | 50 | 3065 | 6.13 | Blue | 457 |
| Example 3 | Compound 20 | 5.36 | 50 | 3230 | 6.46 | Blue | 478 |
| Example 4 | Compound 24 | 5.16 | 50 | 3310 | 6.62 | Blue | 338 |
| Example 5 | Compound 29 | 5.27 | 50 | 3215 | 6.43 | Blue | 416 |
| Example 6 | Compound 36 | 5.21 | 50 | 3190 | 6.38 | Blue | 434 |
| Example 7 | Compound 45 | 5.35 | 50 | 3280 | 6.56 | Blue | 321 |
| Example 8 | Compound 52 | 4.98 | 50 | 3530 | 7.06 | Blue | 345 |
| Example 9 | Compound 62 | 5.03 | 50 | 3570 | 7.14 | Blue | 382 |
| Example 10 | Compound 69 | 5.25 | 50 | 3045 | 6.09 | Blue | 439 |
| Example 11 | Compound 72 | 5.06 | 50 | 2980 | 5.96 | Blue | 395 |
| Example 12 | Compound 83 | 5.26 | 50 | 3110 | 6.22 | Blue | 438 |
| Example 13 | Compound 89 | 5.38 | 50 | 3055 | 6.11 | Blue | 377 |
| Example 14 | Compound 96 | 5.23 | 50 | 3105 | 6.21 | Blue | 465 |
| Example 15 | Compound 103 | 5.04 | 50 | 3200 | 6.40 | Blue | 355 |
| Example 16 | Compound 104 | 5.10 | 50 | 3130 | 6.26 | Blue | 471 |
| Example 17 | Compound 109 | 5.13 | 50 | 3090 | 6.18 | Blue | 420 |
| Example 18 | Compound 110 | 5.16 | 50 | 3050 | 6.10 | Blue | 367 |
| Example 19 | Compound 112 | 5.33 | 50 | 2940 | 5.88 | Blue | 409 |
| Example 20 | Compound 117 | 5.29 | 50 | 3020 | 6.04 | Blue | 425 |
| Comparative | Alq₃ | 7.35 | 50 | 2065 | 4.13 | Blue | 145 |
| Example 1 | | | | | | | |
| Comparative | Compound A | 6.75 | 50 | 2335 | 4.67 | Blue | 183 |
| Example 2 | | | | | | | |

From Table 2, it was confirmed that the driving voltage, current density, brightness, efficiency, and half-lifespan of the organic light-emitting diodes manufactured according to Examples 1 to 20 are higher than the driving voltage, current density, brightness, efficiency, and half-lifespan of the organic light-emitting diodes manufactured according to Comparative Examples 1 and 2.

As described above, an organic light-emitting diode including a condensed compound according to an embodiment may have a low driving voltage, high efficiency, high brightness, and long lifespan.

By way of summation and review, an organic light-emitting diode may include a first electrode disposed on a substrate, and a hole transport region, an emission layer, an electron transport region, and a second electrode, which are sequentially disposed on the first electrode. Holes injected from the first electrode may pass via the hole transport region and migrate toward the emission layer, and electrons injected from the second electrode may pass via the electron transport region toward the emission layer. The holes and the electrons are recombined with each other in the emission layer to generate excitons. Then, the excitons are transitioned from an excited state to a ground state, thereby generating light.

Formula 1 includes a “carbazole-based ring” substituted with CN (cyano) (see Formula 1′ below), and Formula 2 includes a “first carbazole-based ring” and a “second carbazole-based ring”, each of which is substituted with CN (cyano) (see Formula 2′ below).

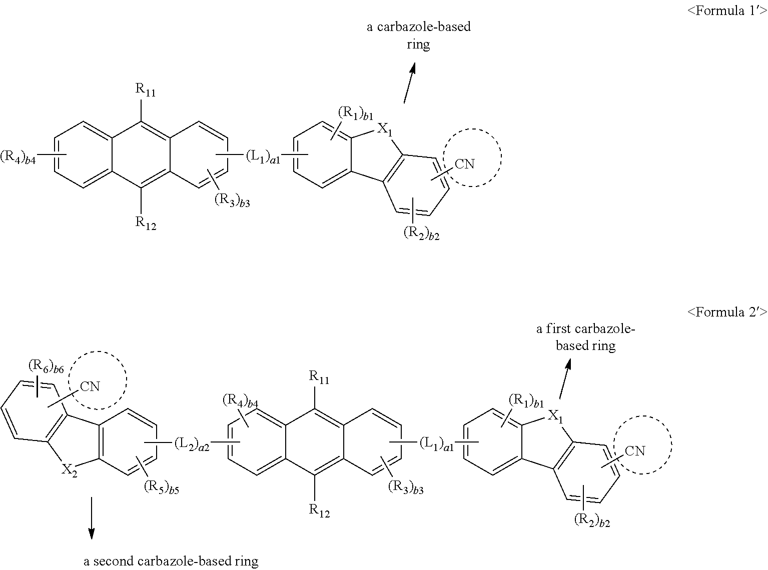

Since Formulae 1 and 2 include a “carbazole-based ring” substituted with CN, an intermolecular binding force may be enhanced. Accordingly, an organic light-emitting diode including at least one of a compound represented by Formula 1 or at least one of a compound represented by Formula 2 may have a long lifespan

Also, Formulae 1 and 2 include a “carbazole-based ring” substituted with CN, and X₁ and X₂, which are heteroatoms of the “carbazole-based ring,” may offset electron pulling effects of CN. Accordingly, the compound represented by Formula 1 and the compound represented by Formula 2 may have excellent thermal stability. An organic light-emitting diode including at least one of a compound represented by Formula 1 or at least one of a compound represented by Formula 2 may have a long lifespan

Without wishing to be bound by any theories, it believed that since Formulae 1 and 2 include a “carbazole-based ring”, though the “carbazole-based ring” is substituted with CN, which has a strong electron withdrawing characteristic, electron-trapping may be reduced or not occur, and a diode including the same may have a long lifespan. For example, in the case of a compound having the same structure as Formula 1 except that “phenanthroline” is employed instead of the “carbazole-based ring”, due to the inclusion of both CN and “phenanthroline”, each of which has a high electron withdrawing characteristic, electron-trapping may occur, and the lifespan of the organic light-emitting diode may be decreased.

Accordingly, an organic light-emitting diode including the condensed compound represented by Formula 1 or Formula 2 may have a low driving voltage, high efficiency, high brightness, and long lifespan.

Example embodiments have been disclosed herein, and although specific terms are employed, they are used and are to be interpreted in a generic and descriptive sense only and not for purpose of limitation. In some instances, as would be apparent to one of skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. A condensed compound for an organic light-emitting diode, the condensed compound being represented by Formula 1 or 2: 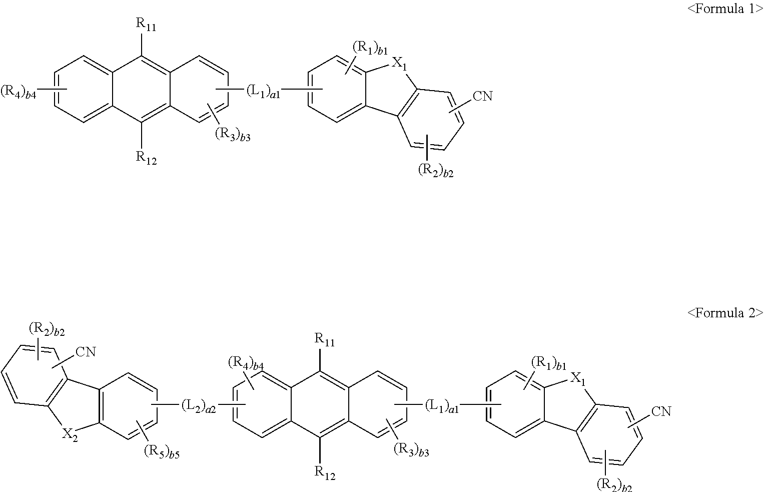
wherein:
X₁ is N(R₂₁), O, or S;
X₂ is N(R₂₂), O, or S;
L₁ and L₂ are each independently selected from a substituted or unsubstituted C₃-C₁₀ cycloalkylene group, a substituted or unsubstituted C₂-C₁₀ heterocycloalkylene group, a substituted or unsubstituted C₃-C₁₀ cycloalkenylene group, a substituted or unsubstituted C₂-C₁₀ heterocycloalkenylene group, a substituted or unsubstituted C₆C₆₀ arylene group, a substituted or unsubstituted C₂-C₆₀ heteroarylene group, a substituted or unsubstituted divalent non-aromatic condensed poylcyclic group, and a substituted or unsubstituted divalent non-aromatic hetero-condensed polycyclic group;
a1 and a2 are each independently selected from 0, 1, 2, and 3;
R₁ to R₆, R₁₁, R₁₂, R₂₁, and R₂₂ are each independently selected from a hydrogen, a deuterium, —F, —Cl, —Br, —I, a hydroxyl group, a cyano group, a nitro group, an amino group, an amidino group, a hydrazine group, a hydrazone group, a carboxylic acid and a salt thereof, a sulfonic acid and a salt thereof, a phosphoric acid and a salt thereof, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₃-C₁₀ cycloalkyl group, a substituted or unsubstituted C₂-C₁₀ heterocycloalkyl group, a substituted or unsubstituted C₃-C₁₀ cycloalkenyl group, a substituted or unsubstituted C₂-C₁₀ heterocycloalkenyl group, a substituted or unsubstituted C₆-C₆₀ aryl group, a substituted or unsubstituted C₆-C₆₀ aryloxy group, a substituted or unsubstituted C₆-C₆₀ arylthio group, a substituted or unsubstituted C₂-C₆₀ heteroaryl group, a substituted or unsubstituted monovalent non-aromatic condensed polycyclic group, a substituted or unsubstituted monovalent non-aromatic hetero-condensed polycyclic group, —N(Q₁)(Q₂), —Si(Q₃)(Q₄)(Q₅), and —B(Q₆)(Q₇);
b1 to b6 are each independently selected from 0, 1, 2, and 3;
at least one substitutent of the substituted C₃-C₁₀ cycloalkylene, the substituted C₂-C₁₀ heterocycloalkylene, the substituted C₃-C₁₀ cycloalkenylene, the substituted C₂-C₁₀ heterocycloalkenylene, the substituted C₆-C₆₀ arylene, the substituted C₂-C₆₀ heteroarylene, the substituted divalent non-aromatic condensed polycyclic group, the substituted divalent non-aromatic hetero-condensed polycyclic group, the substituted C₁-C₆₀ alkyl, the substituted C₂-C₆₀ alkenyl, the substituted C₂-C₆₀ alkynyl, the substituted C₁-C₆₀ alkoxy, the substituted C₃-C₁₀ cycloalkyl, the substituted C₂-C₁₀ heterocycloalkyl, the substituted C₃-C₁₀ cycloalkenyl, the substituted C₂-C₁₀ heterocycloalkenyl, the substituted C₆-C₆₀ aryl, the substituted C₆-C₆₀ aryloxy, the substituted C₆-C₆₀ arylthio, the substituted C₂-C₆₀ heteroaryl, the substituted monovalent non-aromatic condensed polycyclic group, and the substituted monovalent non-aromatic hetero-condensed polycyclic group is selected from
a deuterium, —F, —Cl, —Br, —I, a hydroxyl group, a cyano group, a nitro group, an amino group, an amidino group, a hydrazine group, a hydrazone group, a carboxylic acid and a salt thereof, a sulfonic acid and a salt thereof, a phosphoric acid and a salt thereof, a C₁-C₆₀ alkyl group, a C₂-C₆₀ alkenyl group, a C₂-C₆₀ alkynyl group, and a C₁-C₆₀ alkoxy group;
a C₁-C₆₀ alkyl group, a C₂-C₆₀ alkenyl group, a C₂-C₆₀ alkynyl group, and a C₁-C₆₀ alkoxy group, each substituted with at least one selected from a deuterium, —F, —Cl, —Br, —I, a hydroxyl group, a cyano group, a nitro group, an amino group, an amidino group, a hydrazine group, a hydrazone group, a carboxylic acid and a salt thereof, a sulfonic acid and a salt thereof, a phosphoric acid and a salt thereof, a C₃-C₁₀ cycloalkyl group, a C₂-C₁₀ heterocycloalkyl group, a C₃-C₁₀ cycloalkenyl group, a C₂-C₁₀ heterocycloalkenyl group, a C₆-C₆₀ aryl, a C₆-C₆₀ aryloxy group, a C₆-C₆₀ arylthio group, a C₂-C₆₀ heteroaryl group, a monovalent non-aromatic condensed polycyclic group, a monovalent non-aromatic hetero-condensed polycyclic group, —N(Q₁₁)(Q₁₂), —Si(Q₁₃)(Q₁₄)(Q₁₅), and —B(Q₁₆)(Q₁₇);
a C₃-C₁₀ cycloalkyl group, a C₂-C₁₀ heterocycloalkyl group, a C₃-C₁₀ cycloalkenyl group, a C₂-C₁₀ heterocycloalkenyl group, a C₆-C₆₀ aryl group, a C₆-C₆₀ aryloxy group, a C₆-C₆₀ arylthio group, a C₂-C₆₀ heteroaryl group, a monovalent non-aromatic condensed polycyclic group, and a monovalent non-aromatic hetero-condensed polycyclic group;
a C₃-C₁₀ cycloalkyl group, a C₂-C₁₀ heterocycloalkyl group, a C₃-C₁₀ cycloalkenyl group, a C₂-C₁₀ heterocycloalkenyl group, a C₆-C₆₀ aryl group, a C₆-C₆₀ aryloxy group, a C₆-C₆₀ arylthio group, a C₂-C₆₀ heteroaryl group, a monovalent non-aromatic condensed polycyclic group, and a monovalent non-aromatic hetero-condensed polycyclic group, each substituted with at least one selected from a deuterium, —F, —Cl, —Br, —I, a hydroxyl group, a cyano group, a nitro group, an amino group, an amidino group, a hydrazine group, a hydrazone group, a carboxylic acid and a salt thereof, a sulfonic acid and a salt thereof, a phosphoric acid and a salt thereof, a C₁-C₆₀ alkyl group, a C₂-C₆₀ alkenyl group, a C₂-C₆₀ alkynyl group, a C₁-C₆₀ alkoxy group, a C₃-C₁₀ cycloalkyl group, a C₂-C₁₀ heterocycloalkyl group, a C₃-C₁₀ cycloalkenyl group, a C₂-C₁₀ heterocycloalkenyl group, a C₆-C₆₀ group, aryl group, a C₆-C₆₀ aryloxy group, a C₆-C₆₀ arylthio group, a C₂-C₆₀ heteroaryl group, a monovalent non-aromatic condensed polycyclic group, a monovalent non-aromatic hetero-condensed polycyclic group, —N(Q₂₁)(Q₂₂), —Si(Q₂₃)(Q₂₄)(Q₂₅), and —B(Q₂₆)(Q₂₇); and
—N(Q₃₁)(Q₃₂), —Si(Q₃₃)(Q₃₄)(Q₃₅), and —B(Q₃₆)(Q₃₇); and
Q₁ to Q₇, Q₁₁ to Q₁₇, Q₂₁ to Q₂₇, and Q₃₁ to Q₃₇ are each independently selected from a hydrogen, a deuterium, —F, —Cl, —Br, —I, a hydroxyl group, a cyano group, a nitro group, an amino group, an amidino group, a hydrazine group, a hydrazone group, a carboxylic acid and a salt thereof, a sulfonic acid and a salt thereof, a phosphoric acid and a salt thereof, a C₁-C₆₀ alkyl group, C₂-C₆₀ alkenyl group, a C₂-C₆₀ alkynyl group, a C₁-C₆₀ alkoxy group, a C₃-C₁₀ cycloalkyl group, a C₂-₁₀ heterocycloalkyl group, a C₃-C₁₀ cycloalkenyl group, a C₂-C₁₀ heterocycloalkenyl group, a C₆-C₆₀ aryl group, a C₂-C₆₀ heteroaryl group, a monovalent non-aromatic condensed polycyclic group, and a monovalent non-aromatic hetero-condensed polycyclic group.

2. The condensed compound as claimed in claim 1, wherein L₁ and L₂ are each independently selected from
a phenylene group, a pentalenylene group, an indenylene group, a naphthylene group, an azulenylene group, a heptalenylene group, an indacenylene group, an acenaphthylene group, a fluorenylene group, a spiro-fluorenylene group, a benzofluorenylene group, a dibenzofluorenylene group, a phenalenylene group, a phenanthrenylene group, an anthracenylene group, a fluoranthenylene group, a triphenylenylene group, a pyrenylene group, a chrysenylene group, a naphthacenylene group, a picenylene group, a perylenylene group, a pentaphenylene group, a hexacenylene group, a pentacenylene group, a rubicenylene group, a coronenylene group, an ovalenylene group, a pyrrolylene group, a thiophenylene group, a furanylene group, an imidazolylene group, a pyrazolylene grooup, a thiazolylene group, an isothiazolylene group, an oxazolylene group, an isooxazolylene group, a pyridinylene group, a pyrazinylene group, a pyrmidinylene group, a pyridazinylene group, an isoindolylene group, an indolylene group, an indazolylene group, a purinylene group, a quinolinylene group, an isoquinolinylene group, a benzoquinolinylene group, a phthalazinylene group, a naphthyridinylene group, a quinoxalinylene group, a quinazolinylene group, a cinnolinylene group, a carbazolylene group, a phenanthridinylene group, a acridinylene group, a phenanthrolinylene group, a phenzinylene group, a benzoimidazolylene group, a benzofuranylene group, a benzothiophenylene group, an isobenzothiazolylene group, a benzooxazolylene group, an isobenzooxazolylene group, a triazolylene group, a tetrazolylene group, an oxadiazolylene group, a triazinylene group, a dibenzofuranylene group, a dibenzothiophenylene group, a benzocarbazolylene group, a dibenzocarbazolylene group, a thiadiazolylene group, an imidazopyridinylene group and an imidazopyrimidinylene group; and
a phenylene group, a pentalenylene group, an indenylene group, a naphthalene group, an azulenylene group, a heptalenylene group, an indacenylene group, an acenaphthylene group, a fluorenylene group, a spiro-fluorenylene group, a benzofluorenylene group, a dibenzofluorenylene group, a phenalenylene group, a phenanthrenylene group, an anthracenylene group, a fluorantenylene group, a triphenylenylene group, a pyrenylene group, a chrysenylene group, a naphthacenylene group, a picenylene group, a perylenylene group, a pentaphenylene group, a hexacenylene group, a pentacenylene group, a rubicenylene group, a coronenylene group, an ovalenylene group, a pyrrolylene group, a thiophenylene group, a furanylene group, an imidazolylene group, a pyrazolylene group, a thiazolylene group, an isothiazolylene group, an oxazolylene group, an isoxazolylene group, a pyridinylene group, a pyrazinylene group, a pyrimidinylene group, a pyridazinylene group, an isoindolylene group, an indolylene group, an indazolylene group, a purinylene group, a quinolinylene group, an isoquinolinylene group, a benzoquinolinylene group, a phthalazinylene group, a naphthilidinylene group, a quinoxalinylene group, a quinazolinylene group, a cinnolinylene group, a carbazolylene group, a phenanthridinylene group, an acridinylene group, a phenanthrolinylene group, a phenazinylene group, a benzoimidazolylene group, a benzofuranylene group, a benzothiophenylene group, an isobenzothiazolylene group, a benzooxazolylene group, an isobenzooxazolylene group, a triazolylene group, a tetrazolylene group, an oxadiazolylene group, a triazinylene group, a dibenzofuranylene group, a dibenzothiophenylene group, a benzocarbazolylene group, a dibenzocarbazolylene group, a thiadiazolylene group, an imidazopyridinylene group and an imidazopyrimidinylene group, each substituted with at least one selected from a deuterium, —F, —Cl, —Br, —I, a hydroxyl group, a cyano group, a nitro group, an amino group, an amidino group, a hydrazine group, a hydrazone group, a carboxylic acid and a salt thereof, a sulfonic acid and a salt thereof, a phosphoric acid and a salt thereof, a C₁-C₂₀ alkyl group, a C₁-C₂₀ alkoxy group, a cyclopentyl group, a cyclohexyl group, a cycloheptyl group, a cyclopentenyl group, a cyclohexenyl group, a phenyl group, a pentalenyl group, an indenyl group, a naphthyl group, an azulenyl group, a heptalenyl group, a indacenyl group, an acenaphthyl group, a fluorenyl group, a spiro-fluorenyl group, a benzofluorenyl group, a dibenzofluorenyl group, a phenalenyl group, a phenanthrenyl group, an anthracenyl group, a fluorantenyl group, a triphenylenyl group, a pyrenyl group, a chrysenyl group, a naphthacenyl group, a picenyl group, a perylenyl group, a pentaphenyl group, a hexacenyl group, a pentacenyl group, a rubicenyl group, a coronenyl group, an ovalenyl group, a pyrrolyl group, a thiophenyl group, a furanyl group, a imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a phthalazinyl group, a naphthyridinyl group, a quinoxalinyl group, a quinazolinyl group, a cinnolinyl group, a carbazolyl group, a phenanthridinyl group, an acridinyl group, a phenanthrolinyl group, a phenazinyl group, a benzoimidazolyl group, a benzofuranyl group, a benzothiophenyl group, an isobenzothiazolyl group, a benzooxazolyl group, an isobenzooxazolyl group, a triazolyl group, a tetrazolyl group, an oxadiazolyl group, a triazinyl group, a dibenzofuranyl group, a dibenzothiophenyl group, a benzocarbazolyl group, a dibenzocarbazolyl group, a thiadiazolyl group, an imidazolpyridinyl group, and an imidazopyrimidinyl group.

3. The condensed compound as claimed in claim 1, wherein:
L₁ and L₂ are each independently selected from Formulae 3-1 to 3-32: 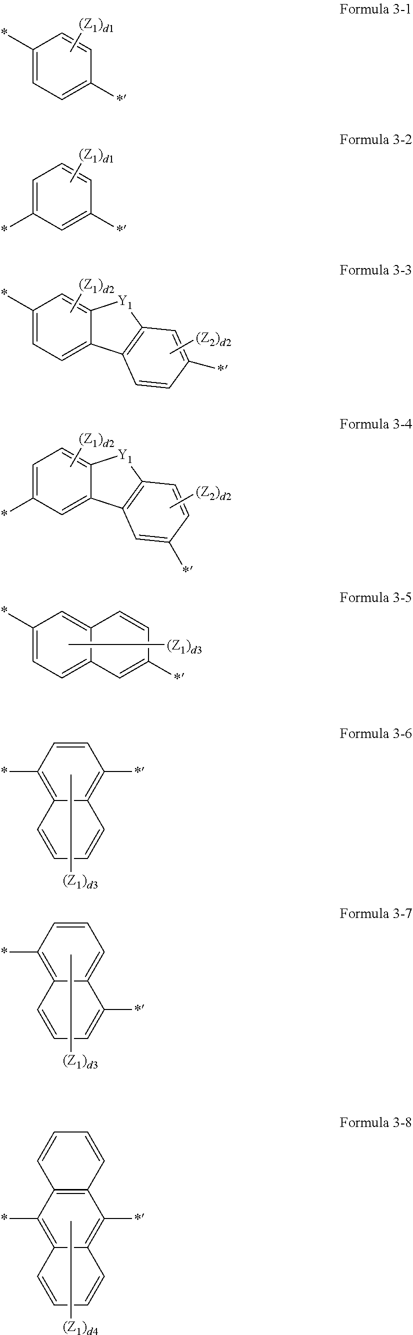 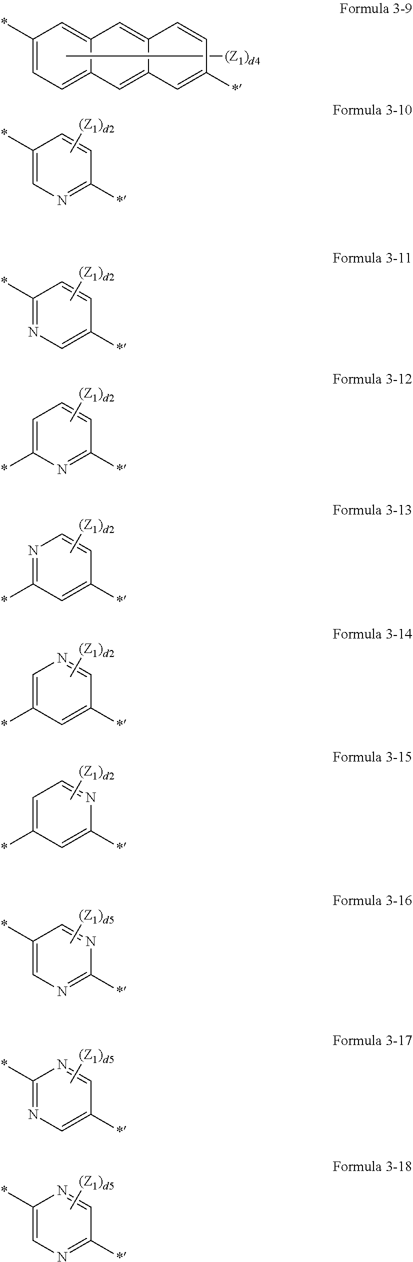 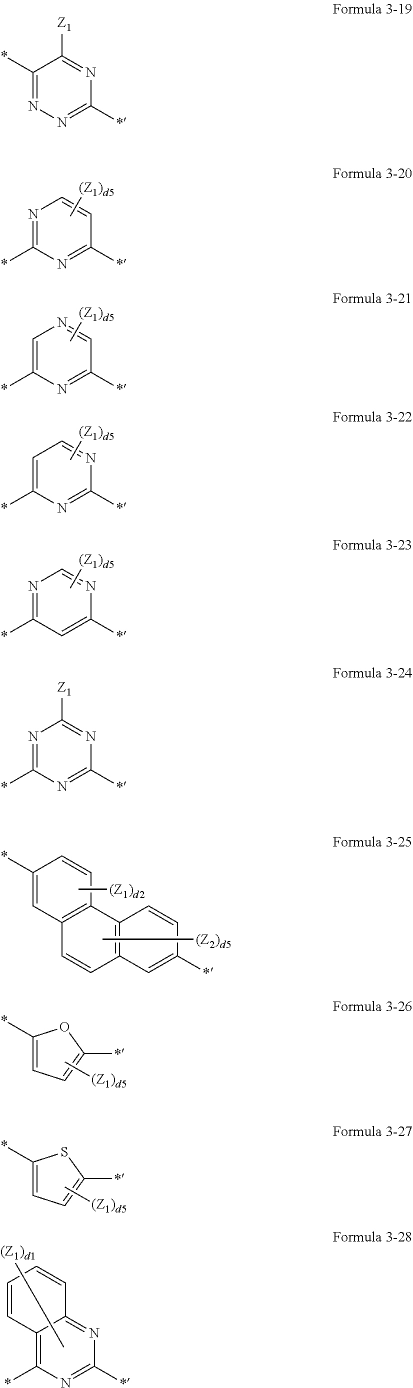 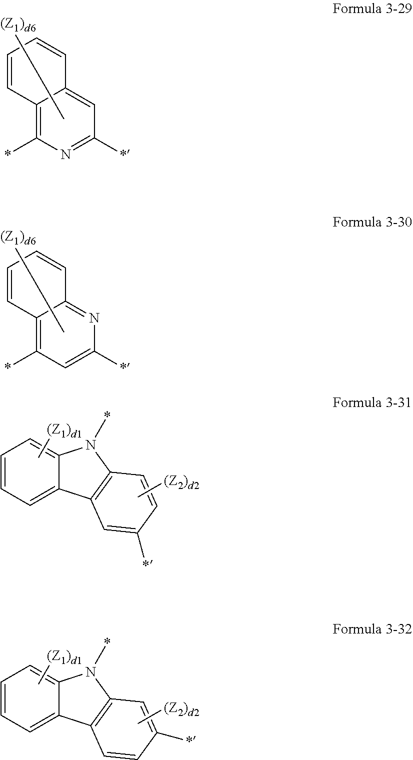
Y₁ is O, S, C(Z₃)(Z₄), N(Z₅), or Si(Z₆)(Z₇);
Z₁ to Z₇ are each independently selected from a hydrogen, a deuterium, —F, —Cl, —Br, —I, a hydroxyl group, a cyano group, a nitro group, an amino group, an amidino group, a hydrazine group, a hydrazone group, a carboxylic acid and a salt thereof, a sulfonic acid and a salt thereof, a phosphoric acid and a salt thereof, a C₁-C₂₀ alkyl group, a C₁-C₂₀ alkoxy group, a phenyl group, a naphthyl group, a fluorenyl group, a spiro-fluorenyl group, a benzofluorenyl group, a dibenzofluorenyl group, a phenanthrenyl group, an anthracenyl group, a pyrenyl group, a chrysenyl group, a pyridinyl group, a pyrazinyl group, a pyrimidinyl group, a pyridazinyl group, a quinolinyl group, an isoquinolinyl group, a quinoxalinyl group, a quinazolinyl group, a carbazolyl group and a triazinyl group,
d1 is selected from an integer of 1 to 4;
d2 is selected from an integer of 1 to 3;
d3 is selected from an integer of 1 to 6;
d4 is selected from an integer of 1 to 8;
d5 is 1 or 2;
d6 is selected from an integer of 1 to 5; and
* and *′ represent bonding sites in the condensed compound.

4. The condensed compound as claimed in claim 1, wherein:
L₁ and L₂ are each independently selected from Formulae 4-1 to 4-23: 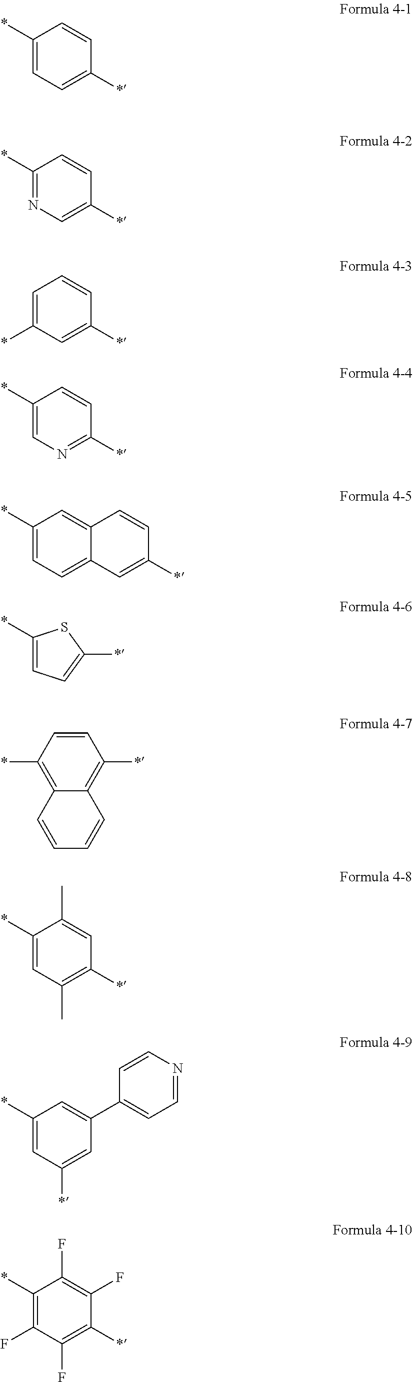 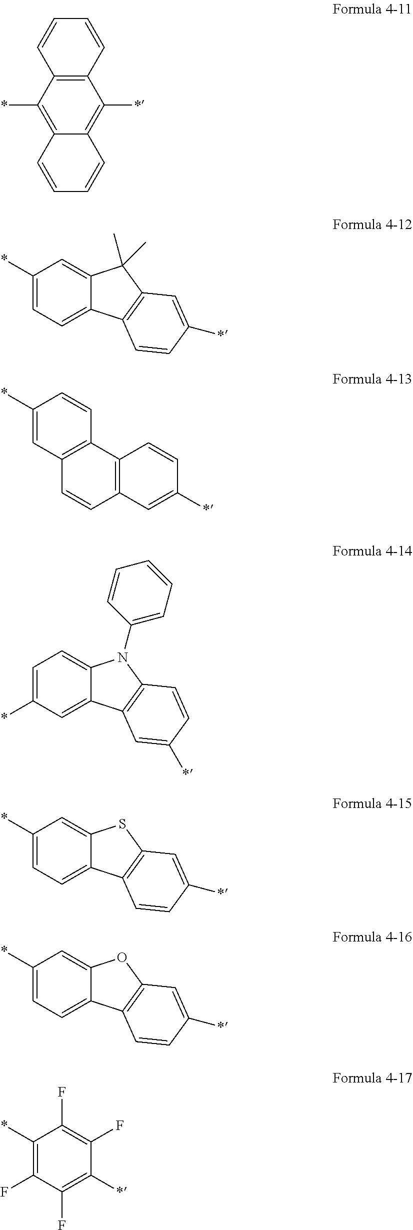 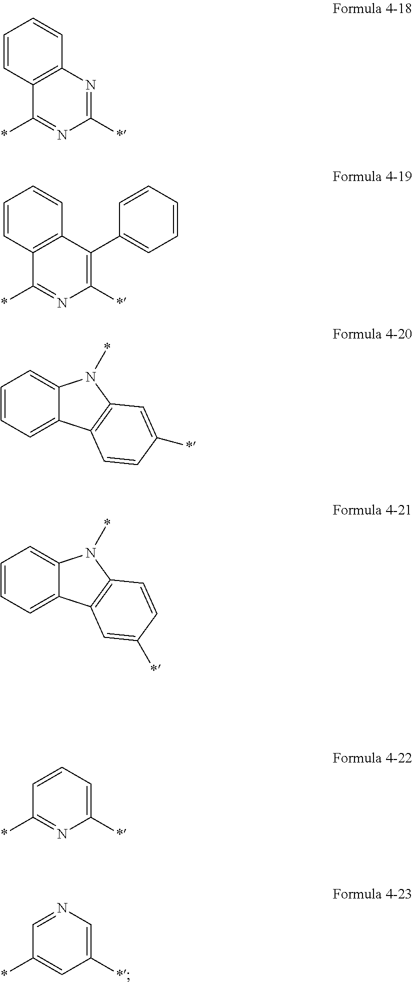
and * and *′ represent bonding sites in the condensed compound.

5. The condensed compound as claimed in claim 1, wherein:
a1 in Formula 1 is 0 or 1, and
a1 and a2 in Formula 2 are each independently 0 or 1.

6. The condensed compound as claimed in claim 1, wherein:
X₁ is N(R₂₁),
X₂ is N(R₂₂), and
R₂₁ and R₂₂ are each independently selected from
a phenyl group, a pentalenyl group, an indenyl group, a naphthyl group, an azulenyl group, a heptalenyl group, an indacenyl group, an acenaphthyl group, a fluorenyl group, a spiro-fluorenyl group, a benzofluorenyl group, a dibenzofluorenyl group, a phenalenyl group, a phenanthrenyl group, an anthracenyl group, a fluoranthenyl group, a triphenylenyl group, a pyrenyl group, a chrysenyl group, a naphthacenyl group, a picenyl group, a perylenyl group, a pentaphenyl group, a hexacenyl group, a pentacenyl group, a rubicenyl group, a coronenyl group, an ovalenyl group, a pyrrolyl group, a thiophenyl group, a furanyl group, an imidazolyl group, a pyrazolyl group, a thiazolyl group, an isothiazolyl group, an oxazolyl group, an isooxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a phthalazinyl group, a naphthyridinyl group, a quinoxalinyl group, a quinazolinyl group, a cinnolinyl group, a carbazolyl group, a phenanthridinyl group, an acridinyl group, a phenanthrolinyl group, a phenazinyl group, a benzoimidazolyl group, a benzofuranyl group, a benzothiophenyl group, an isobenzothiazolyl group, a benzooxazolyl group, an isobenzooxazolyl group, a triazolyl group, a tetrazolyl group, an oxadiazolyl group, a triazinyl group, a dibenzofuranyl group, a dibenzothiophenyl group, a benzocarbazolyl group, a dibenzocarbazolyl group, a thiadiazolyl group, an imidazolpyridinyl group and an imidazopyrimidinyl group; and
a phenyl group, a pentalenyl group, an indenyl group, a naphthyl group, an azulenyl group, a heptalenyl group, an indacenyl group, an acenaphthyl group, a fluorenyl group, a spiro-fluorenyl group, a benzofluorenyl group, a dibenzofluorenyl group, a phenalenyl group, a phenanthrenyl group, an anthracenyl group, a fluorantenyl group, a triphenylenyl group, a pyrenyl group, a chrysenyl group, a naphthacenyl group, a picenyl group, a perylenyl group, a pentaphenyl group, a hexacenyl group, a pentacenyl group, a rubicenyl group, a coronenyl group, an ovalenyl group, a pyrrolyl group, a thiophenyl group, a furanyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a phthalazinyl group, a naphthyridinyl group, a quinoxalinyl group, a quinazolinyl group, a cinnolinyl group, a carbazolyl group, a phenanthridinyl group, an acridinyl group, a phenanthrolinyl group, a phenazinyl group, a benzoimidazolyl group, a benzofuranyl group, a benzothiophenyl group, an isobenzothiazolyl group, a benzooxazolyl group, an isobenzooxazolyl group, a triazolyl group, a tetrazolyl group, an oxadiazolyl group, a triazinyl group, a dibenzofuranyl group, a dibenzothiophenyl group, a benzocarbazolyl group, a dibenzocarbazolyl group, a thiadiazolyl group, an imidazolpyridinyl group and an imidazopyrimidinyl group, each substituted with at least one selected from a deuterium, —F, —Cl, —Br, —I, a hydroxyl group, a cyano group, a nitro group, an amino group, an amidino group, a hydrazine group, a hydrazone group, a carboxylic acid and a salt thereof, a sulfonic acid and a salt thereof, a phosphoric acid and a salt thereof, a C₁-C₂₀ alkyl group, a C₁-C₂₀ alkoxy group, a phenyl group, a pentalenyl group, an indenyl group, a naphthyl group, an azulenyl group, a heptalenyl group, a indacenyl group, an acenaphthyl group, a fluorenyl group, a spiro-fluorenyl group, a benzofluorenyl group, a dibenzofluorenyl group, a phenalenyl group, a phenanthrenyl group, an anthracenyl group, a fluoranthenyl group, a triphenylenyl group, a pyrenyl group, a chrysenyl group, a naphthacenyl group, a picenyl group, a perylenyl group, a pentaphenyl group, a hexacenyl group, a pentacenyl group, a rubicenyl group, a coronenyl group, an ovalenyl group, a pyrrolyl group, a thiophenyl group, a furanyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an isoquinolinyl group, an indolyl group, an indazolyl group, a purinyl group, a quinolinyl group, an isoquinolinyl group, a benzoquinolinyl group, a phthalazinyl group, a naphthyridinyl group, a quinoxalinyl group, a quinazolinyl group, a cinnolinyl group, a carbazolyl group, a phenanthridinyl group, an acridinyl group, a phenanthrolinyl group, a phenazinyl group, a benzoimidazolyl group, a benzofuranyl group, a benzothiophenyl group, an isobenzothiazolyl group, a benzooxazolyl group, an isobenzooxazolyl group, a triazolyl group, a tetrazolyl group, an oxadiazolyl group, a triazinyl group, a dibenzofuranyl group, a dibenzothiophenyl group, a benzocarbazolyl group, a dibenzocarbazolyl group, a thiadiazolyl group, an imidazolpyridinyl and an imidazopyrimidinyl group.

7. The condensed compound as claimed in claim 1, wherein:
X₁ is N(R₂₁),
X₂ is N(R₂₂), and
R₂₁ and R₂₂ are each independently selected from
a phenyl group, a naphthyl group, a fluorenyl group, a spiro-fluorenyl group, a benzofluorenyl group, a dibenzofluorenyl group, a phenanthrenyl group, an anthracenyl group, a pyrenyl group, a chrysenyl group, a pyridinyl group, a pyrazinyl group, a pyrimidinyl group, a pyridazinyl group, a quinolinyl group, an isoquinolinyl group, a quinoxalinyl group, a quinazolinyl group, a carbazolyl group and a triazinyl group; and
a phenyl group, a naphthyl group, a fluorenyl group, a spiro-fluorenyl group, a benzofluorenyl group, a dibenzofluorenyl group, a phenanthrenyl group, an anthracenyl group, a pyrenyl group, a chrysenyl group, a pyridinyl group, a pyrazinyl group, a pyrimidinyl group, a pyridazinyl group, a quinolinyl group, an isoquinolinyl group, a quinoxalinyl group, a quinazolinyl group, a carbazolyl group and a triazinyl group, each substituted with at least one selected from a deuterium, —F, —Cl, —Br, —I, a hydroxyl group, a cyano group, a nitro group, an amino group, an amidino group, a hydrazine group, a hydrazone group, a carboxylic acid and a salt thereof, a sulfonic acid and a salt thereof, a phosphoric acid and a salt thereof, a C₁-C₂₀ alkyl group, a C₁-C₂₀ alkoxy group, a phenyl group, a naphthyl group, a fluorenyl group, a spiro-fluorenyl group, a benzofluorenyl group, a dibenzofluorenyl group, a phenanthrenyl group, an anthracenyl group, a pyrenyl group, a chrysenyl group, a pyridinyl group, a pyrazinyl group, a pyrimidinyl group, a pyridazinyl group, a quinolinyl group, an isoquinolinyl group, a quinoxalinyl group, a quinazolinyl group, a carbazolyl group and a triazinyl group.

8. The condensed compound as claimed in claim 1, wherein R₁ to R₆ are each independently selected from a deuterium, —F, —Cl, —Br, —I, a hydroxyl group, a cyano group, a nitro group, an amino group, an amidino group, a hydrazine group, a hydrazone group, a carboxylic acid and a salt thereof, a sulfonic acid and a salt thereof, a phosphoric acid and a salt thereof, a C₁-C₂₀ alkyl group, a C₁-C₂₀ alkoxy group, a phenyl group, a naphthyl group, a fluorenyl group, a spiro-fluorenyl group, a benzofluorenyl group, a dibenzofluorenyl group, a phenanthrenyl group, an anthracenyl group, a pyrenyl group, a chrysenyl group, a pyridinyl group, a pyrazinyl group, a pyrimidinyl group, a pyridazinyl group, a quinolinyl group, an isoquinolinyl group, a quinoxalinyl group, a quinazolinyl group, a carbazolyl group and a triazinyl group, and Si(Q₃)(Q₄)(Q₅), Q₃ to Q₅ each independently being selected from a C₁-C₂₀ alkyl group, a C₁-C₂₀ alkoxy group, a phenyl group and a naphthyl group.

9. The condensed compound as claimed in claim 1, wherein:
R₁₁ and R₁₂ are each independently selected from
a C₁-C₂₀ alkyl group and a C₁-C₂₀ alkoxy group;
a phenyl group, a naphthyl group, a fluorenyl group, a spiro-fluorenyl group, a benzofluorenyl group, a dibenzofluorenyl group, a phenanthrenyl group, an anthracenyl group, a pyrenyl group, a chrysenyl group, a pyridinyl group, a pyrazinyl group, a pyrimidinyl group, a pyridazinyl group, a quinolinyl group, an isoquinolinyl group, a quinoxalinyl group, a quinazolinyl group, a carbazolyl group and a triazinyl group;
a phenyl group, a naphthyl group, a fluorenyl group, a spiro-fluorenyl group, a benzofluorenyl group, a dibenzofluorenyl group, a phenanthrenyl group, an anthracenyl group, a pyrenyl group, a chrysenyl group, a pyridinyl group, a pyrazinyl group, a pyrimidinyl group, a pyridazinyl group, a quinolinyl group, an isoquinolinyl group, a quinoxalinyl group, a quinazolinyl group, a carbazolyl group and a triazinyl group, each substituted with at least one selected from a deuterium, —F, —Cl, —Br, —I, a hydroxyl group, a cyano group, a nitro group, an amino group, an amidino group, a hydrazine group, a hydrazone group, a carboxylic acid and a salt thereof, a sulfonic acid and a salt thereof, a phosphoric acid and a salt thereof, a C₁-C₂₀ alkyl group, a C₁-C₂₀ alkoxy group, a phenyl group, a naphthyl group, a fluorenyl group, a spiro-fluorenyl group, a benzofluorenyl group, a dibenzofluorenyl group, a phenanthrenyl group, an anthracenyl group, a pyrenyl group, a chrysenyl group, a pyridinyl group, a pyrazinyl group, a pyrimidinyl group, a pyridazinyl group, a quinolinyl group, an isoquinolinyl group, a quinoxalinyl group, a quinazolinyl group, a carbazolyl group and a triazinyl group; and
Si(Q₃)(Q₄)(Q₅), Q₃ to Q₅ each independently being selected from a C₁-C₂₀ alkyl group, a C₁-C₂₀ alkoxy group, a phenyl group and a naphthyl group.

10. The condensed compound as claimed in claim 1, wherein:
R₂₁ and R₂₂ are each independently selected from Formulae 5-1 to 5-34;
R₁ to R₆ are each independently selected from a hydrogen, a deuterium, —F, —Cl, —Br, —I, a hydroxyl group, a cyano group, a nitro group, an amino group, an amidino group, a hydrazine group, a hydrazone group, a carboxylic acid and a salt thereof, a sulfonic acid and a salt thereof, a phosphoric acid and a salt thereof, a C₁-C₂₀ alkyl group, a C₁-C₂₀ alkoxy group and Formulae 5-1 to 5-34; and
R₁₁ and R₁₂ are each independently selected from Formulae 5-1 to 5-34: 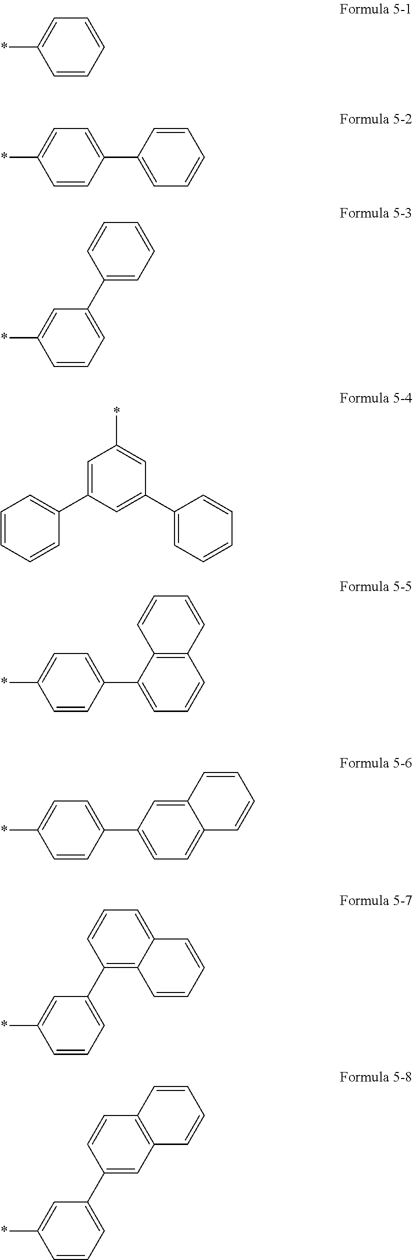 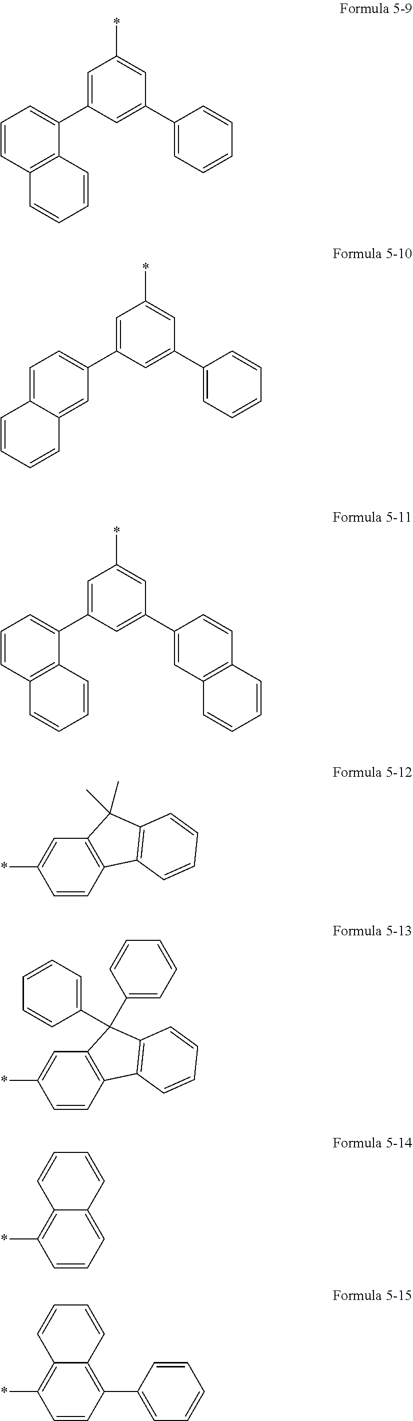 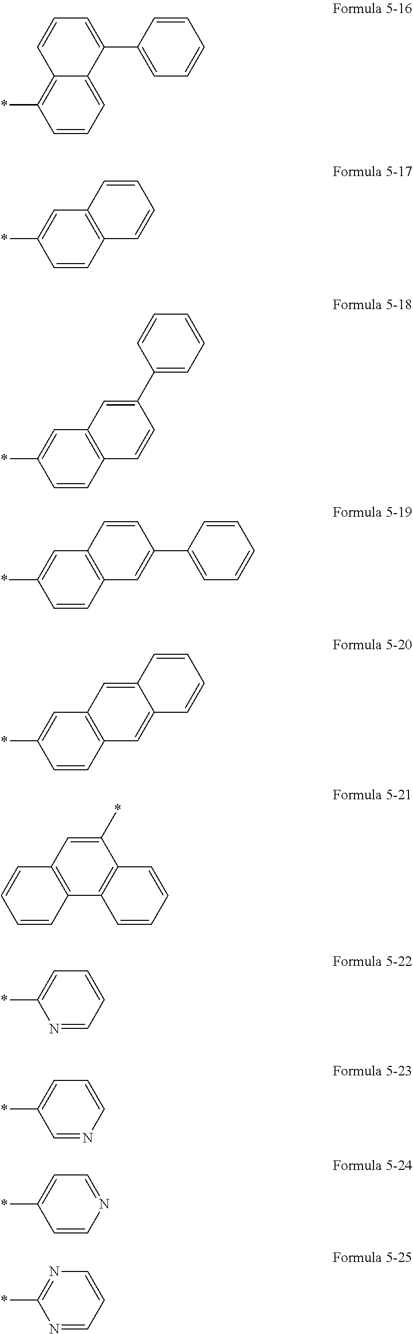 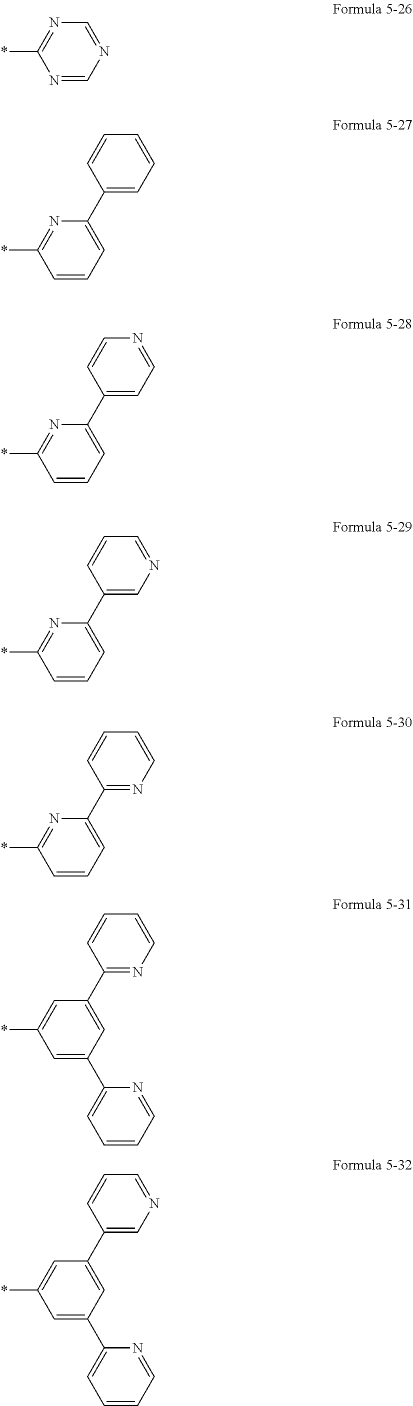 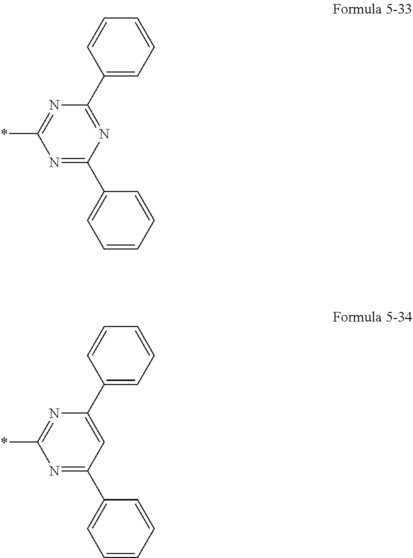 [SMILES: *c1nc(-c2ccccc2)nc(-c2ccccc2)n1 ; *c1nc(-c2ccccc2)cc(-c2ccccc2)n1]
and * represents a bonding site in the condensed compound.

11. The condensed compound as claimed in claim 1, wherein:
the condensed compound is represented by any one of Formulae 1-1 to 1-12 and 2-1 to 2-12: 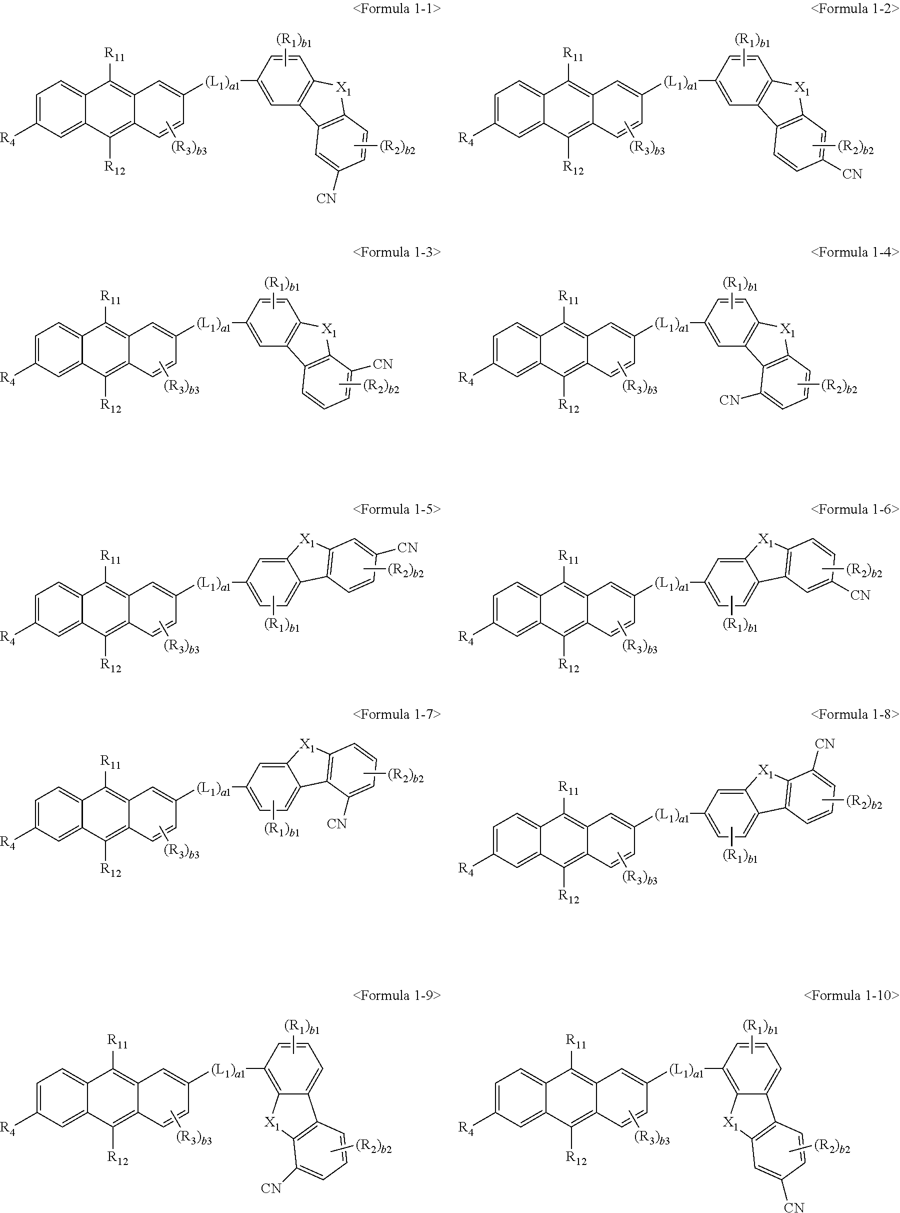 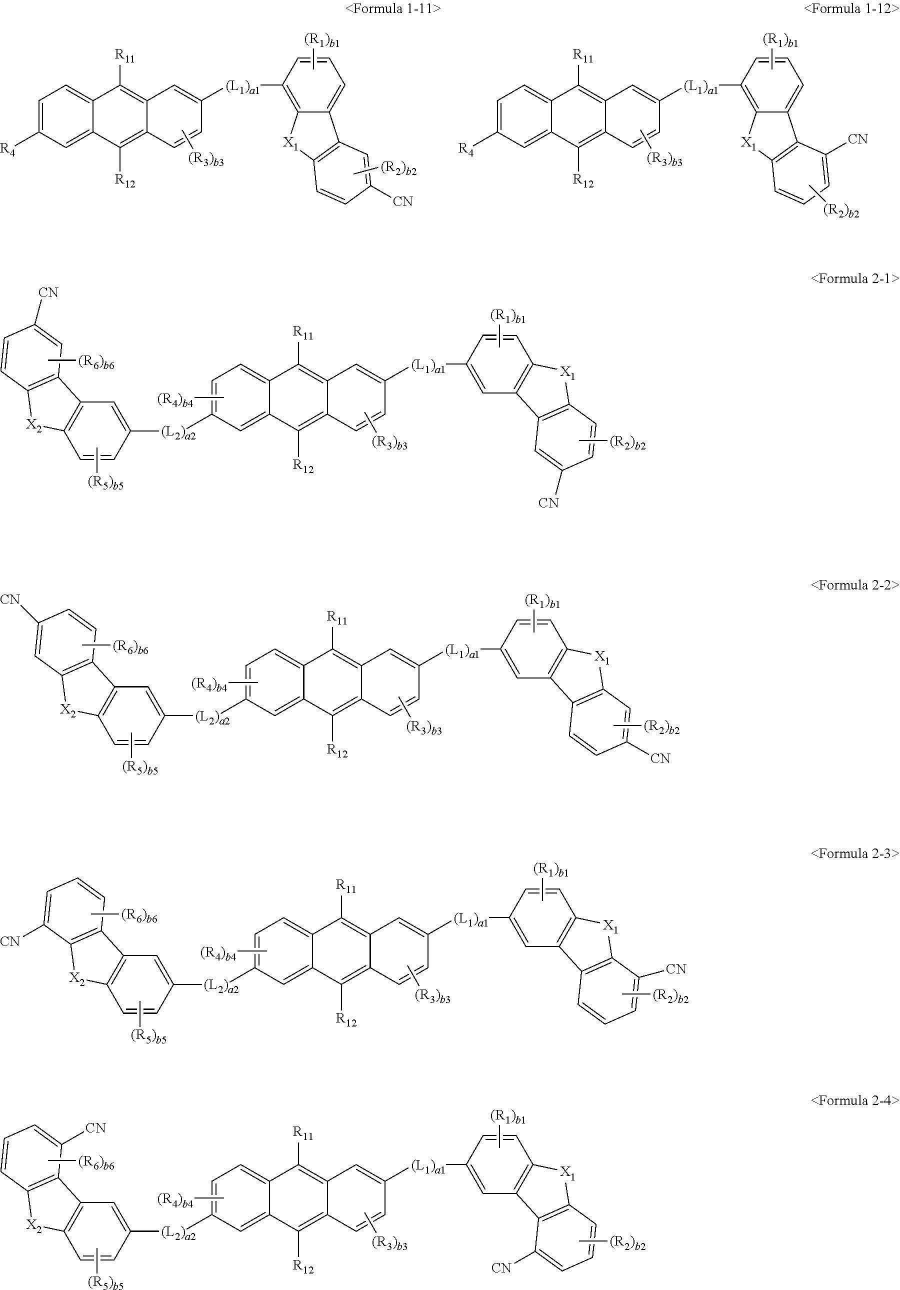 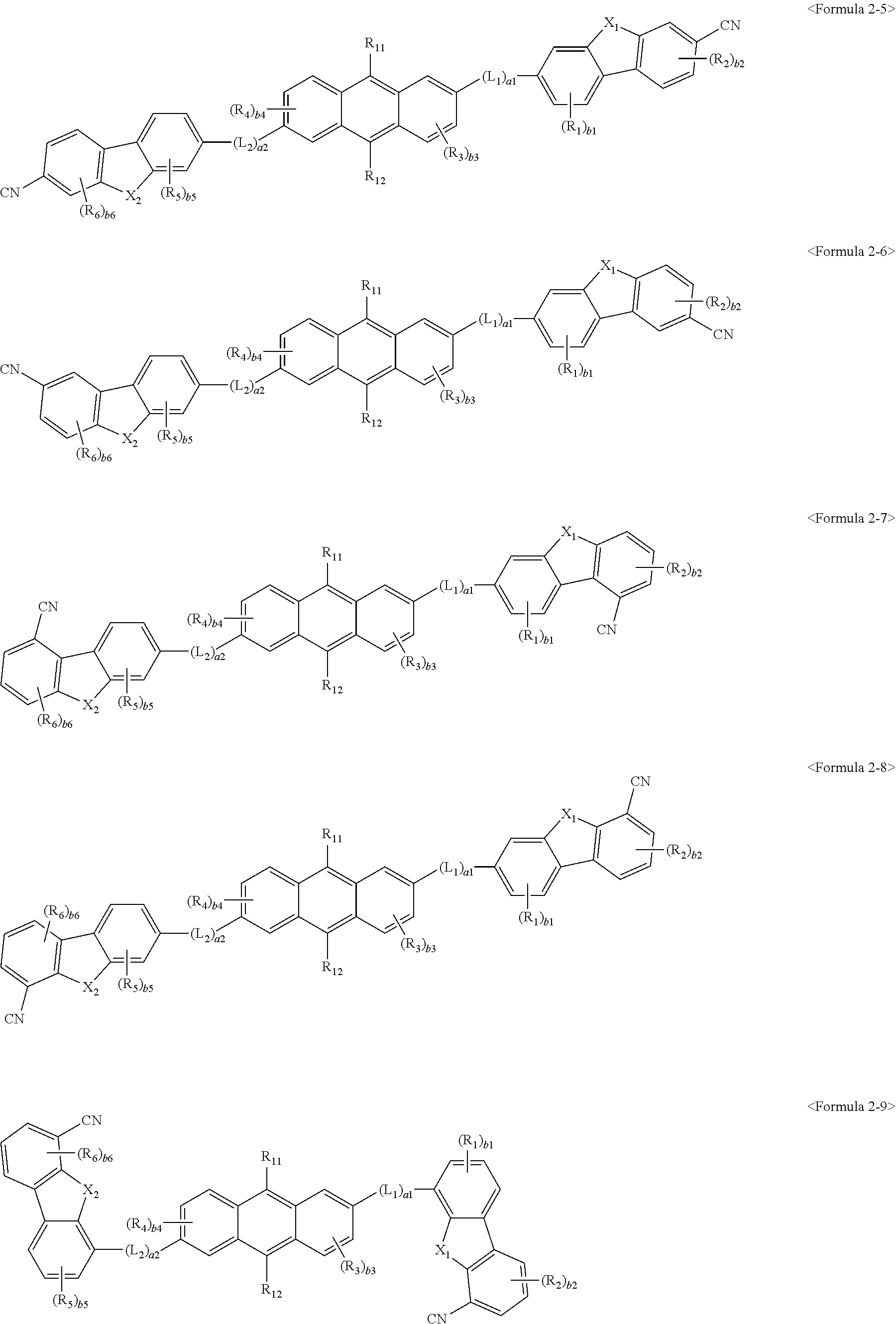 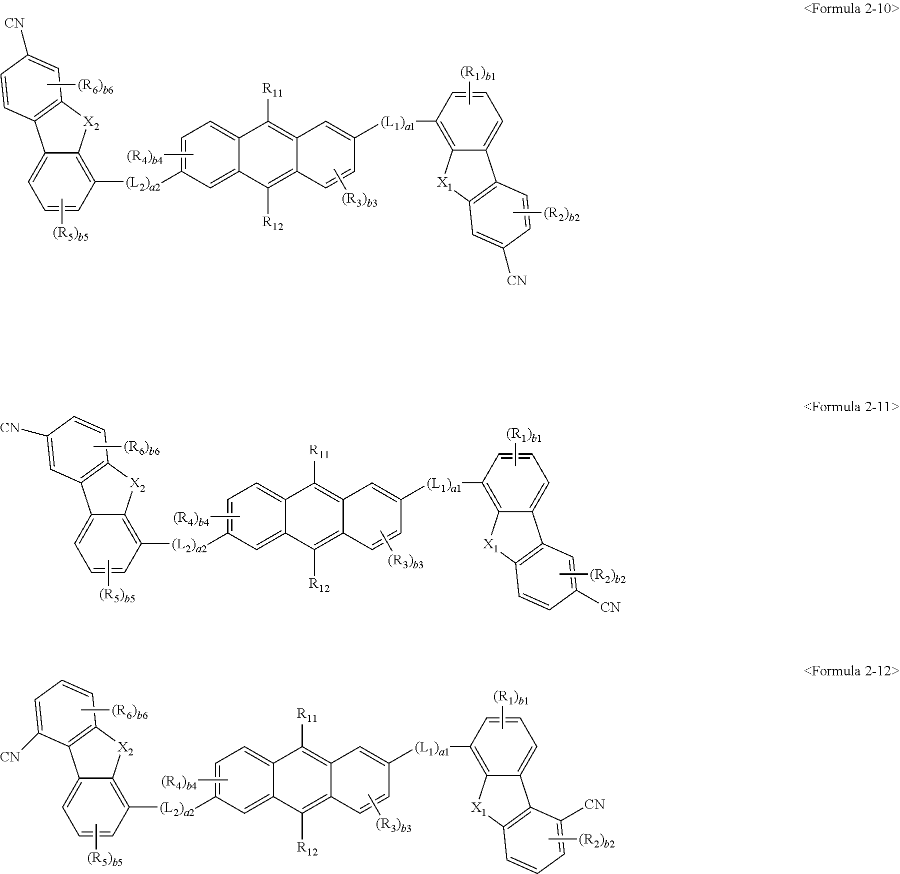
X₁, X₂, L₁, a1, a2, R₁ to R₆, R₁₁, R₁₂, and b1 to b6 are as defined in claim 1.

12. The condensed compound as claimed in claim 11, wherein:
a1 in Formulae 1-1 to 1-12 is 0 or 1, and
a1 and a2 in Formulae 2-1 to 2-12 are each independently 0 or 1;
L₁ and L₂ are each independently represented by one of Formulae 4-1 to 4-23: 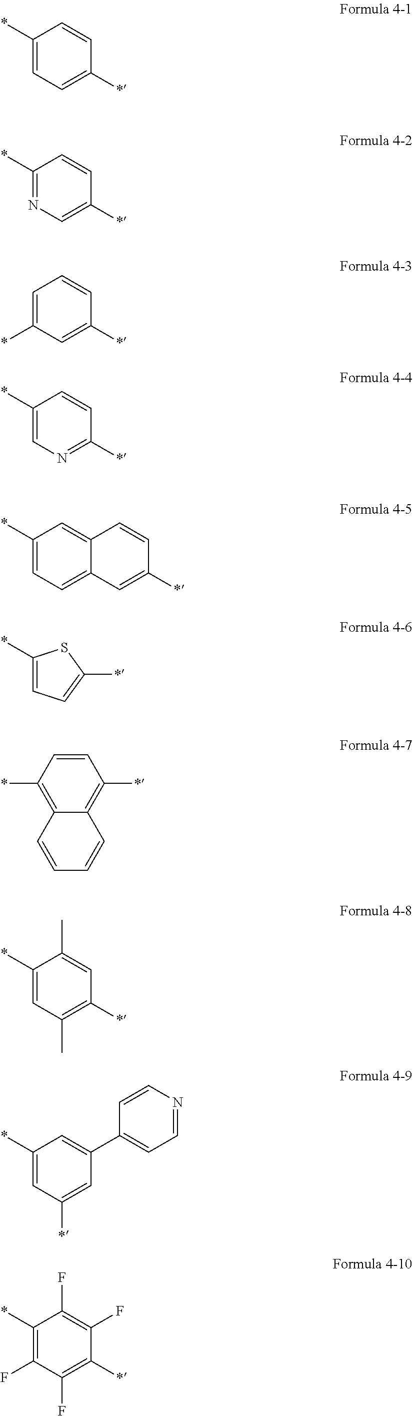 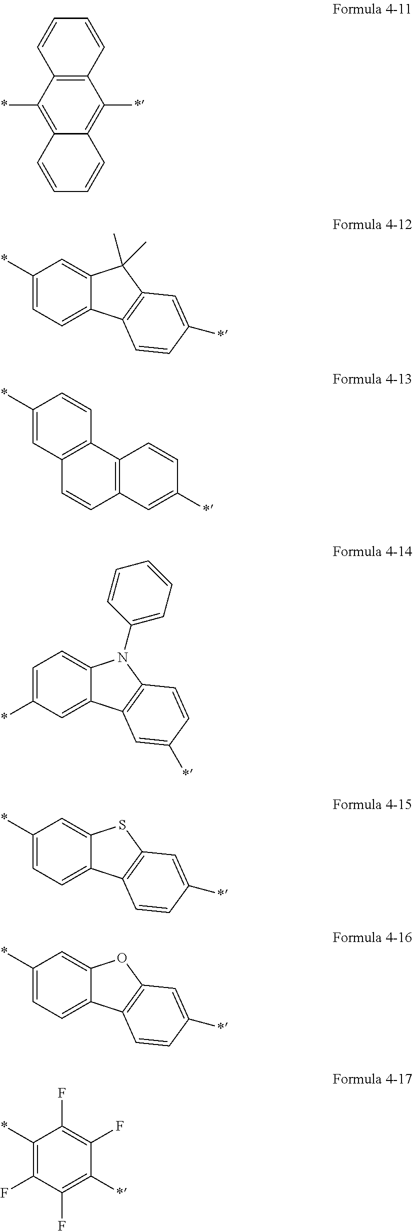 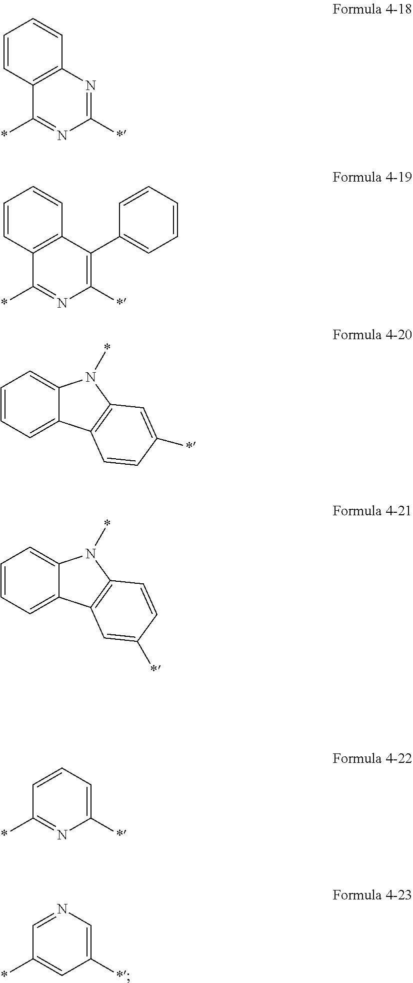
and * and *′ represent bonding sites in the condensed compound.

13. The condensed compound as claimed in claim 11, wherein:
R₂₁ and R₂₂ are each independently selected from Formulae 5-1 to 5-34;
R₁ to R₆ are each independently selected from a hydrogen, a deuterium, —F, —Cl, —Br, —I, a hydroxyl group, a cyano group, a nitro group, an amino group, an amidino group, a hydrazine group, a hydrazone group, a carboxylic acid and a salt thereof, a sulfonic acid and a salt thereof, a phosphoric acid and a salt thereof, a C₁-C₂₀ alkyl group, a C₁-C₂₀ alkoxy group, and Formulae 5-1 to 5-34; and
R₁₁ and R₁₂ are each independently selected from Formulae 5-1 to 5-34: 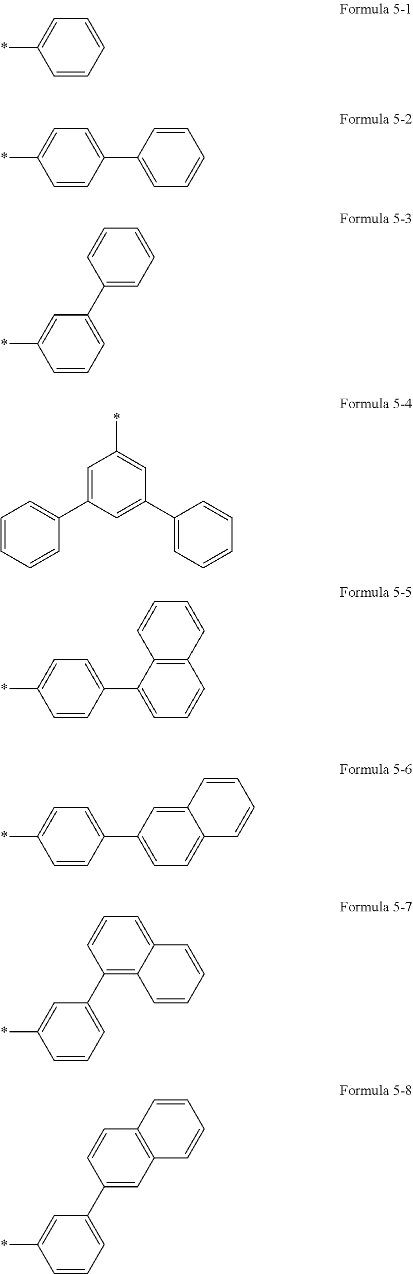 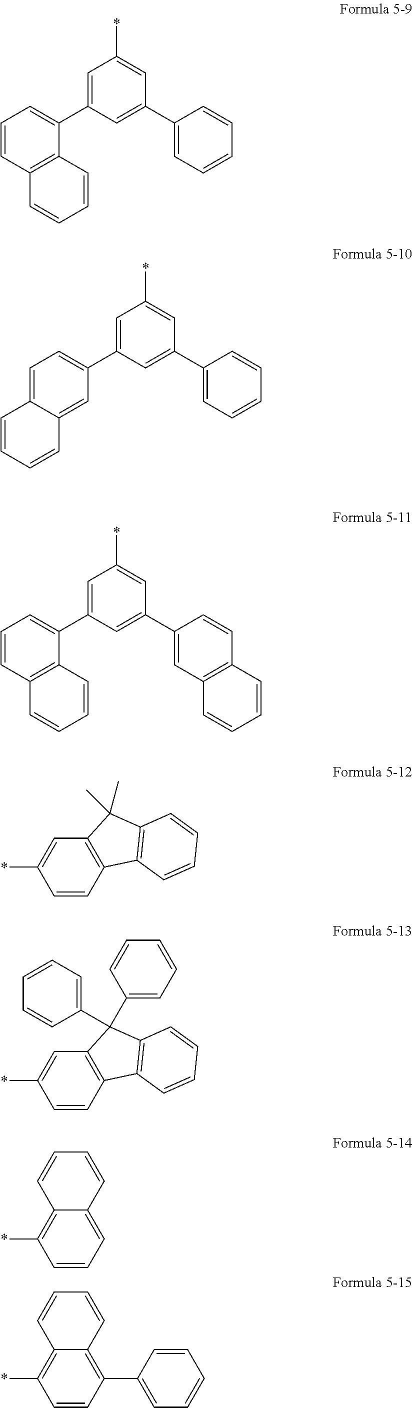 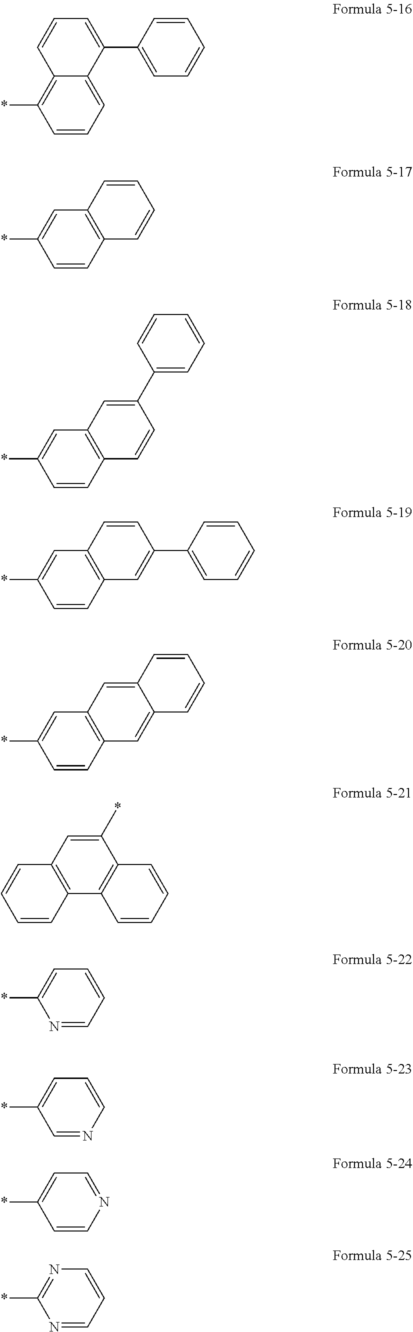 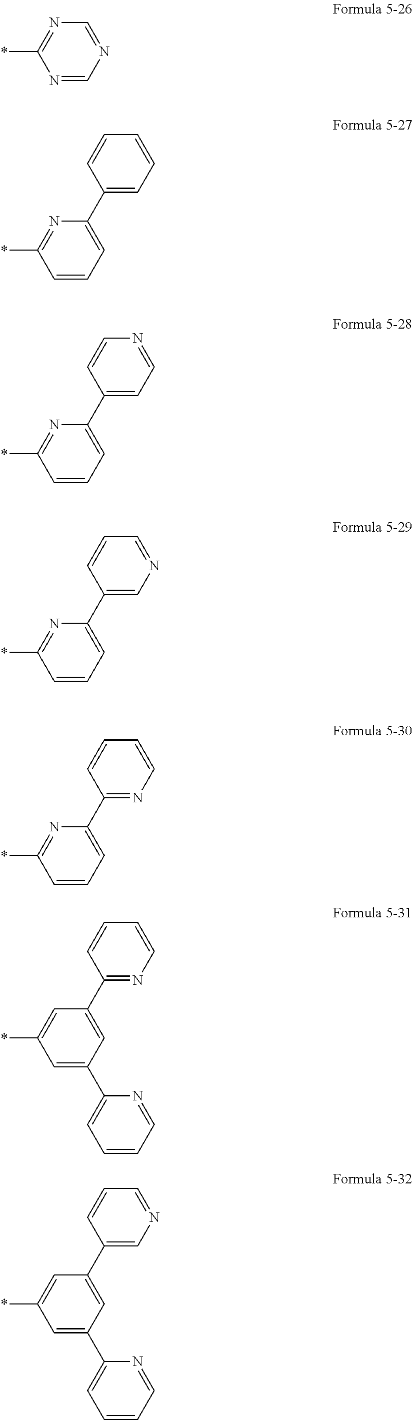 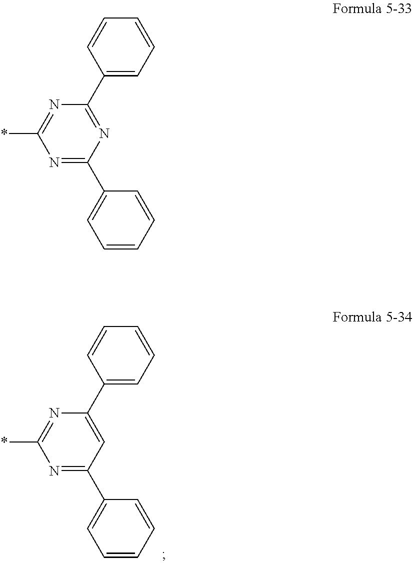 [SMILES: *c1nc(-c2ccccc2)nc(-c2ccccc2)n1 ; *c1nc(-c2ccccc2)cc(-c2ccccc2)n1]
and * represents a bonding site in the condensed compound.

14. The condensed compound as claimed in claim 11, wherein the condensed compound is represented by any one of Formulae 1-1, 1-5, 1-9, 2-1, 2-5, and 2-9.

15. The condensed compound as claimed in claim 1, wherein the condensed compound is one of Compounds 1 to 119:

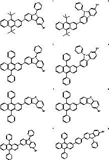

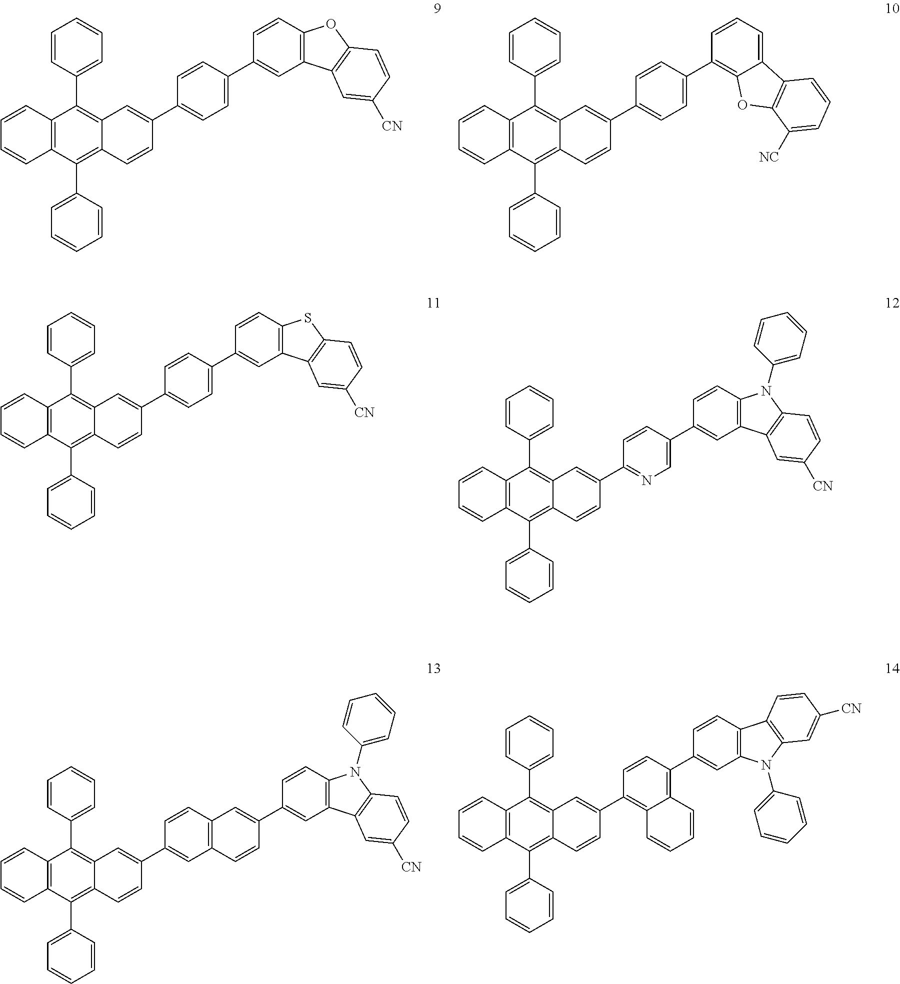

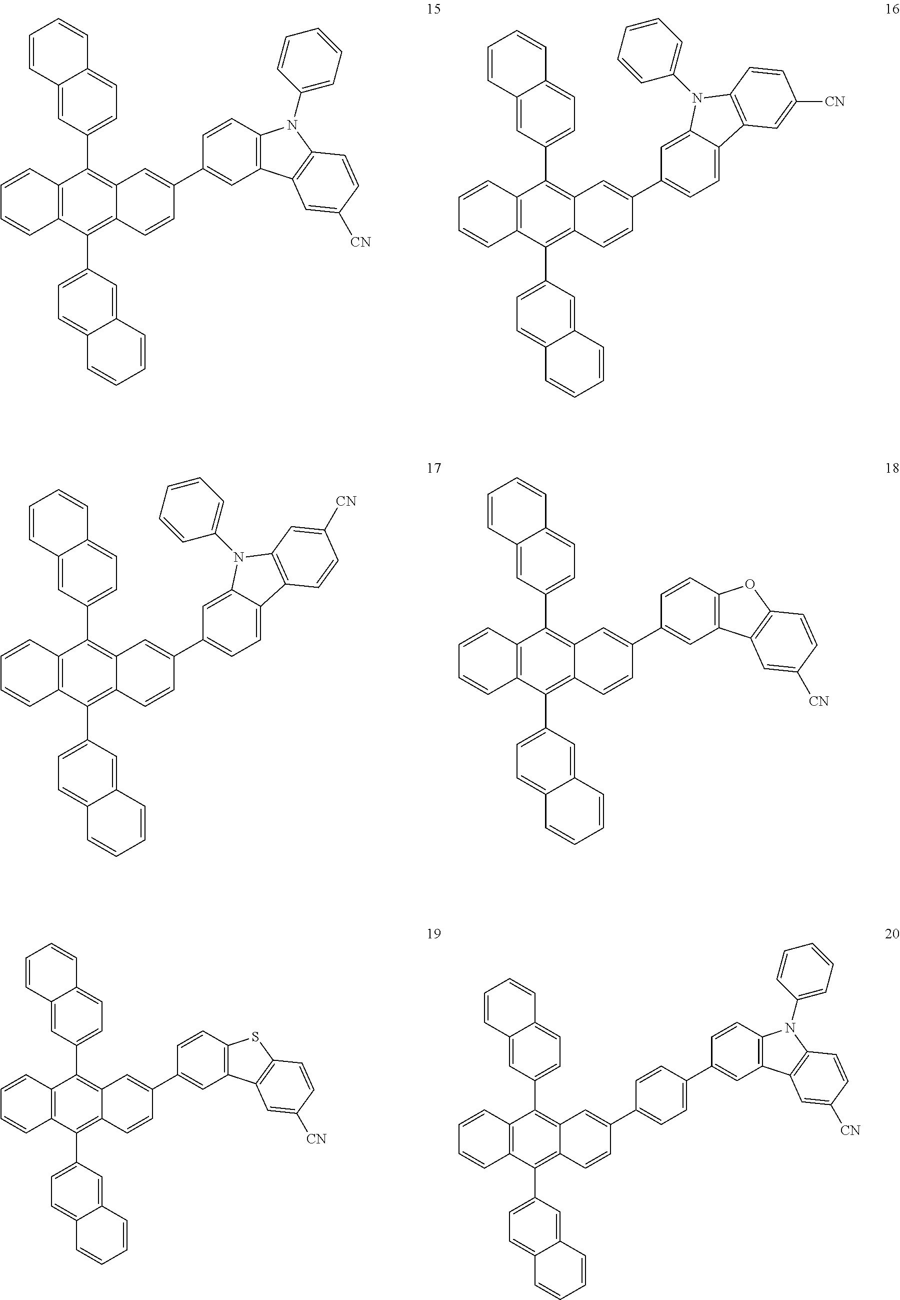

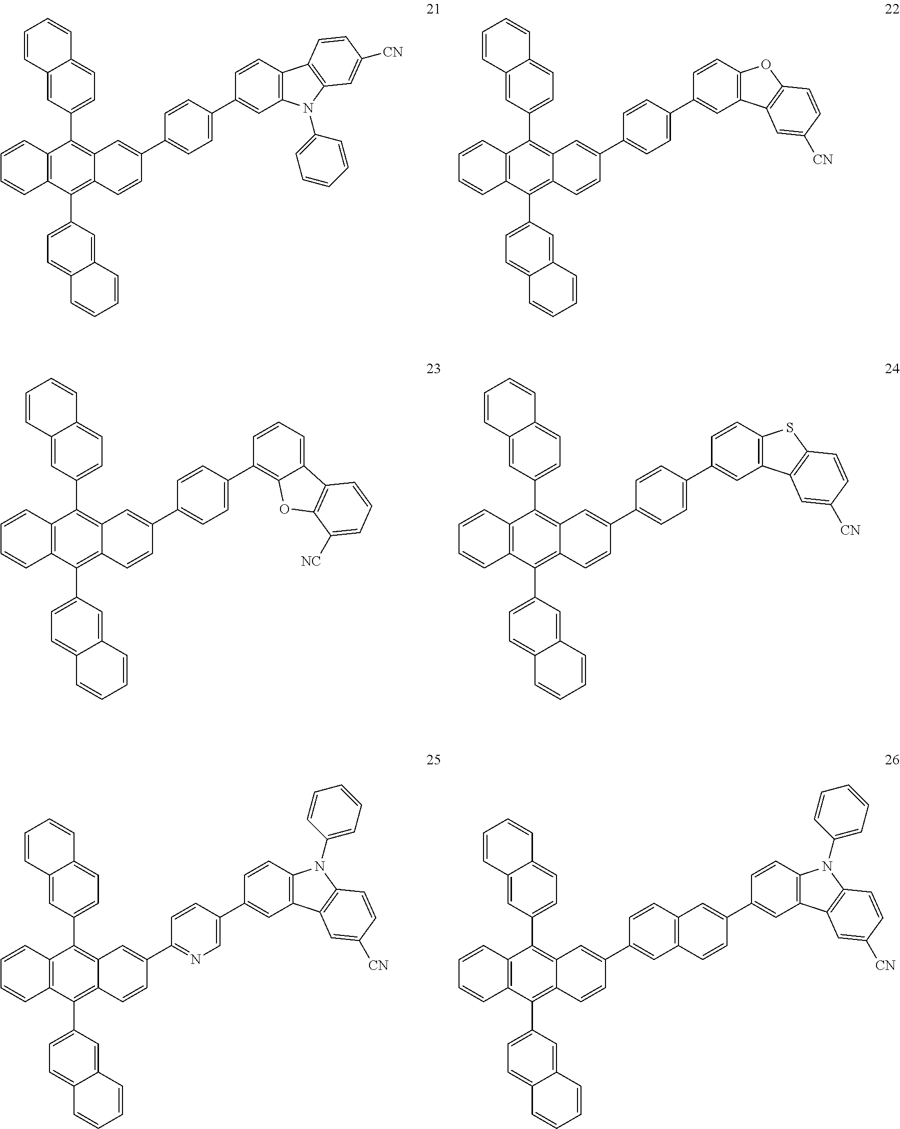

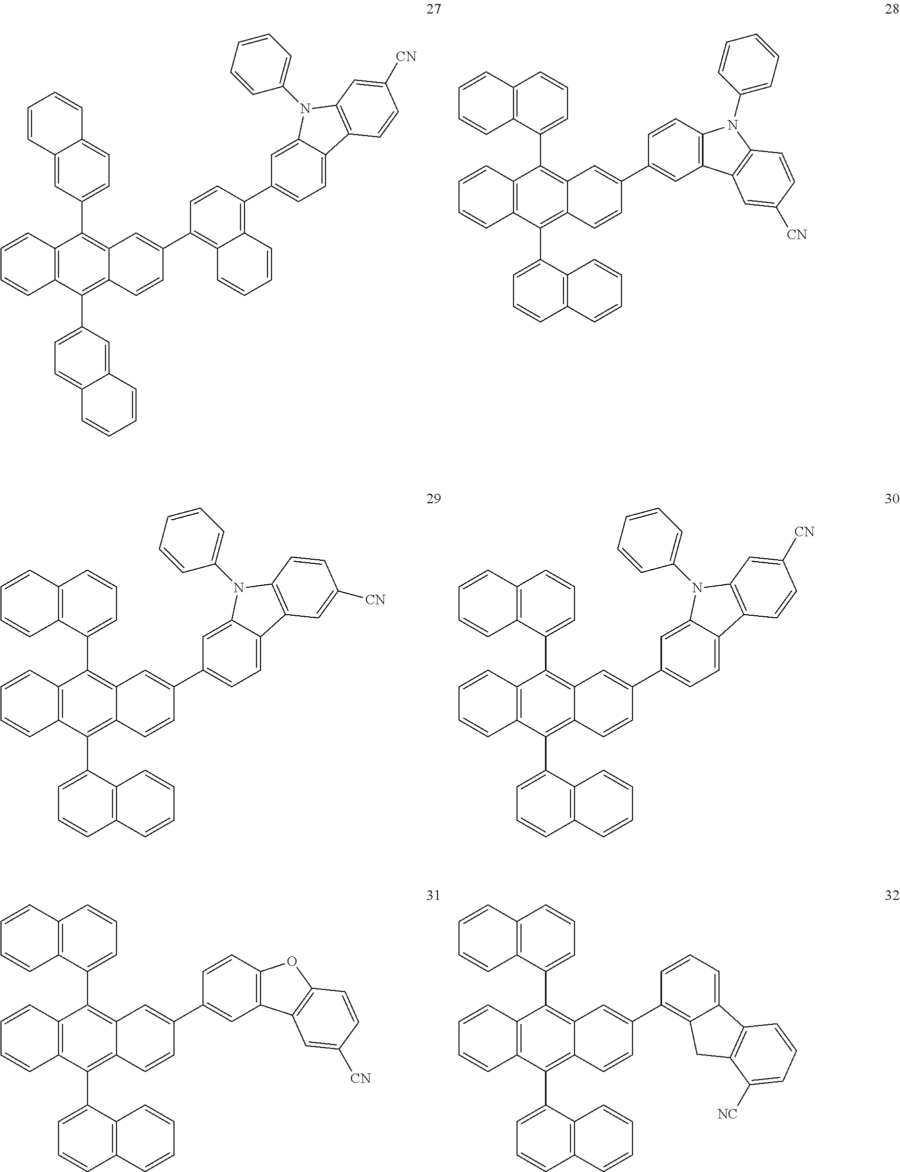

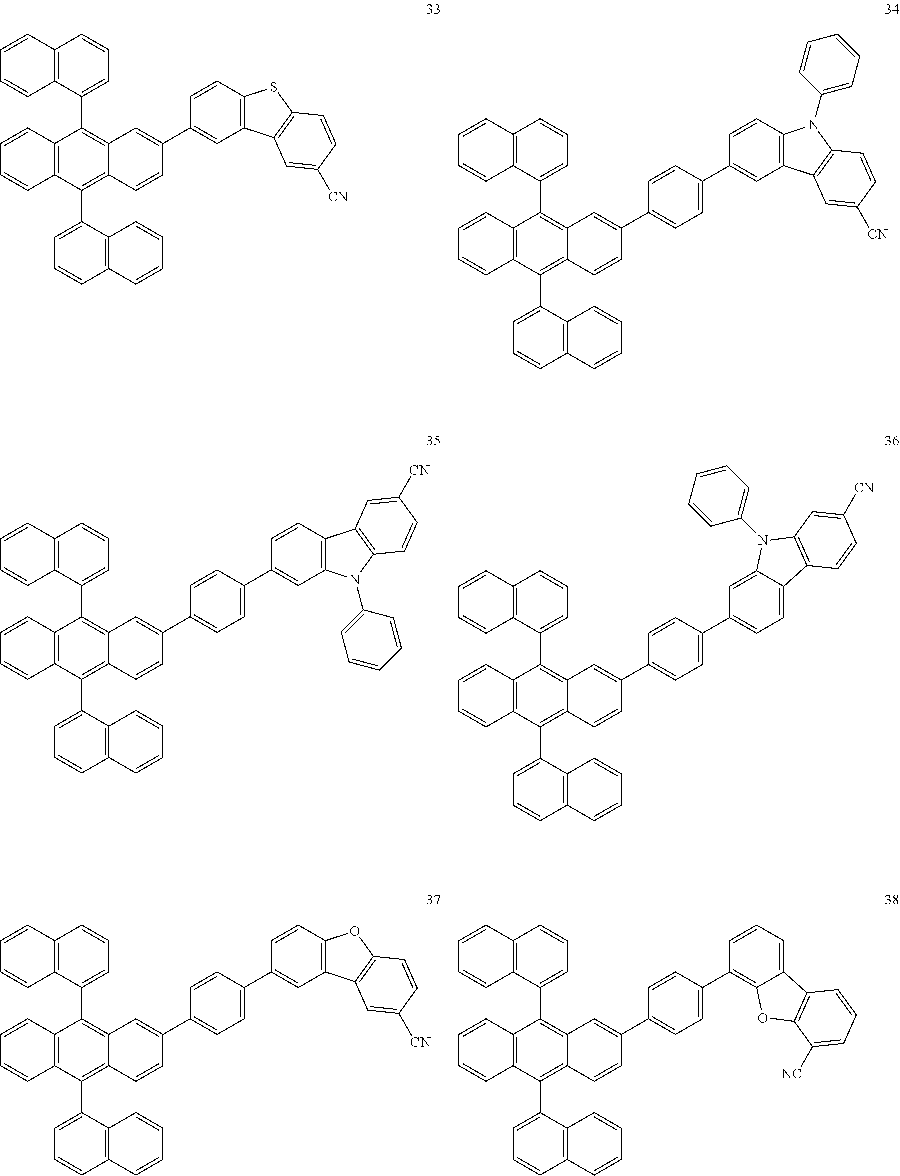

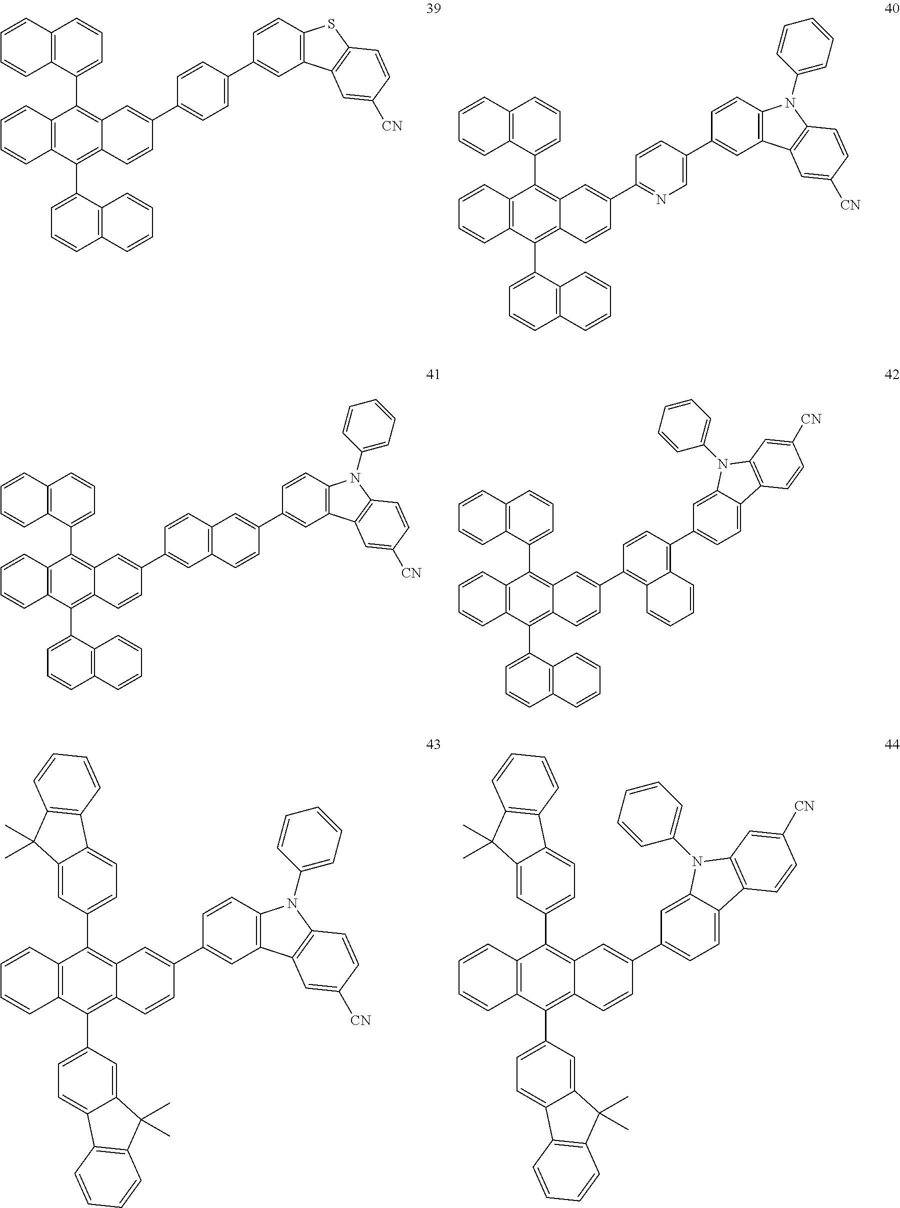

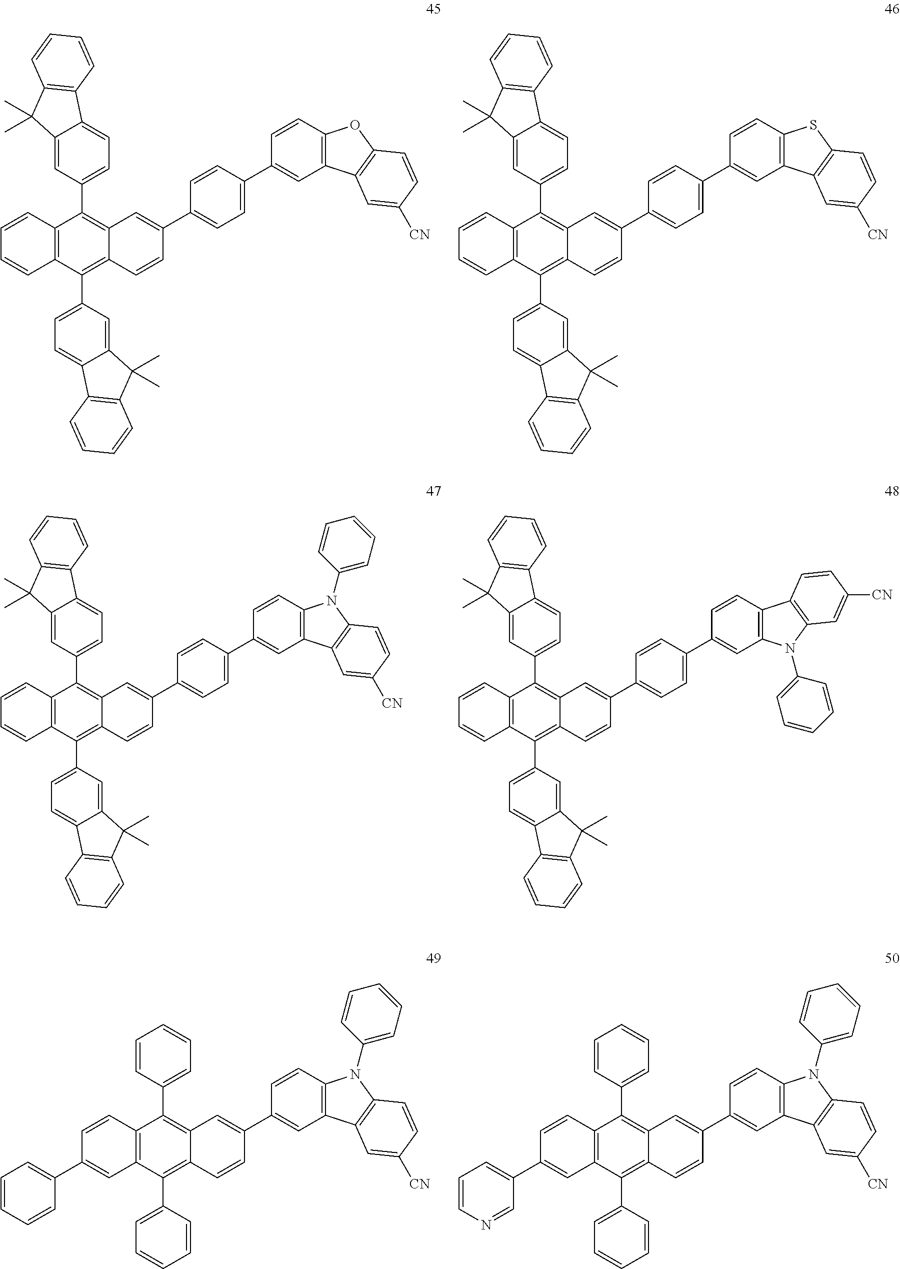

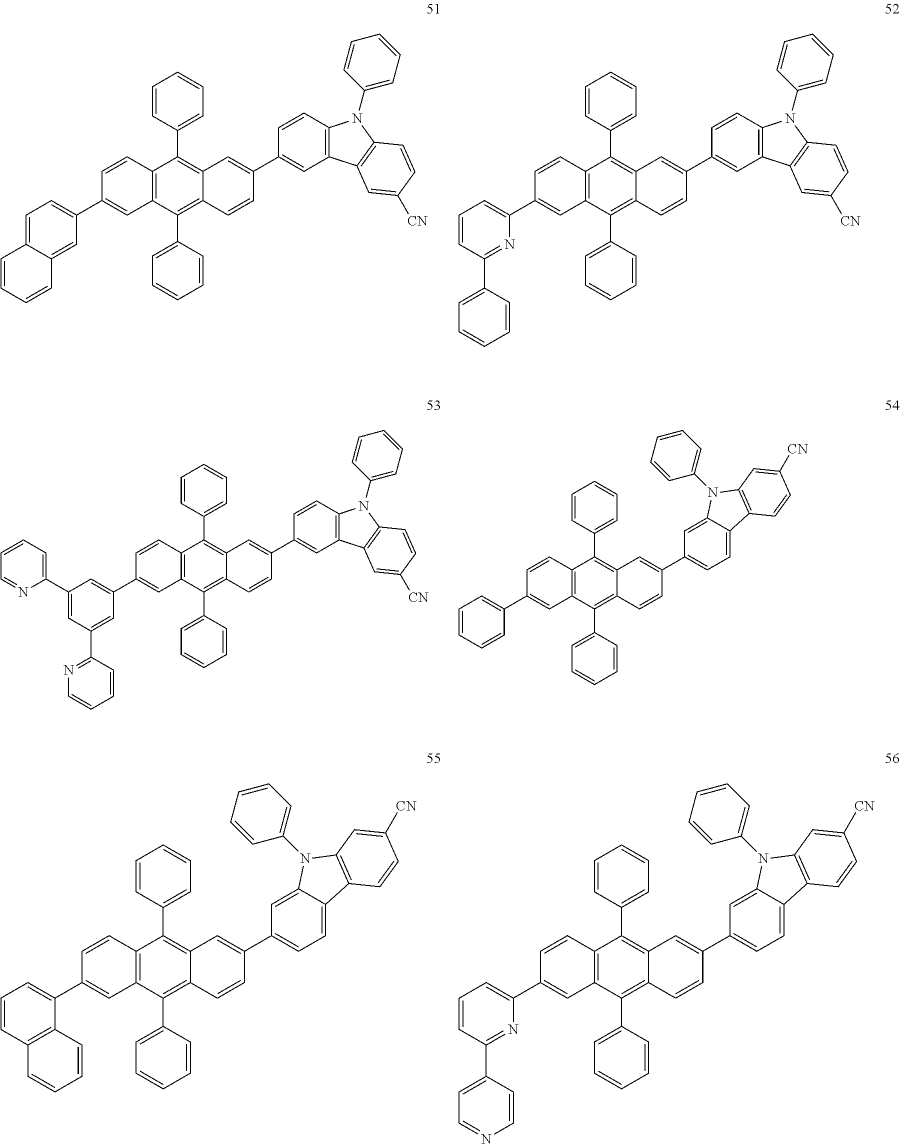

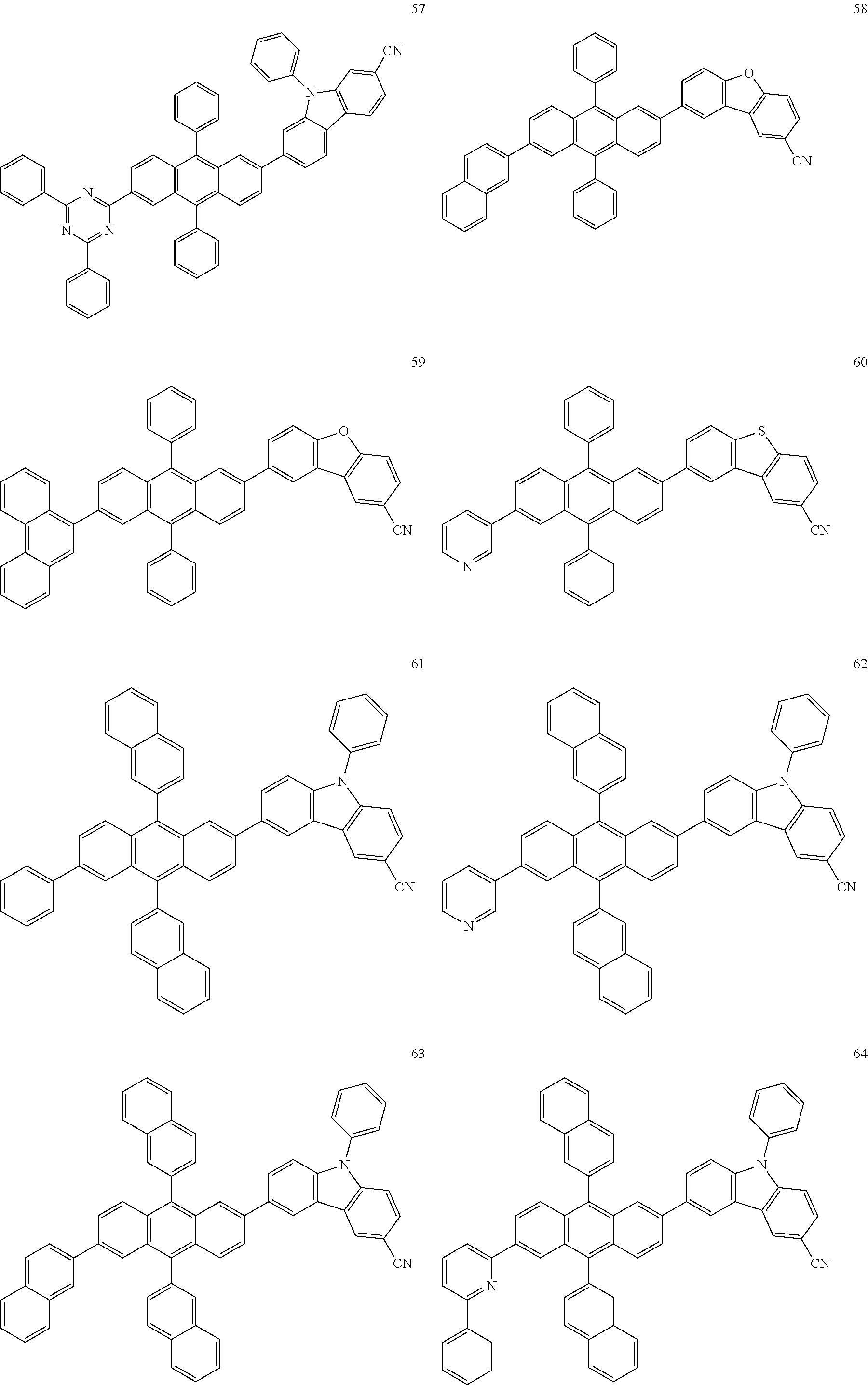

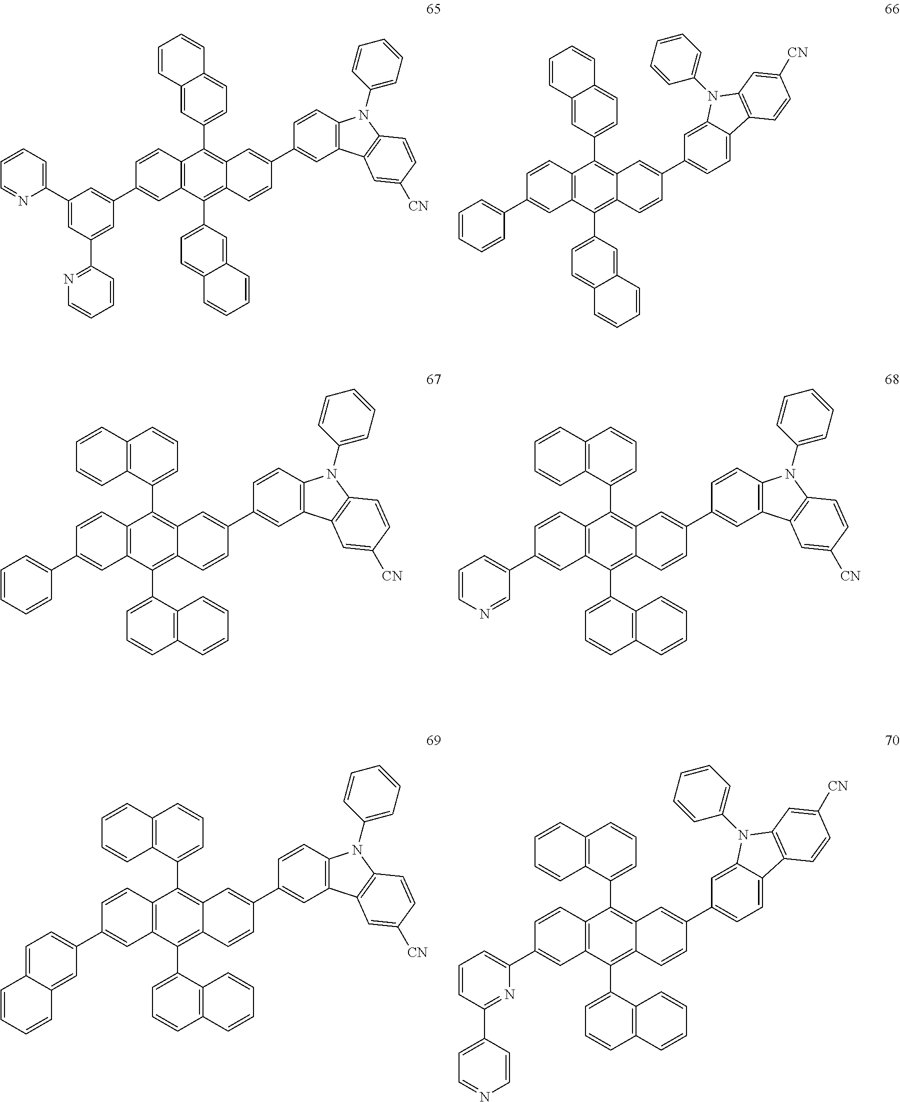

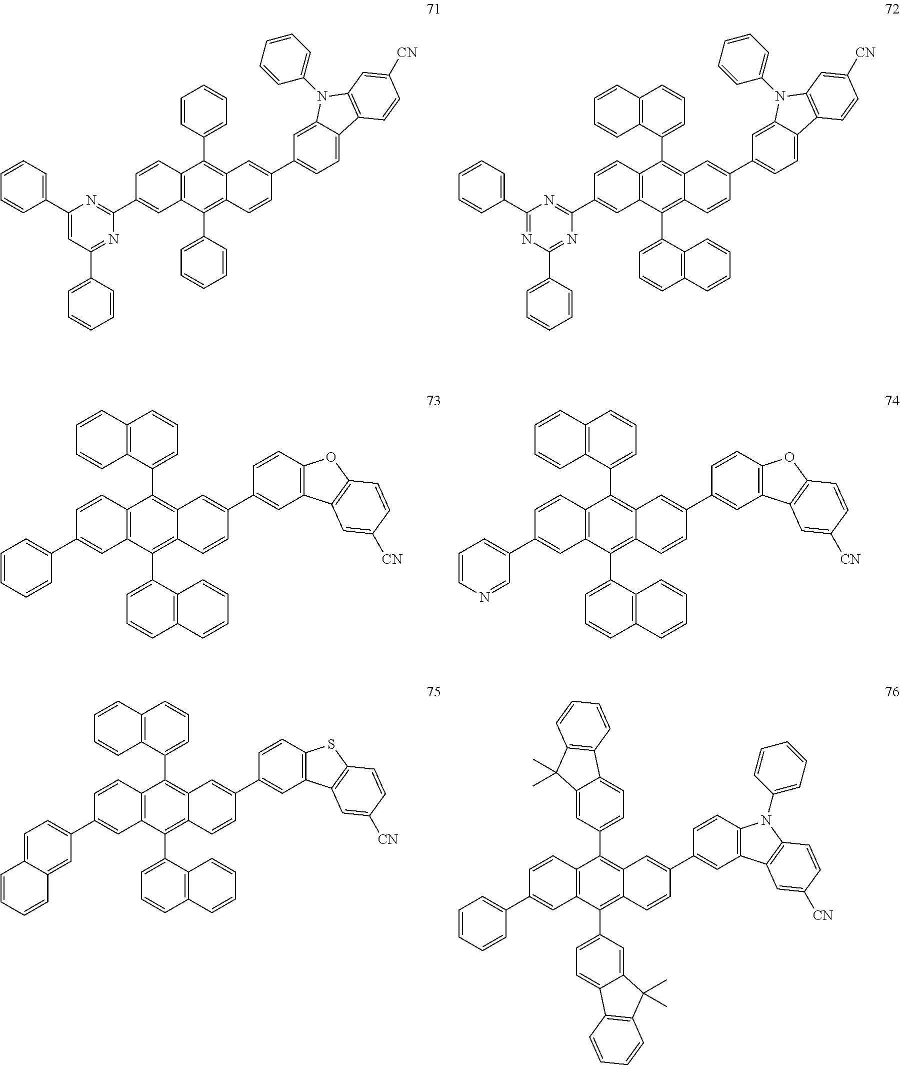

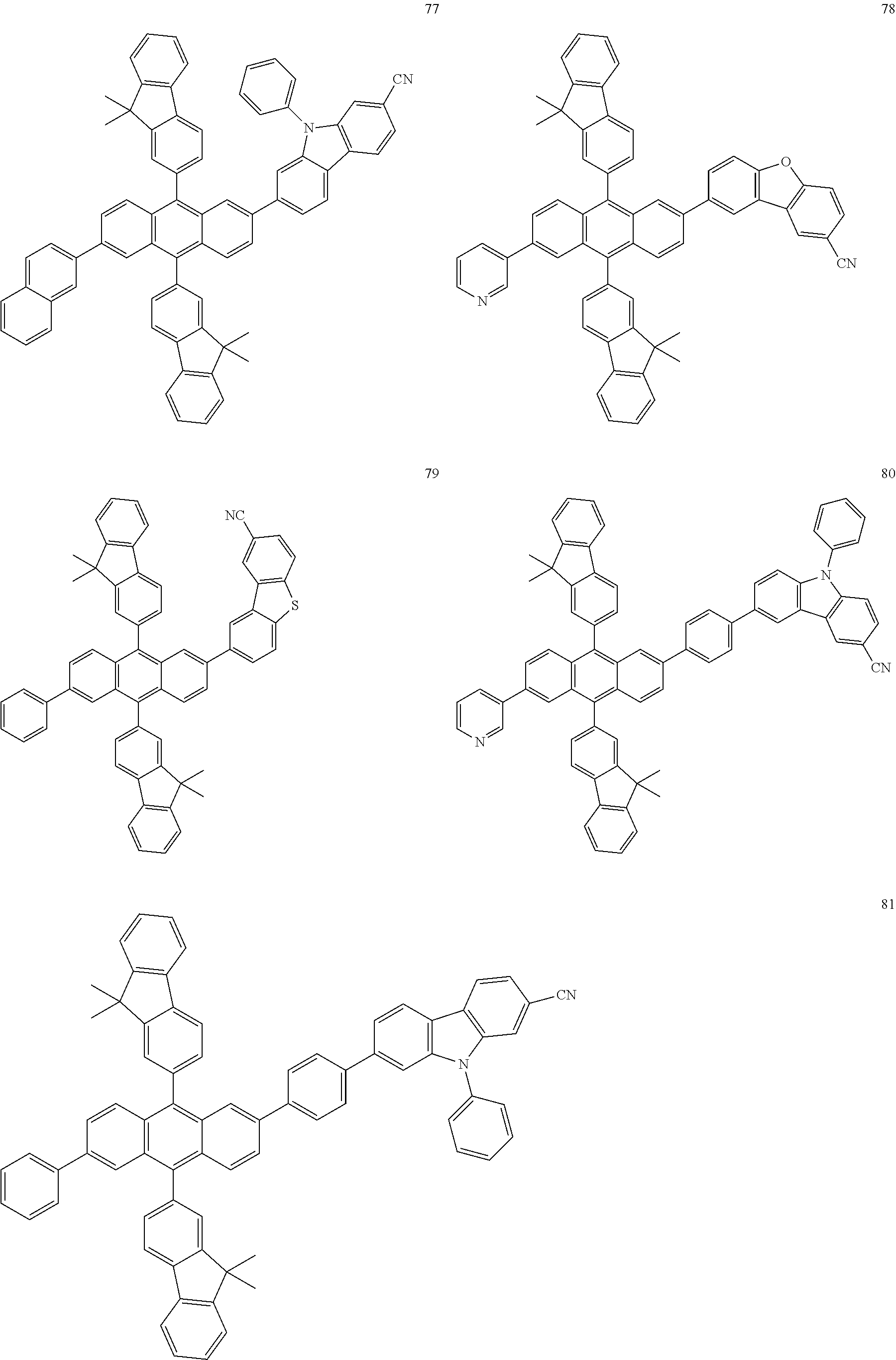

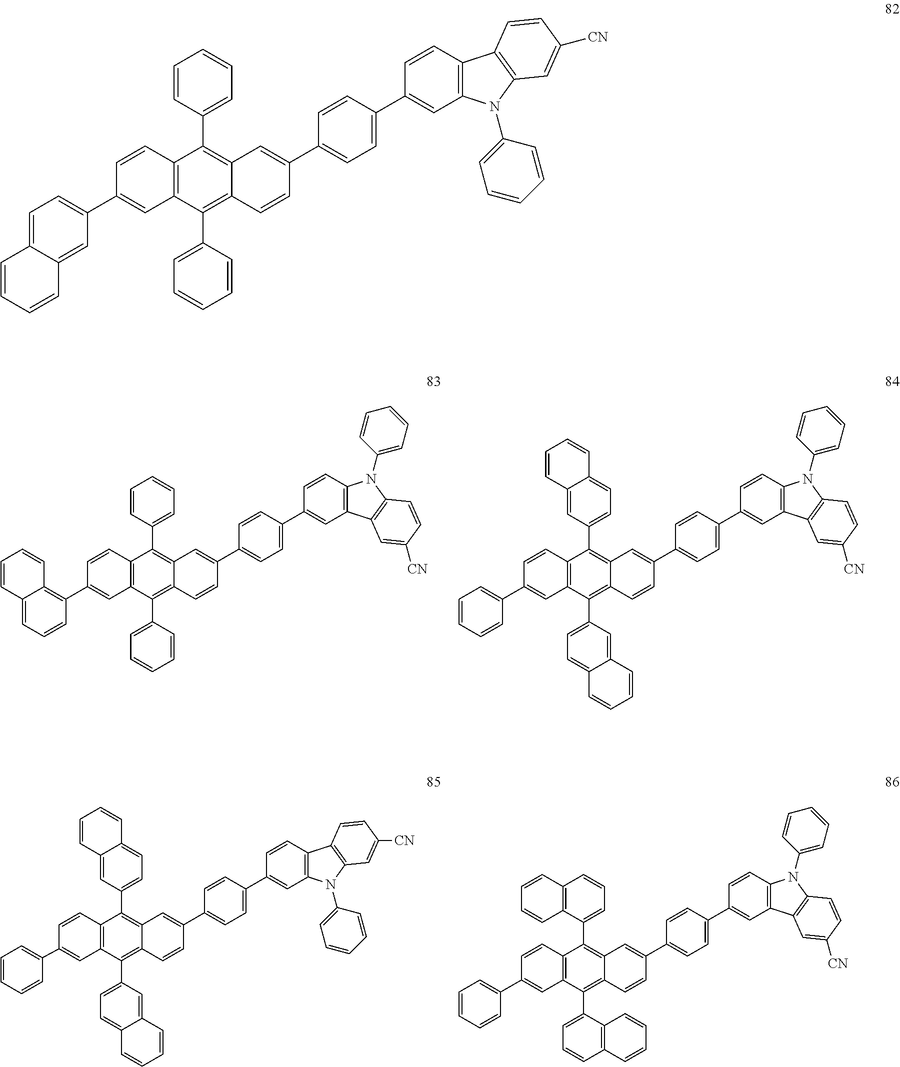

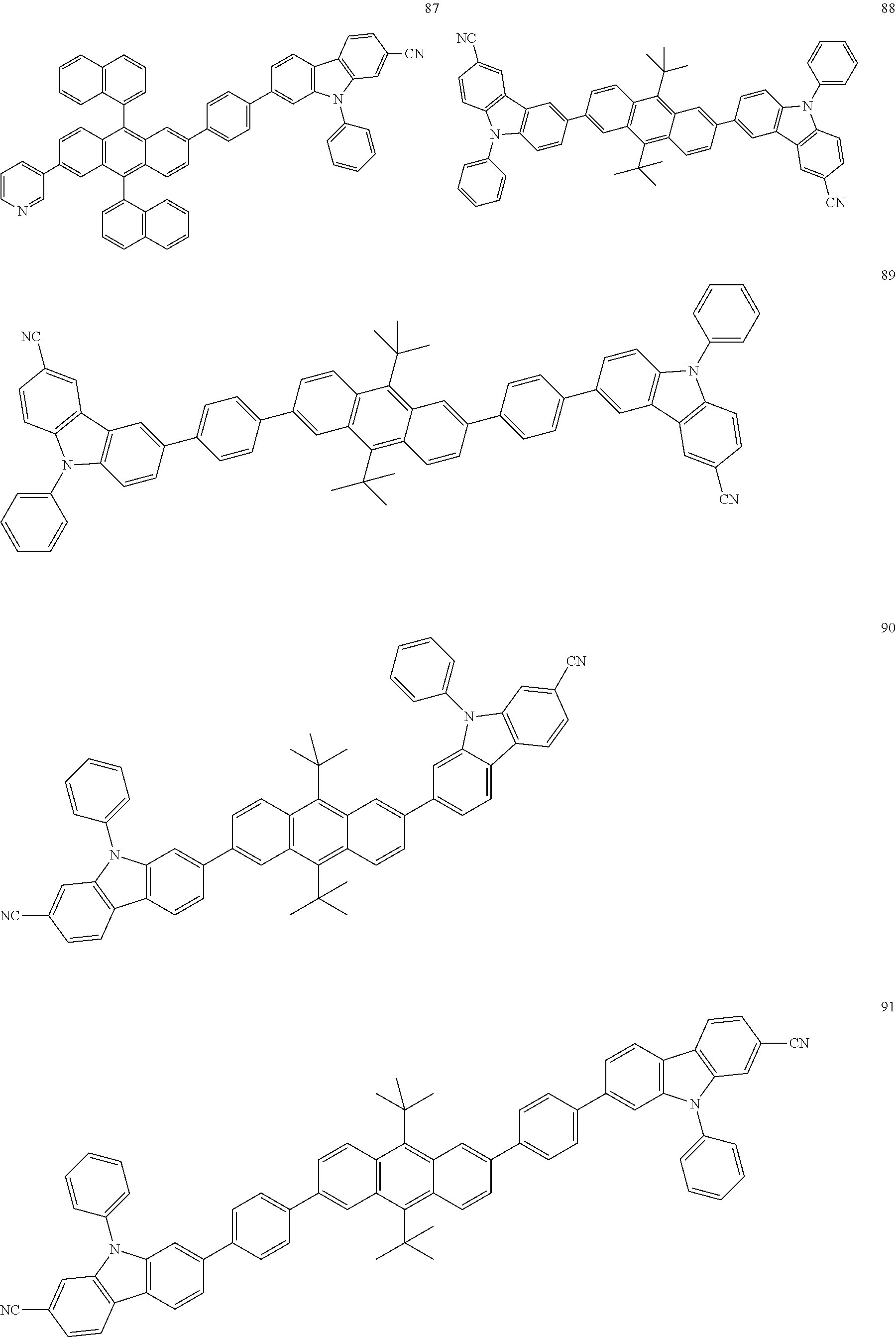

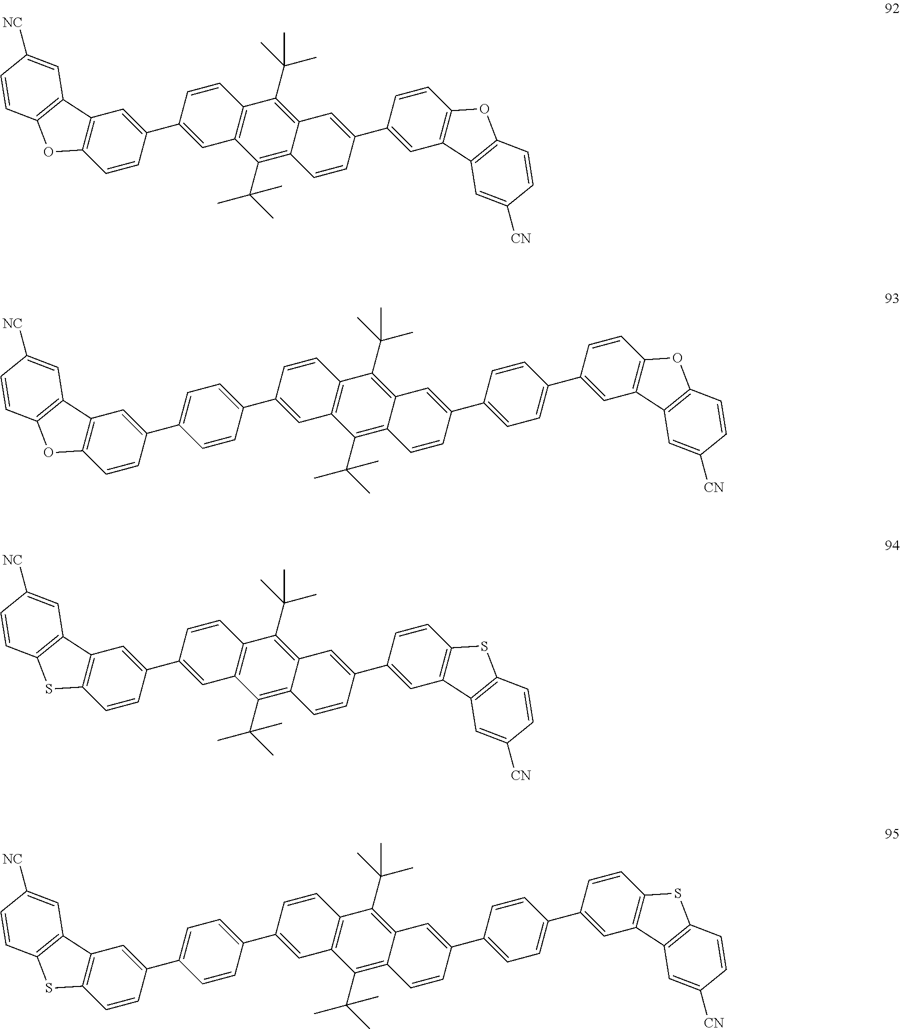 [SMILES: CC(C)(C)c1c2ccc(-c3ccc4oc5ccc(C#N)cc5c4c3)cc2c(C(C)(C)C)c2ccc(-c3ccc4oc5ccc(C#N)cc5c4c3)cc12 ; CC(C)(C)c1c2ccc(-c3ccc(-c4ccc5oc6ccc(C#N)cc6c5c4)cc3)cc2c(C(C)(C)C)c2ccc(-c3ccc(-c4ccc5oc6ccc(C#N)cc6c5c4)cc3)cc12 ; CC(C)(C)c1c2ccc(-c3ccc4sc5ccc(C#N)cc5c4c3)cc2c(C(C)(C)C)c2ccc(-c3ccc4sc5ccc(C#N)cc5c4c3)cc12 ; CC(C)(C)c1c2ccc(-c3ccc(-c4ccc5sc6ccc(C#N)cc6c5c4)cc3)cc2c(C(C)(C)C)c2ccc(-c3ccc(-c4ccc5sc6ccc(C#N)cc6c5c4)cc3)cc12]

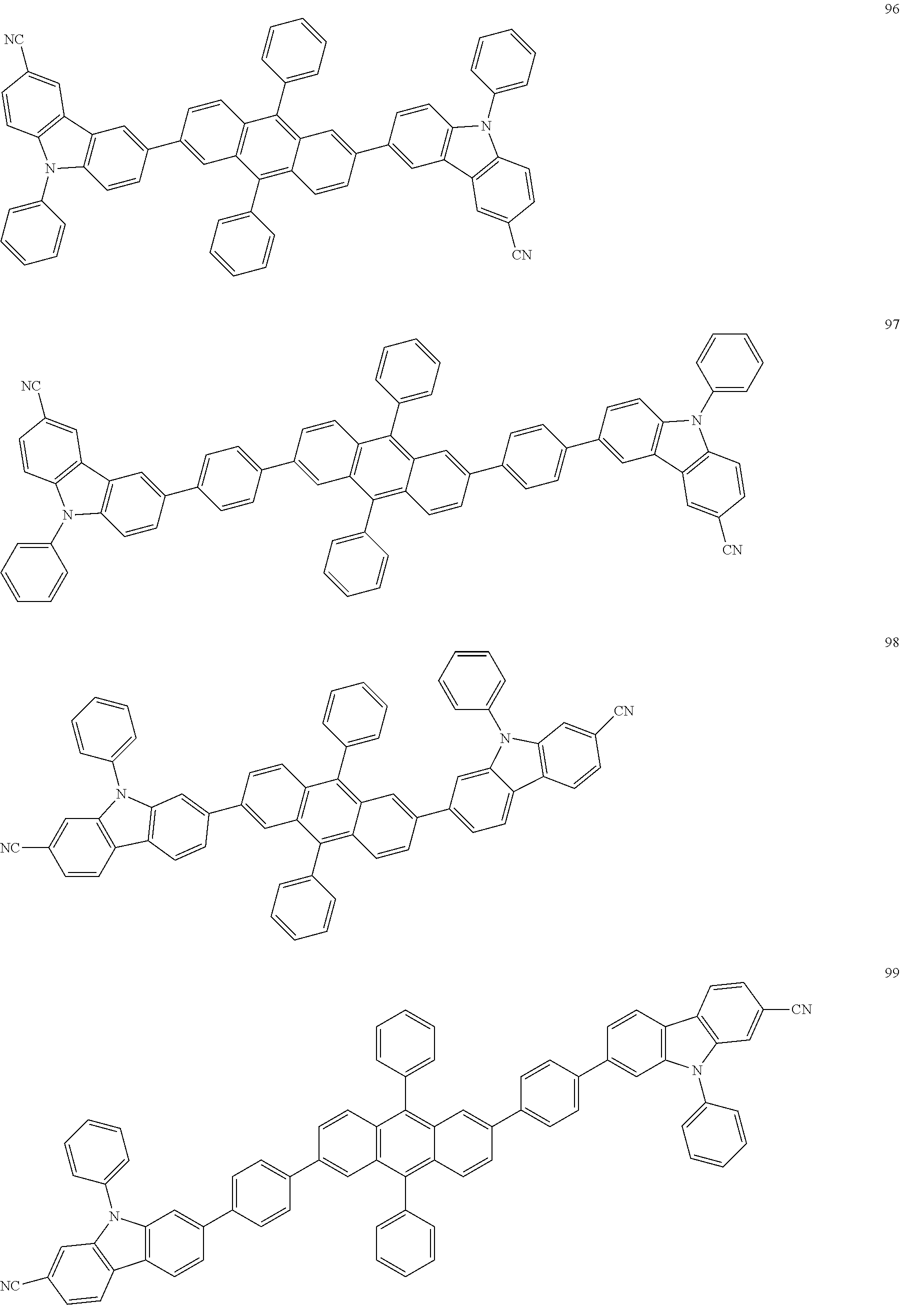

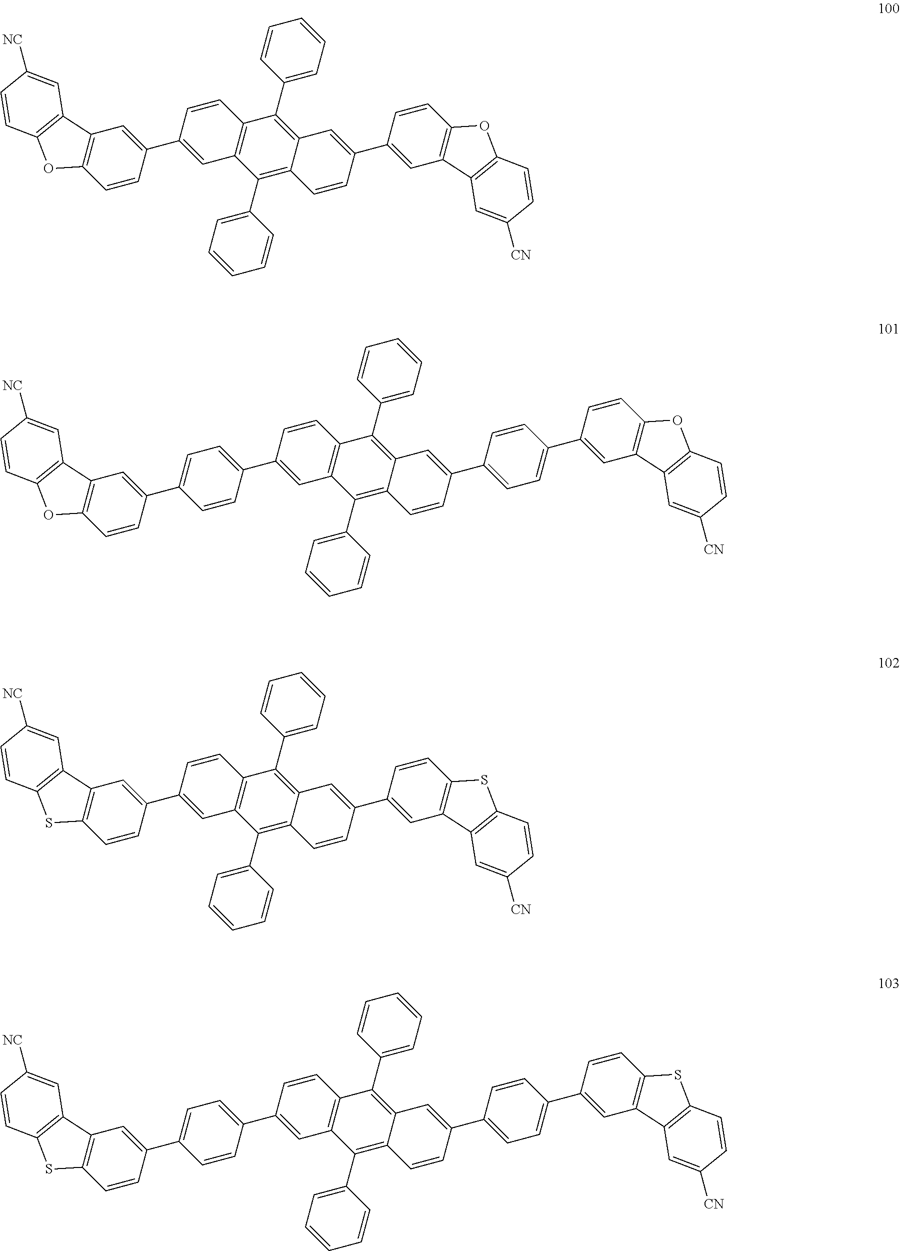 [SMILES: N#Cc1ccc2oc3ccc(-c4ccc5c(-c6ccccc6)c6cc(-c7ccc8oc9ccc(C#N)cc9c8c7)ccc6c(-c6ccccc6)c5c4)cc3c2c1 ; N#Cc1ccc2oc3ccc(-c4ccc(-c5ccc6c(-c7ccccc7)c7cc(-c8ccc(-c9ccc%10oc%11ccc(C#N)cc%11c%10c9)cc8)ccc7c(-c7ccccc7)c6c5)cc4)cc3c2c1 ; N#Cc1ccc2sc3ccc(-c4ccc5c(-c6ccccc6)c6cc(-c7ccc8sc9ccc(C#N)cc9c8c7)ccc6c(-c6ccccc6)c5c4)cc3c2c1 ; N#Cc1ccc2sc3ccc(-c4ccc(-c5ccc6c(-c7ccccc7)c7cc(-c8ccc(-c9ccc%10sc%11ccc(C#N)cc%11c%10c9)cc8)ccc7c(-c7ccccc7)c6c5)cc4)cc3c2c1]

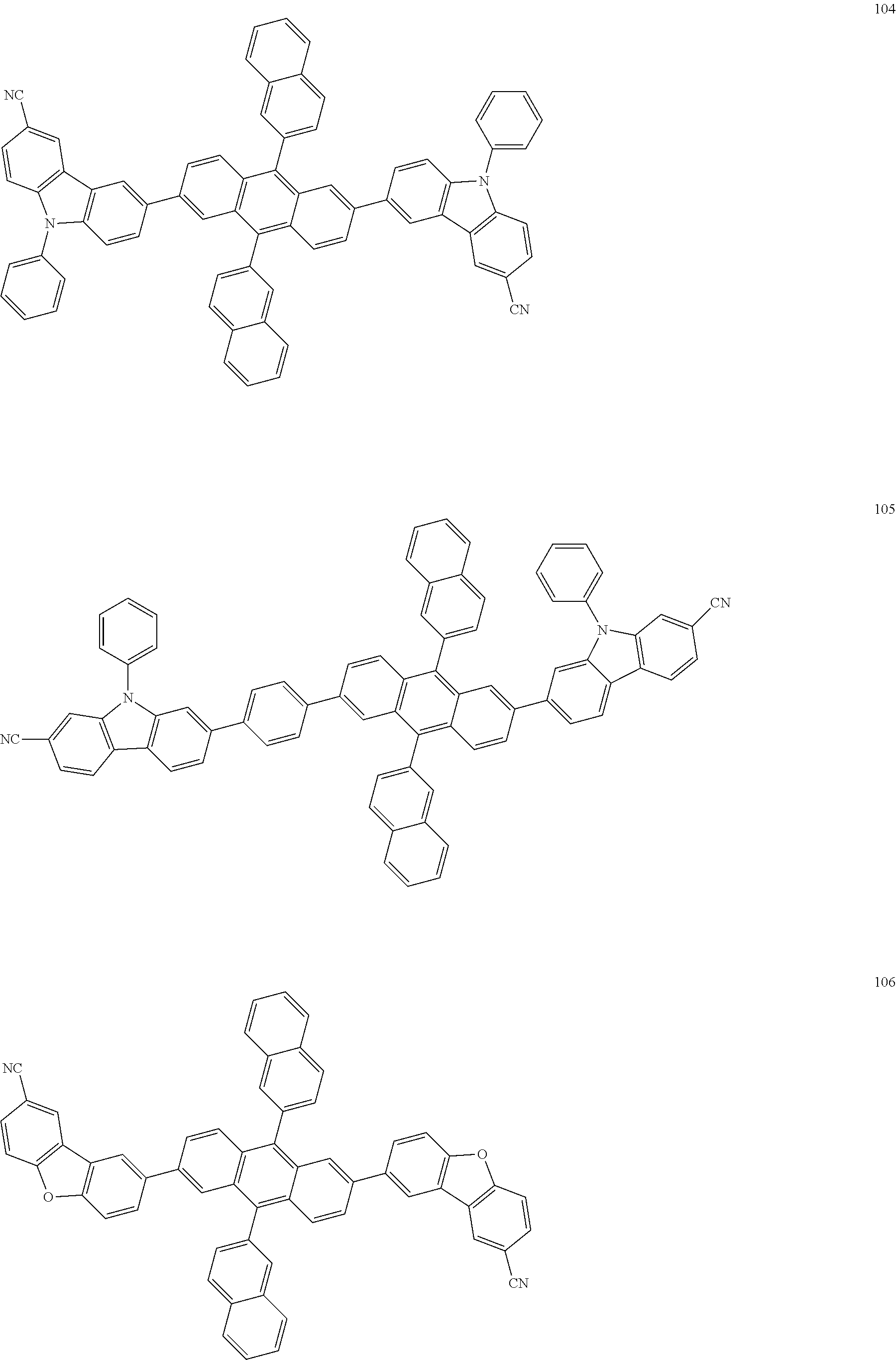 [SMILES: N#Cc1ccc2c(c1)c1cc(-c3ccc4c(-c5ccc6ccccc6c5)c5cc(-c6ccc7c(c6)c6cc(C#N)ccc6n7-c6ccccc6)ccc5c(-c5ccc6ccccc6c5)c4c3)ccc1n2-c1ccccc1 ; N#Cc1ccc2c3ccc(-c4ccc(-c5ccc6c(-c7ccc8ccccc8c7)c7cc(-c8ccc9c%10ccc(C#N)cc%10n(-c%10ccccc%10)c9c8)ccc7c(-c7ccc8ccccc8c7)c6c5)cc4)cc3n(-c3ccccc3)c2c1 ; N#Cc1ccc2oc3ccc(-c4ccc5c(-c6ccc7ccccc7c6)c6cc(-c7ccc8oc9ccc(C#N)cc9c8c7)ccc6c(-c6ccc7ccccc7c6)c5c4)cc3c2c1]

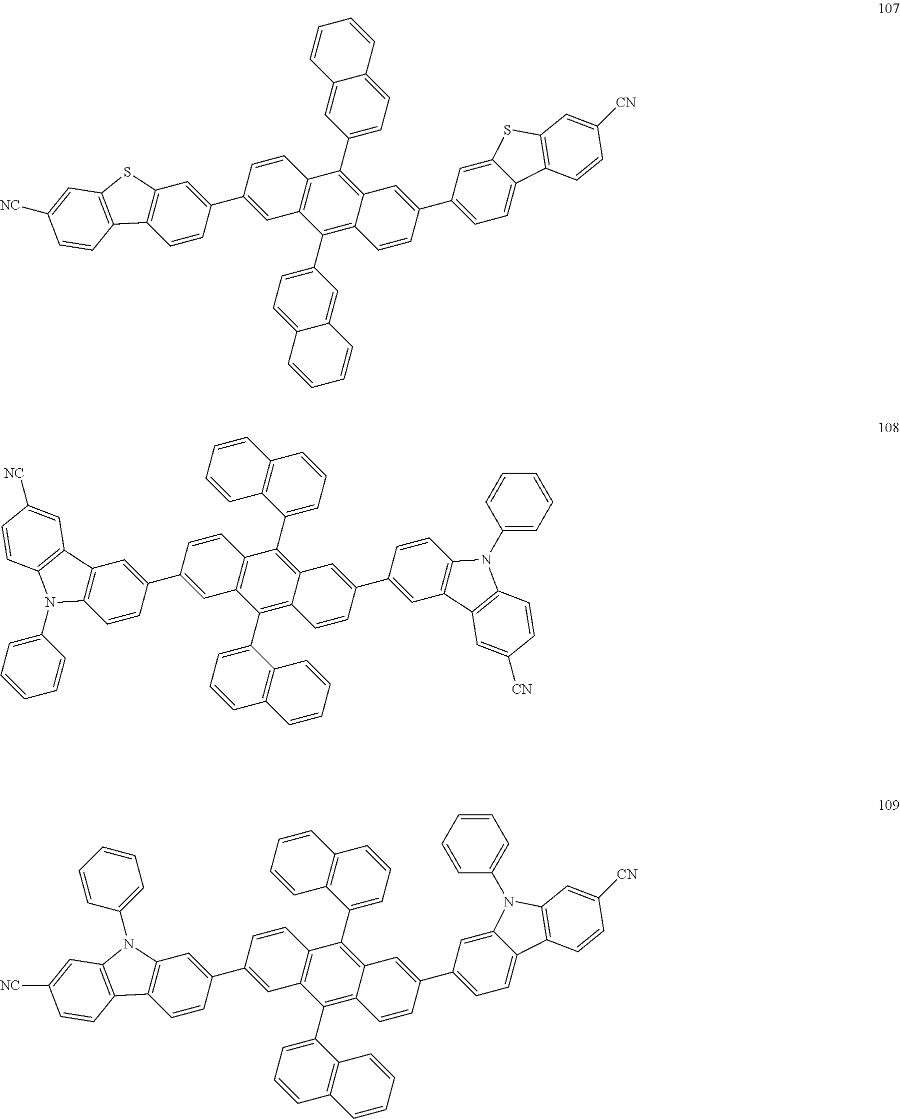 [SMILES: N#Cc1ccc2c(c1)sc1cc(-c3ccc4c(-c5ccc6ccccc6c5)c5cc(-c6ccc7c(c6)sc6cc(C#N)ccc67)ccc5c(-c5ccc6ccccc6c5)c4c3)ccc12 ; N#Cc1ccc2c(c1)c1cc(-c3ccc4c(-c5cccc6ccccc56)c5cc(-c6ccc7c(c6)c6cc(C#N)ccc6n7-c6ccccc6)ccc5c(-c5cccc6ccccc56)c4c3)ccc1n2-c1ccccc1 ; N#Cc1ccc2c3ccc(-c4ccc5c(-c6cccc7ccccc67)c6cc(-c7ccc8c9ccc(C#N)cc9n(-c9ccccc9)c8c7)ccc6c(-c6cccc7ccccc67)c5c4)cc3n(-c3ccccc3)c2c1]

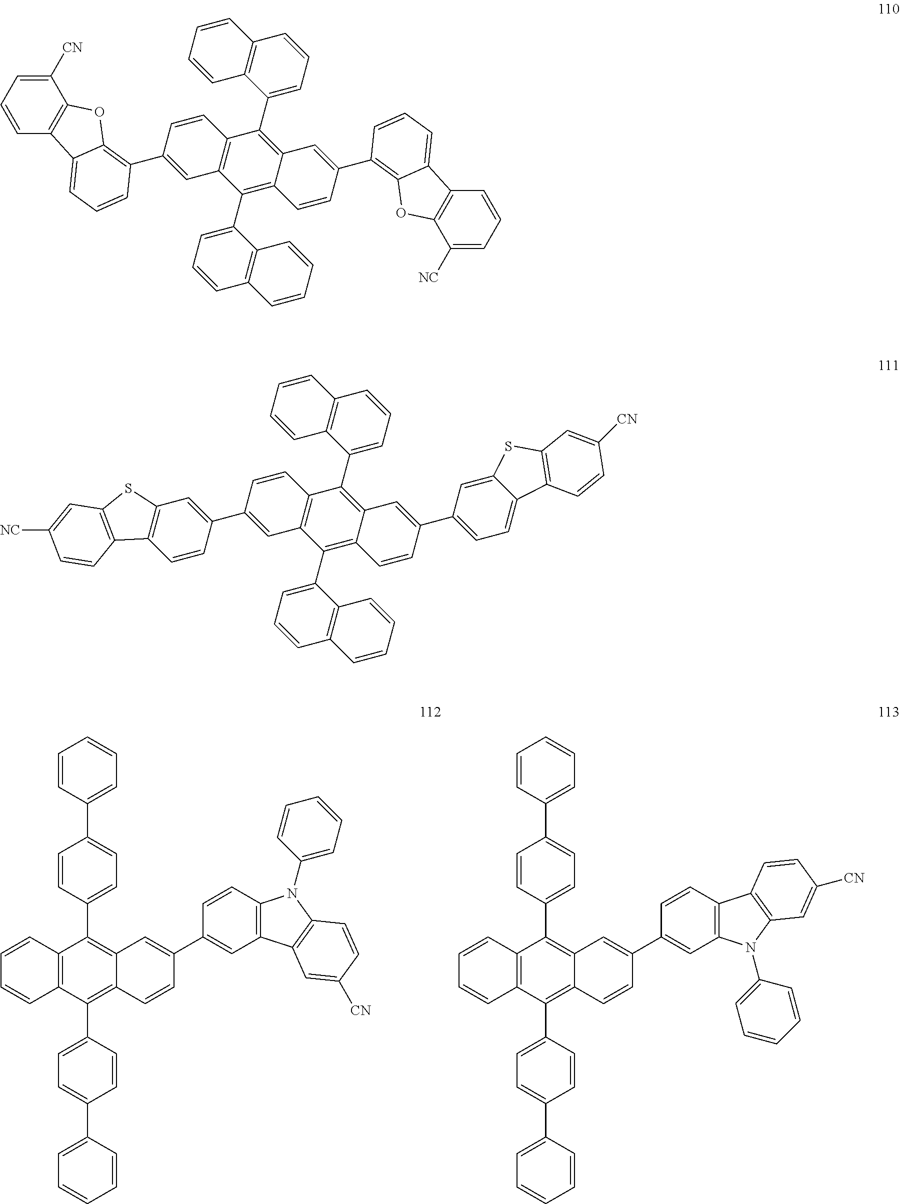 [SMILES: N#Cc1cccc2c1oc1c(-c3ccc4c(-c5cccc6ccccc56)c5cc(-c6cccc7c6oc6c(C#N)cccc67)ccc5c(-c5cccc6ccccc56)c4c3)cccc12 ; N#Cc1ccc2c(c1)sc1cc(-c3ccc4c(-c5cccc6ccccc56)c5cc(-c6ccc7c(c6)sc6cc(C#N)ccc67)ccc5c(-c5cccc6ccccc56)c4c3)ccc12 ; N#Cc1ccc2c(c1)c1cc(-c3ccc4c(-c5ccc(-c6ccccc6)cc5)c5ccccc5c(-c5ccc(-c6ccccc6)cc5)c4c3)ccc1n2-c1ccccc1 ; N#Cc1ccc2c3ccc(-c4ccc5c(-c6ccc(-c7ccccc7)cc6)c6ccccc6c(-c6ccc(-c7ccccc7)cc6)c5c4)cc3n(-c3ccccc3)c2c1]

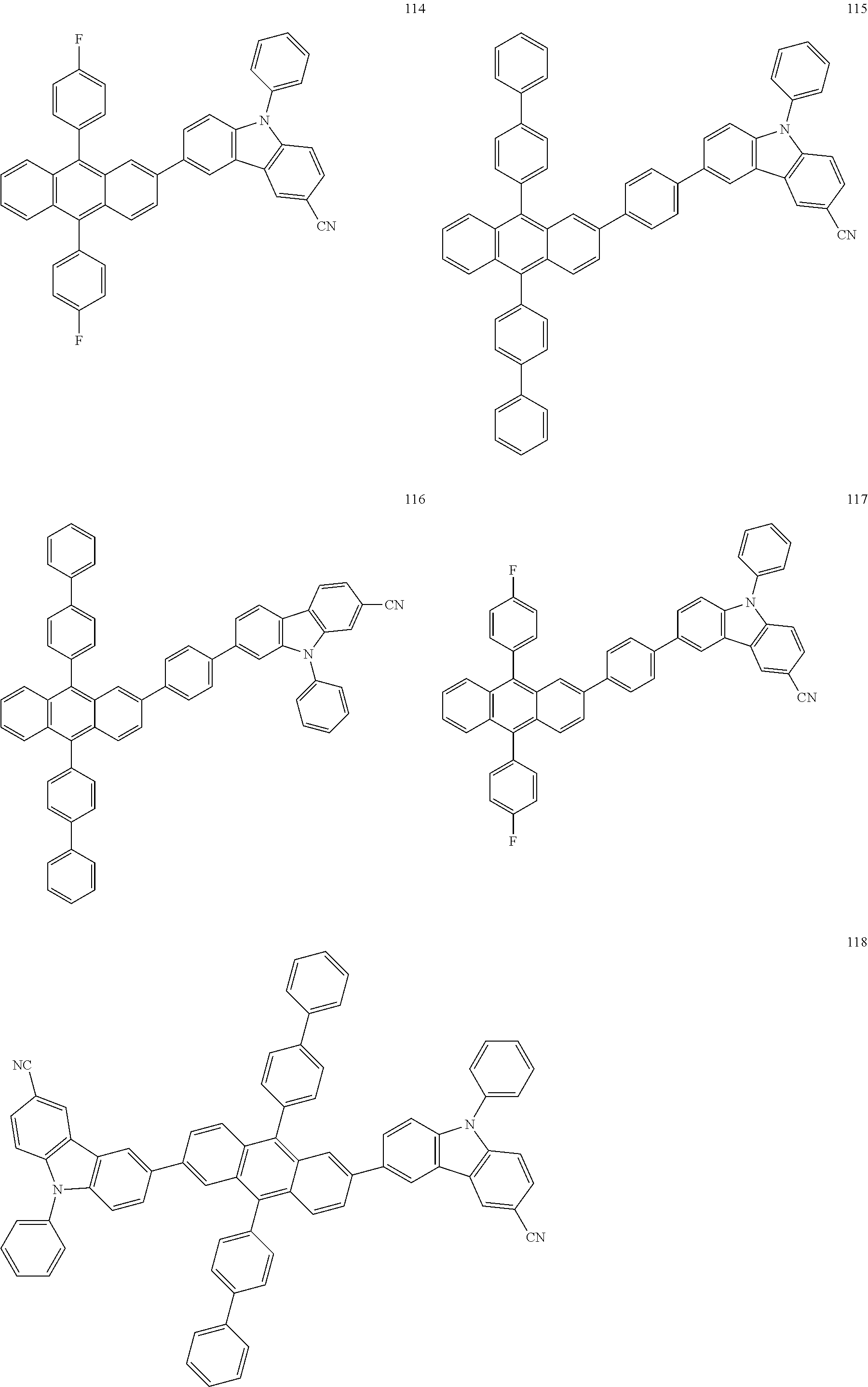

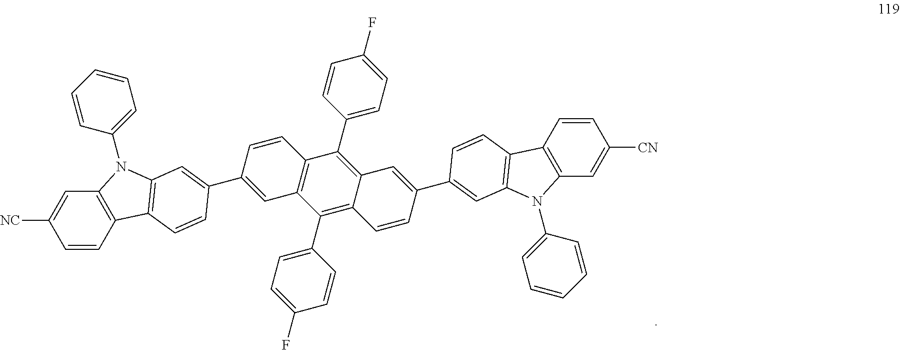 [SMILES: N#Cc1ccc2c3ccc(-c4ccc5c(-c6ccc(F)cc6)c6cc(-c7ccc8c9ccc(C#N)cc9n(-c9ccccc9)c8c7)ccc6c(-c6ccc(F)cc6)c5c4)cc3n(-c3ccccc3)c2c1]

16. An organic light-emitting diode comprising: a first electrode; a second electrode facing the first electrode; and an organic layer that is disposed between the first and second electrodes and includes an emission layer, wherein the organic layer includes at least one condensed compound as claimed in claim 1.

17. The organic light-emitting diode as claimed in claim 16, wherein the organic layer includes:
a hole transport region that is disposed between the first electrode and the emission layer and includes at least one of a hole injection layer, a hole transport layer, a buffer layer, and an electron blocking layer, and
an electron transport region, that is disposed between the emission layer and the second electrode and includes at least one selected from a hole blocking layer, an electron transport layer, and an electron injection layer.

18. The organic light-emitting diode as claimed in claim 17, wherein the electron transport region includes the condensed compound.

19. The organic light-emitting diode as claimed in claim 18, wherein:
the electron transport region includes an electron transport layer, and
the electron transport layer includes the condensed compound.

20. The organic light-emitting diode as claimed in claim 17, wherein:
the hole transport region includes at least one of a compound represented by Formula 201A and a compound represented by Formula 202A: 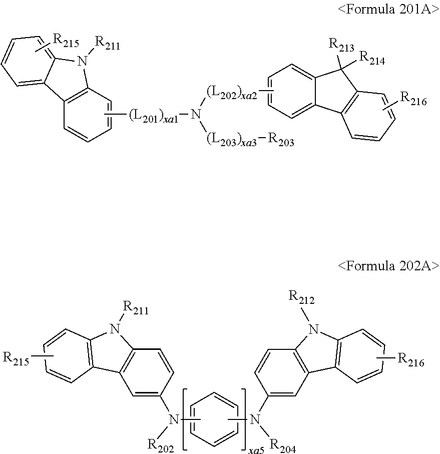
L₂₀₁ to L₂₀₃ are each independently selected from
a phenylene group, a naphthylene group, a fluorenylene group, a spiro-fluorenylene group, a benzofluorenylene group, a dibenzofluorenylene group, a phenanthrenylene group, an anthracenylene group, a pyrenylene group, a chrysenylene group, a pyridinylene group, a pyrazinylene group, a pyrimidinylene group, a pyridazinylene group, a quinolinylene group, an isoquinolinylene group, a quinoxalinylene group, a quinazolinylene group, a carbazolylene group and a triazinylene group; and
a phenylene group, a naphthylene group, a fluorenylene group, a spiro-fluorenylene group, a benzofluoenylene group, a dibenzofluoenylene group, a phenanthrenylene group, an anthracenylene group, a pyrenylene group, a chrysenylene group, a pyridinylene group, a pyrazinylene group, a pyrimidinylene group, a pyridazinylene group, a quinolinylene group, an isoquinolinylene group, a quinoxalinylene group, a quinazolinylene group, a carbazolylene group and a triazinylene group, each substituted with at least one selected from a deuterium, —F, —Cl, —Br, —I, a hydroxyl group, a cyano group, a nitro group, an amino group, an amidino group, a hydrazine group, a hydrazone group, a carboxylic acid and a salt thereof, a sulfonic acid and a salt thereof, a phosphoric acid and a salt thereof, a C₁-C₂₀ alkyl group, a C₁-C₂₀ alkoxy group, a phenyl group, a naphthyl group, a fluorenyl group, a spiro-fluorenyl group, a benzofluorenyl group, a dibenzofluorenyl group, a phenanthrenyl group, an anthracenyl group, a pyrenyl group, a chrysenyl group, a pyridinyl group, a pyrazinyl group, a pyrimidinyl group, a pyridazinyl group, a quinolinyl group, an isoindolyl group, a quinoxalinyl group, a quinazolinyl group, a carbazolyl group and a triazinyl group;
xa1 to xa3 may each independently 0 or 1;
R₂₀₃, R₂₁₁, and R₂₁₂ are each independently selected from
a phenyl group, a naphthyl group, a fluorenyl group, a spiro-fluorenyl group, a benzofluorenyl group, a dibenzofluorenyl group, a phenanthrenyl group, an anthracenyl group, a pyrenyl group, a chrysenyl group, a pyridinyl group, a pyrazinyl group, a pyrimidinyl group, a pyridazinyl group, a quinolinyl group, an isoquinolinyl group, a quinoxalinyl group, a quinazolinyl group, a carbazolyl group and a triazinyl group; and
a phenyl group, a naphthyl group, a fluorenyl group, a spiro-fluorenyl group, a benzofluorenyl group, a dibenzofluorenyl group, a phenanthrenyl group, an anthracenyl group, a pyrenyl group, a chrysenyl group, a pyridinyl group, a pyrazinyl group, a pyrimidinyl group, a pyridazinyl group, a quinolinyl group, an isoquinolinyl group, a quinoxalinyl group, a quinazolinyl group, a carbazolyl group and a triazinyl group, each substituted with at least one selected from a deuterium, —F, —Cl, —Br, —I, a hydroxyl group, a cyano group, a nitro group, an amino group, an amidino group, a hydrazine group, a hydrazone group, a carboxylic acid and a salt thereof, a sulfonic acid and a salt thereof, a phosphoric acid and a salt thereof, a C₁-C₂₀ alkyl group, a C₁-C₂₀ alkoxy group, a phenyl group, a naphthyl group, a fluorenyl group, a spiro-fluorenyl group, a benzofluorenyl group, a dibenzofluorenyl group, a phenanthrenyl group, an anthracenyl group, a pyrenyl group, a chrysenyl group, a pyridinyl group, a pyrazinyl group, a pyrimidinyl group, a pyridazinyl group, a quinolinyl group, an isoquinolinyl group, a quinoxalinyl group, a quinazolinyl group, a carbazolyl group and a triazinyl group;
R₂₁₃ and R₂₁₄ are each independently selected from
a C₁-C₂₀ alkyl group and a C₁-C₂₀ alkoxy group;
a C₁-C₂₀ alkyl group and a C₁-C₂₀ alkoxy group, each substituted with at least one selected from a deuterium, —F, —Cl, —Br, —I, a hydroxyl group, a cyano group, a nitro group, an amino group, an amidino group, a hydrazine group, a hydrazone group, a carboxylic acid and a salt thereof, a sulfonic acid and a salt thereof, a phosphoric acid and a salt thereof, a phenyl group, a naphthyl group, a fluorenyl group, a spiro-fluorenyl group, a benzofluorenyl group, a dibenzofluorenyl group, a phenanthrenyl group, an anthracenyl group, a pyrenyl group, a chrysenyl group, a pyridinyl group, a pyrazinyl group, a pyrimidinyl group, a pyridazinyl group, a quinolinyl group, an isoquinolinyl group, a quinoxalinyl group, a quinazolinyl group, a carbazolyl group and a triazinyl group;
a phenyl group, a naphthyl group, a fluorenyl group, a spiro-fluorenyl group, a benzofluorenyl group, a dibenzofluorenyl group, a phenanthrenyl group, an anthracenyl group, a pyrenyl group, a chrysenyl group, a pyridinyl group, a pyrazinyl group, a pyrimidinyl group, a pyridazinyl group, a quinolinyl group, an isoquinolinyl group, a quinoxalinyl group, a quinazolinyl group, a carbazolyl group and a triazinyl group; and
a phenyl group, a naphthyl group, a fluorenyl group, a spiro-fluorenyl group, a benzofluorenyl group, a dibenzofluorenyl group, a phenanthrenyl group, an anthracenyl group, a pyrenyl group, a chrysenyl group, a pyridinyl group, a pyrazinyl group, a pyrimidinyl group, a pyridazinyl group, a quinolinyl group, an isoquinolinyl group, a quinoxalinyl group, a quinazolinyl group, a carbazolyl group and a triazinyl group, each substituted with at least one selected from a deuterium, —F, —Cl, —Br, —I, a hydroxyl group, a cyano group, a nitro group, an amino group, an amidino group, a hydrazine group, a hydrazone group, a carboxylic acid and a salt thereof, a sulfonic acid and a salt thereof, a phosphoric acid and a salt thereof, a C₁-C₂₀ alkyl group, a C₁-C₂₀ alkoxy group, a phenyl group, a naphthyl group, a fluorenyl group, a spiro-fluorenyl group, a benzofluorenyl group, a dibenzofluorenyl group, a phenanthrenyl group, an anthracenyl group, a pyrenyl group, a chrysenyl group, a pyridinyl group, a pyrazinyl group, a pyrimidinyl group, a pyridazinyl group, a quinolinyl group, an isoquinolinyl group, a quinoxalinyl group, a quinazolinyl group, a carbazolyl group and a triazinyl group; and
R₂₁₅ and R₂₁₆ are each independently selected from
a hydrogen, a deuterium, —F, —Cl, —Br, —I, a hydroxyl group, a cyano group, a nitro group, an amino group, an amidino group, a hydrazine group, a hydrazone group, a carboxylic acid and a salt thereof, a sulfonic acid and a salt thereof, a phosphoric acid and a salt thereof,
a C₁-C₂₀ alkyl group, a C₁-C₂₀ alkoxy group;
a C₁-C₂₀ alkyl group and a C₁-C₂₀ alkoxy group, each substituted with at least one selected from a deuterium, —F, —Cl, —Br, —I, a hydroxyl group, a cyano group, a nitro group, an amino group, an amidino group, a hydrazine group, a hydrazone group, a carboxylic acid and a salt thereof, a sulfonic acid and a salt thereof, a phosphoric acid and a salt thereof, a phenyl group, a naphthyl group, a fluorenyl group, a spiro-fluorenyl group, a benzofluorenyl group, a dibenzofluorenyl group, a phenanthrenyl group, an anthracenyl group, a pyrenyl group, a chrysenyl group, a pyridinyl group, a pyrazinyl group, a pyrimidinyl group, a pyridazinyl group, a quinolinyl group, an isoquinolinyl group, a quinoxalinyl group, a quinazolinyl group, a carbazolyl group and a triazinyl group;
a phenyl group, a naphthyl group, a fluorenyl group, a spiro-fluorenyl group, a benzofluorenyl group, a dibenzofluorenyl group, a phenanthrenyl group, an anthracenyl group, a pyrenyl group, a chrysenyl group, a pyridinyl group, a pyrazinyl group, a pyrimidinyl group, a pyridazinyl group, a quinolinyl group, an isoquinolinyl group, a quinoxalinyl group, a quinazolinyl group, a carbazolyl group and a triazinyl group; and
a phenyl group, a naphthyl group, a fluorenyl group, a spiro-fluorenyl group, a benzofluorenyl group, a dibenzofluorenyl group, a phenanthrenyl group, an anthracenyl group, a pyrenyl group, a chrysenyl group, a pyridinyl group, a pyrazinyl group, a pyrimidinyl group, a pyridazinyl group, a quinolinyl group, an isoquinolinyl group, a quinoxalinyl group, a quinazolinyl group, a carbazolyl group and a triazinyl group, each substituted with at least one selected from a deuterium, —F, —Cl, —Br, —I, a hydroxyl group, a cyano group, a nitro group, an amino group, an amidino group, a hydrazine group, a hydrazone group, a carboxylic acid and a salt thereof, a sulfonic acid and a salt thereof, a phosphoric acid and a salt thereof, a C₁-C₂₀ alkyl group, a C₁-C₂₀ alkoxy group, a phenyl group, a naphthyl group, a fluorenyl group, a spiro-fluorenyl group, a benzofluorenyl group, a dibenzofluorenyl group, a phenanthrenyl group, an anthracenyl group, a pyrenyl group, a chrysenyl group, a pyridinyl group, a pyrazinyl group, a pyrimidinyl group, a pyridazinyl group, a quinolinyl group, an isoquinolinyl group, a quinoxalinyl group, a quinazolinyl group, a carbazolyl group and a triazinyl group; and
xa5 1 or 2.
